(19) United States
(12) Patent Application Publication
(10) Pub. No.: US 2026/0026183 A1
(43) Pub. Date: Jan. 22, 2026

(54) Light-Emitting Device

(71) Applicant: Semiconductor Energy Laboratory Co., Ltd., Kanagawa-ken (JP)

(72) Inventors: Takeyoshi WATABE, Atsugi (JP); Keito TOSU, Atsugi (JP); Hiromi SEO, Sagamihara (JP); Nobuharu OHSAWA, Zama (JP)

(73) Assignee: Semiconductor Energy Laboratory Co., Ltd., Kanagawa-ken (JP)

(21) Appl. No.: 19/267,028

(22) Filed: Jul. 11, 2025

(30) Foreign Application Priority Data
Jul. 19, 2024 (JP) 2024-115982

(51) Int. Cl. H10K 50/11; C09K 11/02; H10K 85/60; H10K 101/00; H10K 101/40; H10K 102/00

(52) U.S. Cl. CPC H10K 50/11; C09K 11/02; H10K 85/654; H10K 85/657; H10K 85/6572; H10K 85/6574; H10K 2101/40; H10K 2101/90; H10K 2102/311

(57) ABSTRACT

A light-emitting device includes a first electrode, a second electrode, a light-emitting layer, a first layer, and a second layer. The first electrode is over a substrate and is between the second electrode and the substrate. The light-emitting layer is between the first electrode and the second electrode. The first layer is between the first electrode and the light-emitting layer. The second layer is between the second electrode and the light-emitting layer. One of the first electrode and the second electrode is an anode and the other is a cathode. A GSP slope (mV/nm) of one of the light-emitting layer and the first layer closer to the cathode is larger than a GSP slope (mV/nm) of the other closer to the anode. A GSP slope (mV/nm) of one of the light-emitting layer and the second layer closer to the anode is larger than a GSP slope (mV/nm) of the other closer to the cathode.

### BACKGROUND OF THE INVENTION

### 1. Field of the Invention

One embodiment of the present invention relates to an organic compound, an organic semiconductor element, a light-emitting element, an organic EL element, a photodiode, a display module, a lighting module, a display device, a light-emitting apparatus, an electronic appliance, a lighting device, and an electronic device. Note that one embodiment of the present invention is not limited to the above technical field. The technical field of one embodiment of the invention disclosed in this specification and the like relates to an object, a method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display device, a liquid crystal display device, a light-emitting apparatus, a lighting device, a power storage device, a memory device, an image capturing device, a driving method thereof, and a manufacturing method thereof.

### 2. Description of the Related Art

Light-emitting devices (organic EL elements) including organic compounds and utilizing electroluminescence (EL) have been put into more practical use. In the basic structure of such organic EL elements, an organic compound layer containing a light-emitting material (an EL layer) is sandwiched between a pair of electrodes. Carriers are injected by application of voltage to the device, and recombination energy of the carriers is used, whereby light emission can be obtained from the light-emitting material.

Such organic EL elements are of self-luminous type and thus have advantages over liquid crystal displays, such as high visibility and no need for backlight when used as pixels of a display, and are particularly suitable for flat panel displays. Displays including such organic EL elements are also highly advantageous in that they can be thin and lightweight. Another feature of such organic EL elements is that they have an extremely fast response speed.

Since light-emitting layers of such organic EL elements can be formed as continuous planar layers, planar light emission can be achieved. This feature is difficult to realize with point light sources typified by incandescent lamps and LEDs or linear light sources typified by fluorescent lamps; thus, such organic EL elements also have great potential as planar light sources, which can be used for lighting devices and the like.

Displays or lighting devices including organic EL elements are suitable for a variety of electronic appliances as described above, and research and development of organic EL elements have progressed for more favorable characteristics (see Non-Patent Document 1, for example).

### REFERENCE

[Non-Patent Document 1] Y. Noguchi et al., “Spontaneous Orientation Polarization of Polar Molecules and Interface Properties of Organic Electronic Devices”, Journal of the Vacuum Society of Japan, 2015, Vol. 58, No. 3.

### SUMMARY OF THE INVENTION

An object of one embodiment of the present invention is to provide a light-emitting device having a low driving voltage. Another object of one embodiment of the present invention is to provide a light-emitting device having high emission efficiency. Another object of one embodiment of the present invention is to provide any of a light-emitting apparatus, an electronic appliance, and a display device each having low power consumption.

Note that the description of these objects does not preclude the existence of other objects. In one embodiment of the present invention, there is no need to achieve all of these objects. Other objects will be apparent from and can be derived from the description of the specification, the drawings, the claims, and the like.

In one embodiment of the present invention, organic compounds used for layers of an organic compound layer are selected such that a parameter representing the level of the giant surface potential (GSP), a GSP slope (mV/nm), of a light-emitting layer is larger in an ordered stacked light-emitting device and smaller in an inverted stacked light-emitting device than GSP slopes (mV/nm) of carrier-transport layers sandwiching the light-emitting layer. Accordingly, an electric field can be applied to the light-emitting layer effectively.

That is, one embodiment of the present invention is a light-emitting device including a first electrode, a second electrode, a light-emitting layer, a first layer, and a second layer. The first electrode is formed over a substrate and is between the second electrode and the substrate. The light-emitting layer is between the first electrode and the second electrode. The first layer is between the first electrode and the light-emitting layer. The second layer is between the second electrode and the light-emitting layer. One of the first electrode and the second electrode is an anode and the other is a cathode. A GSP slope (mV/nm) of one of the light-emitting layer and the first layer closer to the cathode is larger than a GSP slope (mV/nm) of the other closer to the anode. A GSP slope (mV/nm) of one of the light-emitting layer and the second layer closer to the anode is larger than a GSP slope (mV/nm) of the other closer to the cathode. The GSP slope (mV/nm) is a parameter represented by ΔV/Δd, where ΔV (mV) is an amount of change in a surface potential with respect to an amount of change in a thickness Δd (nm).

Another embodiment of the present invention is a light-emitting device including a first electrode, a second electrode, a light-emitting layer, a first layer, and a second layer. The first electrode is electrically connected to a transistor. The light-emitting layer is between the first electrode and the second electrode. The first layer is between the first electrode and the light-emitting layer. The second layer is between the second electrode and the light-emitting layer. One of the first electrode and the second electrode is an anode and the other is a cathode. A GSP slope (mV/nm) of one of the light-emitting layer and the first layer closer to the cathode is larger than a GSP slope (mV/nm) of the other closer to the anode. A GSP slope (mV/nm) of one of the light-emitting layer and the second layer closer to the anode is larger than a GSP slope (mV/nm) of the other closer to the cathode. The GSP slope (mV/nm) is a parameter represented by ΔV/Δd, where ΔV (mV) is an amount of change in a surface potential with respect to an amount of change in a thickness Δd (nm).

Another embodiment of the present invention is a light-emitting device including a first electrode, a second electrode, a light-emitting layer, a first layer, and a second layer. The first electrode is partly covered with an insulator. The light-emitting layer is between the first electrode and the second electrode. The first layer is between the first electrode and the light-emitting layer. The second layer is between the second electrode and the light-emitting layer.

One of the first electrode and the second electrode is an anode and the other is a cathode. A GSP slope (mV/nm) of one of the light-emitting layer and the first layer closer to the cathode is larger than a GSP slope (mV/nm) of the other closer to the anode. A GSP slope (mV/nm) of one of the light-emitting layer and the second layer closer to the anode is larger than a GSP slope (mV/nm) of the other closer to the cathode. The GSP slope (mV/nm) is a parameter represented by ΔV/Δd, where ΔV (mV) is an amount of change in a surface potential with respect to an amount of change in a thickness Δd (nm).

Another embodiment of the present invention is a light-emitting device including a first electrode, a second electrode, a light-emitting layer, a first layer, and a second layer. The first electrode is formed over an insulating film and is between the second electrode and the insulating film. An external connection electrode is over the insulating film. The light-emitting layer is between the first electrode and the second electrode. The first layer is between the first electrode and the light-emitting layer. The second layer is between the second electrode and the light-emitting layer. One of the first electrode and the second electrode is an anode and the other is a cathode. A GSP slope (mV/nm) of one of the light-emitting layer and the first layer closer to the cathode is larger than a GSP slope (mV/nm) of the other closer to the anode. A GSP slope (mV/nm) of one of the light-emitting layer and the second layer closer to the anode is larger than a GSP slope (mV/nm) of the other closer to the cathode. The GSP slope (m V/nm) is a parameter represented by ΔV/Δd, where ΔV (mV) is an amount of change in a surface potential with respect to an amount of change in a thickness Δd (nm).

Another embodiment of the present invention is the light-emitting device having any of the above structures and including a third layer and a fourth layer. The third layer is between the first layer and the first electrode. The fourth layer is between the second layer and the second electrode. A GSP slope (mV/nm) of one of the first layer and the third layer closer to the cathode is larger than a GSP slope (mV/nm) of the other closer to the anode. A GSP slope (mV/nm) of one of the second layer and the fourth layer closer to the anode is larger than a GSP slope (mV/nm) of the other closer to the cathode.

Another embodiment of the present invention is a light-emitting device including a first electrode, a second electrode, a light-emitting layer, a first layer, and a second layer. The first electrode is formed over a substrate and is between the second electrode and the substrate. The light-emitting layer is between the first electrode and the second electrode. The first layer is between the first electrode and the light-emitting layer. The second layer is between the second electrode and the light-emitting layer. The first electrode is an anode. The second electrode is a cathode. A GSP slope (mV/nm) of the light-emitting layer is larger than a GSP slope (mV/nm) of the first layer. The GSP slope (mV/nm) of the light-emitting layer is larger than a GSP slope (mV/nm) of the second layer. The GSP slope (mV/nm) is a parameter represented by ΔV/Δd, where ΔV (mV) is an amount of change in a surface potential with respect to an amount of change in a thickness Δd (nm). In this structure, the first electrode may be electrically connected to a transistor. Alternatively, in this structure, the first electrode may be partly covered with an insulator. Alternatively, in this structure, the first electrode may be formed over an insulating film. Another embodiment of the present invention is the light-emitting device having the above structure and including a third layer and a fourth layer. The third layer is between the first layer and the first electrode. The fourth layer is between the second layer and the second electrode. The GSP slope (mV/nm) of the first layer is larger than a GSP slope (mV/nm) of the third layer. The GSP slope (mV/nm) of the second layer is larger than a GSP slope (mV/nm) of the fourth layer.

Another embodiment of the present invention is a light-emitting device including a first electrode, a second electrode, a light-emitting layer, a first layer, and a second layer. The first electrode is formed over a substrate and is between the second electrode and the substrate. The light-emitting layer is between the first electrode and the second electrode. The first layer is between the first electrode and the light-emitting layer. The second layer is between the second electrode and the light-emitting layer. The first electrode is a cathode. The second electrode is an anode. A GSP slope (mV/nm) of the first layer is larger than a GSP slope (mV/nm) of the light-emitting layer. A GSP slope (mV/nm) of the second layer is larger than the GSP slope (mV/nm) of the light-emitting layer. The GSP slope (mV/nm) is a parameter represented by ΔV/Δd, where ΔV (mV) is an amount of change in a surface potential with respect to an amount of change in a thickness Δd (nm). In this structure, the first electrode may be electrically connected to a transistor. Alternatively, in this structure, the first electrode may be partly covered with an insulator. Alternatively, in this structure, the first electrode may be formed over an insulating film. Another embodiment of the present invention is the light-emitting device having the above structure and including a third layer and a fourth layer. The third layer is between the first layer and the first electrode. The fourth layer is between the second layer and the second electrode. A GSP slope (mV/nm) of the third layer is larger than the GSP slope (mV/nm) of the first layer. A GSP slope (mV/nm) of the fourth layer is larger than the GSP slope (mV/nm) of the second layer.

Another embodiment of the present invention is the light-emitting device having any of the above structures in which at a peak wavelength of an electroluminescence spectrum of the light-emitting device, a refractive index of at least one of the first layer and the second layer is lower than a refractive index of the light-emitting layer.

Another embodiment of the present invention is the light-emitting device having any of the above structures in which at a peak wavelength of an electroluminescence spectrum of the light-emitting device, a refractive index of at least one of the first layer and the second layer is less than or equal to 1.75.

Another embodiment of the present invention is the light-emitting device having any of the above structures in which at a peak wavelength of an electroluminescence spectrum of the light-emitting device, a refractive index of at least one of the first layer, the second layer, the third layer, and the fourth layer is lower than a refractive index of the light-emitting layer.

Another embodiment of the present invention is the light-emitting device having any of the above structures in which at a peak wavelength of an electroluminescence spectrum of the light-emitting device, a refractive index of at least one of the first layer, the second layer, the third layer, and the fourth layer is less than or equal to 1.75.

Another embodiment of the present invention is a light-emitting device including a first electrode, a second electrode, a light-emitting layer, a first layer, and a second layer. The first electrode is formed over a substrate and is between the second electrode and the substrate. The light-emitting layer is between the first electrode and the second electrode. The first layer is between the first electrode and the light-emitting layer. The second layer is between the second electrode and the light-emitting layer. One of the first electrode and the second electrode is an anode and the other is a cathode. The light-emitting layer contains a first host material as a main component and a light-emitting substance as a subcomponent. The first layer contains a first organic compound as a main component. The second layer contains a second organic compound as a main component. A GSP slope (mV/nm) of an evaporated film of the main component of one of the light-emitting layer and the first layer closer to the cathode is larger than a GSP slope (mV/nm) of an evaporated film of the main component of the other closer to the anode. A GSP slope (mV/nm) of an evaporated film of the main component of one of the light-emitting layer and the second layer closer to the anode is larger than a GSP slope (mV/nm) of an evaporated film of the main component of the other closer to the cathode. The GSP slope (mV/nm) is a parameter represented by ΔV/Δd, where ΔV (mV) is an amount of change in a surface potential with respect to an amount of change in a thickness Δd (nm).

Another embodiment of the present invention is a light-emitting device including a first electrode, a second electrode, a light-emitting layer, a first layer, and a second layer. The first electrode is electrically connected to a transistor. The light-emitting layer is between the first electrode and the second electrode. The first layer is between the first electrode and the light-emitting layer. The second layer is between the second electrode and the light-emitting layer. One of the first electrode and the second electrode is an anode and the other is a cathode. The light-emitting layer contains a first host material as a main component and a light-emitting substance as a subcomponent. The first layer contains a first organic compound as a main component. The second layer contains a second organic compound as a main component. A GSP slope (mV/nm) of an evaporated film of the main component of one of the light-emitting layer and the first layer closer to the cathode is larger than a GSP slope (mV/nm) of an evaporated film of the main component of the other closer to the anode. A GSP slope (mV/nm) of an evaporated film of the main component of one of the light-emitting layer and the second layer closer to the anode is larger than a GSP slope (mV/nm) of an evaporated film of the main component of the other closer to the cathode. The GSP slope (m V/nm) is a parameter represented by ΔV/Δd, where ΔV (mV) is an amount of change in a surface potential with respect to an amount of change in a thickness Δd (nm).

Another embodiment of the present invention is a light-emitting device including a first electrode, a second electrode, a light-emitting layer, a first layer, and a second layer. The first electrode is partly covered with an insulator. The light-emitting layer is between the first electrode and the second electrode. The first layer is between the first electrode and the light-emitting layer. The second layer is between the second electrode and the light-emitting layer. One of the first electrode and the second electrode is an anode and the other is a cathode. The light-emitting layer contains a first host material as a main component and a light-emitting substance as a subcomponent. The first layer contains a first organic compound as a main component. The second layer contains a second organic compound as a main component. A GSP slope (mV/nm) of an evaporated film of the main component of one of the light-emitting layer and the first layer closer to the cathode is larger than a GSP slope (mV/nm) of an evaporated film of the main component of the other closer to the anode. A GSP slope (mV/nm) of an evaporated film of the main component of one of the light-emitting layer and the second layer closer to the anode is larger than a GSP slope (mV/nm) of an evaporated film of the main component of the other closer to the cathode. The GSP slope (m V/nm) is a parameter represented by ΔV/Δd, where ΔV (mV) is an amount of change in a surface potential with respect to an amount of change in a thickness Δd (nm).

Another embodiment of the present invention is a light-emitting device including a first electrode, a second electrode, a light-emitting layer, a first layer, and a second layer. The first electrode is formed over an insulating film and is between the second electrode and the insulating film. An external connection electrode is over the insulating film. The light-emitting layer is between the first electrode and the second electrode. The first layer is between the first electrode and the light-emitting layer. The second layer is between the second electrode and the light-emitting layer. One of the first electrode and the second electrode is an anode and the other is a cathode. The light-emitting layer contains a first host material as a main component and a light-emitting substance as a subcomponent. The first layer contains a first organic compound as a main component. The second layer contains a second organic compound as a main component. A GSP slope (mV/nm) of an evaporated film of the main component of one of the light-emitting layer and the first layer closer to the cathode is larger than a GSP slope (m V/nm) of an evaporated film of the main component of the other closer to the anode. A GSP slope (mV/nm) of an evaporated film of the main component of one of the light-emitting layer and the second layer closer to the anode is larger than a GSP slope (mV/nm) of an evaporated film of the main component of the other closer to the cathode. The GSP slope (m V/nm) is a parameter represented by ΔV/Δd, where ΔV (mV) is an amount of change in a surface potential with respect to an amount of change in a thickness Δd (nm).

Another embodiment of the present invention is a light-emitting device including a first electrode, a second electrode, a light-emitting layer, a first layer, and a second layer. The first electrode is formed over a substrate and is between the second electrode and the substrate. The light-emitting layer is between the first electrode and the second electrode. The first layer is between the first electrode and the light-emitting layer. The second layer is between the second electrode and the light-emitting layer. The first electrode is an anode. The second electrode is a cathode. The light-emitting layer contains a first host material and a light-emitting substance.

The first layer contains a first organic compound. The second layer contains a second organic compound. A GSP slope (mV/nm) of an evaporated film of the first host material is larger than a GSP slope (mV/nm) of an evaporated film of the first organic compound. The GSP slope (mV/nm) of the evaporated film of the first host material is larger than a GSP slope (mV/nm) of an evaporated film of the second organic compound. The GSP slope (mV/nm) is a parameter represented by ΔV/Δd, where ΔV (mV) is an amount of change in a surface potential with respect to an amount of change in a thickness Δd (nm). In this structure, the first electrode may be electrically connected to a transistor. Alternatively, in this structure, the first electrode may be partly covered with an insulator. Alternatively, in this structure, the first electrode may be formed over an insulating film. Another embodiment of the present invention is the light-emitting device having the above structure and including a third layer and a fourth layer. The third layer is between the first layer and the first electrode. The fourth layer is between the second layer and the second electrode. The third layer contains a third organic compound. The fourth layer contains a fourth organic compound. The GSP slope (mV/nm) of the evaporated film of the first organic compound is larger than a GSP slope (mV/nm) of an evaporated film of the third organic compound. The GSP slope (mV/nm) of the evaporated film of the second organic compound is larger than a GSP slope (mV/nm) of an evaporated film of the fourth organic compound.

Another embodiment of the present invention is a light-emitting device including a first electrode, a second electrode, a light-emitting layer, a first layer, and a second layer. The first electrode is formed over a substrate and is between the second electrode and the substrate. The light-emitting layer is between the first electrode and the second electrode. The first layer is between the first electrode and the light-emitting layer. The second layer is between the second electrode and the light-emitting layer. The first electrode is a cathode. The second electrode is an anode. The light-emitting layer contains a first host material and a light-emitting substance. The first layer contains a first organic compound. The second layer contains a second organic compound. A GSP slope (mV/nm) of an evaporated film of the first organic compound is larger than a GSP slope (mV/nm) of an evaporated film of the first host material. A GSP slope (mV/nm) of an evaporated film of the second organic compound is larger than the GSP slope (mV/nm) of the evaporated film of the first host material. The GSP slope (m V/nm) is a parameter represented by ΔV/Δd, where ΔV (mV) is an amount of change in a surface potential with respect to an amount of change in a thickness Δd (nm). In this structure, the first electrode may be electrically connected to a transistor. Alternatively, in this structure, the first electrode may be partly covered with an insulator. Alternatively, in this structure, the first electrode may be formed over an insulating film. Another embodiment of the present invention is the light-emitting device having the above structure and including a third layer and a fourth layer. The third layer is between the first layer and the first electrode. The fourth layer is between the second layer and the second electrode. The third layer contains a third organic compound. The fourth layer contains a fourth organic compound. A GSP slope (mV/nm) of an evaporated film of the third organic compound is larger than the GSP slope (mV/nm) of the evaporated film of the first organic compound. A GSP slope (mV/nm) of an evaporated film of the fourth organic compound is larger than the GSP slopc (mV/nm) of the evaporated film of the second organic compound.

Another embodiment of the present invention is the light-emitting device having any of the above structures in which at a peak wavelength of an electroluminescence spectrum of the light-emitting device, a refractive index of at least one of a film of the first organic compound and a film of the second organic compound is lower than a refractive index of a film of the first host material.

Another embodiment of the present invention is a light-emitting device including a first electrode, a second electrode, a light-emitting layer, a first layer, and a second layer. The first electrode is formed over a substrate and is between the second electrode and the substrate. The light-emitting layer is between the first electrode and the second electrode. The first layer is between the first electrode and the light-emitting layer. The second layer is between the second electrode and the light-emitting layer. One of the first electrode and the second electrode is an anode and the other is a cathode. The light-emitting layer contains a first host material and a second host material as main components and a light-emitting substance as a subcomponent. The first layer contains a first organic compound as a main component. The second layer contains a second organic compound as a main component. A GSP slope (mV/nm) of an evaporated film of the main component of one of the light-emitting layer and the first layer closer to the cathode is larger than a GSP slope (mV/nm) of an evaporated film of the main component of the other closer to the anode. A GSP slope (mV/nm) of an evaporated film of the main component of one of the light-emitting layer and the second layer closer to the anode is larger than a GSP slope (mV/nm) of an evaporated film of the main component of the other closer to the cathode. The GSP slope (mV/nm) of the evaporated film of the main component of the light-emitting layer refers to an average GSP slope (mV/nm) of the evaporated film of the first host material and the evaporated film of the second host material. The GSP slope (mV/nm) is a parameter represented by ΔV/Δd, where ΔV (mV) is an amount of change in a surface potential with respect to an amount of change in a thickness Δd (nm).

Another embodiment of the present invention is a light-emitting device including a first electrode, a second electrode, a light-emitting layer, a first layer, and a second layer. The first electrode is electrically connected to a transistor. The light-emitting layer is between the first electrode and the second electrode. The first layer is between the first electrode and the light-emitting layer. The second layer is between the second electrode and the light-emitting layer. One of the first electrode and the second electrode is an anode and the other is a cathode. The light-emitting layer contains a first host material and a second host material as main components and a light-emitting substance as a subcomponent. The first layer contains a first organic compound as a main component. The second layer contains a second organic compound as a main component. A GSP slope (mV/nm) of an evaporated film of the main component of one of the light-emitting layer and the first layer closer to the cathode is larger than a GSP slope (mV/nm) of an evaporated film of the main component of the other closer to the anode. A GSP slope (mV/nm) of an evaporated film of the main component of one of the light-emitting layer and the second layer closer to the anode is larger than a GSP slope (mV/nm) of an evaporated film of the main component of the other closer to the cathode. The GSP slope (mV/nm) of the evaporated film of the main component of the light-emitting layer refers to an average GSP slope (m V/nm) of the evaporated film of the first host material and the evaporated film of the second host material. The GSP slope (mV/nm) is a parameter represented by ΔV/Δd, where ΔV (mV) is an amount of change in a surface potential with respect to an amount of change in a thickness Δd (nm).

Another embodiment of the present invention is a light-emitting device including a first electrode, a second electrode, a light-emitting layer, a first layer, and a second layer. The first electrode is partly covered with an insulator. The light-emitting layer is between the first electrode and the second electrode. The first layer is between the first electrode and the light-emitting layer. The second layer is between the second electrode and the light-emitting layer. One of the first electrode and the second electrode is an anode and the other is a cathode. The light-emitting layer contains a first host material and a second host material as main components and a light-emitting substance as a subcomponent. The first layer contains a first organic compound as a main component. The second layer contains a second organic compound as a main component. A GSP slope (mV/nm) of an evaporated film of the main component of one of the light-emitting layer and the first layer closer to the cathode is larger than a GSP slope (mV/nm) of an evaporated film of the main component of the other closer to the anode. A GSP slope (mV/nm) of an evaporated film of the main component of one of the light-emitting layer and the second layer closer to the anode is larger than a GSP slope (mV/nm) of an evaporated film of the main component of the other closer to the cathode. The GSP slope (mV/nm) of the evaporated film of the main component of the light-emitting layer refers to an average GSP slope (mV/nm) of the evaporated film of the first host material and the evaporated film of the second host material. The GSP slope (mV/nm) is a parameter represented by ΔV/Δd, where ΔV (mV) is an amount of change in a surface potential with respect to an amount of change in a thickness Δd (nm).

Another embodiment of the present invention is a light-emitting device including a first electrode, a second electrode, a light-emitting layer, a first layer, and a second layer. The first electrode is formed over an insulating film and is between the second electrode and the insulating film. An external connection electrode is over the insulating film. The light-emitting layer is between the first electrode and the second electrode. The first layer is between the first electrode and the light-emitting layer. The second layer is between the second electrode and the light-emitting layer. One of the first electrode and the second electrode is an anode and the other is a cathode. The light-emitting layer contains a first host material and a second host material as main components and a light-emitting substance as a subcomponent. The first layer contains a first organic compound as a main component. The second layer contains a second organic compound as a main component. A GSP slope (mV/nm) of an evaporated film of the main component of one of the light-emitting layer and the first layer closer to the cathode is larger than a GSP slope (mV/nm) of an evaporated film of the main component of the other closer to the anode. A GSP slope (mV/nm) of an evaporated film of the main component of one of the light-emitting layer and the second layer closer to the anode is larger than a GSP slope (mV/nm) of an evaporated film of the main component of the other closer to the cathode. The GSP slope (mV/nm) of the evaporated film of the main component of the light-emitting layer refers to an average GSP slope (mV/nm) of the evaporated film of the first host material and the evaporated film of the second host material. The GSP slope (mV/nm) is a parameter represented by ΔV/Δd, where ΔV (mV) is an amount of change in a surface potential with respect to an amount of change in a thickness Δd (nm).

Another embodiment of the present invention is the light-emitting device having any of the above structures and including a third layer and a fourth layer. The third layer is between the first layer and the first electrode. The fourth layer is between the second layer and the second electrode. The third layer contains a third organic compound as a main component. The fourth layer contains a fourth organic compound as a main component. A GSP slope (mV/nm) of an evaporated film of the main component of one of the first layer and the third layer closer to the cathode is larger than a GSP slope (mV/nm) of an evaporated film of the main component of the other closer to the anode. A GSP slope (mV/nm) of an evaporated film of the main component of one of the second layer and the fourth layer closer to the anode is larger than a GSP slope (mV/nm) of an evaporated film of the main component of the other closer to the cathode.

Another embodiment of the present invention is a light-emitting device including a first electrode, a second electrode, a light-emitting layer, a first layer, and a second layer. The first electrode is formed over a substrate and is between the second electrode and the substrate. The light-emitting layer is between the first electrode and the second electrode. The first layer is between the first electrode and the light-emitting layer. The second layer is between the second electrode and the light-emitting layer. The first electrode is an anode. The second electrode is a cathode. The light-emitting layer contains a first host material, a second host material, and a light-emitting substance. The first layer contains a first organic compound. The second layer contains a second organic compound. An average GSP slope (mV/nm) of an evaporated film of the first host material and an evaporated film of the second host material is larger than a GSP slope (mV/nm) of an evaporated film of the first organic compound. The average GSP slope (mV/nm) of the evaporated film of the first host material and the evaporated film of the second host material is larger than a GSP slope (mV/nm) of an evaporated film of the second organic compound. The GSP slope (mV/nm) is a parameter represented by ΔV/Δd, where ΔV (mV) is an amount of change in a surface potential with respect to an amount of change in a thickness Δd (nm). In this structure, the first electrode may be electrically connected to a transistor. Alternatively, in this structure, the first electrode may be partly covered with an insulator. Alternatively, in this structure, the first electrode may be formed over an insulating film. Another embodiment of the present invention is the light-emitting device having the above structure and including a third layer and a fourth layer. The third layer is between the first layer and the first electrode. The fourth layer is between the second layer and the second electrode. The third layer contains a third organic compound. The fourth layer contains a fourth organic compound. The GSP slope (mV/nm) of the evaporated film of the first organic compound is larger than a GSP slope (mV/nm) of an evaporated film of the third organic compound. The GSP slope (m V/nm) of the evaporated film of the second organic compound is larger than a GSP slope (mV/nm) of an evaporated film of the fourth organic compound.

Another embodiment of the present invention is a light-emitting device including a first electrode, a second electrode, a light-emitting layer, a first layer, and a second layer. The first electrode is formed over a substrate and is between the second electrode and the substrate. The light-emitting layer is between the first electrode and the second electrode. The first layer is between the first electrode and the light-emitting layer. The second layer is between the second electrode and the light-emitting layer. The first electrode is a cathode. The second electrode is an anode. The light-emitting layer contains a first host material, a second host material, and a light-emitting substance. The first layer contains a first organic compound. The second layer contains a second organic compound. A GSP slope (mV/nm) of an evaporated film of the first organic compound is larger than an average GSP slope (mV/nm) of an evaporated film of the first host material and an evaporated film of the second host material. A GSP slope (mV/nm) of an evaporated film of the second organic compound is larger than the average GSP slope (mV/nm) of the evaporated film of the first host material and the evaporated film of the second host material. The GSP slope (mV/nm) is a parameter represented by ΔV/Δd, where ΔV (mV) is an amount of change in a surface potential with respect to an amount of change in a thickness Δd (nm). In this structure, the first electrode may be electrically connected to a transistor. Alternatively, in this structure, the first electrode may be partly covered with an insulator. Alternatively, in this structure, the first electrode may be formed over an insulating film. Another embodiment of the present invention is the light-emitting device having the above structure and including a third layer and a fourth layer. The third layer is between the first layer and the first electrode. The fourth layer is between the second layer and the second electrode. The third layer contains a third organic compound. The fourth layer contains a fourth organic compound. A GSP slope (mV/nm) of an evaporated film of the third organic compound is larger than the GSP slope (mV/nm) of the evaporated film of the first organic compound. A GSP slope (mV/nm) of an evaporated film of the fourth organic compound is larger than the GSP slope (mV/nm) of the evaporated film of the second organic compound.

Another embodiment of the present invention is the light-emitting device having any of the above structures in which the light-emitting layer contains the first host material and does not contain the second host material, and at a peak wavelength of an electroluminescence spectrum of the light-emitting device, a refractive index of at least one of a film of the first organic compound and a film of the second organic compound is lower than a refractive index of a film of the first host material.

Another embodiment of the present invention is the light-emitting device having any of the above structures in which the light-emitting layer contains the first host material and the second host material, and at a peak wavelength of an electroluminescence spectrum of the light-emitting device, a refractive index of at least one of a film of the first organic compound and a film of the second organic compound is lower than an average refractive index of a film of the first host material and a film of the second host material.

Another embodiment of the present invention is the light-emitting device having any of the above structures in which at a peak wavelength of an electroluminescence spectrum of the light-emitting device, a refractive index of at least one of a film of the first organic compound and a film of the second organic compound is less than or equal to 1.75.

Another embodiment of the present invention is the light-emitting device having any of the above structures in which at least one of the first organic compound and the second organic compound has at least one group selected from chain alkyl groups having 2 to 10 carbon atoms and cycloalkyl groups having 6 to 12 carbon atoms.

Another embodiment of the present invention is the light-emitting device having any of the above structures in which the light-emitting layer contains the first host material and does not contain the second host material, and at a peak wavelength of an electroluminescence spectrum of the light-emitting device, a refractive index of at least one of a film of the first organic compound, a film of the second organic compound, a film of the third organic compound, and a film of the fourth organic compound is lower than a refractive index of a film of the first host material.

Another embodiment of the present invention is the light-emitting device having any of the above structures in which the light-emitting layer contains the first host material and the second host material, and at a peak wavelength of an electroluminescence spectrum of the light-emitting device, a refractive index of at least one of a film of the first organic compound, a film of the second organic compound, a film of the third organic compound, and a film of the fourth organic compound is lower than an average refractive index of a film of the first host material and a film of the second host material.

Another embodiment of the present invention is the light-emitting device having the above structure in which at a peak wavelength of an electroluminescence spectrum of the light-emitting device, a refractive index of at least one of a film of the first organic compound, a film of the second organic compound, a film of the third organic compound, and a film of the fourth organic compound is less than or equal to 1.75.

Another embodiment of the present invention is the light-emitting device having the above structure in which at least one of the first organic compound, the second organic compound, the third organic compound, and the fourth organic compound has at least one group selected from chain alkyl groups having 2 to 10 carbon atoms and cycloalkyl groups having 6 to 12 carbon atoms.

Another embodiment of the present invention is the light-emitting device having the above structure in which the first organic compound and the third organic compound each independently have a π-electron rich heteroaromatic ring or an aromatic amine skeleton. A HOMO level of the third organic compound is higher than a HOMO level of the first organic compound.

One embodiment of the present invention can provide a light-emitting device having a low driving voltage. Another embodiment of the present invention can provide a light-emitting device having high emission efficiency. Another embodiment of the present invention can provide any of a light-emitting apparatus, an electronic appliance, and a display device each having low power consumption.

Note that the description of these effects does not preclude the existence of other effects. One embodiment of the present invention does not necessarily have all of these effects. Other effects will be apparent from and can be derived from the description of the specification, the drawings, the claims, and the like.

### BRIEF DESCRIPTION OF THE DRAWINGS

FIGS. 1A and 1B illustrate structures of a light-emitting device of an embodiment.

FIGS. 2A and 2B illustrate structures of a light-emitting device of an embodiment.

FIGS. 3A to 3D illustrate structures of a light-emitting device of an embodiment.

FIGS. 4A to 4E illustrate structures of light-emitting devices of an embodiment.

FIGS. 5A and 5B are a top view and a cross-sectional view of a light-emitting apparatus.

FIGS. 6A to 6G are top views showing structure examples of pixels.

FIGS. 7A to 7I are top views showing structure examples of pixels.

FIGS. 8A and 8B are perspective views showing a structure example of a display module.

FIGS. 9A and 9B are cross-sectional views showing structure examples of a light-emitting apparatus.

FIG. 10 is a perspective view showing a structure example of a light-emitting apparatus.

FIG. 11A is a cross-sectional view showing a structure example of a light-emitting apparatus. FIGS. 11B and 11C are cross-sectional views showing structure examples of transistors.

FIG. 12 is a cross-sectional view showing a structure example of a light-emitting apparatus.

FIGS. 13A to 13C are a cross-sectional view and top views showing a structure example of a light-emitting apparatus.

FIGS. 14A to 14D are cross-sectional views showing structure examples of a light-emitting apparatus.

FIGS. 15A to 15C are a cross-sectional view and top views showing a structure example of a light-emitting apparatus.

FIGS. 16A to 16D show examples of electronic appliances.

FIGS. 17A to 17F show examples of electronic appliances.

FIGS. 18A to 18G show examples of electronic appliances.

FIGS. 19A and 19B illustrate an active matrix light-emitting apparatus.

FIGS. 20A and 20B illustrate active matrix light-emitting apparatuses.

FIG. 21 illustrates an active matrix light-emitting apparatus.

FIGS. 22A and 22B illustrate a passive matrix light-emitting apparatus.

FIGS. 23A and 23B illustrate an electronic appliance of an embodiment.

FIG. 24 illustrates electronic appliances of an embodiment.

FIGS. 25A to 25C illustrate structures of devices of an example.

FIG. 26 shows capacity-voltage characteristics of a measurement device 1.

FIG. 27 shows current density-voltage characteristics of the measurement device 1.

FIG. 28 shows luminance-current density characteristics of a light-emitting device 1, a light-emitting device 2, and a comparative light-emitting device 3 to a comparative light-emitting device 5.

FIG. 29 shows luminance-voltage characteristics of the light-emitting device 1, the light-emitting device 2, and the comparative light-emitting device 3 to the comparative light-emitting device 5.

FIG. 30 shows current efficiency-luminance characteristics of the light-emitting device 1, the light-emitting device 2, and the comparative light-emitting device 3 to the comparative light-emitting device 5.

FIG. 31 shows current density-voltage characteristics of the light-emitting device 1, the light-emitting device 2, and the comparative light-emitting device 3 to the comparative light-emitting device 5.

FIG. 32 shows power efficiency-luminance characteristics of the light-emitting device 1, the light-emitting device 2, and the comparative light-emitting device 3 to the comparative light-emitting device 5.

FIG. 33 shows external quantum efficiency-luminance characteristics of the light-emitting device 1, the light-emitting device 2, and the comparative light-emitting device 3 to the comparative light-emitting device 5.

FIG. 34 shows electroluminescence spectra of the light-emitting device 1, the light-emitting device 2, and the comparative light-emitting device 3 to the comparative light-emitting device 5.

FIG. 35 shows luminance-current density characteristics of a light-emitting device 6 to a light-emitting device 8 and a comparative light-emitting device 9.

FIG. 36 shows luminance-voltage characteristics of the light-emitting device 6 to the light-emitting device 8 and the comparative light-emitting device 9.

FIG. 37 shows current efficiency-luminance characteristics of the light-emitting device 6 to the light-emitting device 8 and the comparative light-emitting device 9.

FIG. 38 shows current density-voltage characteristics of the light-emitting device 6 to the light-emitting device 8 and the comparative light-emitting device 9.

FIG. 39 shows power efficiency-luminance characteristics of the light-emitting device 6 to the light-emitting device 8 and the comparative light-emitting device 9.

FIG. 40 shows external quantum efficiency-luminance characteristics of the light-emitting device 6 to the light-emitting device 8 and the comparative light-emitting device 9.

FIG. 41 shows blue index-luminance characteristics of the light-emitting device 6 to the light-emitting device 8 and the comparative light-emitting device 9.

FIG. 42 shows electroluminescence spectra of the light-emitting device 6 to the light-emitting device 8 and the comparative light-emitting device 9.

FIG. 43 shows luminance-current density characteristics of a light-emitting device 10 and a light-emitting device 11 and a comparative light-emitting device 12 to a comparative light-emitting device 14.

FIG. 44 shows luminance-voltage characteristics of the light-emitting device 10 and the light-emitting device 11 and the comparative light-emitting device 12 to the comparative light-emitting device 14.

FIG. 45 shows current density-voltage characteristics of the light-emitting device 10 and the light-emitting device 11 and the comparative light-emitting device 12 to the comparative light-emitting device 14.

FIG. 46 shows electroluminescence spectra of the light-emitting device 10 and the light-emitting device 11 and the comparative light-emitting device 12 to the comparative light-emitting device 14.

FIG. 47 shows a ¹H NMR spectrum of oBP-mmchPh-mDMePyPTzn.

FIG. 48 shows an absorption spectrum and an emission spectrum of a dichloromethane solution of oBP-mmchPh-mDMePyPTzn.

FIG. 49 shows a ¹H NMR spectrum of mmtBuBP-DMePy2PTzn.

FIG. 50 shows an absorption spectrum and an emission spectrum of a dichloromethane solution of mmtBuBP-DMePy2PTzn.

### DETAILED DESCRIPTION OF THE INVENTION

Embodiments of the present invention will be described in detail below with reference to the drawings. Note that the present invention is not limited to the following description, and the modes and details of the present invention can be modified in various ways without departing from the spirit and scope of the present invention. Thus, the present invention should not be construed as being limited to the description in the following embodiments.

Note that the position, size, range, or the like of each component illustrated in the drawings and the like is not accurately represented in some cases for easy understanding. Therefore, the disclosed invention is not necessarily limited to the position, size, range, or the like disclosed in the drawings and the like.

Ordinal numbers such as “first” and “second” in this specification and the like are used for convenience and do not denote the order of steps or the stacking order of layers in some cases. Therefore, for example, description can be made even when “first” is replaced with “second” or “third”, as appropriate. In addition, the ordinal numbers in this specification and the like are not necessarily the same as those used to specify one embodiment of the present invention.

In the description of structures of the present invention in this specification and the like with reference to the drawings, the same components in different drawings are denoted by the same reference numeral in some cases.

In this specification and the like, the terms “film” and “layer” can be interchanged with each other. For example, the term “conductive layer” can be changed into the term “conductive film” in some cases. For another example, the term “insulating film” can be changed into the term “insulating layer” in some cases.

### Embodiment 1

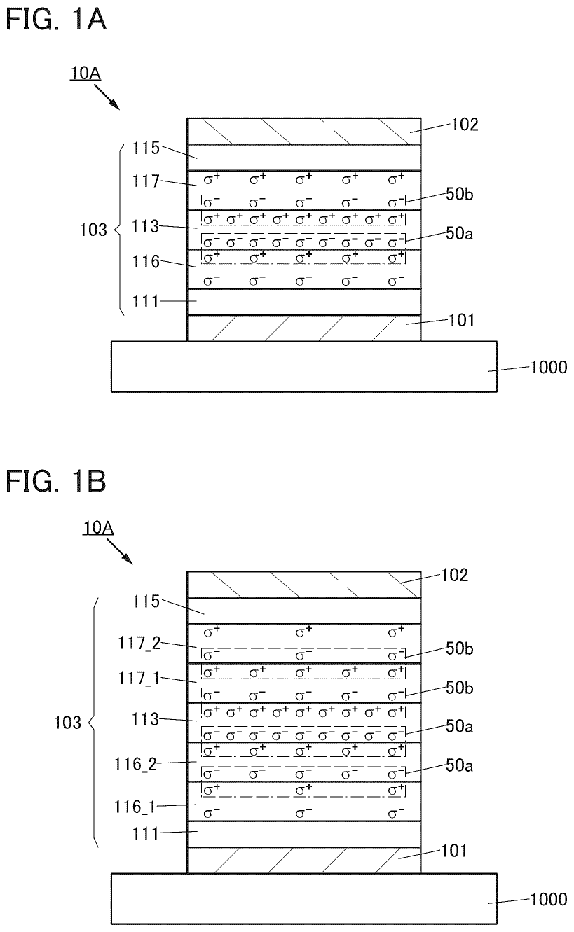

In this embodiment, a light-emitting device 10A and a light-emitting device 10B each of which is a light-emitting device of one embodiment of the present invention are described with reference to FIGS. 1A and 1B, FIGS. 2A and 2B, and FIGS. 3A to 3D.

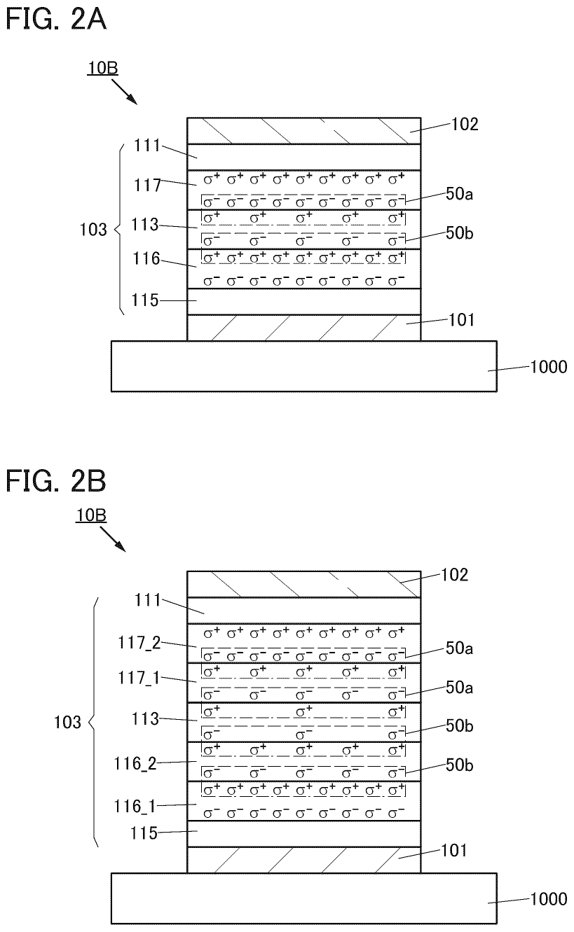

As illustrated in FIGS. 1A and 1B and FIGS. 2A and 2B, the light-emitting devices 10A and 10B are each positioned over a substrate 1000. The light-emitting devices 10A and 10B each include a first electrode 101, a second electrode 102, and an organic compound layer 103 positioned between the first electrode 101 and the second electrode 102. The organic compound layer 103 includes at least a light-emitting layer 113, a first carrier-transport layer 116, and a second carrier-transport layer 117. The first electrode 101 is formed over the substrate 1000. In the organic compound layer 103, the first carrier-transport layer 116 is positioned between the first electrode 101 and the light-emitting layer 113, and the second carrier-transport layer 117 is positioned between the second electrode 102 and the light-emitting layer 113. In the light-emitting devices 10A and 10B, the first electrode 101 is provided between the second electrode 102 and the substrate 1000. That is, the first electrode 101 is provided earlier than the second electrode 102. Note that in the case where the substrate 1000 is provided with a transistor, the first electrode 101 is electrically connected to the transistor through a wiring. Alternatively, the first electrode 101 is provided over an insulating layer provided with an external connection electrode used as, for example, a terminal to which an FPC or the like is attached. The first electrode 101 provided over the substrate 1000 or the insulating layer may be partly covered with an insulator.

The light-emitting device 10A illustrated in FIGS. 1A and 1B and the light-emitting device 10B illustrated in FIGS. 2A and 2B differ in the functions of the first electrode 101 and the second electrode 102. In the light-emitting device 10A illustrated in FIGS. 1A and 1B, the first electrode 101 and the second electrode 102 function as an anode and a cathode, respectively. Meanwhile, in the light-emitting device 10B illustrated in FIGS. 2A and 2B, the first electrode 101 and the second electrode 102 function as a cathode and an anode, respectively. Note that in this specification and the like, in some cases, a light-emitting device like the light-emitting device 10A illustrated in FIGS. 1A and 1B in which a first electrode on the substrate side functions as an anode is referred to as an ordered stacked light-emitting device, and a light-emitting device like the light-emitting device 10B illustrated in FIGS. 2A and 2B in which a first electrode on the substrate side functions as a cathode is referred to as an inverted stacked light-emitting device.

The ordered stacked light-emitting device 10A illustrated in FIGS. 1A and 1B emits light when holes and electrons injected from the first electrode 101 functioning as an anode and the second electrode 102 functioning as a cathode, respectively, into the organic compound layer 103 are recombined in the light-emitting layer 113. Thus, in the light-emitting device 10A, the first carrier-transport layer 116 and the second carrier-transport layer 117 preferably have a function of transporting holes and a function of transporting electrons, respectively.

Meanwhile, the inverted stacked light-emitting device 10B illustrated in FIGS. 2A and 2B emits light when electrons and holes injected from the first electrode 101 functioning as a cathode and the second electrode 102 functioning as an anode, respectively, into the organic compound layer 103 are recombined in the light-emitting layer 113. Thus, in the light-emitting device 10B, the first carrier-transport layer 116 and the second carrier-transport layer 117 preferably have a function of transporting electrons and a function of transporting holes, respectively.

In the light-emitting devices 10A and 10B, the first carrier-transport layer 116 and the second carrier-transport layer 117 may each be either a single layer or stacked layers. In the light-emitting devices 10A and 10B illustrated in FIG. 1B and FIG. 2B, respectively, the organic compound layer 103 includes at least the light-emitting layer 113, a first carrier-transport layer 116_1, a first carrier-transport layer 116_2, a second carrier-transport layer 117_1, and a second carrier-transport layer 117_2. In the organic compound layer 103 of each of the light-emitting devices 10A and 10B, it is preferable that the first carrier-transport layer 116_1 be positioned between the first electrode 101 and the light-emitting layer 113, the first carrier-transport layer 116_2 be positioned between the first carrier-transport layer 116_1 and the light-emitting layer 113, the second carrier-transport layer 117_1 be positioned between the second electrode 102 and the light-emitting layer 113, and the second carrier-transport layer 117_2 be positioned between the second carrier-transport layer 117_1 and the second electrode 102. Hereinafter, in some cases, the first carrier-transport layers 116_1 and 116_2 are collectively referred to as the first carrier-transport layer 116, and the second carrier-transport layers 117_1 and 117_2 are collectively referred to as the second carrier-transport layer 117.

The light-emitting devices 10A and 10B each further preferably include a hole-injection layer 111 between the anode and the layer having a function of transporting holes, and further preferably include an electron-injection layer 115 between the cathode and the layer having a function of transporting electrons. In the ordered stacked light-emitting device 10A illustrated in FIG. 1A, the hole-injection layer 111, the first carrier-transport layer 116, the light-emitting layer 113, the second carrier-transport layer 117, the electron-injection layer 115, and the second electrode 102 functioning as the cathode are stacked in this order over the first electrode 101 functioning as the anode. In the ordered stacked light-emitting device 10A illustrated in FIG. 1B, the hole-injection layer 111, the first carrier-transport layer 116_1, the first carrier-transport layer 116_2, the light-emitting layer 113, the second carrier-transport layer 117_1, the second carrier-transport layer 117_2, the electron-injection layer 115, and the second electrode 102 functioning as the cathode are stacked in this order over the first electrode 101 functioning as the anode. In the inverted stacked light-emitting device 10B illustrated in FIG. 2A, the electron-injection layer 115, the first carrier-transport layer 116, the light-emitting layer 113, the second carrier-transport layer 117, the hole-injection layer 111, and the second electrode 102 functioning as the anode are stacked in this order over the first electrode 101 functioning as the cathode. In the inverted stacked light-emitting device 10B illustrated in FIG. 2B, the electron-injection layer 115, the first carrier-transport layer 116_1, the first carrier-transport layer 116_2, the light-emitting layer 113, the second carrier-transport layer 117_1, the second carrier-transport layer 117_2, the hole-injection layer 111, and the second electrode 102 functioning as the anode are stacked in this order over the first electrode 101 functioning as the cathode. The inverted stacked light-emitting device 10B can further include an electron-relay layer, a charge-generation buffer layer, or the like between the hole-injection layer 111 and the second electrode 102 functioning as the anode.

Note that the structures of the light-emitting devices 10A and 10B are not limited to those illustrated in FIGS. 1A and 1B and FIGS. 2A and 2B. For example, a structure in which one of a hole-transport layer and an electron-transport layer is a single layer and the other consists of two layers may be employed. Alternatively, a structure in which one or both of a hole-transport layer and an electron-transport layer consist of three or more layers may be employed. Alternatively, a structure including a functional layer having a function of lowering a hole- or electron-injection barrier, improving a hole- or electron-transport property, degrading a hole- or electron-transport property, inhibiting a quenching phenomenon by an electrode, or the like may be employed.

The present inventors found that the light-emitting devices 10A and 10B can each have a low driving voltage when materials used for the layers are selected such that the GSP slope of one of the light-emitting layer 113 and the first carrier-transport layer 116 positioned closer to the cathode is larger than the GSP slope of the other positioned closer to the anode, and the GSP slope of one of the light-emitting layer 113 and the second carrier-transport layer 117 positioned closer to the anode is larger than the GSP slope of the other positioned closer to the cathode. Note that GSP is a phenomenon due to spontaneous orientation polarization (SOP) caused by deviation of permanent electric dipole moment orientation of an evaporated film to the thickness direction.

The surface potential of an evaporated film with GSP changes linearly with increasing thickness without saturation. For example, the surface potential of an evaporated film of tris(8-quinolinolato)aluminum (abbreviation: Alq₃) reaches approximately 28 V at a thickness of 560 nm. The electric field strength reaches 5×10⁵ V/cm, which is approximately the same level as electric field strength during driving of a general light-emitting device.

A GSP slope is a parameter represented by ΔV/Δd, where ΔV (mV) is the amount of change in the surface potential with respect to the amount of change in the thickness Δd (nm) of a film whose GSP changes in proportion to the thickness. Note that a GSP slope of a film whose surface potential increases with increasing thickness is a positive GSP slope, and a GSP slope of a film whose surface potential decreases with increasing thickness is a negative GSP slope. It can be said that Alq₃ described above is a material with a positive GSP slope. The potential of a layer with a positive GSP slope is lower on the substrate side, and the potential of a layer with a negative GSP slope is higher on the substrate side.

As described above, GSP is a phenomenon due to SOP caused by deviation of permanent electric dipole moment orientation to the thickness direction. That is, the following phenomena can be regarded as occurring: a negative polarization charge is induced on the side where evaporation starts (the substrate side), and a positive polarization charge is induced on the side where evaporation ends (the second electrode side) in a layer with a positive GSP slope, and in a similar manner, a positive polarization charge is induced on the side where evaporation starts (the substrate side) and a negative polarization charge is induced on the side where evaporation ends (the second electrode side) in a layer with a negative GSP slope. Thus, GSP originates in such phenomena.

Evaporated films of most organic compounds have a positive GSP slope; thus, in the case where a first layer is deposited on and in contact with a second layer, for example, a GSP slope of the first layer and a GSP slope of the second layer are denoted by the same positive sign. In this case, a polarization charge of the second layer on the first layer side is canceled out by a polarization charge of the first layer on the second layer side, and only a remaining charge serves as an interface charge (fixed charge) at the interface between the first layer and the second layer.

One embodiment of the present invention achieves a reduction in driving voltage of a light-emitting device by utilizing the polarization charge and an interface charge in stacked films, which is derived from the polarization charge.

In the light-emitting devices 10A and 10B each including the first carrier-transport layer 116 and the second carrier-transport layer 117 (see FIG. 1A and FIG. 2A, respectively), it is preferable that the GSP slope of one of the light-emitting layer 113 and the first carrier-transport layer 116 positioned closer to the cathode be larger than the GSP slope of the other positioned closer to the anode, and the GSP slope of one of the light-emitting layer 113 and the second carrier-transport layer 117 positioned closer to the anode be larger than the GSP slope of the other positioned closer to the cathode.

In the ordered stacked light-emitting device 10A including the first carrier-transport layer 116 and the second carrier-transport layer 117 (see FIG. 1A), the first electrode 101 and the second electrode 102 function as an anode and a cathode, respectively, as described above. Thus, in the ordered stacked light-emitting device, one of the light-emitting layer 113 and the first carrier-transport layer 116 positioned closer to the cathode refers to the light-emitting layer 113, and the other positioned closer to the anode refers to the first carrier-transport layer 116. In addition, one of the light-emitting layer 113 and the second carrier-transport layer 117 positioned closer to the anode refers to the light-emitting layer 113, and the other positioned closer to the cathode refers to the second carrier-transport layer 117. That is, in the ordered stacked light-emitting device 10A including the first carrier-transport layer 116 and the second carrier-transport layer 117 (see FIG. 1A), it is preferable that the GSP slope of the light-emitting layer 113 be larger than the GSP slopes of the first carrier-transport layer 116 and the second carrier-transport layer 117.

In that case, as illustrated in FIG. 1A, a polarization charge of the first carrier-transport layer 116 on the light-emitting layer 113 side is canceled out by a polarization charge of the light-emitting layer 113 on the first carrier-transport layer 116 side, and a negative interface charge 50a remains at the interface between the first carrier-transport layer 116 and the light-emitting layer 113. The negative interface charge 50a attracts holes from the first electrode 101 side to the interface of the light-emitting layer 113 on the first electrode 101 side; thus, an electric field can be effectively applied to the light-emitting layer 113. In addition, a polarization charge of the light-emitting layer 113 on the second carrier-transport layer 117 side is canceled out by a polarization charge of the second carrier-transport layer 117 on the light-emitting layer 113 side, and a positive interface charge 50b remains at the interface between the light-emitting layer 113 and the second carrier-transport layer 117. The positive interface charge 50b attracts electrons from the second electrode 102 side to the interface of the light-emitting layer 113 on the second electrode 102 side; thus, an electric field can be effectively applied to the light-emitting layer 113. Accordingly, effective application of an electric field to the light-emitting layer 113 is easily achieved, which can reduce the driving voltage of the light-emitting device.

Meanwhile, in the inverted stacked light-emitting device 10B including the first carrier-transport layer 116 and the second carrier-transport layer 117 (see FIG. 2A), the first electrode 101 and the second electrode 102 function as a cathode and an anode, respectively, as described above. Thus, in the inverted stacked light-emitting device, one of the light-emitting layer 113 and the first carrier-transport layer 116 positioned closer to the cathode refers to the first carrier-transport layer 116, and the other positioned closer to the anode refers to the light-emitting layer 113. In addition, one of the light-emitting layer 113 and the second carrier-transport layer 117 positioned closer to the anode refers to the second carrier-transport layer 117, and the other positioned closer to the cathode refers to the light-emitting layer 113. That is, in the inverted stacked light-emitting device 10B including the first carrier-transport layer 116 and the second carrier-transport layer 117 (see FIG. 2A), it is preferable that the GSP slopes of the first carrier-transport layer 116 and the second carrier-transport layer 117 be larger than the GSP slope of the light-emitting layer 113.

In that case, as illustrated in FIG. 2A, a polarization charge of the first carrier-transport layer 116 on the light-emitting layer 113 side is canceled out by a polarization charge of the light-emitting layer 113 on the first carrier-transport layer 116 side, and the positive interface charge 50b remains at the interface between the first carrier-transport layer 116 and the light-emitting layer 113. The positive interface charge 50b attracts electrons from the first electrode 101 side to the interface of the light-emitting layer 113 on the first electrode 101 side; thus, an electric field can be effectively applied to the light-emitting layer 113. In addition, a polarization charge of the light-emitting layer 113 on the second carrier-transport layer 117 side is canceled out by a polarization charge of the second carrier-transport layer 117 on the light-emitting layer 113 side, and the negative interface charge 50a remains at the interface between the light-emitting layer 113 and the second carrier-transport layer 117. The negative interface charge 50a attracts holes from the second electrode 102 side to the interface of the light-emitting layer 113 on the second electrode 102 side; thus, an electric field can be effectively applied to the light-emitting layer 113. Accordingly, effective application of an electric field to the light-emitting layer 113 is easily achieved, which can reduce the driving voltage of the light-emitting device.

In the case where the light-emitting device 10A includes a plurality of the first carrier-transport layers 116 and a plurality of the second carrier-transport layers 117, the light-emitting layer 113 preferably has the largest GSP slope among the plurality of first carrier-transport layers 116, the light-emitting layer 113, and the plurality of second carrier-transport layers 117. In the light-emitting device 10A having the above structure, it is further preferable that the GSP slope of a layer positioned closer to the light-emitting layer 113 be larger than the GSP slope of a layer positioned closer to the first electrode 101 among the plurality of first carrier-transport layers 116, and the GSP slope of a layer positioned closer to the light-emitting layer 113 be larger than the GSP slope of a layer positioned closer to the second electrode 102 among the plurality of second carrier-transport layers 117.

In the light-emitting devices 10A and 10B each including the plurality of first carrier-transport layers 116 and the plurality of second carrier-transport layers 117, it is preferable that the GSP slope of a layer positioned closer to the cathode be larger than the GSP slope of a layer positioned closer to the anode among the light-emitting layer 113 and the plurality of first carrier-transport layers 116, and the GSP slope of a layer positioned closer to the anode be larger than the GSP slope of a layer positioned closer to the cathode among the light-emitting layer 113 and the plurality of second carrier-transport layers 117.

In the light-emitting devices 10A and 10B each including the plurality of first carrier-transport layers (the first carrier-transport layers 116_1 and 116_2) and the plurality of second carrier-transport layers (the second carrier-transport layers 117_1 and 117_2) (see FIG. 1B and FIG. 2B, respectively), it is preferable that the GSP slope of one of the light-emitting layer 113 and the first carrier-transport layer 116_1 positioned closer to the cathode be larger than the GSP slope of the other positioned closer to the anode, the GSP slope of one of the light-emitting layer 113 and the first carrier-transport layer 116_2 positioned closer to the cathode be larger than the GSP slope of the other positioned closer to the anode, the GSP slope of one of the light-emitting layer 113 and the second carrier-transport layer 117_1 positioned closer to the anode be larger than the GSP slope of the other positioned closer to the cathode, and the GSP slope of one of the light-emitting layer 113 and the second carrier-transport layer 117_2 positioned closer to the anode be larger than the GSP slope of the other positioned closer to the cathode. In the light-emitting devices 10A and 10B each having the above structure, it is further preferable that the GSP slope of one of the first carrier-transport layers 116_1 and 116_2 positioned closer to the cathode be larger than the GSP slope of the other positioned closer to the anode, and the GSP slope of one of the second carrier-transport layers 117_1 and 117_2 positioned closer to the anode be larger than the GSP slope of the other positioned closer to the cathode.

In the ordered stacked light-emitting device 10A illustrated in FIG. 1B, the first electrode 101 and the second electrode 102 function as an anode and a cathode, respectively, as described above. Thus, in this light-emitting device, one of the light-emitting layer 113 and the first carrier-transport layer 116_1 positioned closer to the cathode refers to the light-emitting layer 113, and the other positioned closer to the anode refers to the first carrier-transport layer 116_1. One of the light-emitting layer 113 and the first carrier-transport layer 116_2 positioned closer to the cathode refers to the light-emitting layer 113, and the other positioned closer to the anode refers to the first carrier-transport layer 116_2. One of the first carrier-transport layer 116_1 and the first carrier-transport layer 116_2 positioned closer to the cathode refers to the first carrier-transport layer 116_2, and the other positioned closer to the anode refers to the first carrier-transport layer 116_1. One of the light-emitting layer 113 and the second carrier-transport layer 117_1 positioned closer to the anode refers to the light-emitting layer 113, and the other positioned closer to the cathode refers to the second carrier-transport layer 117_1. One of the light-emitting layer 113 and the second carrier-transport layer 117_2 positioned closer to the anode refers to the light-emitting layer 113, and the other positioned closer to the cathode refers to the second carrier-transport layer 117_2. One of the second carrier-transport layer 117_1 and the second carrier-transport layer 117_2 positioned closer to the anode refers to the second carrier-transport layer 117_1, and the other positioned closer to the cathode refers to the second carrier-transport layer 117_2.

That is, in the ordered stacked light-emitting device 10A illustrated in FIG. 1B, it is preferable that the GSP slope of the light-emitting layer 113 be larger than the GSP slopes of the first carrier-transport layers 116_1 and 116_2 and the second carrier-transport layers 117_1 and 117_2. In the ordered stacked light-emitting device 10A having the above structure, it is further preferable that the GSP slope of the first carrier-transport layer 116_2 be larger than the GSP slope of the first carrier-transport layer 116_1, and the GSP slope of the second carrier-transport layer 117_1 be larger than the GSP slope of the second carrier-transport layer 117_2.

In that case, as illustrated in FIG. 1B, the negative interface charge 50a remains at the interface between the first carrier-transport layer 116_1 and the first carrier-transport layer 116_2 and at the interface between the first carrier-transport layer 116_2 and the light-emitting layer 113. The negative interface charge 50a attracts holes from the first electrode 101 side to the interface of the light-emitting layer 113 on the first electrode 101 side; thus, an electric field can be effectively applied to the light-emitting layer 113. Furthermore, the positive interface charge 50b remains at the interface between the light-emitting layer 113 and the second carrier-transport layer 117_1 and at the interface between the second carrier-transport layer 117_1 and the second carrier-transport layer 117_2. The positive interface charge 50b attracts electrons from the second electrode 102 side to the interface of the light-emitting layer 113 on the second electrode 102 side; thus, an electric field can be effectively applied to the light-emitting layer 113. Accordingly, effective application of an electric field to the light-emitting layer 113 is easily achieved, which can reduce the driving voltage of the light-emitting device.

Meanwhile, in the inverted stacked light-emitting device 10B illustrated in FIG. 2B, the first electrode 101 and the second electrode 102 function as a cathode and an anode, respectively, as described above. Thus, in this light-emitting device, one of the light-emitting layer 113 and the first carrier-transport layer 116_1 positioned closer to the cathode refers to the first carrier-transport layer 116_1, and the other positioned closer to the anode refers to the light-emitting layer 113. One of the light-emitting layer 113 and the first carrier-transport layer 116_2 positioned closer to the cathode refers to the first carrier-transport layer 116_2, and the other positioned closer to the anode refers to the light-emitting layer 113. One of the first carrier-transport layer 116_1 and the first carrier-transport layer 116_2 positioned closer to the cathode refers to the first carrier-transport layer 116_1, and the other positioned closer to the anode refers to the first carrier-transport layer 116_2. One of the light-emitting layer 113 and the second carrier-transport layer 117_1 positioned closer to the anode refers to the second carrier-transport layer 117_1, and the other positioned closer to the cathode refers to the light-emitting layer 113. One of the light-emitting layer 113 and the second carrier-transport layer 117_2 positioned closer to the anode refers to the second carrier-transport layer 117_2, and the other positioned closer to the cathode refers to the light-emitting layer 113. One of the second carrier-transport layer 117_1 and the second carrier-transport layer 117_2 positioned closer to the anode refers to the second carrier-transport layer 117_2, and the other positioned closer to the cathode refers to the second carrier-transport layer 117_1.

That is, in the inverted stacked light-emitting device 10B illustrated in FIG. 2B, it is preferable that the GSP slopes of the first carrier-transport layers 116_1 and 116_2 and the second carrier-transport layers 117_1 and 117_2 be larger than the GSP slope of the light-emitting layer 113. In the inverted stacked light-emitting device 10B having the above structure, it is further preferable that the GSP slope of the first carrier-transport layer 116_1 be larger than the GSP slope of the first carrier-transport layer 116_2, and the GSP slope of the second carrier-transport layer 117_2 be larger than the GSP slope of the second carrier-transport layer 117_1.

In that case, as illustrated in FIG. 2B, the positive interface charge 50b remains at the interface between the first carrier-transport layer 116_1 and the first carrier-transport layer 116_2 and at the interface between the first carrier-transport layer 116_2 and the light-emitting layer 113. The positive interface charge 50b attracts electrons from the first electrode 101 side to the interface of the light-emitting layer 113 on the first electrode 101 side; thus, an electric field can be effectively applied to the light-emitting layer 113. The negative interface charge 50a remains at the interface between the light-emitting layer 113 and the second carrier-transport layer 117_1 and at the interface between the second carrier-transport layer 117_1 and the second carrier-transport layer 117_2. The negative interface charge 50a attracts holes from the second electrode 102 side to the interface of the light-emitting layer 113 on the second electrode 102 side; thus, an electric field can be effectively applied to the light-emitting layer 113. Accordingly, effective application of an electric field to the light-emitting layer 113 is easily achieved, which can reduce the driving voltage of the light-emitting device.

### <Method for Obtaining GSP Slope>

Here, a method for obtaining a GSP slope of an organic compound film formed by a vacuum evaporation method will be described.

A phenomenon in which a surface potential of an evaporated film increases in proportion to a thickness of the film is called the giant surface potential as described above. In general, a slope of a plot of a surface potential of an evaporated film in the thickness direction by Kelvin probe measurement is assumed as a parameter representing the level of the giant surface potential, that is, a GSP slope (mV/nm); in the case where two different layers are stacked, a change in the density of charges (mC/m²) accumulated at the interface, which is in association with a GSP, can be utilized to estimate a GSP slope.

Non-Patent Document 1 discloses that the following formulae hold when voltage is applied to a stack of organic thin films (a thin film 1 positioned closer to the anode and a thin film 2 positioned closer to the cathode; the anode is positioned closer to the substrate) with different spontaneous polarizations and carriers accumulated at the interface are holes.

$$\begin{matrix}[ Formula 1 ] & \\ {σ}_{if \_ h} = \frac{{Q}_{if}}{S} = ( {V}_{i} - {V}_{bi} ) \frac{{ε}_{2}}{{d}_{2}} & ( 1 )\end{matrix}$$

$$\begin{matrix}[ Formula 2 ] & \\ {σ}_{if \_ h} = {P}_{1} - {P}_{2} = \frac{{ε}_{1} {V}_{1}}{{d}_{1}} - \frac{{ε}_{2} {V}_{2}}{{d}_{2}} & ( 2 )\end{matrix}$$

In Formula (1), θ_{if_h} is an interface charge density, Vᵢ is a hole-injection voltage, V_{bi} is a threshold voltage, d₂ is a thickness of the thin film 2, and ε₂ is a dielectric constant of the thin film 2. Note that Vᵢ and V_{bi} can be estimated from the capacity-voltage characteristics of a device. The square of an ordinary refractive index nₒ (633 nm) can be used as the dielectric constant. As described above, according to Formula (1), the interface charge density σ_{if_h} can be calculated using Vᵢ and V_{bi} estimated from the capacity-voltage characteristics, the dielectric constant 82 of the thin film 2 calculated from the refractive index, and the thickness d₂ of the thin film 2.

Next, in Formula (2), σ_{if_h} is an interface charge density, Pₙ is spontaneous polarization of the thin film n (n represents 1 or 2) in a normal direction of the substrate, εₙ is a dielectric constant of the thin film n, Vₙ is a potential of the film surface, and dₙ is the thickness of the thin film n. By dividing the potential of the film surface (Vₙ) by the thickness (dₙ), a GSP slope can be obtained. Since the interface charge density σ_{if_h} can be obtained from Formula (1), the use of a substance with a known GSP slope and an appropriate dielectric constant for the thin film 2 enables the GSP slope of the thin film 1 to be estimated.

Hereinafter, an example is described in which a GSP slope of 4,4′-bis[N-(1-naphthyl)-N-phenylamino]biphenyl (abbreviation: NPB) is obtained with use of a measurement device 1 fabricated using tris(8-quinolinolato)aluminum (abbreviation: Alq₃) whose GSP slope is known to be 48 (m V/nm) for the thin film 2.

Table 1 shows a device structure of the measurement device 1. Note that layers 1_1 to 4_1 and a cathode in the measurement device 1 are formed from the anode side by a vacuum evaporation method under the conditions where the substrate temperature is set to room temperature and the deposition rate is within the range of 0.2 nm/sec to 0.6 nm/sec. One layer is formed without interruption of evaporation. In the measurement device 1, the layer 2_1 corresponds to the thin film 1 and the layer 3_1 corresponds to the thin film 2. Note that OCHD-003 is an organic compound with an electron-accepting property.

In fabrication of the measurement device, the deposition rate of each layer is preferably within the range of 3 nm/min to 600 nm/min. The thickness of each layer in the measurement device is preferably greater than or equal to 3 nm and less than or equal to 500 nm, further preferably greater than or equal to 50 nm and less than or equal to 300 nm.

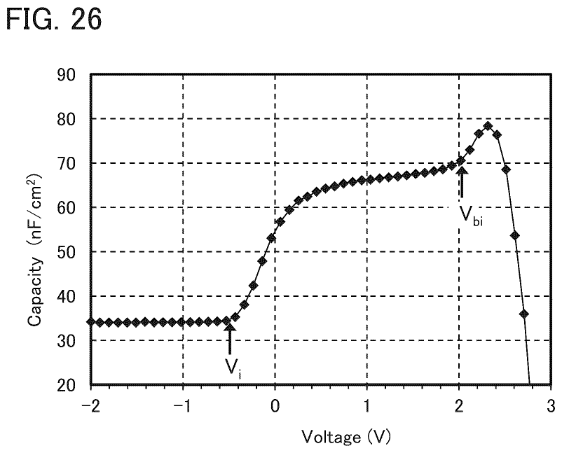

FIG. 26 shows the capacity-voltage characteristics of the measurement device 1.

TABLE 1

| | Thickness | | Measurement device 1 |
|---|---|---|---|
| Cathode | 200 | nm | Al |
| Layer 4_1 | 1 | nm | LiF |
| Layer 3_1 | 60 | nm | Alq₃ |
| Layer 2_1 | 80 | nm | NPB |
| Layer 1_1 | 10 | nm | NPB:OCHD-003 (1:0.1) |
| Anode | 70 | nm | ITSO |

Table 2 shows the hole-injection voltage Vᵢ, the threshold voltage V_{bi}, the interface charge density σ_{if_h}, and a GSP slope of the measurement device 1 that are obtained from FIG. 26 and Formulae (1) and (2) and the refractive indices no of NPB and Alq₃ that are used in the calculation. The refractive indices are measured with a spectroscopic ellipsometer (M-2000U, manufactured by J.A. Woollam Japan Corp.).

TABLE 2

| | Measurement device 1 |
|---|---|
| Hole-injection voltage Vᵢ (V) | −0.53 |
| Threshold voltage V_{bi} (V) | 2.02 |
| Interface charge density σ_{if}_{_{—}}ₕ (mC/m²) | −1.1 |
| Ordinary refractive index nₒ of NPB | 1.77 |
| (@ 633 nm) | |
| Ordinary refractive index nₒ of Alq₃ | 1.71 |
| (@ 633 nm) | |
| GSP slope (mV/nm) | 5.2 |

Note that a measurement device 2 having substantially the same structure as the measurement device 1 except that the thickness of a film of Alq₃ is 80 nm is fabricated. It is confirmed that the hole-injection voltage of the measurement device 2 shifts to a lower voltage side than that of the measurement device 1. That is, it is presumed that holes are injected first and charges are accumulated at the interface with Alq₃ in such a device. Furthermore, the GSP slope is estimated for the measurement device 2 in a manner similar to that for the measurement device 1, and the same results as those of the measurement device 1 are obtained.

In the case where the threshold voltage V_{bi} is difficult to estimate from the capacity-voltage characteristics, a threshold voltage estimated from the current density-voltage characteristics may be used.

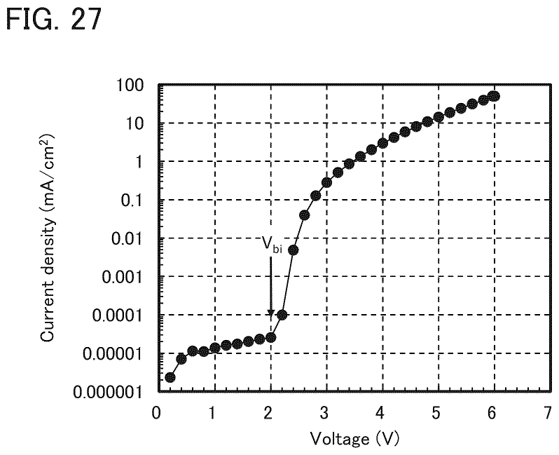

FIG. 27 shows the current density-voltage characteristics of the measurement device 1. Note that V_{bi} estimated from the current density-voltage characteristics is 2.0 V, which is equal to that estimated from the capacity-voltage characteristics.

In this manner, a device in which a film of Alq₃ with a known GSP slope and a film of an organic compound whose GSP slope is to be obtained are stacked is fabricated and the capacity-voltage characteristics are measured, so that the GSP slope of the organic compound can be estimated.

The above is the description of the method for calculating a GSP slope of the case where holes are carriers accumulated at the interface. In the case where electrons are carriers accumulated at the interface, a GSP slope of an organic film can be calculated in a similar manner using Formulae (3) and (4) shown below. In Formulae (3) and (4) shown below, Oif_e is an interface charge density.

$$\begin{matrix}[ Formula 3 ] & \\ {σ}_{if \_ e} = \frac{{Q}_{if}}{S} = ( {V}_{i} - {V}_{b i} ) \frac{{ε}_{1}}{{d}_{1}} & ( 3 )\end{matrix}$$

$$\begin{matrix}[ Formula 4 ] & \\ {σ}_{if \_ e} = - ( {P}_{1} - {P}_{2} ) = - ( \frac{{ε}_{1} {V}_{1}}{{d}_{1}} - \frac{{ε}_{2} {V}_{2}}{{d}_{2}} ) & ( 4 )\end{matrix}$$

Organic compounds used for layers of a light-emitting device are preferably selected in consideration of the GSP slopes of evaporated films of the organic compounds, which are measured in advance by the above measurement method.

Note that a layer formed by co-evaporation of a plurality of kinds of organic compounds is sometimes used for a light-emitting device. The GSP slope of the layer formed by co-evaporation depends on the combination and mixing ratio of organic compounds; thus, the organic compounds are ideally selected in consideration of the GSP slope, which is measured in advance, of a film formed by co-evaporation of the same combination of organic compounds at the same mixing ratio as those for the layer formed by co-evaporation of a plurality of kinds of organic compounds, which is actually used for the light-emitting device. However, this method requires formation of a film by co-evaporation and calculation of a GSP slope for each combination or mixing ratio of organic compounds, which complicates experiments for selecting organic compounds.

Thus, in the case where one layer of a light-emitting device contains a plurality of kinds of organic compounds, the organic compounds are preferably selected on the assumption that the average value of the GSP slopes of evaporated films of the organic compounds that are measured in advance is the GSP slope of the one layer. Accordingly, the organic compounds can be selected relatively easily in consideration of the GSP slope.

Note that in the case where one layer contains a plurality of kinds of organic compounds that significantly differ in content, the organic compounds can be selected on the assumption that the GSP slope of an evaporated film of the organic compound having a high content among the plurality of kinds of organic compounds is the GSP slope of the one layer. For example, in the case where one layer contains two kinds of organic compounds and the content of one organic compound is less than 20 wt % of the total content of the organic compounds in the layer, the layer is determined to contain the one organic compound as a subcomponent and the other having a higher content as a main component, and the GSP slope of an evaporated film of the main component can be regarded as the GSP slope of the layer. In the case where one layer contains three or four kinds of organic compounds and the content of one kind of organic compound is less than 20 wt % of the total content of the organic compounds in the layer, the layer is determined to contain the one kind of organic compound as a subcomponent and the others as main components, and the average GSP slope of evaporated films of the main components can be regarded as the GSP slope of the layer.

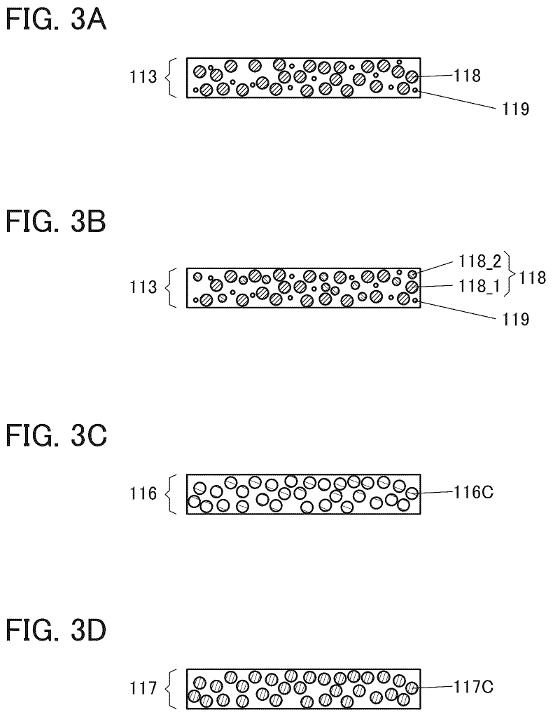

Next, the light-emitting layer 113 of the light-emitting device 10A is described with reference to FIGS. 3A and 3B. In the light-emitting layer 113, host materials 118 are present in the largest proportion by weight, and a guest material 119 is dispersed in the host materials 118.

The light-emitting layer 113 illustrated in FIG. 3A contains the guest material 119 and the host material 118. The guest material 119 is a light-emitting substance. Since the content of the guest material 119 is preferably less than 20 wt % of the total content of the materials in the layer, the light-emitting layer 113 illustrated in FIG. 3A can be regarded as containing the host material 118 as a main component and the guest material 119 as a subcomponent. Thus, organic compounds used for the layers of the light-emitting device are preferably selected on the assumption that the GSP slope of the light-emitting layer 113, which contains only one kind of host material, is the GSP slope of an evaporated film of the host material 118, which is a main component.

The light-emitting layer 113 illustrated in FIG. 3B contains the guest material 119, a first host material 118_1, and a second host material 118_2. In the light-emitting layer 113, it is preferable that the contents of the first host material 118_1 and the second host material 118_2 each be greater than or equal to 25 wt % and the content of the guest material 119 be less than 20 wt % of the total content of the materials in the layer. Thus, the light-emitting layer 113 illustrated in FIG. 3B can be regarded as containing two kinds of host materials (the first host material 118_1 and the second host material 118_2) as main components and the guest material 119 as a subcomponent. Accordingly, organic compounds used for the layers of the light-emitting device are preferably selected on the assumption that the GSP slope of the light-emitting layer 113, which contains the first host material 118_1 and the second host material 118_2 as main components, is the average GSP slope of an evaporated film of the first host material 118_1 and an evaporated film of the second host material 118_2.

As illustrated in FIGS. 3C and 3D, the first carrier-transport layer 116 contains an organic compound 116C as a main component, and the second carrier-transport layer 117 contains an organic compound 117C as a main component. Although not illustrated, the first carrier-transport layer 116_1 contains an organic compound 116_1C as a main component, the first carrier-transport layer 116_2 contains an organic compound 116_2C as a main component, the second carrier-transport layer 117_1 contains an organic compound 117_1C as a main component, and the second carrier-transport layer 117_2 contains an organic compound 117_2C as a main component.

Thus, in the case where the light-emitting devices 10A and 10B are configured such that the GSP slope of one of the light-emitting layer 113 and the first carrier-transport layer 116 positioned closer to the cathode is larger than the GSP slope of the other positioned closer to the anode, and the GSP slope of one of the light-emitting layer 113 and the second carrier-transport layer 117 positioned closer to the anode is larger than the GSP slope of the other positioned closer to the cathode, organic compounds used for the layers are preferably selected as described in the following example.

In the light-emitting devices 10A and 10B each including the first carrier-transport layer 116 and the second carrier-transport layer 117 (see FIG. 1A and FIG. 2A, respectively), it is preferable that the GSP slope of an evaporated film of the main component of one of the light-emitting layer 113 and the first carrier-transport layer 116 positioned closer to the cathode be larger than the GSP slope of an evaporated film of the main component of the other positioned closer to the anode, and the GSP slope of an evaporated film of the main component of one of the light-emitting layer 113 and the second carrier-transport layer 117 positioned closer to the anode be larger than the GSP slope of an evaporated film of the main component of the other positioned closer to the cathode. Note that in the case where the light-emitting layer 113 contains two kinds of host materials (the first host material 118_1 and the second host material 118_2) as main components, the GSP slope of an evaporated film of the main component of the light-emitting layer 113 refers to the average GSP slope of an evaporated film of the first host material 118_1 and an evaporated film of the second host material 118_2.

For example, in the case where the ordered stacked light-emitting device 10A including the first carrier-transport layer 116 and the second carrier-transport layer 117 (see FIG. 1A) has a structure in which the light-emitting layer 113 contains one kind of host material, the host material 118, as a main component (see FIG. 3A), the GSP slope of an evaporated film of the host material 118 is preferably larger than the GSP slopes of an evaporated film of the organic compound 116C and an evaporated film of the organic compound 117C.

For example, in the case where the ordered stacked light-emitting device 10A including the first carrier-transport layer 116 and the second carrier-transport layer 117 (see FIG. 1A) has a structure in which the light-emitting layer 113 contains two kinds of host materials (the first host material 118_1 and the second host material 118_2) (see FIG. 3B), the average GSP slope of an evaporated film of the first host material 118_1 and an evaporated film of the second host material 118_2 is preferably larger than the GSP slopes of an evaporated film of the organic compound 116C and an evaporated film of the organic compound 117C.

In the light-emitting devices 10A and 10B each including the plurality of first carrier-transport layers (the first carrier-transport layers 116_1 and 116_2) and the plurality of second carrier-transport layers (the second carrier-transport layers 117_1 and 117_2) (see FIG. 1B and FIG. 2B, respectively), it is preferable that the GSP slope of an evaporated film of the main component of one of the light-emitting layer 113 and the first carrier-transport layer 116_1 positioned closer to the cathode be larger than the GSP slope of an evaporated film of the main component of the other positioned closer to the anode, the GSP slope of an evaporated film of the main component of one of the light-emitting layer 113 and the first carrier-transport layer 116_2 positioned closer to the cathode be larger than the GSP slope of an evaporated film of the main component of the other positioned closer to the anode, the GSP slope of an evaporated film of the main component of one of the light-emitting layer 113 and the second carrier-transport layer 117_1 positioned closer to the anode be larger than the GSP slope of an evaporated film of the main component of the other positioned closer to the cathode, and the GSP slope of an evaporated film of the main component of one of the light-emitting layer 113 and the second carrier-transport layer 117_2 positioned closer to the anode be larger than the GSP slope of an evaporated film of the main component of the other positioned closer to the cathode. In the light-emitting devices 10A and 10B each having the above structure, it is further preferable that the GSP slope of the evaporated film of the main component of one of the first carrier-transport layers 116_1 and 116_2 positioned closer to the cathode be larger than the GSP slope of the evaporated film of the main component of the other positioned closer to the anode, and the GSP slope of the evaporated film of the main component of one of the second carrier-transport layers 117_1 and 117_2 positioned closer to the anode be larger than the GSP slope of the evaporated film of the main component of the other positioned closer to the cathode. Note that in the case where the light-emitting layer 113 contains two kinds of host materials (the first host material 118_1 and the second host material 118_2) as main components, the GSP slope of an evaporated film of the main component of the light-emitting layer 113 refers to the average GSP slope of an evaporated film of the first host material 118_1 and an evaporated film of the second host material 118_2.

For example, in the case where the ordered stacked light-emitting device 10A including the plurality of first carrier-transport layers (the first carrier-transport layers 116_1 and 116_2) and the plurality of second carrier-transport layers (the second carrier-transport layers 117_1 and 117_2) (see FIG. 1B) has a structure in which the light-emitting layer 113 contains one kind of host material, the host material 118 (see FIG. 3A), the GSP slope of an evaporated film of the host material 118 is preferably larger than the GSP slopes of an evaporated film of the organic compound 116_1C, an evaporated film of the organic compound 116_2C, an evaporated film of the organic compound 117_1C, and an evaporated film of the organic compound 117_2C. In the ordered stacked light-emitting device 10A having the above structure, it is further preferable that the GSP slope of the evaporated film of the organic compound 116_2C be larger than the GSP slope of the evaporated film of the organic compound 116_1C, and the GSP slope of the evaporated film of the organic compound 117_1C be larger than the GSP slope of the evaporated film of the organic compound 117_2C.

For example, in the case where the ordered stacked light-emitting device 10A including the plurality of first carrier-transport layers (the first carrier-transport layers 116_1 and 116_2) and the plurality of second carrier-transport layers (the second carrier-transport layers 117_1 and 117_2) (see FIG. 1B) has a structure in which the light-emitting layer 113 contains two kinds of host materials (the first host material 118_1 and the second host material 118_2) (see FIG. 3B), the average GSP slope of an evaporated film of the first host material 118_1 and an evaporated film of the second host material 118_2 is preferably larger than the GSP slopes of an evaporated film of the organic compound 116_1C, an evaporated film of the organic compound 116_2C, an evaporated film of the organic compound 117_1C, and an evaporated film of the organic compound 117_2C. In the ordered stacked light-emitting device 10A having the above structure, it is further preferable that the GSP slope of the evaporated film of the organic compound 116_2C be larger than the GSP slope of the evaporated film of the organic compound 116_1C, and the GSP slope of the evaporated film of the organic compound 117_1C be larger than the GSP slope of the evaporated film of the organic compound 117_2C.

When organic compounds used for the layers are selected as in the above examples, the light-emitting devices 10A and 10B can each have a low driving voltage. Note that the structure of the light-emitting device of one embodiment of the present invention is not limited to the above examples.

In the case where a layer formed by co-evaporation of a plurality of kinds of organic compounds is used as one or more layers of the first carrier-transport layer 116 and the second carrier-transport layer 117, for example, the organic compounds can be selected in consideration of the GSP slope, which is measured in advance, of a film formed by co-evaporation of the same combination of organic compounds at the same mixing ratio as those for the layer formed by co-evaporation of a plurality of kinds of organic compounds. Alternatively, as described above, the organic compounds can be selected on the assumption that the average value of the GSP slopes of evaporated films of the organic compounds that are measured in advance is the GSP slope of the layer formed by co-evaporation of a plurality of kinds of organic compounds. In the case where the layer contains a plurality of kinds of organic compounds that significantly differ in content, the organic compound having a high content among the plurality of kinds of organic compounds is determined as a main component, and the organic compounds can be selected on the assumption that the GSP slope of an evaporated film of the main component is the GSP slope of the layer.

For example, in the case of a light-emitting device including three or more of the first carrier-transport layers 116 and three or more of the second carrier-transport layers 117, organic compounds can be selected such that the GSP slope of an evaporated film of the organic compound used for a layer positioned closer to the cathode is larger than the GSP slope of an evaporated film of the organic compound used for a layer positioned closer to the anode among three or more of the first carrier-transport layers 116, and the GSP slope of an evaporated film of the organic compound used for a layer positioned closer to the anode is larger than the GSP slope of an evaporated film of the organic compound used for a layer positioned closer to the cathode among the three or more of the second carrier-transport layers 117.

Moreover, when the first carrier-transport layer 116 and the second carrier-transport layer 117 each have a lower refractive index in the light-emitting device of one embodiment of the present invention having the above structure, light extraction efficiency can be further increased. As a result, an extremely favorable light-emitting device having high emission efficiency and a low driving voltage can be provided.

Thus, it is further preferable to select organic compounds used for the layers of the light-emitting device in consideration of not only the GSP slopes of films of the organic compounds but also the refractive indices thereof that are measured in advance.

In the case where one layer contains a plurality of kinds of organic compounds, the organic compounds can be selected in consideration of the refractive index, which is measured in advance, of a film formed using the same combination of organic compounds and the same mixing ratio as those for the one layer. Alternatively, the organic compounds can be selected on the assumption that the average value of the refractive indices of films of the organic compounds that are measured in advance is the refractive index of the one layer.

Note that in the case where one layer contains a plurality of kinds of organic compounds that significantly differ in content, the organic compounds can be selected on the assumption that the refractive index of a film of the organic compound having a high content among the plurality of kinds of organic compounds is the refractive index of the one layer. For example, in the case where one layer contains two kinds of organic compounds and the content of one organic compound is less than 20 wt % of the total content of the organic compounds in the layer, the refractive index of a film of the other organic compound can be regarded as the refractive index of the layer without considering the one organic compound. In the case where one layer contains three or more kinds of organic compounds and the content of one kind of organic compound is less than 20 wt % of the total content of the organic compounds in the layer, the average refractive index of films of the other organic compounds can be regarded as the refractive index of the layer without considering the one kind of organic compound.

When the light-emitting layer 113 contains only one kind of host material (see FIG. 3A), organic compounds used for the layers of the light-emitting device can be selected on the assumption that the refractive index of the light-emitting layer 113 is the refractive index of a film of the host material 118.

When the light-emitting layer 113 contains two kinds of host materials (see FIG. 3B), organic compounds used for the layers of the light-emitting device can be selected on the assumption that the refractive index of the light-emitting layer 113 is the average refractive index of a film of the first host material 118_1 and a film of the second host material 118_2.

Thus, in the case where the light-emitting devices 10A and 10B are configured such that the first carrier-transport layer 116 and the second carrier-transport layer 117 each have a low refractive index while a GSP slope is considered, selecting organic compounds used for the layers as described in the following example enables the light-emitting devices to have a higher light extraction efficiency.

For example, in the case where the light-emitting devices 10A and 10B each including the first carrier-transport layer 116 and the second carrier-transport layer 117 (see FIG. 1A and FIG. 2A, respectively) have a structure in which the light-emitting layer 113 contains only one kind of host material, the host material 118 (see FIG. 3A), it is further preferable that the refractive index of at least one of a film of the organic compound 116C and a film of the organic compound 117C be lower than the refractive index of a film of the host material 118 at the peak wavelength of the electroluminescence spectrum of the light-emitting device, and it is still further preferable that the refractive indices of the two films of the organic compounds be lower than the refractive index of the film of the host material 118 at the peak wavelength of the electroluminescence spectrum of the light-emitting device. In addition, it is further preferable that the refractive index of at least one of the film of the organic compound 116C and the film of the organic compound 117C be less than or equal to 1.75 at the peak wavelength of the electroluminescence spectrum of the light-emitting device, and it is still further preferable that the refractive indices of the two films of the organic compounds be less than or equal to 1.75 at the peak wavelength of the electroluminescence spectrum of the light-emitting device.

For example, in the case where the light-emitting devices 10A and 10B each including the first carrier-transport layer 116 and the second carrier-transport layer 117 (see FIG. 1A and FIG. 2A, respectively) have a structure in which the light-emitting layer 113 contains two kinds of host materials (the first host material 118_1 and the second host material 118_2) (see FIG. 3B), it is further preferable that the refractive index of at least one of a film of the organic compound 116C and a film of the organic compound 117C be lower than the average refractive index of a film of the first host material 118_1 and a film of the second host material 118_2 at the peak wavelength of the electroluminescence spectrum of the light-emitting device, and it is still further preferable that the refractive indices of the two films of the organic compounds be lower than the average refractive index of the film of the first host material 118_1 and the film of the second host material 118_2 at the peak wavelength of the electroluminescence spectrum of the light-emitting device. In addition, it is further preferable that the refractive index of at least one of the film of the organic compound 116C and the film of the organic compound 117C be less than or equal to 1.75 at the peak wavelength of the electroluminescence spectrum of the light-emitting device, and it is still further preferable that the refractive indices of the two films of the organic compounds be less than or equal to 1.75 at the peak wavelength of the electroluminescence spectrum of the light-emitting device.

For example, in the case where the light-emitting devices 10A and 10B each including the plurality of first carrier-transport layers (the first carrier-transport layers 116_1 and 116_2) and the plurality of second carrier-transport layers (the second carrier-transport layers 117_1 and 117_2) (see FIG. 1B and FIG. 2B, respectively) have a structure in which the light-emitting layer 113 contains only one kind of host material, the host material 118 (see FIG. 3A), it is further preferable that the refractive index of at least one of a film of the organic compound 116_1C, a film of the organic compound 116_2C, a film of the organic compound 117_1C, and a film of the organic compound 117_2C be lower than the refractive index of a film of the host material 118 at the peak wavelength of the electroluminescence spectrum of the light-emitting device, and it is still further preferable that the refractive indices of two or more of the films of the organic compounds be lower than the refractive index of the film of the host material 118 at the peak wavelength of the electroluminescence spectrum of the light-emitting device. In addition, it is further preferable that the refractive index of at least one of the film of the organic compound 116_1C, the film of the organic compound 116_2C, the film of the organic compound 117_1C, and the film of the organic compound 117_2C be less than or equal to 1.75 at the peak wavelength of the electroluminescence spectrum of the light-emitting device, and it is still further preferable that the refractive indices of two or more of the films of the organic compounds be less than or equal to 1.75 at the peak wavelength of the electroluminescence spectrum of the light-emitting device.

For example, in the case where the light-emitting devices 10A and 10B each including the plurality of first carrier-transport layers (the first carrier-transport layers 116_1 and 116_2) and the plurality of second carrier-transport layers (the second carrier-transport layers 117_1 and 117_2) (see FIG. 1B and FIG. 2B, respectively) have a structure in which the light-emitting layer 113 contains two kinds of host materials (the first host material 118_1 and the second host material 118_2) (see FIG. 3B), it is further preferable that the refractive index of at least one of a film of the organic compound 116_1C, a film of the organic compound 116_2C, a film of the organic compound 117_1C, and a film of the organic compound 117_2C be lower than the average refractive index of a film of the first host material 118_1 and a film of the second host material 118_2 at the peak wavelength of the electroluminescence spectrum of the light-emitting device, and it is still further preferable that the refractive indices of two or more of the films of the organic compounds be lower than the average refractive index of the film of the first host material 118_1 and the film of the second host material 118_2 at the peak wavelength of the electroluminescence spectrum of the light-emitting device. In addition, it is further preferable that the refractive index of at least one of the film of the organic compound 116_1C, the film of the organic compound 116_2C, the film of the organic compound 117_1C, and the film of the organic compound 117_2C be less than or equal to 1.75 at the peak wavelength of the electroluminescence spectrum of the light-emitting device, and it is still further preferable that the refractive indices of two or more of the films of the organic compounds be less than or equal to 1.75 at the peak wavelength of the electroluminescence spectrum of the light-emitting device. Note that in the case where the electroluminescence spectrum has a plurality of peak wavelengths, the above-described relationship between refractive indices is preferably satisfied at the maximum peak wavelength or at least one of the peak wavelengths. Alternatively, the above-described relationship between refractive indices may be satisfied at the peak wavelength of the emission spectrum of the light-emitting material used for the light-emitting device. The emission spectrum of the light-emitting material can be measured using a thin film of the light-emitting material or a solution of the light-emitting material.

Note that as a material with a low refractive index, it is preferable to use an organic compound in which an alkyl group having smaller polarizability than an aromatic skeleton is bonded to the aromatic skeleton. In particular, it is further preferable to use an organic compound having at least one group selected from chain alkyl groups having 2 to 10 carbon atoms and cycloalkyl groups having 6 to 12 carbon atoms.

Note that a film formed by a vacuum evaporation method using a general compound having an alkyl group and an aromatic skeleton is likely to have an extremely large positive GSP slope. This is because the alkyl group exhibits an electron-donating property with respect to the aromatic skeleton, which facilitates generation of a permanent electric dipole moment that is positively charged on the alkyl group side, and this is also because the aromatic skeleton is, compared to the alkyl group, likely to be drawn to a base substrate, an electrode, and a deposited organic material by the Van der Waals force, whereby the molecule is easily oriented with its alkyl group facing the film surface side.

As described above, in the light-emitting device of one embodiment of the present invention, not only the low refractive indices of the first carrier-transport layer 116 and the second carrier-transport layer 117 but also the relationship between the GSP slopes of these layers and peripheral layers is important. The first carrier-transport layer 116 and the second carrier-transport layer 117 are each required to have a small GSP slope in the ordered stacked light-emitting device and required to have a large GSP slope in the inverted stacked light-emitting device. Thus, the first carrier-transport layer 116 and the second carrier-transport layer 117 of the inverted stacked light-emitting device are each preferably formed by a vacuum evaporation method using a general material with a low refractive index having an alkyl group and an aromatic skeleton, in which case the first carrier-transport layer 116 and the second carrier-transport layer 117 can each easily have an extremely large positive GSP slope. Meanwhile, the ordered stacked light-emitting device requires a compound that can be formed into an evaporated film having a small GSP slope among compounds with a devised molecular structure having an alkyl group and an aromatic skeleton.

Specific examples of organic compounds that can be used for the light-emitting layer 113, the first carrier-transport layer 116, and the second carrier-transport layer 117 of the ordered stacked light-emitting device will be described with structural formulae. Note that the GSP slopes and refractive indices of evaporated films of the organic compounds given below as specific examples are shown in Example 1 or Example 2.

As the host material 118 of the light-emitting layer 113, an organic compound that is formed into an evaporated film having a relatively large GSP slope is preferably used. Specifically, it is preferable to use an organic compound having a heteroaromatic ring containing at least one of a nitrogen atom, an oxygen atom, and a sulfur atom. It is further preferable to use an organic compound having a heteroaromatic ring with low symmetry among heteroaromatic rings containing at least one of a nitrogen atom, an oxygen atom, and a sulfur atom. Such a heteroaromatic ring facilitates generation of a strong permanent electric dipole moment in the molecule, and with use of the organic compound, a film having a large GSP slope is easily obtained. Specific examples of the heteroaromatic ring containing at least one of a nitrogen atom, an oxygen atom, and a sulfur atom include a dibenzofuran ring, a benzonaphthofuran ring, a dibenzothiophene ring, an imidazole ring, a carbazole ring, and an indolocarbazole ring.

Specific examples of the organic compound that can be used as the host material 118 of the light-emitting layer 113 of the ordered stacked light-emitting device include 4-(9H-carbazol-9-yl)-8-(dibenzofuran-2-yl)-[1]benzofuro-[3,2-d]pyrimidine (abbreviation: 8DBf-4CzBfpm), 12,12′-(biphenyl-3,3′-diyl)bis(5,12-dihydro-5-phenylindolo[3,2-a]-5H,12H-carbazole) (abbreviation: mICz2BP), and 1-[10-(phenyl-2,3,4,5,6-d₅)-9-anthryl]benzo[b]naphtho[2,3-d]furan (abbreviation: Bnf (II) PhA-02-d₅). Shown below are the structural formulae of the organic compounds.

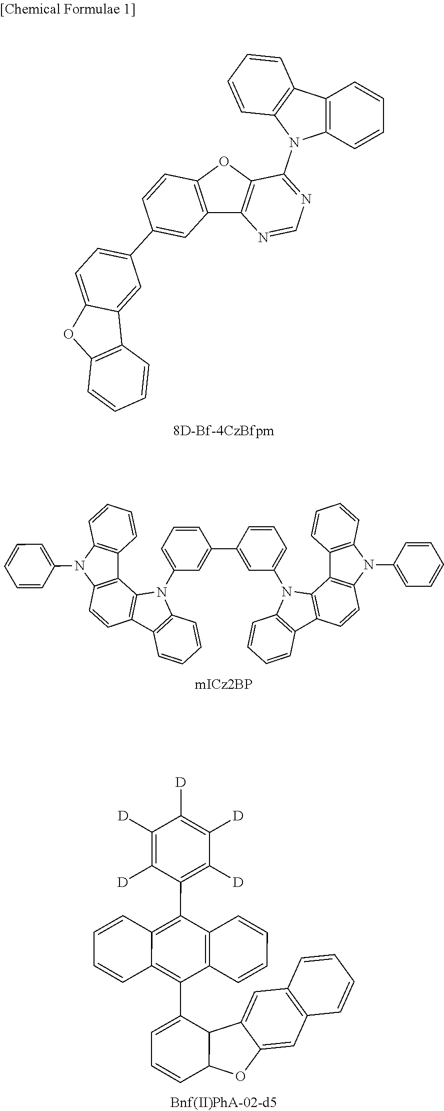 [SMILES: c1ccc2c(c1)oc1ccc(-c3ccc4oc5c(-n6c7ccccc7c7ccccc76)ncnc5c4c3)cc12 ; c1ccc(-n2c3ccccc3c3c2ccc2c4ccccc4n(-c4cccc(-c5cccc(-n6c7ccccc7c7ccc8c(c9ccccc9n8-c8ccccc8)c76)c5)c4)c23)cc1 ; [2H]c1c([2H])c([2H])c(-c2c3ccccc3c(C3=CC=CC4Oc5cc6ccccc6cc5C34)c3ccccc23)c([2H])c1[2H]]

As the organic compound used for the first carrier-transport layer 116 of the ordered stacked light-emitting device, a hole-transport organic compound that is formed into an evaporated film having a relatively small GSP slope is preferably used. Specifically, an organic compound having any of aromatic skeletons and heteroaromatic skeletons such as a π-electron rich heteroaromatic ring and an aromatic amine skeleton is preferably used, and an organic compound having an aromatic skeleton or a heteroaromatic skeleton containing a nitrogen element and having high symmetry is further preferably used. Owing to molecular symmetry, such a skeleton inhibits or cancels polarization generated from the nitrogen element, so that a permanent electric dipole moment is less likely to be generated in the molecule. As a result, a film having a small GSP slope is easily obtained. Examples of the π-electron rich heteroaromatic ring include a heteroaromatic ring having a pyrrole skeleton, a heteroaromatic ring having a furan skeleton, and a heteroaromatic ring having a thiophene skeleton. Examples of the aromatic skeleton or the heteroaromatic skeleton containing a nitrogen element and having high symmetry include a triphenylamine skeleton and a 3,3′-bicarbazole skeleton.

Specific examples of the organic compound used for the first carrier-transport layer 116 of the ordered stacked light-emitting device include organic compounds having a π-electron rich heteroaromatic ring or an aromatic amine skeleton, such as N,N-bis(biphenyl-4-yl)-9,9′-spirobi[9H-fluoren]-2-amine (abbreviation: BBASF), N-(biphenyl-2-yl)-N-(3″,5′, 5″-tri-tert-butyl-[1,1′: 3′,1″-terphenyl]-4-yl)-9,9-dimethyl-9H-fluoren-2-amine (abbreviation: mmtBumTPOFBi-04), N,N-bis(4-cyclohexylphenyl)-9,9′-spirobi[9H-fluoren]-2-amine (abbreviation: dchPASF), N-phenyl-N-[4-(9-phenyl-9H-carbazol-3-yl)phenyl]-9,9′-spirobi[9H-fluoren]-2-amine (abbreviation: PCBASF), N-(3′,5′-di-tert-butyl-biphenyl-4-yl)-N-(9,9-dimethyl-9H-fluoren-4-yl)-9,9-dimethyl-9H-fluoren-2-amine (abbreviation: mmtBuBiFF-02), and N-(3′,5′-ditertiarybutylbiphenyl-4-yl)-N-(biphenyl-2-yl)-9,9-dimethyl-9H-fluoren-2-amine (abbreviation: mmtBuBioFBi). Shown below are the structural formulae of the organic compounds.

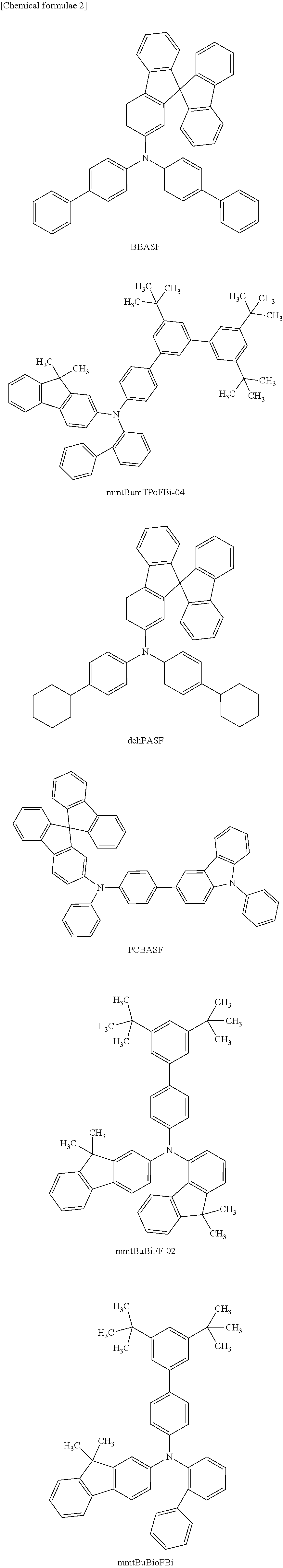

Among the above organic compounds, mmtBumTPOFBi-04, dchPASF, mmtBuBiFF-02, and mmtBuBioFBi each have at least one group selected from chain alkyl groups having 2 to 10 carbon atoms and cycloalkyl groups having 6 to 12 carbon atoms and thus have a low refractive index. Thus, these organic compounds are further preferably used for the first carrier-transport layer 116 of the ordered stacked light-emitting device.

As the organic compound used for the second carrier-transport layer 117 of the ordered stacked light-emitting device, an electron-transport organic compound that is formed into an evaporated film having a relatively small GSP slope is preferably used. Specifically, an organic compound that has a heteroaromatic skeleton containing at least one of a nitrogen atom, an oxygen atom, and a sulfur atom and having high symmetry is further preferable. Owing to molecular symmetry, this skeleton inhibits or cancels polarization generated from at least one of the nitrogen atom, the oxygen atom, and the sulfur atom, so that a permanent electric dipole moment is hardly generated in the molecule. As a result, a film having a small GSP slope is easily obtained. Examples of the heteroaromatic skeleton containing at least one of a nitrogen atom, an oxygen atom, and a sulfur atom and having high symmetry include a pyrimidine skeleton, a pyrazine skeleton, a triazine skeleton, and a 4,4′-bipyridine skeleton.

Specific examples of the organic compound used for the second carrier-transport layer 117 of the ordered stacked light-emitting device include organic compounds having a π-electron deficient heteroaromatic ring, such as 2-{3-(2,6-dimethylpyridin-3-yl)-5-[(3,5-di-tert-butyl)phenyl]phenyl}-4,6-diphenyl-1,3,5-triazine (abbreviation: mmtBuPh-mDMePyPTzn), 2-[3-(2,6-dimethyl-3-pyridinyl)-5-(9-phenanthryl)phenyl]-4,6-diphenyl-1,3,5-triazine (abbreviation: mPn-mDMePyPTzn), 2-(biphenyl-2-yl)-4-[3-(3,5-dicyclohexylphenyl)-5-(2,6-dimethylpyridin-3-yl)]phenyl-6-phenyl-1,3,5-triazine (abbreviation: oBP-mmchPh-mDMePyPTzn), 2-[3,5-bis(2,6-dimethylpyridin-3-yl)phenyl]-4-(3′,5′-di-tert-butylbiphenyl-4-yl)-6-phenyl-1,3,5-triazine (abbreviation: mmtBuBP-DMePy2PTzn), 2,4,6-tris(3′-(pyridin-3-yl) biphenyl-3-yl)-1,3,5-triazine (abbreviation: TmPPPyTz), and 8-quinolinolato-lithium (abbreviation: Liq). Shown below are the structural formulae of the organic compounds.

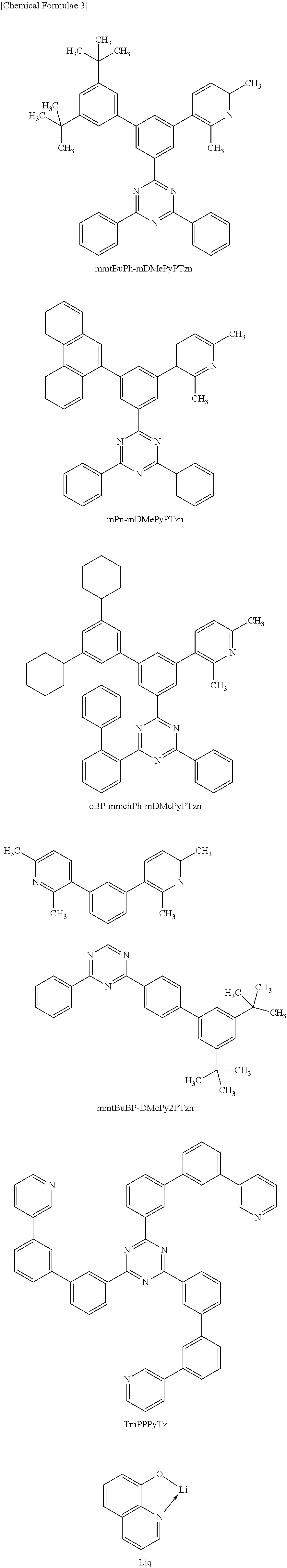

Among the above organic compounds, mmtBuPh-mDMePyPTzn, oBP-mmchPh-mDMePyPTzn, and mmtBuBP-DMePy2PTzn each have at least one group selected from chain alkyl groups having 2 to 10 carbon atoms and cycloalkyl groups having 6 to 12 carbon atoms and thus have a low refractive index. Thus, these organic compounds are further preferably used for the second carrier-transport layer 117 of the ordered stacked light-emitting device.

Generally, in a stacked-layer structure including a hole-injection layer and the components thereover up to a light-emitting layer of a light-emitting device, when a material having a high HOMO level is used for a layer closer to the hole-injection layer and a material having a low HOMO level is used for a layer closer to the light-emitting layer, a hole barrier due to a potential gap is generated at the interface between the layers and hinders hole injection, which tends to cause a problem of a high driving voltage of the light-emitting device.

Meanwhile, the light-emitting device of one embodiment of the present invention achieves a low driving voltage by utilizing the interface charge in the stacked films, which is derived from the polarization charge. Thus, the light-emitting device can have a low driving voltage even when the HOMO level of the organic compound 116_1C is higher than the HOMO level of the organic compound 116_2C, for example.

The values of HOMO and LUMO levels used in this specification can be obtained by electrochemical measurement. Typical examples of the electrochemical measurement include cyclic voltammetry (CV) measurement and differential pulse voltammetry (DPV) measurement.

In the cyclic voltammetry (CV) measurement, the values (E) of HOMO and LUMO levels can be calculated on the basis of an oxidation peak potential (Eₚₐ) and a reduction peak potential (E_{pc}), which are obtained by changing the potential of a working electrode with respect to a reference electrode. In the measurement, a HOMO level and a LUMO level are obtained by potential scanning in the positive direction and potential scanning in the negative direction, respectively. The scanning speed in the measurement is 0.1 V/s.

Calculation steps of the HOMO level and the LUMO level are described in detail. A standard oxidation-reduction potential (Eₒ) (=Eₚₐ+E_{pc})/2) is calculated from an oxidation peak potential (Eₚₐ) and a reduction peak potential (E_{pc}), which are obtained by the cyclic voltammogram of a material. Then, the standard oxidation-reduction potential (Eₒ) is subtracted from the potential energy (Eₓ) of the reference electrode with respect to a vacuum level, whereby each of the values (E) (=Eₓ−Eₒ) of HOMO and LUMO levels can be obtained.

Note that the reversible oxidation-reduction wave is obtained in the above case; in the case where an irreversible oxidation-reduction wave is obtained, the HOMO level is calculated as follows: a value obtained by subtracting a predetermined value (0.1 eV) from an oxidation peak potential (Eₚₐ) is assumed to be a reduction peak potential (E_{pc}), and a standard oxidation-reduction potential (Eₒ) is calculated to one decimal place. To calculate the LUMO level, a value obtained by adding a predetermined value (0.1 eV) to a reduction peak potential (E_{pc}) is assumed to be an oxidation peak potential (Eₚₐ), and a standard oxidation-reduction potential (Eₒ) is calculated to one decimal place.

Note that the compounds described in this embodiment can be used in combination with any of the structures described in the other embodiments as appropriate.

### Embodiment 2

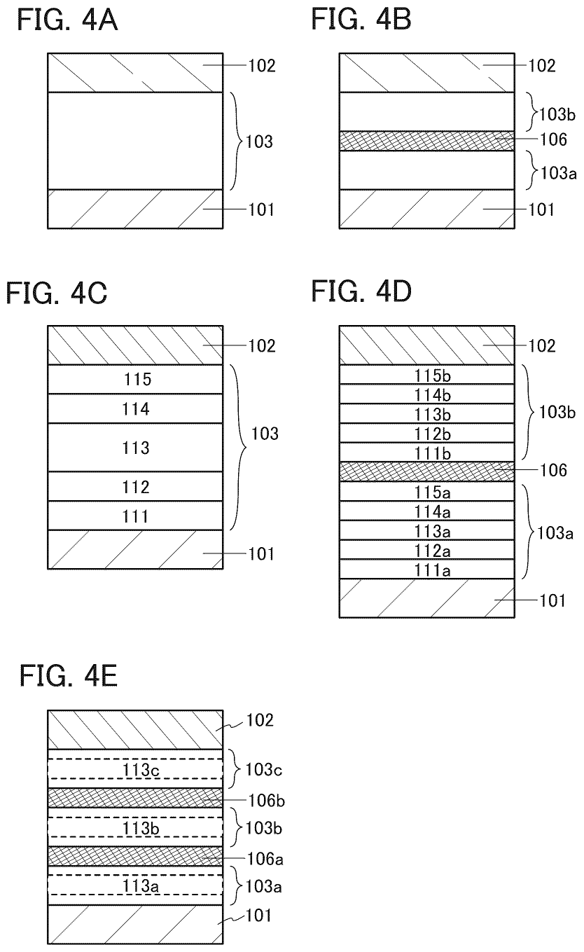

In this embodiment, other structures of a light-emitting device of one embodiment of the present invention are described with reference to FIGS. 4A to 4E.

### <Basic Structure of Light-Emitting Device>

Basic structures of the light-emitting device will be described. FIG. 4A illustrates a (single structure) light-emitting device including, between a pair of electrodes, an organic compound layer including a light-emitting layer. Specifically, the organic compound layer 103 is sandwiched between the first electrode 101 and the second electrode 102.

FIG. 4B illustrates a light-emitting device that has a stacked-layer structure (tandem structure) in which a plurality of organic compound layers (two organic compound layers 103a and 103b in FIG. 4B) are provided between a pair of electrodes and a charge-generation layer 106 is provided between the organic compound layers. A light-emitting device having a tandem structure enables manufacturing a light-emitting apparatus that increases efficiency without changing the amount of current.

The charge-generation layer 106 has a function of injecting electrons into one of the organic compound layers 103a and 103b and injecting holes into the other of the organic compound layers 103a and 103b when a potential difference is caused between the first electrode 101 and the second electrode 102. Thus, when voltage is applied in FIG. 4B so that the potential of the first electrode 101 is higher than that of the second electrode 102, the charge-generation layer 106 injects electrons into the organic compound layer 103a and injects holes into the organic compound layer 103b.

Note that in terms of light extraction efficiency, the charge-generation layer 106 preferably has a property of transmitting visible light (specifically, the charge-generation layer 106 preferably has a visible light transmittance higher than or equal to 40%). The charge-generation layer 106 functions even if it has lower conductivity than the first electrode 101 and the second electrode 102.

FIG. 4C illustrates a stacked-layer structure of the organic compound layer 103 in the light-emitting device of one embodiment of the present invention. In this case, the first electrode 101 is regarded as functioning as an anode, and the second electrode 102 is regarded as functioning as a cathode. The organic compound layer 103 has a structure in which the hole-injection layer 111, a hole-transport layer 112, the light-emitting layer 113, an electron-transport layer 114, and the electron-injection layer 115 are stacked in this order over the first electrode 101. Note that the light-emitting layer 113 may have a stacked-layer structure of a plurality of light-emitting layers that emit light of different colors. For example, a light-emitting layer containing a light-emitting substance that emits red light, a light-emitting layer containing a light-emitting substance that emits green light, and a light-emitting layer containing a light-emitting substance that emits blue light may be stacked with or without a layer containing a carrier-transport material therebetween. Alternatively, a light-emitting layer containing a light-emitting substance that emits yellow light and a light-emitting layer containing a light-emitting substance that emits blue light may be used in combination. Note that the stacked-layer structure of the light-emitting layer 113 is not limited to the above. For example, the light-emitting layer 113 may have a stacked-layer structure of a plurality of light-emitting layers that emit light of the same color. For example, a first light-emitting layer containing a light-emitting substance that emits blue light and a second light-emitting layer containing a light-emitting substance that emits blue light may be stacked with or without a layer containing a carrier-transport material therebetween. The structure in which a plurality of light-emitting layers that emit light of the same color are stacked can sometimes achieve higher reliability than a single-layer structure. In the case where a plurality of organic compound layers are provided as in the tandem structure illustrated in FIG. 4B, the layers in each organic compound layer are sequentially stacked from the anode side as described above. When the first electrode 101 functions as a cathode and the second electrode 102 functions as an anode, the stacking order of the layers in the organic compound layer 103 is reversed. Specifically, the layer 111 over the first electrode 101 functioning as a cathode is an electron-injection layer; the layer 112 is an electron-transport layer; the layer 113 is a light-emitting layer; the layer 114 is a hole-transport layer; and the layer 115 is a hole-injection layer.

The light-emitting layer 113 included in the organic compound layers (103, 103a, and 103b) includes an appropriate combination of a light-emitting substance and a plurality of substances, so that fluorescent light of a desired color or phosphorescent light of a desired color can be obtained. The light-emitting layer 113 may have a stacked-layer structure having different emission colors. In that case, a light-emitting substance and other substances are different between the stacked light-emitting layers. Alternatively, the plurality of organic compound layers (103a and 103b) in FIG. 4B may exhibit their respective emission colors. Also in this case, the light-emitting substance and the other substances can differ between the light-emitting layers.

The light-emitting device of one embodiment of the present invention can have a micro optical resonator (microcavity) structure when, for example, the first electrode 101 is a reflective electrode and the second electrode 102 is a transflective electrode in FIG. 4C. Thus, light from the light-emitting layer 113 in the organic compound layer 103 can be resonated between the electrodes and light emitted through the second electrode 102 can be intensified. Thus, high definition can be easily achieved. In addition, emission intensity at a predetermined wavelength in the front direction can be increased, whereby power consumption can be reduced.

Note that when the first electrode 101 of the light-emitting device is a reflective electrode having a stacked-layer structure of a reflective conductive material and a light-transmitting conductive material (transparent conductive film), optical adjustment can be performed by adjusting the thickness of the transparent conductive film. Specifically, when the wavelength of light obtained from the light-emitting layer 113 is λ, the optical path length between the first electrode 101 and the second electrode 102 (the product of the thickness and the refractive index) is preferably adjusted to be mλ/2 (m is an integer greater than or equal to 1) or close to mλ/2.

To amplify desired light (wavelength: λ) obtained from the light-emitting layer 113, it is preferable to adjust each of the optical path length from the first electrode 101 to a region where the desired light is obtained in the light-emitting layer 113 (light-emitting region) and the optical path length from the second electrode 102 to the region where the desired light is obtained in the light-emitting layer 113 (light-emitting region) to be (2m′+1) λ/4 (m′ is an integer greater than or equal to 1) or close to (2m′+1) λ/4. Here, the light-emitting region means a region where holes and electrons are recombined in the light-emitting layer 113.

By such optical adjustment, the spectrum of specific monochromatic light obtained from the light-emitting layer 113 can be narrowed and light emission with high color purity can be obtained.

In the above case, the optical path length between the first electrode 101 and the second electrode 102 is, to be exact, the total thickness from a reflective region in the first electrode 101 to a reflective region in the second electrode 102. However, it is difficult to precisely determine the reflective regions in the first electrode 101 and the second electrode 102; thus, it is assumed that the above effect can be sufficiently obtained wherever the reflective regions may be set in the first electrode 101 and the second electrode 102. Furthermore, the optical path length between the first electrode 101 and the light-emitting layer that emits the desired light is, to be exact, the optical path length between the reflective region in the first electrode 101 and the light-emitting region in the light-emitting layer that emits the desired light. However, it is difficult to precisely determine the reflective region in the first electrode 101 and the light-emitting region in the light-emitting layer that emits the desired light; thus, it is assumed that the above effect can be sufficiently obtained wherever the reflective region and the light-emitting region may be set in the first electrode 101 and the light-emitting layer that emits the desired light, respectively.

The light-emitting device illustrated in FIG. 4D is a light-emitting device having the tandem structure. The tandem structure enables a light-emitting device to emit light with high luminance. Furthermore, the amount of current needed for obtaining a predetermined luminance can be smaller in the tandem structure than in the single structure; thus, the tandem structure enables higher reliability. In addition, power consumption can be reduced.

The light-emitting device illustrated in FIG. 4E is an example of the light-emitting device having the tandem structure illustrated in FIG. 4B, and includes three organic compound layers (103a, 103b, and 103c) stacked with charge-generation layers (106a and 106b) positioned therebetween, as illustrated in FIG. 4E. The three organic compound layers (103a, 103b, and 103c) include respective light-emitting layers (113a, 113b, and 113c), and the emission colors of the light-emitting layers can be selected freely. For example, the light-emitting layer 113a can emit blue light, the light-emitting layer 113b can emit red light, green light, or yellow light, and the light-emitting layer 113c can emit blue light; alternatively, the light-emitting layer 113a can emit red light, the light-emitting layer 113b can emit blue light, green light, or yellow light, and the light-emitting layer 113c can emit red light.

In the above light-emitting device of one embodiment of the present invention, at least one of the first electrode 101 and the second electrode 102 is a light-transmitting electrode (e.g., a transparent electrode or a transflective electrode). In the case where the light-transmitting electrode is a transparent electrode, the transparent electrode has a visible light transmittance higher than or equal to 40%. In the case where the light-transmitting electrode is a transflective electrode, the transflective electrode has a visible light reflectance higher than or equal to 20% and lower than or equal to 80%, preferably higher than or equal to 40% and lower than or equal to 70%. These electrodes preferably have a resistivity lower than or equal to 1×10⁻² Ω·cm.

When one of the first electrode 101 and the second electrode 102 is a reflective electrode in the above light-emitting device of one embodiment of the present invention, the visible light reflectance of the reflective electrode is higher than or equal to 40% and lower than or equal to 100%, preferably higher than or equal to 70% and lower than or equal to 100%. This electrode preferably has a resistivity lower than or equal to 1×10⁻² Ω·cm.

### <Specific Structure of Light-Emitting Device>

Next, a specific structure of the light-emitting device of one embodiment of the present invention will be described. Here, the description is made using FIG. 4D illustrating the tandem structure. Note that the structure of the organic compound layer applies also to the structure of the light-emitting devices having the single structure in FIGS. 4A and 4C. When the light-emitting device in FIG. 4D has a microcavity structure, the first electrode 101 is formed as a reflective electrode and the second electrode 102 is formed as a transflective electrode. Thus, a single-layer structure or a stacked-layer structure can be formed using one or more kinds of desired electrode materials. Note that the second electrode 102 is formed after formation of the organic compound layer 103b, with the use of a material selected as appropriate.

### <Materials of Light-Emitting Device>

### <<Light-Emitting Layer>>

The light-emitting layers (113, 113a, and 113b) contain a light-emitting substance. Note that as a light-emitting substance that can be used in the light-emitting layers (113, 113a, and 113b), a substance whose emission color is blue, violet, bluish violet, green, yellowish green, yellow, orange, red, or the like can be used as appropriate. When a plurality of light-emitting layers are provided, the use of different light-emitting substances for the light-emitting layers enables exhibiting different emission colors (e.g., white light emission obtained by a combination of complementary emission colors). Furthermore, one light-emitting layer may have a stacked-layer structure including different light-emitting substances.

The light-emitting layers (113, 113a, and 113b) may each contain one or more kinds of organic compounds (e.g., a host material) in addition to a light-emitting substance (a guest material). When containing a plurality of host materials, the light-emitting layers (113, 113a, and 113b) can each have the structure described in Embodiment 1 with reference to FIG. 3B, for example. In the light-emitting layer, the host materials 118 are present in the largest proportion by weight, and the guest material 119 is dispersed in the host materials 118. In the light-emitting layer, the Ti level of the host material 118 (the first host material 118_1 and the second host material 118_2) is preferably higher than the T₁ level of the guest material (the guest material 119).

As the first host material 118_1, a material having an electron-transport property higher than a hole-transport property can be used, and a material having an electron mobility higher than or equal to 1× 10⁻⁶ cm²/Vs is preferable. A compound having a π-electron deficient heteroaromatic ring skeleton such as a nitrogen-containing heteroaromatic compound, or a zinc- or aluminum-based metal complex can be used, for example, as a material which easily accepts electrons (a material having an electron-transport property). Examples of the compound having a π-electron deficient heteroaromatic ring skeleton include compounds such as an oxadiazole derivative, a triazole derivative, a benzimidazole derivative, a quinoxaline derivative, a dibenzoquinoxaline derivative, a phenanthroline derivative, a pyridine derivative, a bipyridine derivative, a pyrimidine derivative, and a triazine derivative. Examples of the zinc- or aluminum-based metal complex include a metal complex having a quinoline ligand, a metal complex having a benzoquinoline ligand, a metal complex having an oxazole ligand, and a metal complex having a thiazole ligand.

Specific examples thereof include metal complexes having a quinoline or benzoquinoline skeleton, such as tris(8-quinolinolato)aluminum (III) (abbreviation: Alq), tris(4-methyl-8-quinolinolato)aluminum (III) (abbreviation: Almq₃), bis(10-hydroxybenzo[h]quinolinato) beryllium (II) (abbreviation: BeBq₂), bis(2-methyl-8-quinolinolato) (4-phenylphenolato)aluminum (III) (abbreviation: BAlq), and bis(8-quinolinolato) zinc (II) (abbreviation: Znq). Alternatively, a metal complex having an oxazole-based or thiazole-based ligand, such as bis[2-(2-benzoxazolyl)phenolato]zinc (II) (abbreviation: ZnPBO) or bis[2-(2-benzothiazolyl) phenolato]zinc (II) (abbreviation: ZnBTZ), can be used. Other than such metal complexes, any of the following can be used: heterocyclic compounds such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 3-(4-biphenylyl)-4-phenyl-5-(4-tert-butylphenyl)-1,2,4-triazole (abbreviation: TAZ), 9-[4-(4,5-diphenyl-4H-1,2,4-triazol-3-yl)phenyl]-9H-carbazole (abbreviation: CzTAZI), 2,2′,2″-(1,3,5-benzenctriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), bathophenanthroline (abbreviation: BPhen), and bathocuproine (abbreviation: BCP); heterocyclic compounds having a diazine skeleton such as 2-[3-(dibenzothiophen-4-yl)phenyl]dibenzo[f,h]quinoxaline (abbreviation: 2mDBTPDBq-II), 2-[3′-(dibenzothiophen-4-yl) biphenyl-3-yl]dibenzo[f,h]quinoxaline (abbreviation: 2mDBTBPDBq-II), 2-[3′-(9H-carbazol-9-yl) biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 2-[3-(3,9′-bi-9H-carbazol-9-yl)phenyl]dibenzo[f,h]quinoxaline (abbreviation: 2mCzCzPDBq), 4,6-bis[3-(phenanthren-9-yl)phenyl]pyrimidinc (abbreviation: 4,6mPnP2Pm), 4,6-bis[3-(dibenzothiophen-4-yl)phenyl]pyrimidine (abbreviation: 4,6mDBTP2Pm-II), and 4,6-bis[3-(9H-carbazol-9-yl)phenyl]pyrimidine (abbreviation: 4,6mCzP2Pm); heterocyclic compounds having a triazine skeleton such as 2-{4-[3-(N-phenyl-9H-carbazol-3-yl)-9H-carbazol-9-yl]phenyl}-4,6-diphenyl-1,3,5-triazine (abbreviation: PCCzPTzn); heterocyclic compounds having a pyridine skeleton such as 3,5-bis[3-(9H-carbazol-9-yl)phenyl]pyridine (abbreviation: 35DCzPPy) and 1,3,5-tri[3-(3-pyridyl)phenyl]benzene (abbreviation: TmPyPB); and heteroaromatic compounds such as 4,4′-bis(5-methylbenzoxazol-2-yl) stilbene (abbreviation: BzOs). Among the heterocyclic compounds, the heterocyclic compounds having a triazine skeleton, a diazine (pyrimidine, pyrazine, or pyridazine) skeleton, or a pyridine skeleton are highly reliable and stable and are thus preferably used. In addition, the heterocyclic compounds having any of these skeletons have a high electron-transport property to contribute to a reduction in driving voltage. Further alternatively, a high-molecular compound such as poly(2,5-pyridinediyl) (abbreviation: PPy), poly[(9,9-dihexylfluorcnc-2,7-diyl)-co-(pyridine-3,5-diyl)] (abbreviation: PF-Py), or poly[(9,9-dioctylfluorene-2,7-diyl)-co-(2,2′-bipyridine-6,6′-diyl)](abbreviation: PF-BPy) can be used. The substances described here are mainly substances having an electron mobility higher than or equal to 1×10⁻⁶ cm²/Vs. Note that other substances may also be used as long as their electron-transport properties are higher than their hole-transport properties.

As the second host material 118_2, a substance which can form an exciplex together with the first host material 118_1 is preferably used. Specifically, the second host material 118_2 preferably includes a skeleton having a high donor property, such as a π-electron rich heteroaromatic ring or an aromatic amine skeleton. Examples of the compound having a π-electron rich heteroaromatic ring include heteroaromatic compounds such as a dibenzothiophene derivative, a dibenzofuran derivative, and a carbazole derivative. In that case, it is preferable that the first host material 118_1, the second host material 118_2, and the guest material 119 be selected such that the emission peak of the exciplex formed by the first host material 118_1 and the second host material 118_2 overlaps with an absorption band, specifically the longest-wavelength absorption band, of a triplet metal to ligand charge transfer (MLCT) transition of the guest material 119. This makes it possible to provide a light-emitting device with drastically improved emission efficiency. Note that in the case where a thermally activated delayed fluorescence material is used as the guest material 119, it is preferable that the longest-wavelength absorption band be a singlet absorption band.

As the second host material 118_2, any of hole-transport materials given below can be used. A material having a hole-transport property higher than an electron-transport property can be used as a hole-transport material, and a material having a hole mobility higher than or equal to 1 ×10⁻⁶ cm²/Vs is preferably used. Specifically, an aromatic amine, a carbazole derivative, an aromatic hydrocarbon, a stilbene derivative, or the like can be used. Furthermore, the hole-transport material may be a high molecular compound.

Specific examples of the aromatic amine compounds that can be used as the material having a high hole-transport property include N,N′-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), N,N′-bis[4-bis(3-methylphenyl)aminophenyl]-N,N′-diphenyl-4,4′-diaminobiphenyl (abbreviation: DNTPD), and 1,3,5-tris[N-(4-diphenylaminophenyl)-N-phenylamino]benzene (abbreviation: DPA3B).

Specific examples of the carbazole derivative include 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), 3,6-bis[N-(4-diphenylaminophenyl)-N-(1-naphthyl)amino]-9-phenylcarbazole (abbreviation: PCzTPN2), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), and 3-[N-(1-naphthyl)-N-(9-phenylcarbazol-3-yl)amino]-9-phenylcarbazole (abbreviation: PCzPCN1).

Other examples of the carbazole derivative include 4,4′-di(N-carbazolyl) biphenyl (abbreviation: CBP), 1,3,5-tris[4-(N-carbazolyl)phenyl]benzene (abbreviation: TCPB), 9-[4-(10-phenyl-9-anthryl)phenyl]-9H-carbazole (abbreviation: CzPA), and 1,4-bis[4-(N-carbazolyl)phenyl]-2,3,5,6-tetraphenylbenzene.

Examples of the aromatic hydrocarbon include 2-tert-butyl-9,10-di(2-naphthyl) anthracene (abbreviation: 1-BuDNA), 2-tert-butyl-9,10-di(1-naphthyl) anthracene, 9,10-bis(3,5-diphenylphenyl) anthracene (abbreviation: DPPA), 2-tert-butyl-9,10-bis(4-phenylphenyl) anthracene (abbreviation: 1-BuDBA), 9,10-di(2-naphthyl) anthracene (abbreviation: DNA), 9,10-diphenylanthracene (abbreviation: DPAnth), 2-tert-butylanthracene (abbreviation: 1-BuAnth), 9,10-bis(4-methyl-1-naphthyl) anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl) anthracene, 2,3,6,7-tetramethyl-9,10-di(2-naphthyl) anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, and 2,5,8,11-tetra(tert-butyl) perylene. Other examples include pentacene and coronene. The aromatic hydrocarbon having a hole mobility higher than or equal to 1×10⁻⁶ cm²/Vs and having 14 to 42 carbon atoms is particularly preferable.

The aromatic hydrocarbon may have a vinyl skeleton. Examples of the aromatic hydrocarbon having a vinyl skeleton include 4,4′-bis(2,2-diphenylvinyl) biphenyl (abbreviation: DPVBi) and 9,10-bis[4-(2,2-diphenylvinyl)phenyl]anthracene (abbreviation: DPVPA).

A high molecular compound such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl) methacrylamide] (abbreviation: PTPDMA), or poly[N,N-bis(4-butylphenyl)-N,N′-bis(phenyl)benzidine] (abbreviation: Poly-TPD) can also be used.

Examples of the material having a high hole-transport property include aromatic amine compounds such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), 4,4′,4″-tris(carbazol-9-yl)triphenylamine (abbreviation: TCTA), 4,4′,4″-tris[N-(1-naphthyl)-N-phenylamino]triphenylamine (abbreviation: l′-TNATA), 4,4′,4″-tris(N,N-diphenylamino)triphenylaminc (abbreviation: TDATA), 4,4′,4″-tris[N-(3-methylphenyl)-N-phenylamino]triphenylamine (abbreviation: m-MTDATA), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylaminc (abbreviation: mBPAFLP), N-(9,9-dimethyl-9H-fluoren-2-yl)-N-{9,9-dimethyl-2-[N′-phenyl-N′-(9,9-dimethyl-9H-fluoren-2-yl)amino]-9H-fluoren-7-yl}phenylamine (abbreviation: DFLADFL), N-(9,9-dimethyl-2-diphenylamino-9H-fluoren-7-yl)diphenylamine (abbreviation: DPNF), N-(9,9-spirobi[9H-fluoren]-2-yl)-N,N′,N′-triphenyl-1,4-phenylenediamine (abbreviation: DPASF), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 4-phenyldiphenyl-(9-phenyl-9H-carbazol-3-yl)amine (abbreviation: PCA1BP), N,N′-bis(9-phenylcarbazol-3-yl)-N,N′-diphenylbenzene-1,3-diamine (abbreviation: PCA2B), N,N, N″-triphenyl-N,N′,N″-tris(9-phenylcarbazol-3-yl)benzene-1,3,5-triamine (abbreviation: PCA3B), N-(9,9-diphenyl-9H-fluoren-2-yl)-N,9-diphenyl-9H-carbazol-3-amine (abbreviation: PCAFLP (2)), N-(9,9-diphenyl-(abbreviation: PCAFLP (2)-02), N-9H-fluoren-2-yl)-N,9-diphenyl-9H-carbazol-2-amine (biphenyl-4-yl)-N-(9,9-dimethyl-9H-fluoren-2-yl)-9-phenyl-9H-carbazol-3-amine (abbreviation: PCBiF), N-(biphenyl-4-yl)-N-[4-(9-phenyl-9H-carbazol-3-yl)phenyl]-9,9-dimethyl-9H-fluoren-2-amine (abbreviation: PCBBiF), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]-9,9′-spirobi[9H-fluoren]-2-amine (abbreviation: PCBASF), N-(9,9-spirobi[9H-fluoren]-2-yl)-N,9-diphenylcarbazol-3-amine (abbreviation: PCASF), N,N′-diphenyl-N,N′-bis(4-diphenylaminophenyl)spirobi[9H-fluorene]-2,7-diamine (abbreviation: DPA2SF), N-[4-(9H-carbazol-9-yl)phenyl]-N-(4-phenyl)phenylaniline (abbreviation: YGAIBP), and N,N-bis[4-(carbazol-9-yl)phenyl]-N,N-diphenyl-9,9-dimethylfluorene-2,7-diamine (abbreviation: YGA2F). Other examples are amine compounds, carbazole compounds, thiophene compounds, furan compounds, fluorene compounds, triphenylene compounds, phenanthrene compounds, and the like such as 3-[4-(1-naphthyl)phenyl]-9-phenyl-9H-carbazole (abbreviation: PCPN), 9-[4-(9-phenyl-9H-carbazol-3-yl)phenyl]phenanthrene (abbreviation: PCPPn), 3,3′-bis(9-phenyl-9H-carbazole) (abbreviation: PCCP), 9,9′-bis(biphenyl-4-yl)-3,3′-bi-9H-carbazole (abbreviation: 9-(biphenyl-3-yl)-9′-(biphenyl-4-yl)-9H,9′H-3,3′-bicarbazole (abbreviation: BisBPCz), mBPCCBP), 9-(2-naphthyl)-9′-phenyl-3,3′-bi-9H-carbazole (abbreviation: BNCCP), 9-(3-biphenyl)-9′-(2-naphthyl)-3,3′-bi-9H-carbazole (abbreviation: BNCCmBP), 9-(4-biphenyl)-9′-(2-naphthyl)-3,3′-bi-9H-carbazole (abbreviation: BNCCBP), 9,9′-di-2-naphthyl-3,3′-9H,9′H-bicarbazole (abbreviation: BisβNCz), 9-[3-(triphenylsilyl)phenyl]-3,9′-bi-9H-carbazole (abbreviation: PSiCzCz), 1,3-bis(N-carbazolyl)benzene (abbreviation: mCP), 3,6-bis(3,5-diphenylphenyl)-9-phenylcarbazole (abbreviation: CzTP), 3,6-di(9H-carbazol-9-yl)-9-phenyl-9H-carbazole (abbreviation: PhCzGI), 2,8-di(9H-carbazol-9-yl)dibenzothiophene (abbreviation: Cz2DBT), 4-{3-[3-(9-phenyl-9H-fluoren-9-yl)phenyl]phenyl}dibenzofuran (abbreviation: mmDBFFLBi-II), 4,4′,4″-(benzene-1,3,5-triyl)tri (dibenzofuran) (abbreviation: DBF3P-II), 4,4′,4″-(benzene-1,3,5-triyl)tri (dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), 4-[4-(9-phenyl-9H-fluoren-9-yl)phenyl]-6-phenyldibenzothiophene (abbreviation: DBTFLP-IV), and 4-[3-(triphenylen-2-yl)phenyl]dibenzothiophene (abbreviation: mDBTPTp-II). Among the above compounds, compounds having a pyrrole skeleton, a furan skeleton, a thiophene skeleton, or an aromatic amine skeleton are preferable because of their high stability and high reliability. In addition, the compounds having any of these skeletons have a high hole-transport property to contribute to a reduction in driving voltage.

In the case where the first host material 118_1 is an organic compound having an electron-transport property and the second host material 118_2 is an organic compound having a hole-transport property, the HOMO level of the organic compound having a hole-transport property is preferably higher than or equal to the HOMO level of the organic compound having an electron-transport property. The LUMO level of the organic compound having a hole-transport property is preferably higher than or equal to the LUMO level of the organic compound having an electron-transport property, in which case the exciplex can be formed more efficiently.

The values of HOMO and LUMO levels can be obtained by cyclic voltammetry (CV) measurement.

In the cyclic voltammetry (CV) measurement, the values (E) of HOMO and LUMO levels can be calculated on the basis of an oxidation peak potential (Eₚₐ) and a reduction peak potential (E_{pc}), which are obtained by changing the potential of a working electrode with respect to a reference electrode. In the measurement, a HOMO level and a LUMO level can be obtained by potential scanning in positive direction and potential scanning in negative direction, respectively. The scanning speed in the measurement is 0.1 V/s.

Specifically, a standard oxidation-reduction potential (Eₒ) (=Eₚₐ+E_{pc})/2) is calculated from an oxidation peak potential (Eₚₐ) and a reduction peak potential (E_{pc}), which are obtained by the cyclic voltammogram of a material. Then, the standard oxidation-reduction potential (Eₒ) is subtracted from the potential energy (Eₓ) of the reference electrode with respect to a vacuum level, whereby each of the values (E) (=Eₓ−Eₒ) of HOMO and LUMO levels can be obtained.

Note that the reversible oxidation-reduction wave is obtained in the above case; in the case where an irreversible oxidation-reduction wave is obtained, the HOMO level is calculated as follows: a value obtained by subtracting a predetermined value (0.1 eV) from an oxidation peak potential (Eₚₐ) is assumed to be a reduction peak potential (E_{pc}), and a standard oxidation-reduction potential (Eₒ) is calculated to one decimal place. To calculate the LUMO level, a value obtained by adding a predetermined value (0.1 eV) to a reduction peak potential (Eₚₑ) is assumed to be an oxidation peak potential (Eₚₐ), and a standard oxidation-reduction potential (Eₒ) is calculated to one decimal place.

There is no particular limitation on the guest material 119 that can be used for the light-emitting layers (113, 113a, and 113b), and a light-emitting substance that converts singlet excitation energy into light in the visible light range or a light-emitting substance that converts triplet excitation energy into light in the visible light range can be used.

<<Light-Emitting Substance that Converts Singlet Excitation Energy into Light Emission>>

The following substances that emit fluorescent light (fluorescent substances) can be given as examples of the light-emitting substance that converts singlet excitation energy into light emission and can be used in the light-emitting layers (113, 113a, and 113b): a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative. A pyrene derivative is particularly preferable because it has a high emission quantum yield. Specific examples of the pyrene derivative include N,N′-bis(3-methylphenyl)-N,N-bis[3-(9-phenyl-9H-fluoren-9-yl)phenyl]pyrene-1,6-diamine (abbreviation: 1,6mMcmFLPAPrn), N,N′-diphenyl-N,N-bis[4-(9-phenyl-9H-fluoren-9-yl)phenyl]pyrene-1,6-diamine (abbreviation: 1,6FLPAPrn), N,N-bis(dibenzofuran-2-yl)-N,N′-diphenylpyrene-1,6-diaminc (abbreviation: 1,6FrAPrn), N,N-bis(dibenzothiophen-2-yl)-N,N-diphenylpyrene-1,6-diamine (abbreviation: 1,6ThAPrn), N,N′-(pyrene-1,6-diyl)bis[(N-phenylbenzo[b]naphtho[1,2-d]furan)-6-amine] (abbreviation: 1,6BnfAPrn), N,N-(pyrenc-1,6-diyl)bis[(N-phenylbenzo[b]naphtho[1,2-d]furan)-8-amine] (abbreviation: 1,6BnfAPrn-02), and N,N-(pyrene-1,6-diyl)bis[(6,N-diphenylbenzo[b]naphtho[1,2-d]furan)-8-amine] (abbreviation: 1,6BnfAPrn-03).

In addition, it is possible to use, for example, 5,6-bis[4-(10-phenyl-9-anthryl)phenyl]-2,2′-bipyridinc (abbreviation: PAP2BPy), 5,6-bis[4′-(10-phenyl-9-anthryl) biphenyl-4-yl]-2,2′-bipyridinc (abbreviation: PAPP2BPy), N,N-bis[4-(9H-carbazol-9-yl)phenyl]-N,N′-diphenyl-4,4′-stilbenediamine (abbreviation: YGA2S), 4-(9H-carbazol-9-yl)-4′-(10-phenyl-9-anthryl)triphenylaminc (abbreviation: YGAPA), 4-(9H-carbazol-9-yl)-4′-(9,10-diphenyl-2-anthryl)triphenylaminc (abbreviation: 2YGAPPA), N,9-diphenyl-N-[4-(10-phenyl-9-anthryl)phenyl]-9H-carbazol-3-amine (abbreviation: PCAPA), 4-(10-phenyl-9-anthryl)-4′-(9-phenyl-9H-carbazol-3-yl)triphenylaminc (abbreviation: PCBAPA), 4-[4-(10-phenyl-9-anthryl)phenyl]-4′-(9-phenyl-9H-carbazol-3-yl)triphenylamine (abbreviation: PCBAPBA), perylene, 2,5,8,11-tetra-tert-butylperylene (abbreviation: TBP), N,N″-(2-tert-butylanthracene-9,10-diyldi-4,1-phenylenc)bis(N,N′,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), or the like.

It is also possible to usc, for example, N,N,N′,N′,N″,N″, N′″N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidenc) propanedinitrile (abbreviation: DCM1), 2-{2-methyl-6-[2-(2,3,6,7-tetrahydro-1H,5H-benzo[ij]quinolizin-9-yl) ethenyl]-4H-pyran-4-ylidenc}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl) acenaphtho[1,2-a]fluoranthenc-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl) ethenyl]-4H-pyran-4-ylidenc}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl) ethenyl]-4H-pyran-4-ylidenc}propanedinitrile (abbreviation: DCJTB), 2-(2,6-bis {2-[4-(dimethylamino)phenyl]ethenyl}-4H-pyran-4-ylidenc) propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl) ethenyl]-4H-pyran-4-ylidene}propanedinitrile (abbreviation: BisDCJTM), 1,6BnfAPrn-03, N,N′-diphenyl-N,N-bis(9-phenyl-9H-carbazol-2-yl) naphtho[2,3-b;6,7-b′]bisbenzofuran-3,10-diamine (abbreviation: 3,10PCA2Nbf (IV)-02), or N,N′-bis(dibenzofuran-3-yl)-N,N′-diphenylnaphtho[2,3-b;6,7-b′]bisbenzofuran-3,10-diamine (abbreviation: 3,10FrA2Nbf (IV)-02). In particular, a pyrenediamine compound such as 1,6FLPAPrn, 1,6mMemFLPAPrn, or 1,6BnfAPrn-03 can be used, for example.

A condensed heteroaromatic compound containing nitrogen and boron, especially a compound having a diaza-boranaphtho-anthracene skeleton, exhibits a narrow emission spectrum, emits blue light with high color purity, and can thus be suitably used. Examples of the compound include 5,9-diphenyl-5,9-diaza-13b-boranaphtho[3,2,1-de]anthracene (abbreviation: DABNA1), 9-(biphenyl-3-yl)-N,N,5,11-tetraphenyl-5H,9H-[1,4]benzazaborino[2,3,4-k/]phenazaborin-3-amine (abbreviation: DABNA2), 2,12-di(tert-butyl)-5,9-di(4-tert-butylphenyl)-N,N-diphenyl-5H,9H-[1,4]benzazaborino[2,3,4-k/]phenazaborin-7-amine (abbreviation: DPhA-tBu4DABNA), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA), 2,12-di(tert-butyl)-5,9-di(4-tert-butylphenyl)-7-methyl-5H,9H-[1,4]benzazaborino[2,3,4-kl]phenazaborine (abbreviation: Me-tBu4DABNA), N⁷,N⁷,N¹³,N¹³,5,9,11,15-octaphenyl-5H,9H,11H,15H-[1,4]benzazaborino[2,3,4-k/][1,4]benzazaborino[4′,3′,2′: 4,5][1,4]benzazaborino[3,2-b]phenazaborine-7,13-diamine (abbreviation: v-DABNA), and 2-(4-tert-butylphenyl)benz[5,6]indolo[3,2,1-jk]benzo[b]carbazole (abbreviation: BuPBibc).

Besides the above compounds, a compound having an indole skeleton, such as 9,10,11-tris[3,6-bis(1,1-dimethylethyl)-9H-carbazolyl-9-yl]-2,5,15,18-tetrakis(1,1-dimethylethyl) indolo[3,2,1-de]indolo[3′,2′, l′: 8,1][1,4]benzazaborino[2,3,4-k/]phenazaborine (abbreviation: BBCz-G) or 9,11-bis[3,6-bis(1,1-dimethylethyl)-9H-carbazolyl-9-yl]-2,5,15,18-tetrakis(1,1-dimethylethyl) indolo[3,2,1-de]indolo[3′,2′, l′: 8,1][1,4]benzazaborino[2,3,4-kl]phenazaborine (abbreviation: BBCz-Y), can be suitably used.

<<Light-Emitting Substance that Converts Triplet Excitation Energy into Light Emission>>

Examples of the light-emitting substance that converts triplet excitation energy into light emission and can be used in the light-emitting layer 113 include substances that emit phosphorescent light (phosphorescent substances) and thermally activated delayed fluorescent (TADF) materials that exhibit thermally activated delayed fluorescence.

A phosphorescent substance is a compound that emits phosphorescent light but does not emit fluorescent light at a temperature higher than or equal to a low temperature (e.g., 77 K) and lower than or equal to room temperature (i.e., higher than or equal to 77 K and lower than or equal to 313 K). The phosphorescent substance preferably includes a metal element with large spin-orbit interaction, and can be an organometallic complex, a metal complex (platinum complex), or a rare earth metal complex, for example. Specifically, the phosphorescent substance preferably includes a transition metal element. It is preferable that the phosphorescent substance include a platinum group element (ruthenium (Ru), rhodium (Rh), palladium (Pd), osmium (Os), iridium (Ir), or platinum (Pt)), especially iridium, in which case the probability of direct transition between the singlet ground state and the triplet excited state can be increased.

<<Phosphorescent Substance (from 400 nm to Less than 580 nm: Blue or Green)>>

As examples of a phosphorescent substance which emits blue or green light and whose emission spectrum has a peak wavelength greater than or equal to 400 nm and less than 580 nm, the following substances can be given.

Examples include organometallic complexes having a 4H-triazole ring, such as tris {2-[5-(2-methylphenyl)-4-(2,6-dimethylphenyl)-4H-1,2,4-triazol-3-yl-κN²]phenyl-κC}iridium (III) [Ir (mpptz-dmp)₃]), tris(5-methyl-3,4-diphenyl-4H-1,2,4-triazolato) iridium (III) (abbreviation: (abbreviation: [Ir (Mptz)₃]), tris[4-(3-biphenyl)-5-isopropyl-3-phenyl-4H-1,2,4-triazolato]iridium (III) (abbreviation: [Ir (iPrptz-3b)₃]), and tris[3-(5-biphenyl)-5-isopropyl-4-phenyl-4H-1,2,4-triazolato]iridium (III) (abbreviation: [Ir (iPr5btz)₃]); organometallic complexes having a 1H-triazole ring, such as tris[3-methyl-1-(2-methylphenyl)-5-phenyl-1H-1,2,4-triazolato]iridium (III) (abbreviation: [Ir (Mptz1-mp)₃]) and tris(1-methyl-5-phenyl-3-propyl-1H-1,2,4-triazolato) iridium (III) (abbreviation: [Ir(Prptz1-Me)₃]); organometallic complexes having an imidazole ring, such as fac-tris[1-(2,6-diisopropylphenyl)-2-phenyl-1H-imidazole]iridium (III) (abbreviation: [Ir (iPrpim)₃]), tris[3-(2,6-dimethylphenyl)-7-methylimidazo[1,2-f]phenanthridinato]iridium (III) (abbreviation: [Ir (dmpimpt-Me)₃]), and tris(2-{1-[2,6-bis(1-methylethyl)phenyl]-1H-imidazol-2-yl-κN³}-4-cyanophenyl-κC) iridium (III) (abbreviation: CNImIr); organometallic complexes having a benzimizazolidene skeleton, such as tris[(6-tert-butyl-3-phenyl-2H-imidazo[4,5-b]pyrazin-1-yl-κC²)phenyl-κC]iridium (III) (abbreviation: [Ir (cb)₃]); organometallic complexes in which a phenylpyridine derivative having an electron-withdrawing group is a ligand, such as bis[2-(4′,6′-difluorophenyl)pyridinato-N,C^{2′}]iridium (III) tetrakis(1-pyrazolyl) borate (abbreviation: Flr6), bis[2-(4′,6′-difluorophenyl)pyridinato-N,C^{2′}]iridium (III) picolinate (abbreviation: FIrpic), bis {2-[3′,5′-bis(trifluoromethyl)phenyl]pyridinato-N,C^{2′}}iridium (III) picolinate (abbreviation: [Ir(CF₃ppy)₂ (pic)]), bis[2-(4′,6′-difluorophenyl)pyridinato-N,C²]iridium (III) acetylacetonate (abbreviation: Flr (acac)), and platinum complexes such as (2-{3-[3-(3,5-di-tert-butylphenyl)benzimidazol-1-yl-2-ylidene-κC²]phenoxy-κC²}-9-(4-tert-butyl-2-pyridinyl-κN) carbazole-2,1-diyl-κC¹) platinum (II) (abbreviation: PtON-TBBI). A compound obtained by substituting deuterium for part of hydrogen in any of these compounds can also be used.

<<Phosphorescent Substance (from 490 nm to Less than 590 nm: Green or Yellow)>>

As examples of a phosphorescent substance which emits green or yellow light and whose emission spectrum has a peak wavelength greater than or equal to 490 nm and less than 590 nm, the following substances can be given.

Examples of the phosphorescent substance include organometallic iridium complexes having a pyrimidine ring, such as tris(4-methyl-6-phenylpyrimidinato) iridium (III) (abbreviation: [Ir (mppm)₃]), tris(4-1-butyl-6-phenylpyrimidinato) iridium (III) (abbreviation: [Ir (tBuppm)₃]), (acetylacetonato)bis(6-methyl-4-phenylpyrimidinato) iridium (III) (abbreviation: [Ir (mppm) 2 (acac)]), (acetylacetonato)bis(6-tert-butyl-4-phenylpyrimidinato) iridium (III) (abbreviation: [Ir (tBuppm)₂ (acac)]), (acetylacetonato)bis[6-(2-norbornyl)-4-phenylpyrimidinato]iridium (III) (abbreviation: [Ir (nbppm)₂ (acac)]), (acetylacetonato)bis[5-methyl-6-(2-methylphenyl)-4-phenylpyrimidinato]iridium (III) (abbreviation: [Ir (mpmppm)₂ (acac)]), (acetylacetonato)bis {4,6-dimethyl-2-[6-(2,6-dimethylphenyl)-4-pyrimidinyl-κN³]phenyl-κC}iridium (III) (abbreviation: [Ir (dmppm-dmp)₂ (acac)]), and (acetylacetonato)bis(4,6-diphenylpyrimidinato) iridium (III) (abbreviation: [Ir (dppm)₂ (acac)]); organometallic iridium complexes having a pyrazine ring, such as (acetylacetonato)bis(3,5-dimethyl-2-phenylpyrazinato) iridium (III) (abbreviation: [Ir (mppr-Mc)₂ (acac)]) and (acetylacctonato)bis(5-isopropyl-3-methyl-2-phenylpyrazinato) iridium (III) (abbreviation: [Ir (mppr-iPr)₂ (acac)]); organometallic iridium complexes having a pyridine ring, such as tris(2-phenylpyridinato-N,C^{2′}) iridium (III) (abbreviation: [Ir (ppy)₃]), bis(2-phenylpyridinato-N,C^{2′}) iridium (III) (abbreviation: acetylacetonate [Ir (ppy)₂ (acac)]), bis(benzo[h]quinolinato) iridium (III) acetylacetonate (abbreviation: [Ir (bzq)₂ (acac)]), tris(benzo[h]quinolinato) iridium (III) (abbreviation: [Ir (bzq)₃]), tris(2-phenylquinolinato-N,C^{2′}) iridium (III) (abbreviation: [Ir (pq)₃]), bis(2-phenylquinolinato-N,C^{2′}) iridium (III) acetylacetonate (abbreviation: [Ir (pq)₂ (acac)]), bis[2-(2-pyridinyl-κN)phenyl-κC][2-(4-phenyl-2-pyridinyl-κN)phenyl-κC]iridium (III) (abbreviation: [Ir (ppy)₂ (4dppy)]), bis[2-(2-pyridinyl-κN)phenyl-κC][2-(4-methyl-5-phenyl-2-pyridinyl-κN)phenyl-κC], [2-d₃-methyl-8-(2-pyridinyl-κN)benzofuro[2,3-b]pyridine-κC]bis[2-(5-d₃-methyl-2-pyridinyl-κN²)phenyl-κC]iridium (III) (abbreviation: Ir(5mppy-d₃)₂ (mbfpypy-d₃)), {2-(methyl-d₃)-8-[4-(1-methylethyl-1-d)-2-pyridinyl-κN]benzofuro[2,3-b]pyridin-7-yl-κC}bis {5-(methyl-d₃)-2-[5-(methyl-d₃)-2-pyridinyl-κN]phenyl-κC}iridium (III) (abbreviation: Ir(5mtpy-d₆)₂ (mbfpypy-iPr-d₄)), [2-d₃-methyl-(2-pyridinyl-κN)benzofuro[2,3-b]pyridine-κC]bis[2-(2-pyridinyl-κN)phenyl-κC]iridium (III) (abbreviation: Ir (ppy)₂ (mbfpypy-d₃)), [2-(4-methyl-5-phenyl-2-pyridinyl-κN)phenyl-κC]bis[2-(2-pyridinyl-κN)phenyl-κC]iridium (III) (abbreviation: Ir (ppy)₂ (mdppy)), [2-(4-d₃-methyl-5-phenyl-2-pyridinyl-κN²)phenyl-κC]bis[2-(5-d₃-methyl-2-pyridinyl-κN²)phenyl-κC]iridium (III) (abbreviation: [Ir(5mppy-d₃)₂ (mdppy-d₃)]), [2-methyl-(2-pyridinyl-κN)benzofuro[2,3-b]pyridine-κC]bis[2-(2-pyridinyl-κN)phenyl-κC]iridium (III) (abbreviation: [Ir (ppy)₂ (mbfpypy)]), and tris {2-[5-(methyl-d₃)-4-phenyl-2-pyridinyl-κN]phenyl-κC}iridium (III) (abbreviation: Ir(5m4dppy-d₃)₃); organometallic complexes such as bis(2,4-diphenyl-1,3-oxazolato-N,C^{2′}) iridium (III) acetylacetonate (abbreviation: [Ir (dpo)₂ (acac)]), bis {2-[4′-(perfluorophenyl)phenyl]pyridinato-N,C^{2′}}iridium (III) acetylacetonate (abbreviation: [Ir (p-PF-ph)² (acac)]), and bis(2-phenylbenzothiazolato-N,C^{2′}) iridium (III) acetylacetonate (abbreviation: [Ir (bt)₂ (acac)]); a rare earth metal complex such as tris(acetylacetonato) (monophenanthroline) terbium (III) (abbreviation: [Tb(acac)₃ (Phen)]); and organometallic platinum complexes, such as (2-{1-(5-tert-butylbiphenyl-2-yl)-4-[3-tert-butyl-5-(4-phenyl-2-pyridinyl-κN)phenyl-κC⁶]-2-benzimidazolyl-κN³}-4,6-di-tert-butylphenolato-κO) platinum (II) (abbreviation: Pt (tBudppymmtBubiz-tBubp)) and [2-(4-(3,5-di-tert-butylphenyl)-6-{3-[4-(5′-tert-butyl[1,1′: 3′,1″-terphenyl]-2′-yl)-2-pyridinyl-κN]phenyl-κC²}-2-pyridinyl-κN) phenolato-κO]platinum (II) (abbreviation: Pt (4tButpppypyp-mmtBup)). A compound obtained by substituting deuterium for part of hydrogen in any of these compounds can also be used.

<<Phosphorescent Substance (from 570 nm to Less than 750 nm: Yellow or Red)>>

As examples of a phosphorescent substance which emits yellow or red light and whose emission spectrum has a peak wavelength greater than or equal to 570 nm and less than 750 nm, the following substances can be given.

Examples of the phosphorescent substance include organometallic complexes having a pyrimidine ring, such as (diisobutyrylmethanato)bis[4,6-bis(3-methylphenyl)pyrimidinato]iridium (III) (abbreviation: [Ir(5mdppm)₂ (dibm)]), bis[4,6-bis(3-methylphenyl)pyrimidinato](dipivaloylmethanato) iridium (III) (abbreviation: [Ir(5mdppm)₂ (dpm)]), and (dipivaloylmethanato)bis[4,6-di(naphthalen-1-yl)pyrimidinato]iridium (III) (abbreviation: [Ir (dlnpm)₂ (dpm)]); organometallic complexes having a pyrazine ring, such as (acetylacetonato)bis(2,3,5-triphenylpyrazinato) iridium (III) (abbreviation: [Ir (tppr)₂ (acac)]), bis(2,3,5-triphenylpyrazinato) (dipivaloylmethanato) iridium (III) (abbreviation: [Ir (tppr)₂ (dpm)]), bis {4,6-dimethyl-2-[3-(3,5-dimethylphenyl)-5-phenyl-2-pyrazinyl-κN]phenyl-κC}(2,6-dimethyl-3,5-heptanedionato-K₂O,O′) iridium (III) (abbreviation: [Ir (dmdppr-P)₂ (dibm)]), bis {4,6-dimethyl-2-[5-(4-cyano-2,6-dimethylphenyl)-3-(3,5-dimethylphenyl)-2-pyrazinyl-κN]phenyl-κC}(2,2,6,6-tetramethyl-3,5-heptanedionato-κ²O,O′) iridium (III) (abbreviation: [Ir (dmdppr-dmCP)₂ (dpm)]), bis {2-[5-(2,6-dimethylphenyl)-3-(3,5-dimethylphenyl)-2-pyrazinyl-κN]-4,6-dimethylphenyl-κC}(2,2′,6,6′-tetramethyl-3,5-heptanedionato-κ²O,O′) iridium (III) (abbreviation: [Ir (dmdppr-dmp)₂ (dpm)]), (acetylacetonato)bis(2-methyl-3-phenylquinoxalinato-N,C^{2′}) iridium (III) (abbreviation: [Ir (mpq)₂ (acac)]), (acetylacetonato)bis(2,3-diphenylquinoxalinato-N,C^{2′}) iridium (III) (abbreviation: [Ir (dpq)₂ (acac)]), and (acetylacetonato)bis[2,3-bis(4-fluorophenyl) quinoxalinato]iridium (III) (abbreviation: [Ir(Fdpq)₂ (acac)]); organometallic complexes having a pyridine ring, such as tris(1-phenylisoquinolinato-N,C^{2′}) iridium (III) (abbreviation: [Ir (piq)₃]), bis(1-phenylisoquinolinato-N,C^{2′}) iridium (III) acetylacetonate (abbreviation: [Ir (piq)₂ (acac)]), bis[4,6-dimethyl-2-(2-quinolinyl-κN)phenyl-κC](2,4-pentanedionato-κ²O,O′) iridium (III) (abbreviation: [Ir (dmpqn)₂ (acac)]), (3,7-diethyl-4,6-nonanedionato-κO¹,κO⁶)bis[2,4-dimethyl-6-[7-(1-methylethyl)-1-isoquinolinyl-κN]phenyl-κC]iridium (III), and (3,7-diethyl-4,6-nonanedionato-κO⁴,κO⁶)bis[2,4-dimethyl-6-[5-(1-methylethyl)-2-quinolinyl-κN]phenyl-κC]iridium (III); a platinum complex such as 2,3,7,8,12,13,17,18-octaethyl-21H,23H-porphyrin platinum (II) (abbreviation: [PtOEP]); and rare earth metal complexes such as tris(1,3-diphenyl-1,3-propanedionato) (monophenanthroline) europium (III) (abbreviation: [Eu (DBM)₃ (Phen)]) and tris[1-(2-thenoyl)-3,3,3-trifluoroacetonato](monophenanthroline) europium (III) (abbreviation: [Eu (TTA)₃ (Phen)]). A compound obtained by substituting deuterium for part of hydrogen in any of these compounds can also be used.

### <<TADF Material>>

Any of materials described below can be used as the TADF material. The TADF material is a material that has a small difference between its S₁ and T₁ levels (preferably less than or equal to 0.20 eV), enables up-conversion of a triplet excited state into a singlet excited state (i.e., reverse intersystem crossing) using a little thermal energy, and efficiently exhibits light (fluorescent light) from the singlet excited state. The thermally activated delayed fluorescence is efficiently obtained under the condition where the difference in energy between the triplet excitation energy level and the singlet excitation energy level is greater than or equal to 0.00 eV and less than or equal to 0.20 eV, preferably greater than or equal to 0.00 eV and less than or equal to 0.10 eV. Delayed fluorescent light by the TADF material refers to light emission having a spectrum similar to that of normal fluorescent light and an extremely long lifetime. The lifetime is longer than or equal to 1×10⁻⁶ seconds, or longer than or equal to 1×10⁻³ seconds.

Note that the TADF material can be also used as an electron-transport material, a hole-transport material, or a host material.

Examples of the TADF material include fullerene, a derivative thereof, an acridine derivative such as proflavine, and eosin. Other examples include a metal-containing porphyrin, such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (abbreviation: SnF₂ (Proto IX)), a mesoporphyrin-tin fluoride complex (abbreviation: SnF₂ (Meso IX)), a hematoporphyrin-tin fluoride complex (abbreviation: SnF₂ (Hemato IX)), a coproporphyrin tetramethyl ester-tin fluoride complex (abbreviation: SnF₂ (Copro III-4Me)), an octaethylporphyrin-tin fluoride complex (abbreviation: SnF₂ (OEP)), an etioporphyrin-tin fluoride complex (abbreviation: SnF₂ (Etio I)), and an octaethylporphyrin-platinum chloride complex (abbreviation: PtCl₂OEP).

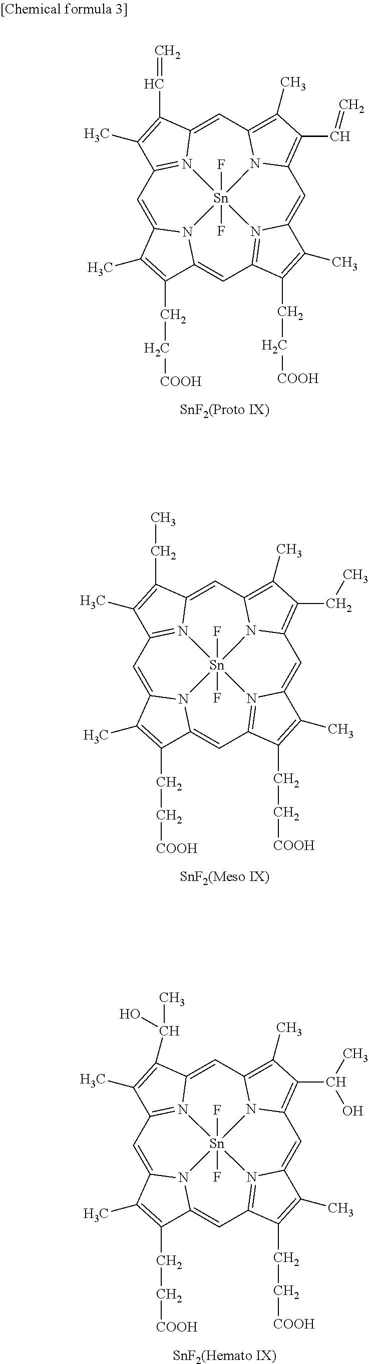

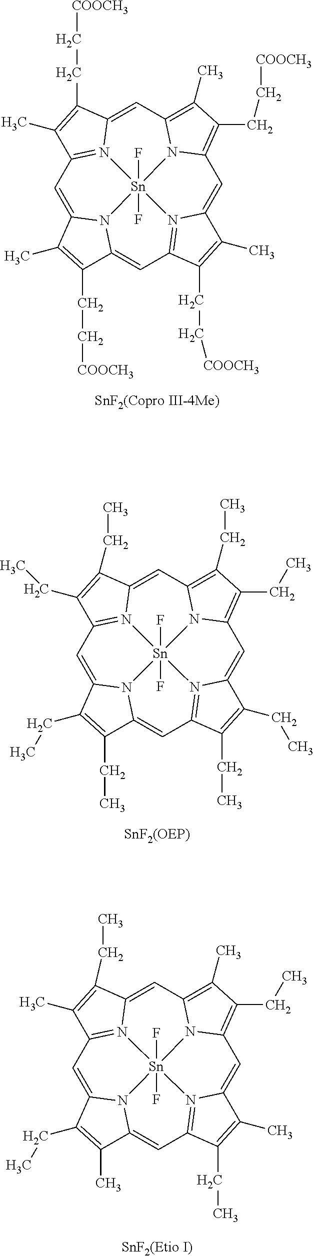

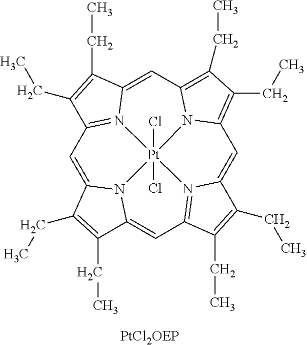

Δd ditionally, a heteroaromatic compound having a π-electron rich heteroaromatic compound and a π-electron deficient heteroaromatic compound, such as 2-(biphenyl-4-yl)-4,6-bis(12-phenylindolo[2,3-a]carbazol-11-yl)-1,3,5-triazine (abbreviation: PIC-TRZ), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H,10′H-spiro[acridin-9,9′-anthracen]-10′-one (abbreviation: ACRSA), 4-(9′-phenyl-[3,3′-bi-9H-carbazol]-9-yl)benzofuro[3,2-d]pyrimidine (abbreviation: 4PCCzBfpm), 4-[4-(9′-phenyl-[3,3′-bi-9H-carbazol]-9-yl)phenyl]benzofuro[3,2-d]pyrimidine (abbreviation: 4PCCzPBfpm), or 9-[3-(4,6-diphenyl-1,3,5-triazin-2-yl)phenyl]-9′-phenyl-2,3′-bi-9H-carbazole (abbreviation: mPCCzPTzn-02) may be used.

Note that a substance in which a π-electron rich heteroaromatic compound is directly bonded to a π-electron deficient heteroaromatic compound is particularly preferable because both the donor property of the π-electron rich heteroaromatic compound and the acceptor property of the π-electron deficient heteroaromatic compound are enhanced and the energy difference between the singlet excited state and the triplet excited state becomes small. As the TADF material, a TADF material in which the singlet and triplet excited states are in thermal equilibrium (TADF100) may be used. Since such a TADF material enables a short emission lifetime (excitation lifetime), the efficiency of a light-emitting device in a high-luminance region can be less likely to decrease.

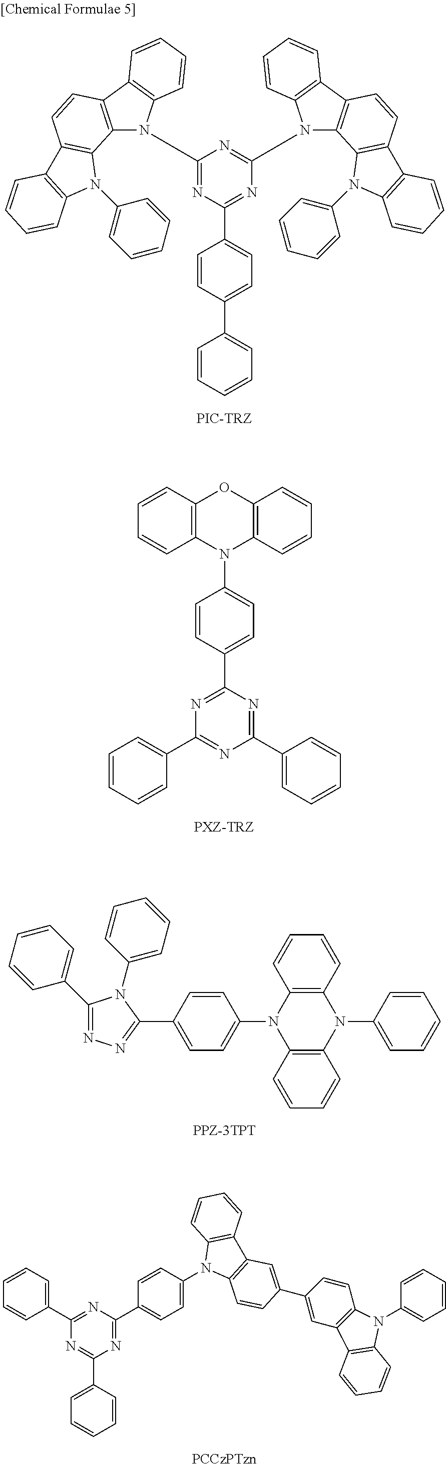 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

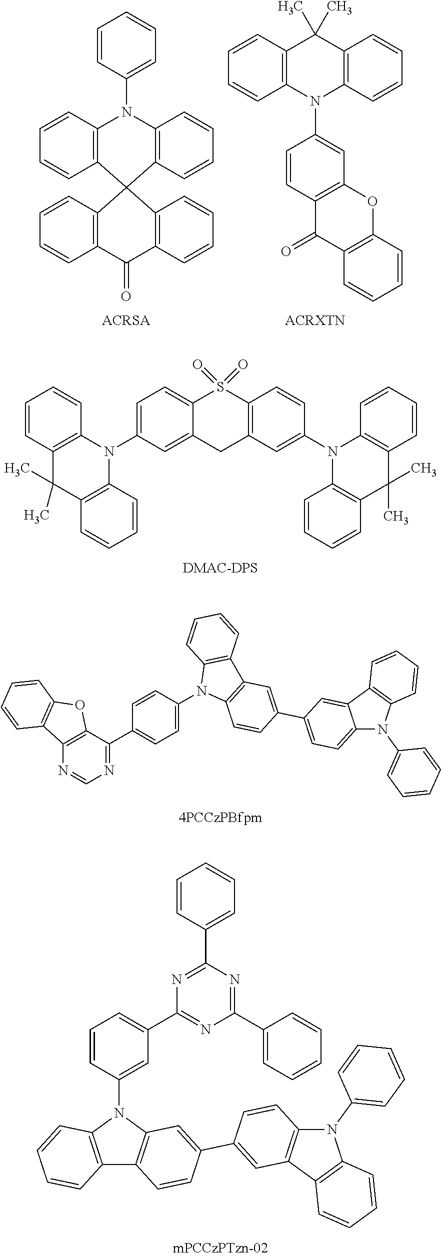 [SMILES: O=C1c2ccccc2C2(c3ccccc31)c1ccccc1N(c1ccccc1)c1ccccc12 ; CC1(C)c2ccccc2N(c2ccc3c(=O)c4ccccc4oc3c2)c2ccccc21 ; CC1(C)c2ccccc2N(c2ccc3c(c2)Cc2cc(N4c5ccccc5C(C)(C)c5ccccc54)ccc2S3(=O)=O)c2ccccc21 ; c1ccc(-n2c3ccccc3c3cc(-c4ccc5c(c4)c4ccccc4n5-c4ccc(-c5ncnc6c5oc5ccccc56)cc4)ccc32)cc1 ; c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1]

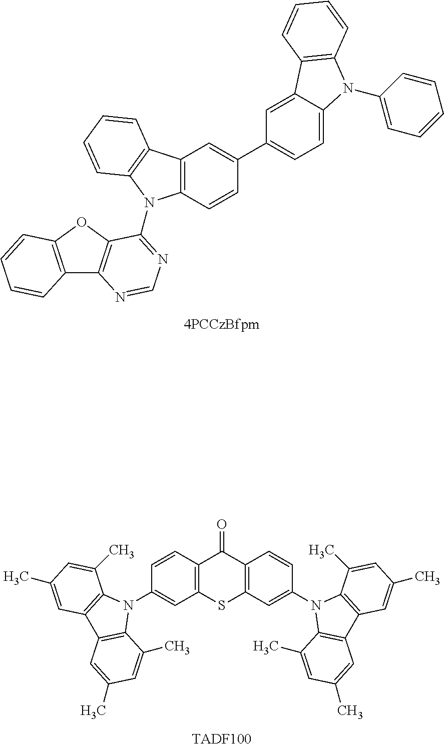

In addition to the above, another example of a material having a function of converting triplet excitation energy into light emission is a nano-structure of a transition metal compound having a perovskite structure. In particular, a nano-structure of a metal halide perovskite material is preferable. The nano-structure is preferably a nanoparticle or a nanorod.

The light-emitting layer 113 can include two or more layers. For example, in the case where the light-emitting layer 113 is formed by stacking a first light-emitting layer and a second light-emitting layer in this order from the hole-transport layer side, the first light-emitting layer is formed using a substance having a hole-transport property as the host material and the second light-emitting layer is formed using a substance having an electron-transport property as the host material. A light-emitting material contained in the first light-emitting layer may be the same as or different from a light-emitting material contained in the second light-emitting layer. In addition, the materials may have functions of emitting light of the same color or light of different colors. When light-emitting materials having functions of emitting light of different colors are used for the two light-emitting layers, light of a plurality of emission colors can be obtained at the same time. It is particularly preferable to select light-emitting materials of the light-emitting layers so that white light can be obtained by combining light emission from the two light-emitting layers.

The light-emitting layer 113 may contain a material other than the host material 118 and the guest material 119.

Note that the light-emitting layer 113 can be formed by an evaporation method (including a vacuum evaporation method), an ink-jet method, a coating method, a gravure printing method, or the like. Besides the above-mentioned materials, an inorganic compound such as a quantum dot or a high molecular compound (e.g., an oligomer, a dendrimer, or a polymer) may be used.

### <<Hole-Injection Layer>>

The hole-injection layers (111, 111a, and 111b) inject holes from the first electrode 101 functioning as an anode and the charge-generation layers (106, 106a, and 106b) to the organic compound layers (103, 103a, and 103b) and contain an organic acceptor material and a material having a high hole-injection property.

The hole-injection layers (111, 111a, and 111b) have a function of lowering a barrier for hole injection from one of the pair of electrodes (the first electrode 101 or the second electrode 102) to promote hole injection and is formed using a transition metal oxide, a phthalocyanine derivative, or an aromatic amine, for example. As examples of the transition metal oxide, molybdenum oxide, vanadium oxide, ruthenium oxide, tungsten oxide, and manganese oxide can be given. As examples of the phthalocyanine derivative, phthalocyanine and metal phthalocyanine can be given. As examples of the aromatic amine, a benzidine derivative and a phenylenediamine derivative can be given. It is also possible to use a high molecular compound such as polythiophene or polyaniline; a typical example thereof is poly(ethylenedioxythiophene)/poly(styrenesulfonic acid), which is self-doped polythiophene.

As each of the hole-injection layers (111, 111a, and 111b), a layer containing a composite material of a hole-transport material and a material having a property of accepting electrons from the hole-transport material can also be used. Alternatively, a stack of a layer containing a material having an electron-accepting property and a layer containing a hole-transport material may also be used. In a steady state or in the presence of an electric field, charge can be transferred between these materials. As examples of the material having an electron-accepting property, organic acceptors such as a quinodimethane derivative, a chloranil derivative, and a hexaazatriphenylene derivative can be given. A specific example is a compound having an electron-withdrawing group (a halogen group or a cyano group), such as 7,7,8,8-tetracyano-2,3,5,6-tetrafluoroquinodimethane (abbreviation: F₄-TCNQ), chloranil, or 2,3,6,7,10,11-hexacyano-1,4,5,8,9,12-hexaazatriphenylene (abbreviation: HAT-CN). Alternatively, a transition metal oxide such as an oxide of a metal from Group 4 to Group 8 can be used. Specifically, vanadium oxide, niobium oxide, tantalum oxide, chromium oxide, molybdenum oxide, tungsten oxide, manganese oxide, rhenium oxide, or the like can be used. In particular, molybdenum oxide is preferable because it is stable in the air, has a low hygroscopic property, and is easily handled.

A material having a hole-transport property higher than an electron-transport property can be used as a hole-transport material, and a material having a hole mobility higher than or equal to 1×10⁻⁶ cm²/Vs is preferably used. Specifically, any of the aromatic amine, carbazole derivative, aromatic hydrocarbon, stilbene derivative, and the like described as examples of the hole-transport material that can be used in the light-emitting layer 113 can be used. Furthermore, the hole-transport material may be a high molecular compound.

### <<Hole-Transport Layer>>

The hole-transport layers (112, 112a, and 112b) contain a hole-transport material and can be formed using any of the hole-transport materials given as examples of the material of the hole-injection layers (111, 111a, and 111b). In order that the hole-transport layers (112, 112a, and 112b) can have a function of transporting holes injected into the hole-injection layers (111, 111a, and 111b) to the light-emitting layers (113, 113a, and 113b), the HOMO level of the hole-transport layers (112, 112a, and 112b) is preferably equal or close to the HOMO level of the hole-injection layers (111, 111a, and 111b).

As the hole-transport material, a substance having a hole mobility higher than or equal to 1×10⁻⁶ cm²/Vs is preferably used. Note that other substances may also be used as long as their hole-transport properties are higher than their electron-transport properties. The layer containing a substance having a high hole-transport property is not limited to a single layer and may be a stack of two or more layers each containing any of the above substances.

### <<Electron-Transport Layer>>

The electron-transport layers (114, 114a, and 114b) have a function of transporting, to the light-emitting layer 113, electrons injected from the other of the pair of electrodes (the first electrode 101 or the second electrode 102) through the electron-injection layers (115, 115a, and 115b). As the electron-transport material, a material having an electron-transport property higher than a hole-transport property can be used, and a material having an electron mobility higher than or equal to 1×10⁻⁶ cm²/Vs is preferable. A compound having a π-electron deficient heteroaromatic ring skeleton such as a nitrogen-containing heteroaromatic compound or a metal complex can be used, for example, as a compound which easily accepts electrons (a material having an electron-transport property). Specific examples include a metal complex having a quinoline ligand, a metal complex having a benzoquinoline ligand, a metal complex having an oxazole ligand, and a metal complex having a thiazole ligand, which are described as the electron-transport materials usable for the light-emitting layer 113. In addition, an oxadiazole derivative, a triazole derivative, a benzimidazole derivative, a quinoxaline derivative, a dibenzoquinoxaline derivative, a phenanthroline derivative, a pyridine derivative, a bipyridine derivative, a pyrimidine derivative, a triazine derivative, or the like can be used. As the electron-transport material, a substance having an electron mobility higher than or equal to 1×10⁻⁶ cm²/Vs is preferably used. Note that other substances may also be used for the electron-transport layer as long as their electron-transport properties are higher than their hole-transport properties. Each of the electron-transport layers (114, 114a, and 114b) is not limited to a single layer and may be a stack of two or more layers each including any of the above substances.

Between the electron-transport layer (114, 114a, or 114b) and the light-emitting layer (113, 113a, or 113b), a layer that controls transfer of electron carriers may be provided. This is a layer formed by addition of a small amount of a substance having a high electron-trapping property to a material having a high electron-transport property as described above, and the layer is capable of adjusting carrier balance by suppressing transport of electron carriers. Such a structure is very effective in inhibiting a problem (such as a reduction in element lifetime) caused when electrons pass through the light-emitting layer.

### <<Electron-Injection Layer>>

The electron-injection layers (115, 115a, and 115b) have a function of reducing a barrier for electron injection from the second electrode 102 to promote electron injection and can be formed using a Group 1 metal or a Group 2 metal, or an oxide, a halide, or a carbonate of any of these metals, for example. Alternatively, a composite material including the electron-transport material described above and a material having a property of donating electrons to the electron-transport material can also be used. As examples of the material having an electron-donating property, a Group 1 metal, a Group 2 metal, an oxide of any of these metals, and the like can be given. Specifically, an alkali metal, an alkaline earth metal, or a compound thereof, such as lithium fluoride (LiF), sodium fluoride (NaF), cesium fluoride (CsF), calcium fluoride (CaF₂), or lithium oxide (LiOₓ), can be used. Alternatively, a rare earth metal compound like erbium fluoride (ErF₃) can be used. Electride may also be used for the electron-injection layer 115. Examples of the electride include a substance in which electrons are added at high concentration to calcium oxide-aluminum oxide. The electron-injection layers (115, 115a, and 115b) can be formed using the substance that can be used for the electron-transport layers (114, 114a, and 114b).

A composite material in which an organic compound and an electron donor (donor) are mixed may also be used for the electron-injection layers (115, 115a, and 115b). Such a composite material is excellent in an electron-injection property and an electron-transport property because electrons are generated in the organic compound by the electron donor. In this case, the organic compound is preferably a material that is excellent in transporting the generated electrons. Specifically, the above-described substances for forming the second carrier transport layer 117 and the electron-transport layer 114 of the ordered stacked light-emitting device (e.g., a metal complex or a heteroaromatic compound) can be used, for example. As the electron donor, a substance showing an electron-donating property with respect to an organic compound can be used. Specifically, it is preferable to use an alkali metal, an alkaline earth metal, or a rare earth metal, such as lithium, sodium, cesium, magnesium, calcium, erbium, or ytterbium. It is also preferable to use an alkali metal oxide or an alkaline earth metal oxide, such as lithium oxide, calcium oxide, or barium oxide. Alternatively, a Lewis base such as magnesium oxide can be used. Further alternatively, an organic compound such as tetrathiafulvalene (abbreviation: TTF) can be used.

A strongly basic material may be used for the electron-injection layers (115, 115a, and 115b). As the strongly basic material, an organic compound such as 1-(9,9′-spirobi[9H-fluoren]-2-yl)-1,3,4,6,7,8-hexahydro-2H-pyrimido[1,2-a]pyrimidine (abbreviation: 2hppSF), 2,9-bis(1,3,4,6,7,8-hexahydro-2H-pyrimido[1,2-a]pyrimidin-1-yl)-1,10-phenanthroline (abbreviation: 2,9hpp2Phen), 4,7-di-1-pyrrolidinyl-1,10-phenanthroline (abbreviation: Pyrrd-Phen), or 8,8′-pyridine-2,6-diyl-bis(5,6,7,8-tetrahydroimidazo[1,2-a]pyrimidine) (abbreviation: 2,6tip2Py) can be specifically used, for example.

Note that in the ordered stacked light-emitting device, the light-emitting layer is preferably formed by an evaporation method (including a vacuum evaporation method), and the hole-injection layer, the hole-transport layer, the electron-transport layer, and the electron-injection layer can each be formed by an evaporation method (including a vacuum evaporation method), an ink-jet method, a coating method, a gravure printing method, or the like. In the inverted stacked light-emitting device, the light-emitting layer can be formed by an evaporation method (including a vacuum evaporation method), an ink-jet method, a coating method, a gravure printing method, or the like, and the hole-injection layer, the hole-transport layer, the electron-transport layer, and the electron-injection layer are each preferably formed by an evaporation method (including a vacuum evaporation method). Besides the above-mentioned materials, an inorganic compound such as a quantum dot or a high molecular compound (e.g., an oligomer, a dendrimer, or a polymer) may be used in the light-emitting layer, the hole-injection layer, the hole-transport layer, the electron-transport layer, and the electron-injection layer.

The quantum dot may be a colloidal quantum dot, an alloyed quantum dot, a core-shell quantum dot, or a core quantum dot, for example. The quantum dot including elements belonging to Groups 2 and 16, elements belonging to Groups 13 and 15, elements belonging to Groups 13 and 17, elements belonging to Groups 11 and 17, or elements belonging to Groups 14 and 15 may be used. Alternatively, the quantum dot including an element such as cadmium (Cd), selenium (Se), zinc (Zn), sulfur(S), phosphorus (P), indium (In), tellurium (Te), lead (Pb), gallium (Ga), arsenic (As), or aluminum (Al) may be used.

### <<Pair of Electrodes>>

The first electrode 101 and the second electrode 102 function as an anode and a cathode of the light-emitting device. The first electrode 101 and the second electrode 102 can be formed using a metal, an alloy, or a conductive compound, a mixture or a stack thereof, or the like.

One of the first electrode 101 and the second electrode 102 is preferably formed using a conductive material having a function of reflecting light. Examples of the conductive material include aluminum (Al), an alloy including Al, and the like. Examples of the alloy including Al include an alloy including Al and L (L represents one or more of titanium (Ti), neodymium (Nd), nickel (Ni), and lanthanum (La)), such as an alloy including Al and Ti and an alloy including Al, Ni, and La. Aluminum has low resistance and high light reflectivity. Aluminum is included in earth's crust in large amount and is inexpensive; thus, it is possible to reduce costs for manufacturing a light-emitting device with aluminum. Alternatively, silver (Ag), an alloy of Ag and N (N represents one or more of yttrium (Y), Nd, magnesium (Mg), ytterbium (Yb), Al, Ti, gallium (Ga), zinc (Zn), indium (In), tungsten (W), manganese (Mn), tin (Sn), iron (Fc), Ni, copper (Cu), palladium (Pd), iridium (Ir), and gold (Au)), or the like may be used. Examples of the alloy including silver include an alloy including silver, palladium, and copper, an alloy including silver and copper, an alloy including silver and magnesium, an alloy including silver and nickel, an alloy including silver and gold, an alloy including silver and ytterbium, and the like. Besides, a transition metal such as tungsten, chromium (Cr), molybdenum (Mo), copper, or titanium can be used.

Light emitted from the light-emitting layer is extracted through the first electrode 101 and/or the second electrode 102. Thus, at least one of the first electrode 101 and the second electrode 102 is preferably formed using a conductive material having a function of transmitting light. As the conductive material, a conductive material having a visible light transmittance higher than or equal to 40% and lower than or equal to 100%, preferably higher than or equal to 60% and lower than or equal to 100%, and a resistivity lower than or equal to 1×10⁻² Ω·cm can be used.

The first electrode 101 and the second electrode 102 may each be formed using a conductive material having functions of transmitting light and reflecting light. As the conductive material, a conductive material having a visible light reflectivity higher than or equal to 20% and lower than or equal to 80%, preferably higher than or equal to 40% and lower than or equal to 70%, and a resistivity lower than or equal to 1×10⁻² Ω·cm can be used. For example, one or more kinds of conductive metals and alloys, conductive compounds, and the like can be used. Specifically, a metal oxide such as indium tin oxide (hereinafter, referred to as ITO), indium tin oxide including silicon or silicon oxide (ITSO), indium oxide-zinc oxide (indium zinc oxide), indium oxide-tin oxide including titanium, indium titanium oxide, or indium oxide including tungsten oxide and zinc oxide can be used. A metal thin film having a thickness that allows transmission of light (preferably, a thickness greater than or equal to 1 nm and less than or equal to 30 nm) can also be used. As the metal, Ag, an alloy of Ag and Al, an alloy of Ag and Mg, an alloy of Ag and Au, an alloy of Ag and Yb, or the like can be used.

In this specification and the like, as the material having a function of transmitting light, a material having a function of transmitting visible light and having conductivity is used. Examples of the material include, in addition to the above-described oxide conductor typified by ITO, an oxide semiconductor and an organic conductor including an organic substance. Examples of the organic conductor including an organic substance include a composite material in which an organic compound and an electron donor (donor) are mixed and a composite material in which an organic compound and an electron acceptor (acceptor) are mixed. Alternatively, an inorganic carbon-based material such as graphene may be used. The resistivity of the material is preferably lower than or equal to 1×10⁵ Ω·cm, further preferably lower than or equal to 1×10⁴ Ω·cm.

The first electrode 101 and/or the second electrode 102 may be formed by stacking two or more of the materials described above.

In order to improve the light extraction efficiency, a material whose refractive index is higher than that of an electrode having a function of transmitting light may be formed in contact with the electrode. The material may be electrically conductive or non-conductive as long as it has a function of transmitting visible light. In addition to the oxide conductors described above, an oxide semiconductor and an organic substance are given as the examples of the material. Examples of the organic substance include the materials for the light-emitting layer, the hole-injection layer, the hole-transport layer, the electron-transport layer, and the electron-injection layer. Alternatively, an inorganic carbon-based material or a metal film thin enough to transmit light can be used. Further alternatively, stacked layers with a thickness of several nanometers to several tens of nanometers may be used.

In the case where the first electrode 101 or the second electrode 102 has a function of the cathode, the electrode preferably includes a material having a low work function (lower than or equal to 3.8 eV). For example, it is possible to use an element belonging to Group 1 or 2 of the periodic table (e.g., an alkali metal such as lithium, sodium, or cesium, an alkaline earth metal such as calcium or strontium, or magnesium), an alloy including any of these elements (e.g., Ag—Mg or Al—Li), a rare earth metal such as europium (Eu) or Yb, an alloy including any of these rare earth metals, an alloy including aluminum or silver, or the like.

When the first electrode 101 or the second electrode 102 is used as an anode, a material with a high work function (4.0 eV or higher) is preferably used.

The first electrode 101 and the second electrode 102 may be a stacked layer of a conductive material having a function of reflecting light and a conductive material having a function of transmitting light. This structure is preferably employed, in which case the first electrode 101 and the second electrode 102 can have a function of adjusting the optical path length so that light of a desired wavelength emitted from each light-emitting layer resonates and is intensified.

As the method for forming the first electrode 101 and the second electrode 102, a sputtering method, an evaporation method, a printing method, a coating method, a molecular beam epitaxy (MBE) method, a chemical vapor deposition (CVD) method, a pulsed laser deposition method, an atomic layer deposition (ALD) method, or the like can be used as appropriate.

### <<Charge-Generation Layer>>

The charge-generation layer 106 has a function of injecting electrons into the organic compound layer 103a and injecting holes into the organic compound layer 103b when a voltage is applied between the first electrode (anode) 101 and the second electrode (cathode) 102. The charge-generation layer 106 may be either a p-type layer in which an electron acceptor (acceptor) is added to a hole-transport material or an electron-injection buffer layer in which an electron donor (donor) is added to an electron-transport material. Alternatively, both of these structures may be stacked. Furthermore, an electron-relay layer may be provided between the p-type layer and the electron-injection buffer layer. Note that forming the charge-generation layer 106 with the use of any of the above materials can inhibit an increase in driving voltage caused by the stack of the organic compound layers.

In the case where the charge-generation layer 106 is a p-type layer in which an electron acceptor is added to a hole-transport material, which is an organic compound, any of the materials described in this embodiment can be used as the hole-transport material. Examples of the electron acceptor include 7,7,8,8-tetracyano-2,3,5,6-tetrafluoroquinodimethane (abbreviation: F₄-TCNQ) and chloranil. Other examples include oxides of metals that belong to Group 4 to Group 8 of the periodic table. Specific examples include vanadium oxide, niobium oxide, tantalum oxide, chromium oxide, molybdenum oxide, tungsten oxide, manganese oxide, and rhenium oxide.

Any of the above-described acceptor materials may be used. Furthermore, a mixed film obtained by mixing materials of a p-type layer or a stack of films including the respective materials may be used.

In the case where the charge-generation layer 106 is an electron-injection buffer layer in which an electron donor is added to an electron-transport material, any of the materials described in this embodiment can be used as the electron-transport material. As the electron donor, it is possible to use an alkali metal, an alkaline earth metal, a rare earth metal, a metal belonging to Group 2 or Group 13 of the periodic table, or an oxide or a carbonate thereof. Specifically, lithium (Li), cesium (Cs), magnesium (Mg), calcium (Ca), ytterbium (Yb), indium (In), lithium oxide (Li₂O), cesium carbonate, or the like is preferably used. An organic compound such as tetrathianaphthacene may be used as the electron donor.

When an electron-relay layer is provided between a p-type layer and an electron-injection buffer layer in the charge-generation layer 106, the electron-relay layer contains at least a substance having an electron-transport property and has a function of preventing an interaction between the electron-injection buffer layer and the p-type layer and transferring electrons smoothly. The LUMO level of the substance having an electron-transport property in the electron-relay layer is preferably between the LUMO level of the acceptor substance in the p-type layer and the LUMO level of the substance having an electron-transport property in the electron-transport layer in contact with the charge-generation layer 106. Specifically, the LUMO level of the substance having an electron-transport property in the electron-relay layer is preferably higher than or equal to −5.0 eV, further preferably higher than or equal to −5.0 eV and lower than or equal to −3.0 eV. Note that as the substance having an electron-transport property in the electron-relay layer, a phthalocyanine-based material or a metal complex having a metal-oxygen bond and an aromatic ligand is preferably used.

Although FIG. 4D illustrates the structure in which two of the organic compound layers 103 are stacked, three or more organic compound layers may be stacked with charge-generation layers each provided between different organic compound layers.

### <<Cap Layer>>

Although not illustrated in FIGS. 4A to 4E, a cap layer may be provided over the second electrode 102 of the light-emitting device. For example, a material with a high refractive index can be used for the cap layer. When the cap layer is provided over the second electrode 102, extraction efficiency of light emitted through the second electrode 102 can be improved.

Specific examples of a material that can be used for the cap layer include 5,5′-diphenyl-2,2′-di-5H-[1]benzothieno[3,2-c]carbazole (abbreviation: BisBTc) and 4,4′,4″-(benzene-1,3,5-triyl)tri (dibenzothiophene) (abbreviation: DBT3P-II).

### <<Substrate>>

A light-emitting device of one embodiment of the present invention may be formed over a substrate of glass, plastic, or the like. As the way of stacking layers over the substrate, layers may be sequentially stacked from the first electrode 101 side or sequentially stacked from the second electrode 102 side.

For the substrate over which the light-emitting device of one embodiment of the present invention can be formed, glass, quartz, plastic, or the like can be used, for example. Alternatively, a flexible substrate may be used. The flexible substrate means a substrate that can be bent, such as a plastic substrate made of polycarbonate or polyarylate, for example. Alternatively, a film, an inorganic vapor deposition film, or the like can be used. Another material may be used as long as the substrate functions as a support in a manufacturing process of the light-emitting devices or the optical elements. Another material having a function of protecting the light-emitting devices or the optical elements may be used.

In this specification and the like, a light-emitting device can be formed using any of a variety of substrates, for example. There is no particular limitation on the type of the substrate. Examples of the substrate include a semiconductor substrate (e.g., a single crystal substrate or a silicon substrate); an SOI substrate; a glass substrate; a quartz substrate; a plastic substrate; a metal substrate; a stainless steel substrate; a substrate including stainless steel foil; a tungsten substrate; a substrate including tungsten foil; a flexible substrate; an attachment film; and cellulose nanofiber (CNF), paper, and a base material film that include a fibrous material. Examples of a glass substrate include a barium borosilicate glass substrate, an aluminoborosilicate glass substrate, and a soda lime glass substrate. Examples of the flexible substrate, the attachment film, the base material film, and the like are substrates of plastics typified by polyethylene terephthalate (PET), polyethylene naphthalate (PEN), polyether sulfone (PES), and polytetrafluoroethylene (PTFE). Another example is an acrylic resin. Furthermore, polypropylene, polyester, polyvinyl fluoride, and polyvinyl chloride can be given as examples. Other examples include a resin such as a polyamide resin, a polyimide resin, an aramid resin, or an epoxy resin, an inorganic vapor deposition film, and paper.

Alternatively, a flexible substrate may be used as the substrate, and a light-emitting device may be provided directly on the flexible substrate. Further alternatively, a separation layer may be provided between the substrate and the light-emitting device. The separation layer can be used to separate part or the whole of the light-emitting device, which is formed over the separation layer, from the substrate and transfer the separated component onto another substrate. In that case, the light-emitting device can be transferred to a substrate having low heat resistance or a flexible substrate as well. For the above separation layer, a stack including inorganic films, which are a tungsten film and a silicon oxide film, or a structure in which a resin film of polyimide or the like is formed over a substrate can be used, for example.

In other words, after the light-emitting device is formed using a substrate, the light-emitting device may be transferred to another substrate. Examples of the substrate to which the light-emitting device is transferred are, in addition to the above substrates, a cellophane substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupro, rayon, or regenerated polyester), and the like), a leather substrate, a rubber substrate, and the like. When such a substrate is used, a light-emitting device with high durability, high heat resistance, reduced weight, or reduced thickness can be formed.

The light-emitting device may be formed over an electrode electrically connected to a field-effect transistor (FET), for example, that is formed over any of the above-described substrates. Accordingly, an active matrix display device in which the FET controls the driving of the light-emitting device can be manufactured.

The structure described above in this embodiment can be used in combination with any of the structures described in the other embodiments as appropriate.

### Embodiment 3

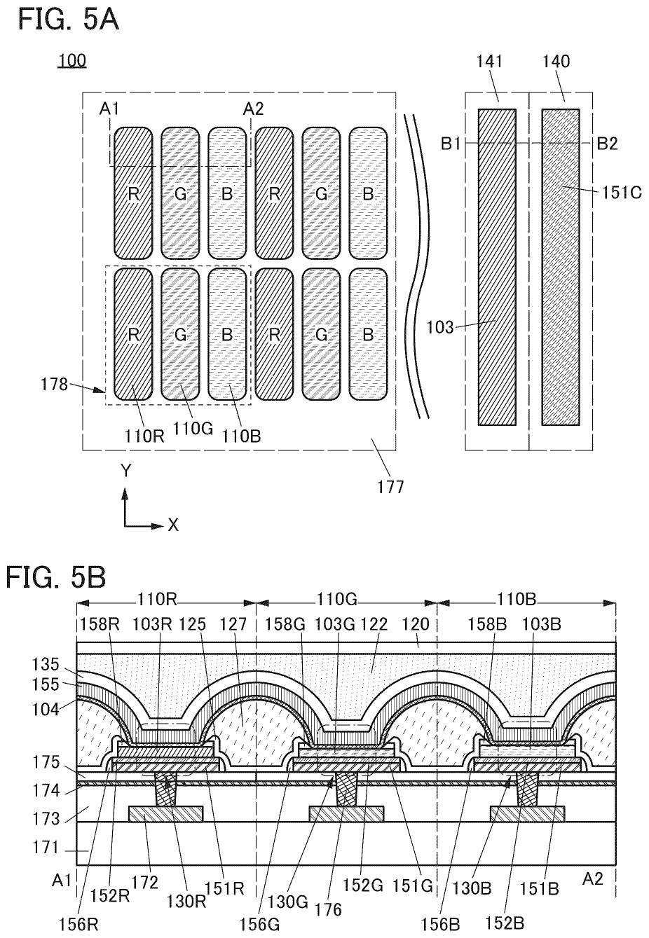

As shown in FIG. 5B, a plurality of light-emitting devices 130 are formed over an insulating layer 175 to constitute a display device. In this embodiment, the display device of one embodiment of the present invention will be described in detail.

A display device 100 includes a pixel portion 177 in which a plurality of pixels 178 are arranged in matrix. The pixel 178 includes a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, an image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and yellow (Y), and four subpixels emitting light of R, G, and B and infrared (IR) light.

In this specification and the like, the row direction and the column direction are sometimes referred to as the X direction and the Y direction, respectively. The X direction and the Y direction intersect with each other and are perpendicular to each other, for example.

FIG. 5A shows an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. The region 141 is provided between the pixel portion 177 and the connection portion 140. The organic compound layer 103 is provided in the region 141. A conductive layer 151C is provided in the connection portion 140.

Although FIG. 5A shows an example where the region 141 and the connection portion 140 are positioned on the right side of the pixel portion 177, there is no particular limitation on the positions of the region 141 and the connection portion 140. The number of regions 141 and the number of connection portions 140 can each be one or two or more.

FIG. 5B is an example of a cross-sectional view along the dashed-dotted line A1-A2 in FIG. 5A. As shown in FIG. 5A, the display device 100 includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not shown). An opening reaching the conductive layer 172 is provided in the insulating layers 175, 174, and 173, and a plug 176 is provided to fill the opening.

In the pixel portion 177, the light-emitting device 130 is provided over the insulating layer 175 and the plug 176. A protective layer 135 is provided to cover the light-emitting device 130. A substrate 120 is bonded onto the protective layer 135 with a resin layer 122. An inorganic insulating layer 125 and an insulating layer 127 over the inorganic insulating layer 125 are preferably provided between adjacent light-emitting devices 130.

Although FIG. 5B shows cross sections of a plurality of the inorganic insulating layers 125 and a plurality of the insulating layers 127, the inorganic insulating layers 125 are preferably connected to each other and the insulating layers 127 are preferably connected to each other when the display device 100 is seen from above. That is, the inorganic insulating layer 125 and the insulating layer 127 preferably include opening portions over first electrodes.

In FIG. 5B, a light-emitting device 130R, a light-emitting device 130G, and a light-emitting device 130B are each shown as the light-emitting device 130. The light-emitting devices 130R, 130G, and 130B emit light of different colors. For example, the light-emitting device 130R can emit red light, the light-emitting device 130G can emit green light, and the light-emitting device 130B can emit blue light. Alternatively, the light-emitting device 130R, the light-emitting device 130G, or the light-emitting device 130B may emit visible light of another color or infrared light.

The display device of one embodiment of the present invention can be, for example, a top-emission display device where light is emitted in the direction opposite to a substrate over which light-emitting devices are formed. Note that the display device of one embodiment of the present invention may be a bottom-emission display device.

Examples of a light-emitting substance included in the light-emitting device 130 include organic compounds or organometallic complexes such as a substance emitting fluorescent light (a fluorescent material), a substance emitting phosphorescent light (a phosphorescent material), and a substance exhibiting thermally activated delayed fluorescence (a thermally activated delayed fluorescent (TADF) material). Other examples include inorganic compounds (e.g., a quantum dot material).

The light-emitting device 130R has a structure as described in Embodiment 1. The light-emitting device 130R includes the first electrode (pixel electrode) including a conductive layer 151R and a conductive layer 152R, an organic compound layer 103R over the first electrode, a common layer 104 over the organic compound layer 103R, and a common electrode 155 over the common layer 104. The common electrode 155 corresponds to the second electrode 102 in Embodiments 1 and 2. Although the common layer 104 is not necessarily provided, it is preferable to provide the common layer 104 to reduce damage to the organic compound layer 103R during processing. In the case where the common layer 104 is provided, the common layer 104 is preferably an electron-injection layer. Furthermore, in the case where the common layer 104 is not provided, the organic compound layer 103R corresponds to the organic compound layer 103 in Embodiments 1 and 2. In the case where the common layer 104 is provided, a stack of the organic compound layer 103R and the common layer 104 corresponds to the organic compound layer 103 in Embodiments 1 and 2.

The light-emitting device 130G has a structure as described in Embodiment 1. The light-emitting device 130G includes the first electrode (pixel electrode) including a conductive layer 151G and a conductive layer 152G, an organic compound layer 103G over the first electrode, the common layer 104 over the organic compound layer 103G, and the common electrode 155 over the common layer 104. The common electrode 155 corresponds to the second electrode 102 in Embodiments 1 and 2. Although the common layer 104 is not necessarily provided, it is preferable to provide the common layer 104 to reduce damage to the organic compound layer 103G during processing. Furthermore, in the case where the common layer 104 is not provided, the organic compound layer 103G corresponds to the organic compound layer 103 in Embodiments 1 and 2. In the case where the common layer 104 is provided, a stack of the organic compound layer 103G and the common layer 104 corresponds to the organic compound layer 103 in Embodiments 1 and 2.

The light-emitting device 130B has a structure as described in Embodiment 1. The light-emitting device 130B includes the first electrode (pixel electrode) including a conductive layer 151B and a conductive layer 152B, an organic compound layer 103B over the first electrode, the common layer 104 over the organic compound layer 103B, and the common electrode 155 over the common layer 104. The common electrode 155 corresponds to the second electrode 102 in Embodiments 1 and 2. Although the common layer 104 is not necessarily provided, it is preferable to provide the common layer 104 to reduce damage to the organic compound layer 103B during processing. Furthermore, in the case where the common layer 104 is not provided, the organic compound layer 103B corresponds to the organic compound layer 103 in Embodiments 1 and 2. In the case where the common layer 104 is provided, a stack of the organic compound layer 103B and the common layer 104 corresponds to the organic compound layer 103 in Embodiments 1 and 2.

In the light-emitting device, one of the pixel electrode and the common electrode functions as an anode and the other functions as a cathode. Hereinafter, description is made on the assumption that the pixel electrode functions as the anode and the common electrode functions as the cathode unless otherwise specified.

The organic compound layer 103R, the organic compound layer 103G, and the organic compound layer 103B are island-shaped layers and are isolated on a light-emitting device basis or on an emission color basis. Providing the island-shaped organic compound layer 103 in each of the light-emitting devices 130 can suppress leakage current between the adjacent light-emitting devices 130 even in a high-definition display device. This can prevent crosstalk, so that a display device with extremely high contrast can be provided. Specifically, a display device having high current efficiency at low luminance can be provided.

The island-shaped organic compound layer 103 is formed by forming an EL film and processing the EL film by a lithography method.

In the display device of one embodiment of the present invention, the first electrode (pixel electrode) of the light-emitting device preferably has a stacked-layer structure. For example, in the example shown in FIG. 5B, the first electrode of the light-emitting device 130 is a stack of the conductive layer 151 (the conductive layers 151R, 151G, and 151B) and the conductive layer 152 (the conductive layers 152R, 152G, and 152B). In the case where the display device 100 is of a top-emission type and the pixel electrode of the light-emitting device 130 functions as the anode, for example, the conductive layer 151 preferably has high visible light reflectance, and the conductive layer 152 preferably has a visible-light-transmitting property and a high work function. In the case where the display device 100 is of a top-emission type, the higher the visible light reflectance of the pixel electrode is, the higher the efficiency of extraction of the light emitted by the organic compound layer 103 is. In the case where the pixel electrode functions as the anode, the higher the work function of the pixel electrode is, the easier hole injection into the organic compound layer 103 is. Accordingly, when the pixel electrode of the light-emitting device 130 has a stacked-layer structure of the conductive layer 151 having high visible light reflectance and the conductive layer 152 having a high work function, the light-emitting device 130 can have high light extraction efficiency and a low driving voltage. In this specification and the like, description common to the conductive layers 151R, 151G, and 151B is sometimes made using the collective term “conductive layer 151”.

In the case where the conductive layer 151 has high visible light reflectance, the visible light reflectance of the conductive layer 151 is preferably higher than or equal to 40% and lower than or equal to 100% or higher than or equal to 70% and lower than or equal to 100%, for example. When used as an electrode having a visible-light-transmitting property, the conductive layer 152 preferably has a visible light transmittance higher than or equal to 40%, for example.

Here, a pixel electrode being a stack composed of a plurality of layers might change in quality as a result of, for example, a reaction between the plurality of layers. For example, when a film formed after the formation of the pixel electrode is removed by a wet etching method, contact of a chemical solution with the pixel electrode might cause galvanic corrosion.

Thus, in the display device 100 of this embodiment, an insulating layer 156 (insulating layers 156R, 156G, and 156B) is formed on the side surfaces of the conductive layers 151 and 152. This can inhibit a chemical solution from coming into contact with the conductive layer 151 even when a film that is formed after formation of the pixel electrode including the conductive layer 151 and the conductive layer 152 is removed by a wet etching method, for example. Accordingly, occurrence of galvanic corrosion in the pixel electrode can be inhibited, for example. This allows the display device 100 to be manufactured by a high-yield method and to be accordingly inexpensive. In addition, generation of a defect in the display device 100 can be inhibited, which makes the display device 100 highly reliable. In this specification and the like, description common to the conductive layers 156R, 156G, and 156B is sometimes made using the collective term “conductive layer 156”.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy including an appropriate combination of any of these metals, for example.

For the conductive layer 152, an oxide containing one or more selected from indium, tin, zinc, gallium, titanium, aluminum, and silicon can be used. For example, it is preferable to use a conductive oxide including one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a high work function, for example, a work function higher than or equal to 4.0 eV.

The conductive layer 151 and the conductive layer 152 may each be a stack of a plurality of layers that contain different materials. In that case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 is a stack of two or more layers, for example, a layer in contact with the conductive layer 152 can be formed using a material that can be used for the conductive layer 152.

The structure described in this embodiment can be used in combination with any of the structures described in the other embodiments as appropriate.

### Embodiment 4

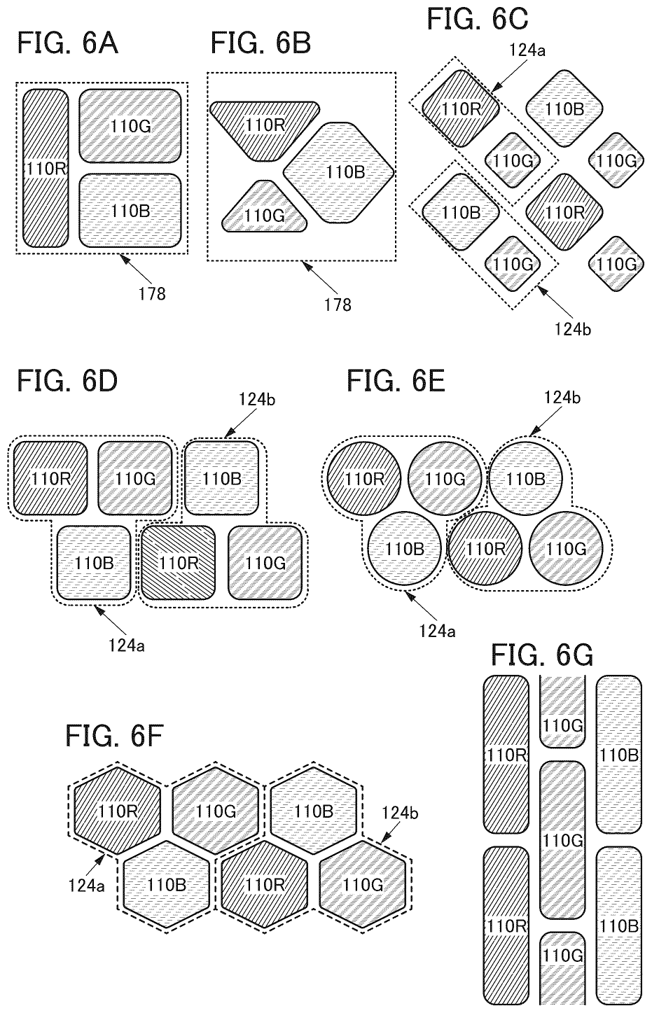

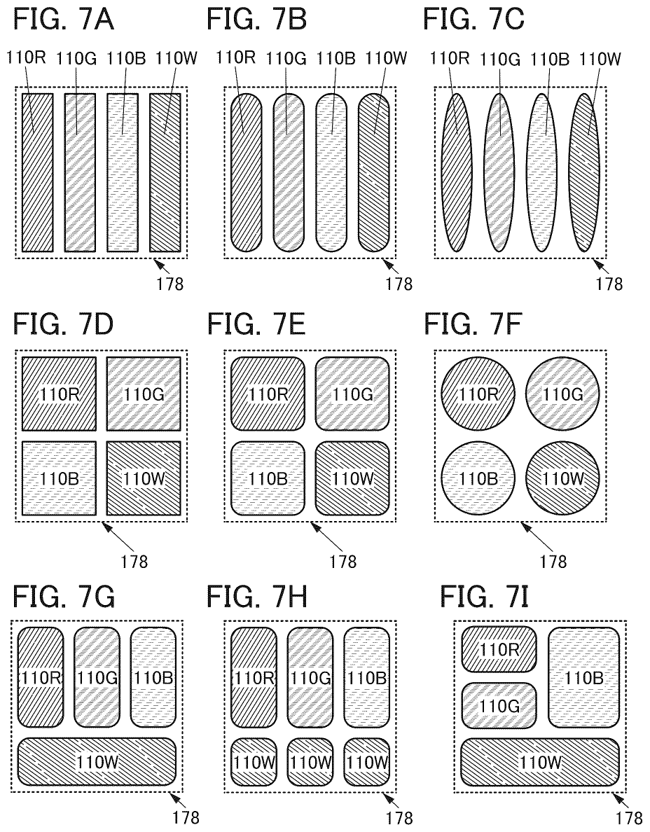

In this embodiment, the light-emitting apparatus of one embodiment of the present invention will be described with reference to FIGS. 6A to 6G and FIGS. 7A to 7I.

### [Pixel Layout]

In this embodiment, pixel layouts different from that in FIG. 5A will be mainly described. There is no particular limitation on the subpixel layout, and a variety of methods can be employed. Examples of the subpixel layout include stripe layout, S-stripe layout, matrix layout, delta layout, Bayer layout, and PenTile layout.

In this embodiment, top surface shapes of the subpixels shown in the diagrams correspond to top surface shapes of light-emitting regions.

Examples of a top surface shape of the subpixel include polygons such as a triangle, a tetragon (including a rectangle and a square), and a pentagon; these polygons with rounded corners; an ellipse; and a circle.

The circuit constituting the subpixel is not necessarily placed within the dimensions of the subpixel shown in the diagrams and may be placed outside the subpixel.

The pixel 178 shown in FIG. 6A employs S-stripe layout. The pixel 178 shown in FIG. 6A includes three subpixels, the subpixel 110R, the subpixel 110G, and the subpixel 110B.

The pixel 178 shown in FIG. 6B includes the subpixel 110R whose top surface has a rough trapezoidal shape with rounded corners or a rough triangular shape with rounded corners, the subpixel 110G whose top surface has a rough trapezoidal shape with rounded corners or a rough triangular shape with rounded corners, and the subpixel 110B whose top surface has a rough tetragonal shape with rounded corners or a rough hexagonal shape with rounded corners. The subpixel 110R has a larger light-emitting area than the subpixel 110G. In this manner, the shapes and sizes of the subpixels can be determined independently. For example, the size of a subpixel including a light-emitting device with higher reliability can be smaller.

Pixels 124a and 124b shown in FIG. 6C employ PenTile layout. FIG. 6C shows an example in which the pixels 124a including the subpixels 110R and 110G and the pixels 124b including the subpixels 110G and 110B are alternately arranged.

The pixels 124a and 124b shown in FIGS. 6D to 6F employ delta layout. The pixel 124a includes two subpixels (the subpixels 110R and 110G) in the upper row (first row) and one subpixel (the subpixel 110B) in the lower row (second row). The pixel 124b includes one subpixel (the subpixel 110B) in the upper row (first row) and two subpixels (the subpixels 110R and 110G) in the lower row (second row).

FIG. 6D shows an example where the top surface of each subpixel has a rough tetragonal shape with rounded corners. FIG. 6E shows an example where the top surface of each subpixel is circular. FIG. 6F shows an example where the top surface of each subpixel has a rough hexagonal shape with rounded corners.

In FIG. 6F, subpixels are placed in respective hexagonal regions that are arranged densely. One subpixel of the subpixels is placed so as to be surrounded by six subpixels. The subpixels are arranged so that subpixels that emit light of the same color are not adjacent to each other. For example, one subpixel 110R is surrounded by three subpixels 110G and three subpixels 110B that are alternately arranged.

FIG. 6G shows an example where subpixels of different colors are arranged in a zigzag manner. Specifically, the positions of the top sides of two subpixels arranged in the row direction (e.g., the subpixels 110R and 110G or the subpixels 110G and 110B) are not aligned in the top view.

In the pixels shown in FIGS. 6A to 6G, for example, it is preferable that the subpixel 110R be a subpixel R that emits red light, the subpixel 110G be a subpixel G that emits green light, and the subpixel 110B be a subpixel B that emits blue light. Note that the structures of the subpixels are not limited thereto, and the colors and the order of the subpixels can be determined as appropriate. For example, the subpixel 110G may be the subpixel R that emits red light, and the subpixel 110R may be the subpixel G that emits green light.

In a photolithography method, as a pattern to be formed by processing becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel may have a polygonal shape with rounded corners, an elliptical shape, a circular shape, or the like.

Furthermore, in the method for fabricating the light-emitting apparatus of one embodiment of the present invention, the organic compound layer is processed into an island shape with the use of a resist mask. A resist film formed over the organic compound layer needs to be cured at a temperature lower than the upper temperature limit of the organic compound layer. Therefore, the resist film is insufficiently cured in some cases depending on the upper temperature limit of the material of the organic compound layer and the curing temperature of the resist material. An insufficiently cured resist film may have a shape different from a desired shape by processing. As a result, the top surface of the organic compound layer may have a polygonal shape with rounded corners, an elliptical shape, a circular shape, or the like. For example, when a resist mask with a square top surface is intended to be formed, a resist mask with a circular top surface may be formed, and the top surface of the organic compound layer may be circular.

To obtain a desired top surface shape of the organic compound layer, a technique of correcting a mask pattern in advance so that a transferred pattern agrees with a design pattern (an optical proximity correction (OPC) technique) may be used. Specifically, with the OPC technique, a pattern for correction is added to a corner portion of a figure on a mask pattern, for example.

As shown in FIGS. 7A to 71, the pixel can include four types of subpixels.

The pixels 178 shown in FIGS. 7A to 7C employ stripe layout.

FIG. 7A shows an example where each subpixel has a rectangular top surface shape. FIG. 7B shows an example where each subpixel has a top surface shape formed by combining two half circles and a rectangle. FIG. 7C shows an example where each subpixel has an elliptical top surface shape.

The pixels 178 shown in FIGS. 7D to 7F employ matrix layout.

FIG. 7D shows an example where each subpixel has a square top surface shape. FIG. 7E shows an example where each subpixel has a substantially square top surface shape with rounded corners. FIG. 7F shows an example where each subpixel has a circular top surface shape.

FIGS. 7G and 7H each show an example where one pixel 178 is composed of two rows and three columns.

The pixel 178 shown in FIG. 7G includes three subpixels (the subpixels 110R, 110G, and 110B) in the upper row (first row) and one subpixel (a subpixel 110W) in the lower row (second row). In other words, the pixel 178 includes the subpixel 110R in the left column (first column), the subpixel 110G in the middle column (second column), the subpixel 110B in the right column (third column), and the subpixel 110W across these three columns.

The pixel 178 shown in FIG. 7H includes three subpixels (the subpixels 110R, 110G, and 110B) in the upper row (first row) and three of the subpixels 110W in the lower row (second row). In other words, the pixel 178 includes the subpixels 110R and 110W in the left column (first column), the subpixels 110G and 110W in the middle column (second column), and the subpixels 110B and 110W in the right column (third column). Matching the positions of the subpixels in the upper row and the lower row as shown in FIG. 7H enables dust that would be produced in the fabrication process, for example, to be removed efficiently. Thus, a light-emitting apparatus having high display quality can be provided.

In the pixel 178 shown in FIGS. 7G and 7H, the subpixels 110R, 110G, and 110B are arranged in a stripe layout, whereby the display quality can be improved.

FIG. 7I shows an example where one pixel 178 is composed of three rows and two columns.

The pixel 178 shown in FIG. 7I includes the subpixel 110R in the upper row (first row), the subpixel 110G in the middle row (second row), the subpixel 110B across the first row and the second row, and one subpixel (the subpixel 110W) in the lower row (third row). In other words, the pixel 178 includes the subpixels 110R and 110G in the left column (first column), the subpixel 110B in the right column (second column), and the subpixel 110W across these two columns.

In the pixel 178 shown in FIG. 7I, the subpixels 110R, 110G, and 110B are arranged in what is called an S-stripe layout, whereby the display quality can be improved.

The pixel 178 shown in each of FIGS. 7A to 71 is composed of four subpixels, which are the subpixels 110R, 110G, 110B, and 110W. For example, the subpixel 110R can be a subpixel that emits red light, the subpixel 110G can be a subpixel that emits green light, the subpixel 110B can be a subpixel that emits blue light, and the subpixel 110W can be a subpixel that emits white light. Note that at least one of the subpixels 110R, 110G, 110B, and 110W may be a subpixel that emits cyan light, magenta light, yellow light, or near-infrared light.

As described above, the pixel composed of the subpixels each including the light-emitting device can employ any of a variety of layouts in the light-emitting apparatus of one embodiment of the present invention.

This embodiment can be combined as appropriate with any of the other embodiments and examples. In this specification, in the case where a plurality of structure examples are shown in one embodiment, the structure examples can be combined as appropriate.

### Embodiment 5

In this embodiment, a light-emitting apparatus of one embodiment of the present invention will be described.

The light-emitting apparatus in this embodiment can be a high-definition light-emitting apparatus. Thus, the light-emitting apparatus in this embodiment can be used for display portions of information terminals (wearable devices) such as watch-type and bracelet-type information terminals and display portions of wearable devices capable of being worn on a head, such as a virtual reality (VR) device like a head mounted display (HMD) and a glasses-type augmented reality (AR) device.

The light-emitting apparatus in this embodiment can be a high-resolution light-emitting apparatus or a large-sized light-emitting apparatus. Accordingly, the light-emitting apparatus in this embodiment can be used for display portions of a digital camera, a digital video camera, a digital photo frame, a mobile phone, a portable game console, a portable information terminal, and an audio reproducing device, in addition to display portions of electronic appliances with a relatively large screen, such as a television device, desktop and notebook personal computers, a monitor of a computer and the like, digital signage, and a large game machine such as a pachinko machine.

### [Display Module]

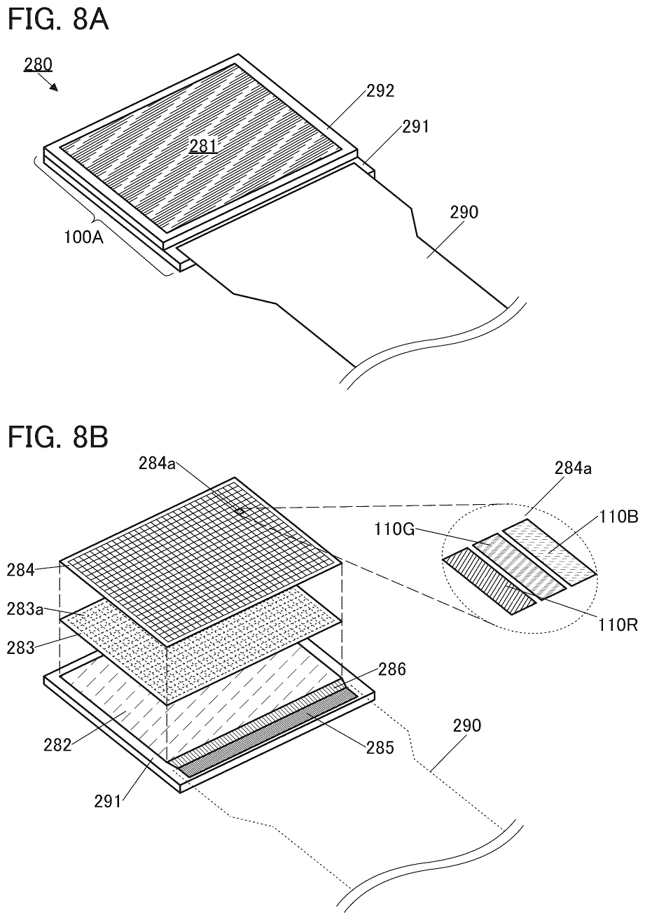

FIG. 8A is a perspective view of a display module 280. The display module 280 includes a display device 100A and an FPC 290. Note that the light-emitting apparatus included in the display module 280 is not limited to the display device 100A and may be any of display devices 100B to 100F described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 8B is a perspective view schematically showing the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion not overlapping with the pixel portion 284 over the substrate 291. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is shown on the right side in FIG. 8B. The pixels 284a can employ any of the structures described in the above embodiments. FIG. 8B shows an example where the pixel 284a has a structure similar to that of the pixel 178 shown in FIG. 5A. The pixel circuit portion 283 includes a plurality of pixel circuits 283a arranged periodically.

One pixel circuit 283a is a circuit that controls driving of a plurality of elements included in one pixel 284a. One pixel circuit 283a can be provided with three circuits each of which controls light emission of one light-emitting device. For example, the pixel circuit 283a can include at least one selection transistor, one current control transistor (driving transistor), and a capacitor per light-emitting device. A gate signal is input to a gate of the selection transistor, and a video signal is input to a source or a drain of the selection transistor. With such a structure, an active-matrix light-emitting apparatus is obtained.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have significantly high definition. For example, the pixels 284a are preferably arranged in the display portion 281 to give a definition higher than or equal to 2000 ppi, further preferably higher than or equal to 3000 ppi, still further preferably higher than or equal to 5000 ppi, yet still further preferably higher than or equal to 6000 ppi, and lower than or equal to 20000 ppi or lower than or equal to 30000 ppi.

Such a display module 280 has extremely high definition, and thus can be suitably used for a VR device such as an HMD or a glasses-type AR device. For example, even in the case of a structure in which the display portion of the display module 280 is seen through a lens, pixels of the extremely-high-definition display portion 281 included in the display module 280 are prevented from being recognized when the display portion is enlarged by the lens, so that display providing a high sense of immersion can be performed. Without being limited thereto, the display module 280 can be suitably used for electronic appliances including a relatively small display portion. For example, the display module 280 can be favorably used in a display portion of a wearable electronic appliance, such as a wrist watch.

### [Display Device 100A]

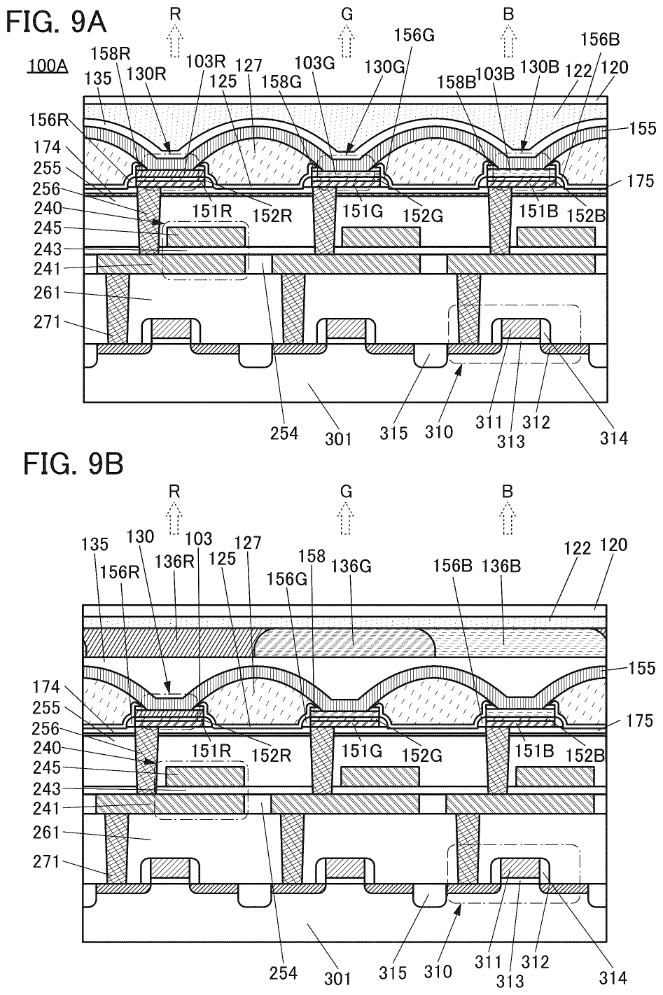

The display device 100A shown in FIG. 9A includes a substrate 301, the light-emitting devices 130R, 130G, and 130B, a capacitor 240, and a transistor 310.

The substrate 301 corresponds to the substrate 291 in FIGS. 8A and 8B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. FIG. 9A shows an example in which the light-emitting devices 130R, 130G, and 130B each have the stacked-layer structure shown in FIG. 1A. An insulator is provided in regions between adjacent light-emitting devices. For example, in FIG. 9A, the inorganic insulating layer 125 and the insulating layer 127 over the inorganic insulating layer 125 are provided in those regions.

The insulating layer 156R is provided to include a region overlapping with the side surface of the conductive layer 151R of the light-emitting device 130R. The insulating layer 156G is provided to include a region overlapping with the side surface of the conductive layer 151G of the light-emitting device 130G. The insulating layer 156B is provided to include a region overlapping with the side surface of the conductive layer 151B of the light-emitting device 130B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. A sacrificial layer 158R is positioned over the organic compound layer 103R of the light-emitting device 130R. A sacrificial layer 158G is positioned over the organic compound layer 103G of the light-emitting device 130G. A sacrificial layer 158B is positioned over the organic compound layer 103B of the light-emitting device 130B.

The conductive layers 151R, 151G, and 151B are electrically connected to the sources or the drains of the corresponding transistors 310 through plugs 256 embedded in the insulating layers 243, 255, 174, and 175, the conductive layers 241 embedded in the insulating layer 254, and the plugs 271 embedded in the insulating layer 261. The top surface of the insulating layer 175 and the top surface of the plug 256 are level with or substantially level with each other. Any of a variety of conductive materials can be used for the plugs.

The protective layer 135 is provided over the light-emitting devices 130R, 130G, and 130B. The substrate 120 is bonded onto the protective layer 135 with the resin layer 122. Embodiment 3 can be referred to for the details of the light-emitting device 130 and the components thereover up to the substrate 120. The substrate 120 corresponds to the substrate 292 in FIG. 8A.

FIG. 9B shows a modification example of the display device 100A shown in FIG. 9A. The light-emitting apparatus shown in FIG. 9B includes coloring layers 136R, 136G, and 136B, and each of the light-emitting devices 130 includes a region overlapping with one of the coloring layers 136R, 136G, and 136B. In the light-emitting apparatus shown in FIG. 9B, the light-emitting device 130 can emit white light, for example. For example, the coloring layer 136R, the coloring layer 136G, and the coloring layer 136B can transmit red light, green light, and blue light, respectively.

### [Display Device 100B]

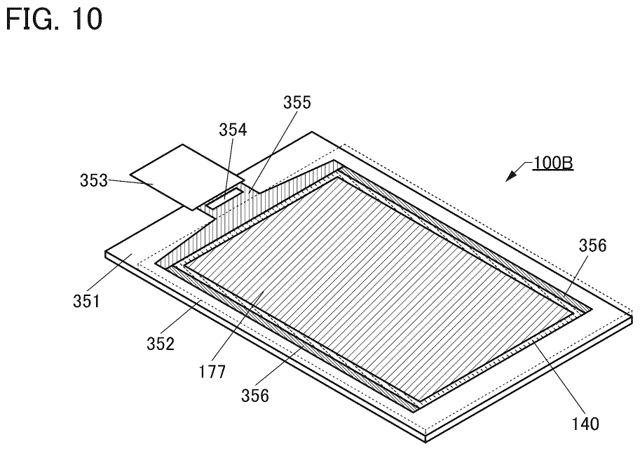

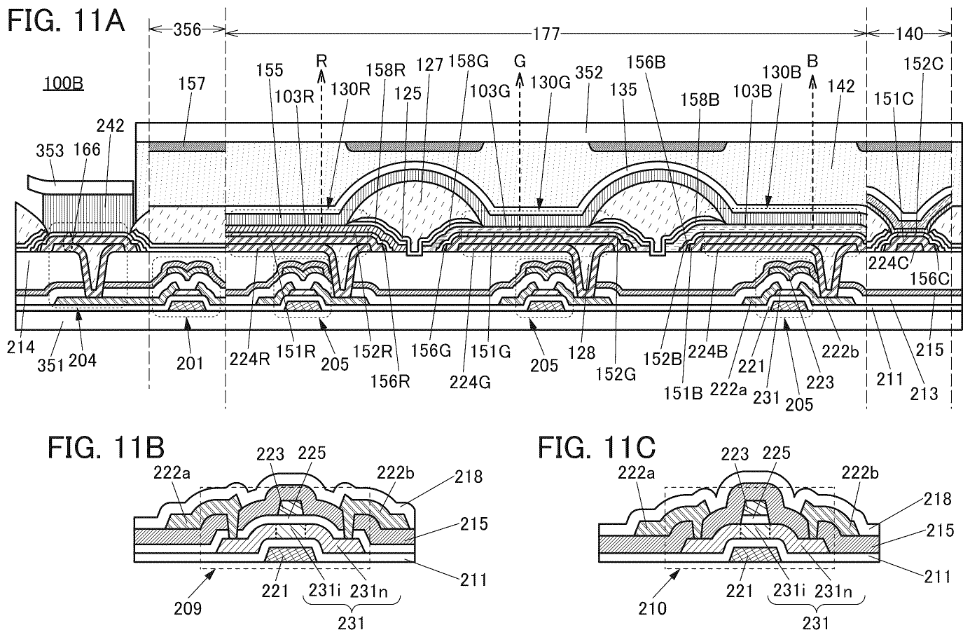

FIG. 10 is a perspective view of the display device 100B, and FIG. 11A is a cross-sectional view of the display device 100B.

In the display device 100B, a substrate 352 and a substrate 351 are bonded to each other. In FIG. 10, the substrate 352 is denoted by a dashed line.

The display device 100B includes the pixel portion 177, the connection portion 140, a circuit 356, a wiring 355, and the like. FIG. 10 shows an example in which an integrated circuit (IC) 354 and an FPC 353 are mounted on the display device 100B. Thus, the structure shown in FIG. 10 can be regarded as a display module including the display device 100B, the IC, and the FPC. Here, a light-emitting apparatus in which a substrate is equipped with a connector such as an FPC or mounted with an IC is referred to as a display module.

The connection portion 140 is provided outside the pixel portion 177. The connection portion 140 can be provided along one side or a plurality of sides of the pixel portion 177. The number of connection portions 140 may be one or more. FIG. 10 shows an example in which the connection portion 140 is provided to surround the four sides of the pixel portion 177. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 10 shows an example in which the IC 354 is provided over the substrate 351 by a chip on glass (COG) method, a chip on film (COF) method, or the like. An IC including a scan line driver circuit, a signal line driver circuit, or the like can be used as the IC 354, for example. Note that the display device 100B and the display module are not necessarily provided with an IC. Alternatively, the IC may be mounted on the FPC by a COF method, for example.

FIG. 11A shows an example of cross sections of part of a region including the FPC 353, part of the circuit 356, part of the pixel portion 177, part of the connection portion 140, and part of a region including an end portion of the display device 100B.

The display device 100B shown in FIG. 11A includes a transistor 201, a transistor 205, the light-emitting device 130R that emits red light, the light-emitting device 130G that emits green light, the light-emitting device 130B that emits blue light, and the like between the substrate 351 and the substrate 352.

The stacked-layer structure of each of the light-emitting devices 130R, 130G, and 130B is the same as that shown in FIG. 1A except for the structure of the pixel electrode. The above embodiments can be referred to for the details of the light-emitting devices.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B. Here, the conductive layers 224R, 151R, and 152R can be collectively referred to as the pixel electrode of the light-emitting device 130R; the conductive layers 151R and 152R excluding the conductive layer 224R can also be referred to as the pixel electrode of the light-emitting device 130R. Similarly, the conductive layers 224G, 151G, and 152G can be collectively referred to as the pixel electrode of the light-emitting device 130G; the conductive layers 151G and 152G excluding the conductive layer 224G can also be referred to as the pixel electrode of the light-emitting device 130G. The conductive layers 224B, 151B, and 152B can be collectively referred to as the pixel electrode of the light-emitting device 130B; the conductive layers 151B and 152B excluding the conductive layer 224B can also be referred to as the pixel electrode of the light-emitting device 130B.

The conductive layer 224R is connected to a conductive layer 222b included in the transistor 205 through the opening provided in an insulating layer 214. An end portion of the conductive layer 151R is positioned outward from an end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G and the insulating layer 156G in the light-emitting device 130G are not described in detail because they are respectively similar to the conductive layers 224R, 151R, and 152R and the insulating layer 156R in the light-emitting device 130R; the same applies to the conductive layers 224B, 151B, and 152B and the insulating layer 156B in the light-emitting device 130B.

The conductive layers 224R, 224G, and 224B each have a depressed portion covering an opening provided in the insulating layer 214. A layer 128 is embedded in the depressed portion.

The layer 128 has a function of filling the depressed portions of the conductive layers 224R, 224G, and 224B to enable planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the depressed portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 135 is provided over the light-emitting devices 130R, 130G, and 130B. The protective layer 135 and the substrate 352 are bonded to each other with an adhesive layer 142. The substrate 352 is provided with a light-blocking layer 157. A solid scaling structure, a hollow sealing structure, or the like can be employed to seal the light-emitting device 130. In FIG. 11A, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided not to overlap with the light-emitting device. Furthermore, the space may be filled with a resin other than the frame-shaped adhesive layer 142.

FIG. 11A shows an example in which the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and a conductive layer 152C obtained by processing the same conductive film as the conductive layers 152R, 152G, and 152B. In the example shown in FIG. 11A, the insulating layer 156C is provided to include a region overlapping with the side surface of the conductive layer 151C.

The display device 100B has a top-emission structure. Light from the light-emitting device is emitted toward the substrate 352. For the substrate 352, a material having a high visible-light-transmitting property is preferably used. The pixel electrode includes a material that reflects visible light, and the counter electrode (the common electrode 155) includes a material that transmits visible light.

The transistor 201 and the transistor 205 are formed over the substrate 351. These transistors can be fabricated using the same materials in the same steps.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material that does not easily allow diffusion of impurities such as water and hydrogen is preferably used for at least one of the insulating layers covering the transistors. This is because such an insulating layer can function as a barrier layer. Such a structure can effectively reduce diffusion of impurities to the transistors from the outside and increase the reliability of the light-emitting apparatus.

An inorganic insulating film is preferably used as each of the insulating layers 211, 213, and 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. Two or more of the above insulating films may also be stacked.

An organic insulating layer is suitable for the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The outermost layer of the insulating layer 214 preferably functions as an etching protective layer. This can inhibit formation of a depressed portion in the insulating layer 214 at the time of processing of the conductive layer 224R, 151R, or 152R or the like. Alternatively, a depressed portion may be provided in the insulating layer 214 at the time of processing of the conductive layer 224R, 151R, or 152R or the like.

Each of the transistors 201 and 205 includes a conductive layer 221 functioning as a gate, the insulating layer 211 functioning as a gate insulating layer, a conductive layer 222a and a conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the light-emitting apparatus of this embodiment. For example, a planar transistor, a staggered transistor, or an inverted staggered transistor can be used. A top-gate transistor or a bottom-gate transistor can be used. Alternatively, gates may be provided above and below a semiconductor layer where a channel is formed.

The structure in which the semiconductor layer where a channel is formed is provided between two gates is employed for each of the transistors 201 and 205. The two gates may be connected to each other and supplied with the same signal to drive the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) can be used. A semiconductor having crystallinity is preferably used, in which case deterioration of transistor characteristics can be suppressed.

The semiconductor layer of the transistor preferably includes a metal oxide. That is, a transistor including a metal oxide in its channel formation region (hereinafter, referred to as an OS transistor) is preferably used in the light-emitting apparatus of this embodiment.

Examples of an oxide semiconductor having crystallinity include a c-axis-aligned crystalline oxide semiconductor (CAAC-OS) and a nanocrystalline oxide semiconductor (nc-OS).

Alternatively, a transistor including silicon in its channel formation region (a Si transistor) may be used. Examples of silicon include single crystal silicon, polycrystalline silicon, and amorphous silicon. In particular, a transistor including low-temperature polysilicon (LTPS) in its semiconductor layer (hereinafter also referred to as an LTPS transistor) can be used. The LTPS transistor has high field-effect mobility and excellent frequency characteristics.

With the use of Si transistors such as LTPS transistors, a circuit required to be driven at a high frequency (e.g., a source driver circuit) can be formed on the same substrate as the display portion. This allows for simplification of an external circuit mounted on the light-emitting apparatus and a reduction in costs of parts and mounting costs.

An OS transistor has much higher field-effect mobility than a transistor including amorphous silicon. In addition, the OS transistor has an extremely low leakage current between a source and a drain in an off state, and charge accumulated in a capacitor that is connected in series to the transistor can be held for a long period. Furthermore, the light-emitting apparatus can consume less power by including the OS transistor.

To increase the luminance of the light-emitting device included in the pixel circuit, the amount of current fed through the light-emitting device needs to be increased. To increase the current amount, the source-drain voltage of a driving transistor included in the pixel circuit needs to be increased. An OS transistor has a higher withstand voltage between a source and a drain than a Si transistor; hence, a high voltage can be applied between the source and the drain of the OS transistor. Therefore, when an OS transistor is used as the driving transistor in the pixel circuit, the amount of current flowing through the light-emitting device can be increased, so that the luminance of the light-emitting device can be increased.

Regarding saturation characteristics of a current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can be fed through light-emitting devices even when the current-voltage characteristics of the light-emitting devices vary, for example. In other words, when the OS transistor operates in the saturation region, the source-drain current hardly changes with an increase in the source-drain voltage; hence, the luminance of the light-emitting device can be stable.

As described above, by using OS transistors as the driving transistors included in the pixel circuits, it is possible to suppress black-level degradation, increase the luminance, increase the number of gray levels, and suppress variations in light-emitting devices, for example.

The semiconductor layer preferably contains indium, M (M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more of aluminum, gallium, yttrium, and tin.

It is particularly preferable that an oxide containing indium (In), gallium (Ga), and zinc (Zn) (also referred to as IGZO) be used for the semiconductor layer. It is preferable to use an oxide containing indium, tin, and zinc. It is preferable to use an oxide containing indium, gallium, tin, and zinc. It is preferable to use an oxide containing indium (In), aluminum (Al), and zinc (Zn) (also referred to as IAZO). It is preferable to use an oxide containing indium (In), aluminum (Al), gallium (Ga), and zinc (Zn) (also referred to as IAGZO). Alternatively, it is preferable to use an oxide containing indium (also referred to as IO).

When the semiconductor layer is an In-M-Zn oxide, the atomic proportion of In is preferably higher than or equal to the atomic proportion of M in the In-M-Zn oxide. Examples of the atomic ratio of the metal elements in such an In-M-Zn oxide are In:M:Zn=1:1:1, 1:1:1.2, 2:1:3, 3:1:2, 4:2:3, 4:2:4.1, 5:1:3, 5:1:6, 5:1:7, 5:1:8, 6:1:6, and 5:2:5 and a composition in the neighborhood of any of the above atomic ratios. Note that the neighborhood of the atomic ratio includes ±30% of an intended atomic ratio.

When the atomic ratio is described as In:Ga:Zn=4:2:3 or a composition in the neighborhood thereof, the case is included where the atomic proportion of Ga is greater than or equal to 1 and less than or equal to 3 and the atomic proportion of Zn is greater than or equal to 2 and less than or equal to 4 with the atomic proportion of In being 4. In addition, when the atomic ratio is described as In:Ga:Zn=5:1:6 or a composition in the neighborhood thereof, the case is included where the atomic proportion of Ga is greater than 0.1 and less than or equal to 2 and the atomic proportion of Zn is greater than or equal to 5 and less than or equal to 7 with the atomic proportion of In being 5. Furthermore, when the atomic ratio is described as In:Ga:Zn=1:1:1 or a composition in the neighborhood thereof, the case is included where the atomic proportion of Ga is greater than 0.1 and less than or equal to 2 and the atomic proportion of Zn is greater than 0.1 and less than or equal to 2 with the atomic proportion of In being 1.

The transistors included in the circuit 356 and the transistors included in the pixel portion 177 may have the same structure or different structures. One structure or two or more kinds of structures may be employed for a plurality of transistors included in the circuit 356. Similarly, one structure or two or more kinds of structures may be employed for a plurality of transistors included in the pixel portion 177.

All transistors included in the pixel portion 177 may be OS transistors, or all transistors included in the pixel portion 177 may be Si transistors. Alternatively, some of the transistors included in the pixel portion 177 may be OS transistors and the others may be Si transistors.

For example, when both an LTPS transistor and an OS transistor are used in the pixel portion 177, the light-emitting apparatus can have low power consumption and high driving capability. Note that a structure in which an LTPS transistor and an OS transistor are used in combination is referred to as LTPO in some cases. For example, it is preferable that an OS transistor be used as a transistor functioning as a switch for controlling electrical continuity between wirings and an LTPS transistor be used as a transistor for controlling a current.

For example, one transistor included in the pixel portion 177 functions as a transistor for controlling a current flowing through the light-emitting device and can be referred to as a driving transistor. One of a source and a drain of the driving transistor is electrically connected to the pixel electrode of the light-emitting device. An LTPS transistor is preferably used as the driving transistor. In that case, the amount of current flowing through the light-emitting device can be increased in the pixel circuit.

Another transistor included in the pixel portion 177 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. In that case, the gray level of the pixel can be maintained even with an extremely low frame frequency (e.g., lower than or equal to 1 fps); thus, power consumption can be reduced by stopping the driver in displaying a still image.

As described above, the light-emitting apparatus of one embodiment of the present invention can have all of a high aperture ratio, high definition, high display quality, and low power consumption.

Note that the light-emitting apparatus of one embodiment of the present invention has a structure including the OS transistor and the light-emitting device having a metal maskless (MML) structure. This structure can significantly reduce a leakage current that would flow through a transistor and a leakage current that would flow between adjacent light-emitting devices (sometimes referred to as a horizontal leakage current or a lateral leakage current). Displaying images on the light-emitting apparatus having this structure can bring one or more of image crispness, image sharpness, high color saturation, and a high contrast ratio to the viewer. When a leakage current that would flow through the transistor and a lateral leakage current that would flow between the light-emitting devices are extremely low, leakage of light at the time of black display (black-level degradation) or the like can be minimized.

In particular, in the case where a light-emitting device having an MML structure employs a side-by-side (SBS) structure, which is the above-described structure for separately forming or coloring light-emitting layers, a layer provided between light-emitting devices (for example, also referred to as an organic layer or a common layer which is shared by the light-emitting devices) is disconnected; accordingly, side leakage can be prevented or be made extremely low.

FIGS. 11B and 11C show other structure examples of transistors.

Transistors 209 and 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned at least between the conductive layer 223 and the channel formation region 231i. Furthermore, an insulating layer 218 covering the transistor may be provided.

FIG. 11B shows an example of the transistor 209 in which the insulating layer 225 covers the top and side surfaces of the semiconductor layer 231. The conductive layer 222a and the conductive layer 222b are connected to the corresponding low-resistance regions 231n through openings provided in the insulating layer 225 and the insulating layer 215. One of the conductive layers 222a and 222b functions as a source, and the other functions as a drain.

In the transistor 210 shown in FIG. 11C, the insulating layer 225 overlaps with the channel formation region 231i of the semiconductor layer 231 and does not overlap with the low-resistance regions 231n. The structure shown in FIG. 11C can be obtained by processing the insulating layer 225 with the conductive layer 223 used as a mask, for example. In FIG. 11C, the insulating layer 215 is provided to cover the insulating layer 225 and the conductive layer 223, and the conductive layer 222a and the conductive layer 222b are connected to the corresponding low-resistance regions 231n through openings in the insulating layer 215.

A connection portion 204 is provided in a region of the substrate 351 where the substrate 352 does not overlap. In the connection portion 204, the wiring 355 is electrically connected to the FPC 353 through a conductive layer 166 and a connection layer 242. An example is described in which the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

The light-blocking layer 157 is preferably provided on the surface of the substrate 352 on the substrate 351 side. The light-blocking layer 157 can be provided over a region between adjacent light-emitting devices, in the connection portion 140, in the circuit 356, and the like. A variety of optical members can be arranged on the outer surface of the substrate 352.

A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

### [Display Device 100C]

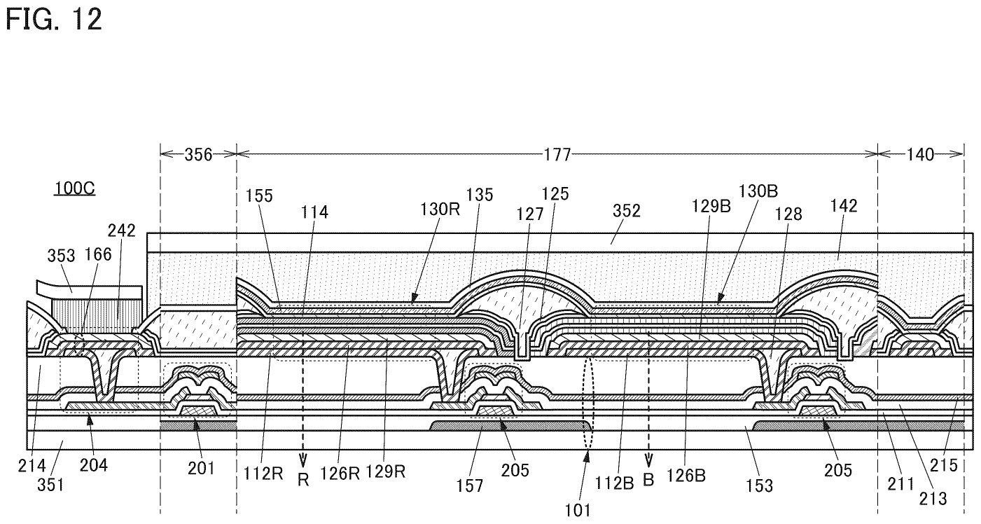

The display device 100C shown in FIG. 12 differs from the display device 100B shown in FIG. 11A mainly in having a bottom-emission structure.

Light from the light-emitting device is emitted toward the substrate 351. For the substrate 351, a material having a high visible-light-transmitting property is preferably used. By contrast, there is no limitation on the light-transmitting property of a material used for the substrate 352.

The light-blocking layer 157 is preferably formed between the substrate 351 and the transistor 201 and between the substrate 351 and the transistor 205. FIG. 12 shows an example in which the light-blocking layer 157 is provided over the substrate 351, an insulating layer 153 is provided over the light-blocking layer 157, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material having a high visible-light-transmitting property is used for each of the conductive layers 112R, 112B, 126R, 126B, 129R, and 129B. A material that reflects visible light is preferably used for the common electrode 155.

Although not shown in FIG. 12, the light-emitting device 130G is also provided.

Although FIG. 12 and the like show an example in which the top surface of the layer 128 includes a flat portion, the shape of the layer 128 is not particularly limited.

### [Display Device 100D]

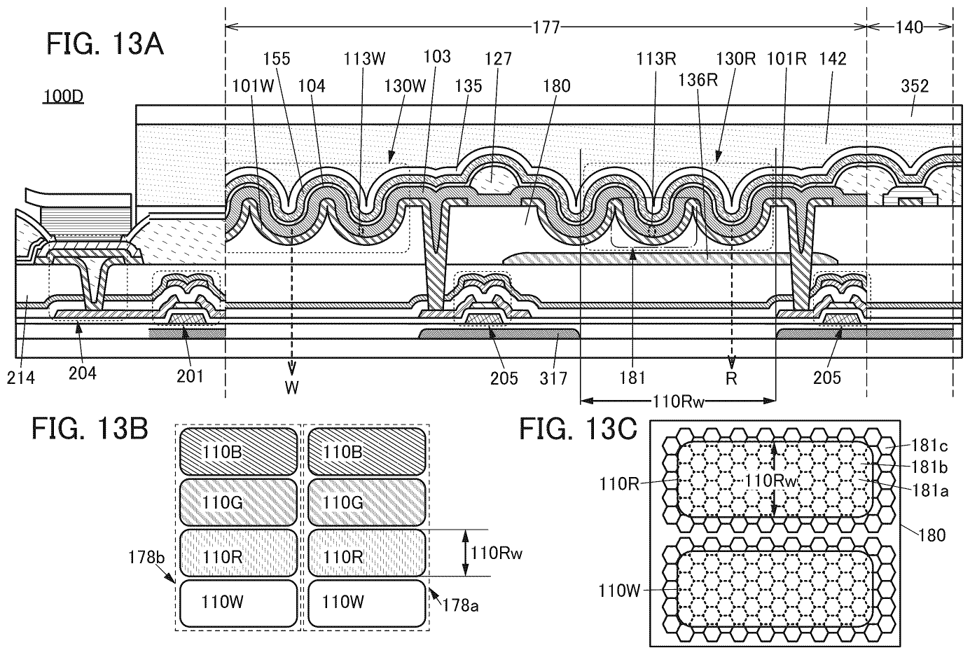

The display device 100D with a bottom-emission structure shown in FIGS. 13A to 13C is an example of a bottom-emission display device different from the display device 100C shown in FIG. 12. The display device 100D is different from the display device 100C in including an organic resin layer 180. Note that in the drawings, reference numerals of some of the components that are shown in FIG. 12 are omitted; for the details of the components, the description made with reference to FIG. 12 is to be referred to.

FIG. 13B is a top-view layout of the pixels 178 (a pixel 178a and a pixel 178b) each including the subpixels 110 (the subpixels 110R, 110G, 110B, and 110W), and FIG. 13C is a top view of the organic resin layer 180 in a region where the subpixels 110R and 110W of the pixel 178 are formed. Note that the width of the region between the light-blocking layers 317 corresponds to a width 110Rw in a light-emitting region of the subpixel 110R.

As shown in FIG. 13A, the organic resin layer 180 is provided over the insulating layer 214. As shown in FIG. 13C and the region surrounded by the dashed-dotted line in FIG. 13A, the organic resin layer 180 includes a depressed portion 181 (depressed portions 181a and 181b) having a curved surface at least in a region where the subpixel is formed. Note that the depressed portion 181 may be provided outside the light-emitting region, like a depressed portion 181c. When the depressed portion 181c is provided, light that has been emitted in the region overlapping with the light-blocking layer 317 or light that has progressed to the region overlapping with the light-blocking layer 317 can be refracted and extracted from the light-emitting region, increasing the emission efficiency.

A plurality of the depressed portions 181 may be formed in a matrix. The depressed portions 181a and 181b may be provided in contact with each other or may have a flat surface therebetween.

In FIGS. 13A and 13C, although the top surface shape and the cross-sectional shape of the depressed portion are hexagonal (FIG. 13C) and semicircular (FIG. 13A), respectively, other shapes may be employed as needed. Examples of a top surface shape of the depressed portion include polygons such as a triangle, a tetragon (including a rectangle and a square), and a pentagon; these polygons with rounded corners; an ellipse; and a circle.

As the organic resin layer 180, an insulating layer containing an organic material can be used. For the organic resin layer 180, an acrylic resin, a polyimide resin, an epoxy resin, an imide resin, a polyamide resin, a polyimide-amide resin, a silicone resin, a siloxane resin, a benzocyclobutene-based resin, a phenol resin, or a precursor of any of these resins can be used, for example. Alternatively, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used for the organic resin layer 180.

Further alternatively, a photosensitive resin can be used for the organic resin layer 180. A photoresist may be used as the photosensitive resin. As the photosensitive resin, a positive photosensitive material or a negative photosensitive material can be used.

The organic resin layer 180 may include a material absorbing visible light. For example, the organic resin layer 180 itself may be made of a material absorbing visible light, or the organic resin layer 180 may include a pigment absorbing visible light. For the organic resin layer 180, for example, a resin that can be used as a color filter transmitting red, blue, or green light and absorbing light of the other colors or a resin that includes carbon black as a pigment and functions as a black matrix can be used.

The first electrodes 101 (a first electrode 101R and a first electrode 101W) are provided over the organic resin layer 180, and the organic compound layer 103 is provided over the first electrodes 101. End portions of the first electrode 101 and the organic compound layer 103 may be covered with the insulating layer 127.

Along the depressed portion of the organic resin layer 180, the first electrode 101 formed over the organic resin layer 180 has a depressed portion in a manner similar to that of the organic resin layer 180. Furthermore, along the depressed portion of the first electrode 101, the organic compound layer 103 formed over the first electrode 101 has a depressed portion in a manner similar to that of the first electrode 101. Furthermore, along the depressed portion of the organic compound layer 103, the common layer 104 formed over the organic compound layer 103 has a depressed portion in a manner similar to that of the organic compound layer 103. Furthermore, along the depressed portion of the common layer 104, the common electrode 155 formed over the common layer 104 has a depressed portion in a manner similar to that of the common layer 104. That is, the depressed portions of the organic resin layer 180, the first electrode 101, the organic compound layer 103, the common layer 104, and the common electrode 155 overlap with each other.

The common layer 104 is provided over the organic compound layer 103 and the insulating layer 127, and the common electrode 155 is provided over the common layer 104. The protective layer 135 is provided over the common electrode 155, and the substrate 352 is bonded with the use of the adhesive layer 142.

Although the light-emitting devices 130G and 130B are not shown in FIGS. 13A to 13C, the light-emitting devices 130G and 130B are also provided.

### [Display Device 100E]

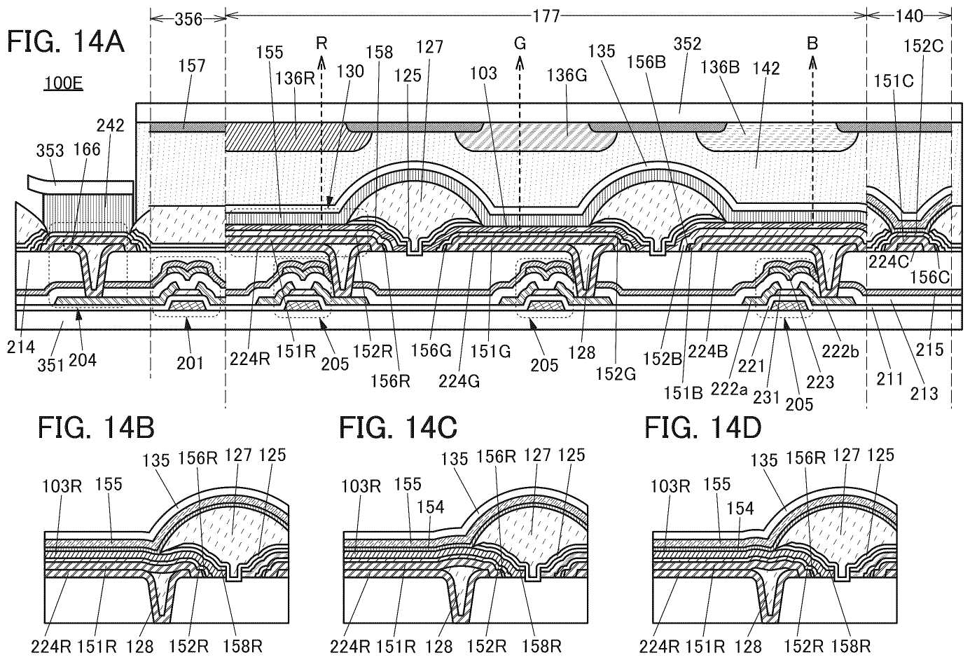

The display device 100E shown in FIG. 14A is a modification example of the top-emission display device 100B shown in FIG. 11A and differs from the display device 100B mainly in including the coloring layers 136R, 136G, and 136B.

In the display device 100E, the light-emitting device 130 includes a region overlapping with one of the coloring layers 136R, 136G, and 136B. The coloring layers 136R, 136G, and 136B can be provided on the surface of the substrate 352 on the substrate 351 side. End portions of the coloring layers 136R, 136G, and 136B can overlap with the light-blocking layer 157.

In the display device 100E, the light-emitting device 130 can emit white light, for example. For example, the coloring layer 136R, the coloring layer 136G, and the coloring layer 136B can transmit red light, green light, and blue light, respectively. Note that in the display device 100E, the coloring layers 136R, 136G, and 136B may be provided between the protective layer 135 and the adhesive layer 142.

Although FIG. 11A, FIG. 14A, and the like each show an example in which the top surface of the layer 128 includes a flat portion, the shape of the layer 128 is not particularly limited. FIGS. 14B to 14D show modification examples of the layer 128.

As shown in FIGS. 14B and 14D, the top surface of the layer 128 can have a shape such that its middle and the vicinity thereof are depressed (i.e., a shape including a concave surface) in a cross-sectional view. A common layer 154 may be provided so as to be in contact with the common electrode 155.

As shown in FIG. 14C, the top surface of the layer 128 can have a shape in which its center and the vicinity thereof bulge, i.e., a shape including a convex surface, in a cross-sectional view.

The top surface of the layer 128 may include one or both of a convex surface and a concave surface. The number of convex surfaces and the number of concave surfaces included in the top surface of the layer 128 are not limited and can each be one or two or more.

The level of the top surface of the layer 128 and the level of the top surface of the conductive layer 224R may be the same or substantially the same, or may be different from each other. For example, the level of the top surface of the layer 128 may be lower or higher than the level of the top surface of the conductive layer 224R.

In the example shown in FIG. 14B, it can be said that the layer 128 fits inside the depressed portion of the conductive layer 224R. By contrast, as shown in FIG. 14D, the layer 128 is also present outside the depressed portion of the conductive layer 224R, i.e., the top surface of the layer 128 may extend beyond the depressed portion.

### [Display Device 100F]

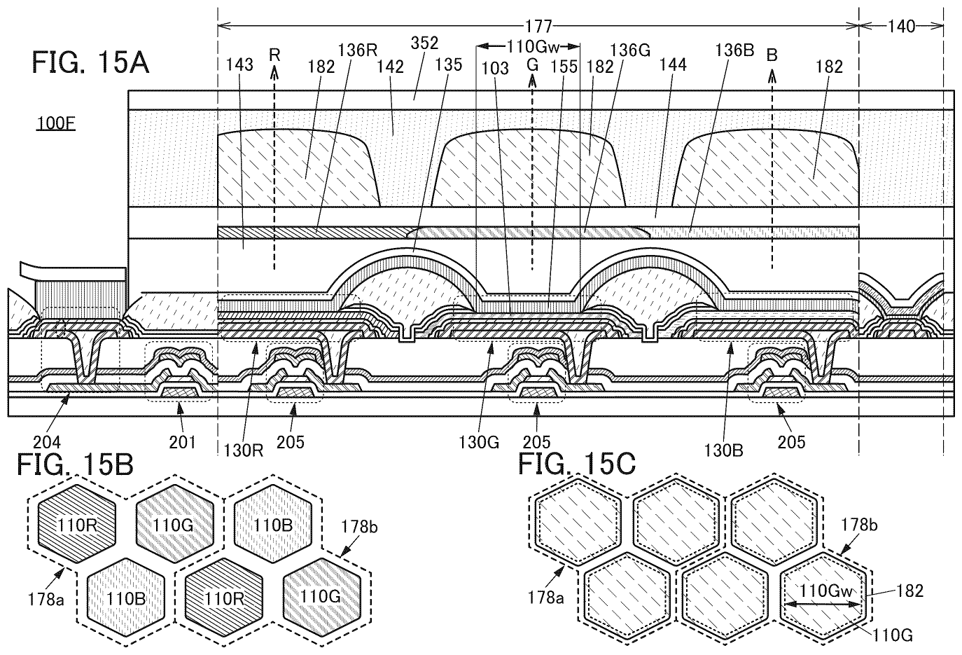

The display device 100F shown in FIG. 15A is a modification example of the top-emission display device 100B shown in FIGS. 11A to 11C and includes microlenses 182 over the coloring layers 136R, 136G, and 136B. Note that in the drawings, reference numerals of some of the components that are shown in FIGS. 11A to 11C are omitted; for the details of the components, the description made with reference to FIGS. 11A to 11C is to be referred to.

FIG. 15B is a top-view layout of the pixels 178 (the pixels 178a and 178b) each including the subpixels 110 (the subpixels 110R, 110G, and 110B), and FIG. 15C is a top view of the microlens 182 in a region where the subpixels 110R, 110G, and 110B of the pixel 178 are formed. Note that the width of the region where the common electrode 155 and the organic compound layer 103 are in contact with each other corresponds to a width 110Gw in a light-emitting region of the subpixel 110G.

In the display device 100F shown in FIG. 13A, a planarization film 143 is provided over the protective layer 135, and the coloring layers 136R, 136G, and 136B are provided over a planarization film 144. The planarization film 144 is provided to cover the coloring layers 136R, 136G, and 136B. The microlenses 182 are provided over the planarization film 144.

Note that as shown in FIG. 15C, the microlenses 182 are preferably provided on a subpixel basis in the region where the subpixels are formed.

Although the top surface shape of the microlens 182 is hexagonal in FIG. 15C, a different shape may be employed as needed. Examples of a top surface shape of the microlens 182 include polygons such as a triangle, a tetragon (including a rectangle and a square), and a pentagon; these polygons with rounded corners; an ellipse; and a circle.

The microlenses 182 can be formed using a material similar to that of the organic resin layer 180.

This embodiment can be combined as appropriate with any of the other embodiments or examples. In this specification, in the case where a plurality of structure examples are shown in one embodiment, the structure examples can be combined as appropriate.

### Embodiment 6

In this embodiment, electronic appliances of embodiments of the present invention will be described.

Electronic appliances of this embodiment include the light-emitting apparatus of one embodiment of the present invention in their display portions. The light-emitting apparatus of one embodiment of the present invention is highly reliable and can be easily increased in definition and resolution. Thus, the light-emitting apparatus of one embodiment of the present invention can be used for display portions of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

In particular, the light-emitting apparatus of one embodiment of the present invention can have high definition, and thus can be favorably used for an electronic appliance having a relatively small display portion. Examples of such an electronic appliance include watch-type and bracelet-type information terminal devices (wearable devices) and wearable devices capable of being worn on a head, such as a VR device like a head-mounted display, a glasses-type AR device, and an MR device.

The resolution of the light-emitting apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840× 2160), or 8K (number of pixels: 7680× 4320). In particular, 4K resolution, 8K resolution, or higher resolution is preferable. The pixel density (definition) of the light-emitting apparatus of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. With such a light-emitting apparatus having one or both of high resolution and high definition, the electronic appliance can provide higher realistic sensation, sense of depth, and the like. There is no particular limitation on the screen ratio (aspect ratio) of the light-emitting apparatus of one embodiment of the present invention. For example, the light-emitting apparatus is compatible with a variety of screen ratios such as 1:1 (a square), 4:3, 16:9, and 16:10.

The electronic appliance in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic appliance in this embodiment can have a variety of functions. For example, the electronic appliance in this embodiment can have a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

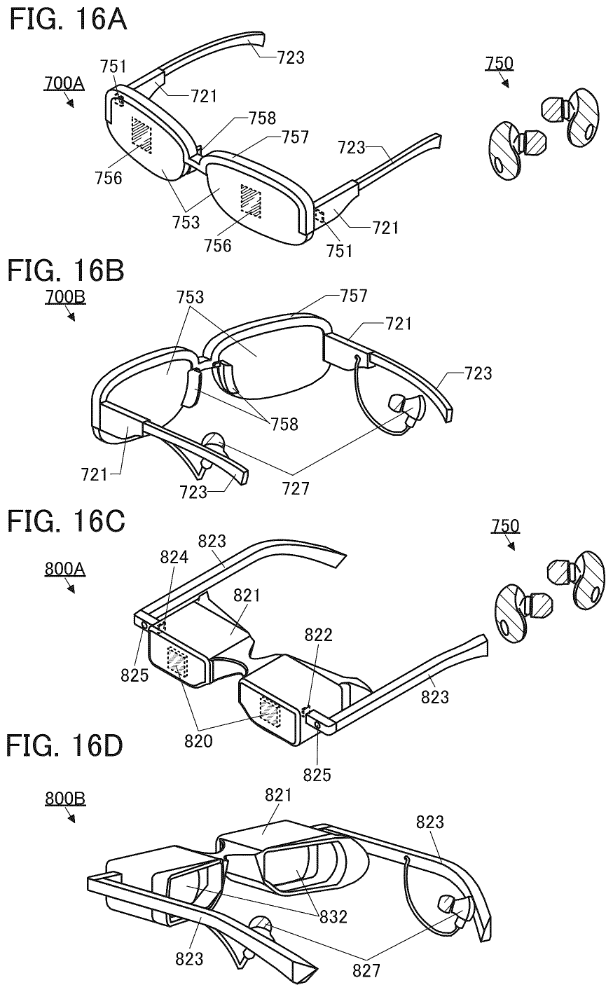

Examples of head-mounted wearable devices are described with reference to FIGS. 16A to 16D. These wearable devices have at least one of a function of displaying AR contents, a function of displaying VR contents, a function of displaying SR contents, and a function of displaying MR contents. The electronic appliance having a function of displaying contents of at least one of AR, VR, SR, MR, and the like enables the user to feel a higher level of immersion.

An electronic appliance 700A shown in FIG. 16A and an electronic appliance 700B shown in FIG. 16B each include a pair of display panels 751, a pair of housings 721, a communication portion (not shown), a pair of wearing portions 723, a control portion (not shown), an image capturing portion (not shown), a pair of optical members 753, a frame 757, and a pair of nose pads 758.

The light-emitting apparatus of one embodiment of the present invention can be used for the display panels 751. Thus, a highly reliable electronic appliance is obtained.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic appliances 700A and 700B are electronic appliances capable of AR display.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic appliances 700A and 700B are provided with a battery, so that they can be charged wirelessly and/or by wire.

A touch sensor module may be provided in the housing 721. The touch sensor module has a function of detecting a touch on the outer surface of the housing 721. Various types of processing can be executed by detecting a tap operation, a slide operation, or the like by the user with the touch sensor module. For example, a moving image can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving element. One or both of an inorganic semiconductor and an organic semiconductor can be used for an active layer of the photoelectric conversion device.

An electronic appliance 800A shown in FIG. 16C and an electronic appliance 800B shown in FIG. 16D each include a pair of display portions 820, a housing 821, a communication portion 822, a pair of wearing portions 823, a control portion 824, a pair of image capturing portions 825, and a pair of lenses 832.

The light-emitting apparatus of one embodiment of the present invention can be used in the display portions 820. Thus, a highly reliable electronic appliance is obtained.

The display portions 820 are positioned inside the housing 821 so as to be seen through the lenses 832. When the pair of display portions 820 display different images, three-dimensional display using parallax can be performed.

The electronic appliances 800A and 800B can function as electronic appliances for VR. The user who wears the electronic appliance 800A or the electronic appliance 800B can see images displayed on the display portions 820 through the lenses 832.

The electronic appliances 800A and 800B preferably include a mechanism for adjusting horizontally the positions of the lenses 832 and the display portions 820 so that the lenses 832 and the display portions 820 are positioned optimally in accordance with the positions of the user's eyes. Moreover, the electronic appliances 800A and 800B preferably include a mechanism for adjusting focus by changing the distance between the lenses 832 and the display portions 820.

The electronic appliance 800A or the electronic appliance 800B can be mounted on the user's head with the wearing portions 823. FIG. 16C, for instance, shows an example where the wearing portion 823 has a shape like a temple (also referred to as a joint or the like) of glasses; however, one embodiment of the present invention is not limited thereto. The wearing portion 823 can have any shape with which the user can wear the electronic appliance, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portions 825 are provided is described here, a range sensor (hereinafter also referred to as a sensing portion) capable of measuring the distance between the user and an object may be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic appliance 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy video and sound only by wearing the electronic appliance 800A.

The electronic appliances 800A and 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750. The earphones 750 include a communication portion (not shown) and have a wireless communication function. The earphones 750 can receive information (e.g., audio data) from the electronic appliance with the wireless communication function. For example, the electronic appliance 700A in FIG. 16A has a function of transmitting information to the earphones 750 with the wireless communication function. For another example, the electronic appliance 800A in FIG. 16C has a function of transmitting information to the earphones 750 with the wireless communication function.

The electronic appliance may include an earphone portion. The electronic appliance 700B in FIG. 16B includes earphone portions 727. For example, the earphone portion 727 can be connected to the control portion by a wiring. Part of the wiring that connects the earphone portion 727 and the control portion may be positioned inside the housing 721 or the wearing portion 723.

Similarly, the electronic appliance 800B in FIG. 16D includes earphone portions 827. For example, the earphone portion 827 can be connected to the control portion 824 by a wiring. Part of the wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic appliance may include an audio output terminal to which earphones, headphones, or the like can be connected. The electronic appliance may include one or both of an audio input terminal and an audio input mechanism. As the audio input mechanism, a sound collecting device such as a microphone can be used, for example. The electronic appliance may have a function of a headset by including the audio input mechanism.

As described above, both the glasses-type device (e.g., the electronic appliances 700A and 700B) and the goggles-type device (e.g., the electronic appliances 800A and 800B) are preferable as the electronic appliance of one embodiment of the present invention.

The electronic appliance of one embodiment of the present invention can transmit information to earphones by wire or wirelessly.

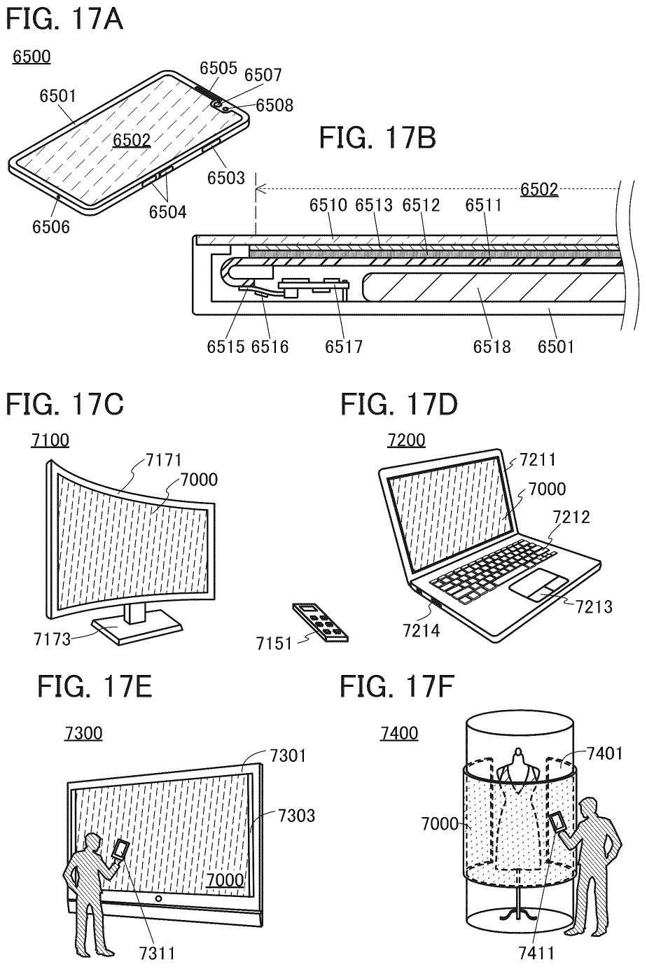

An electronic appliance 6500 shown in FIG. 17A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The light-emitting apparatus of one embodiment of the present invention can be used in the display portion 6502. Thus, a highly reliable electronic appliance is obtained.

FIG. 17B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not shown).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The light-emitting apparatus of one embodiment of the present invention can be used in the display panel 6511. Thus, an extremely lightweight electronic appliance can be obtained.

Since the display panel 6511 is extremely thin, the battery 6518 with high capacity can be mounted without an increase in the thickness of the electronic appliance. An electronic appliance with a narrow bezel can be provided when part of the display panel 6511 is folded back and the portion connected to the FPC 6515 is provided on the back side of a pixel portion.

FIG. 17C shows an example of a television device. In a television device 7100, a display portion 7000 is incorporated in a housing 7171. Here, the housing 7171 is supported by a stand 7173.

The light-emitting apparatus of one embodiment of the present invention can be used in the display portion 7000. Thus, a highly reliable electronic appliance is obtained.

Operation of the television device 7100 shown in FIG. 17C can be performed with an operation switch provided in the housing 7171 and a separate remote controller 7151. Alternatively, the display portion 7000 may include a touch sensor, and the television device 7100 may be operated by touch on the display portion 7000 with a finger or the like. The remote controller 7151 may be provided with a display portion for displaying information output from the remote controller 7151. With operation keys or a touch panel of the remote controller 7151, channels and volume can be controlled and video displayed on the display portion 7000 can be controlled.

Note that the television device 7100 includes a receiver, a modem, and the like. A general television broadcast can be received with the receiver. When the television device is connected to a communication network with or without wires via the modem, one-way (from a transmitter to a receiver) or two-way (e.g., between a transmitter and a receiver or between receivers) information communication can be performed.

FIG. 17D shows an example of a notebook personal computer. A notebook personal computer 7200 includes a housing 7211, a keyboard 7212, a pointing device 7213, an external connection port 7214, and the like. The display portion 7000 is incorporated in the housing 7211.

The light-emitting apparatus of one embodiment of the present invention can be used in the display portion 7000. Thus, a highly reliable electronic appliance is obtained.

FIGS. 17E and 17F show examples of digital signage that can be used for a store window, a showcase, or the like.

Digital signage 7300 shown in FIG. 17E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 17F shows digital signage 7400 attached to a cylindrical pillar 7401. The digital signage 7400 includes the display portion 7000 provided along a curved surface of the pillar 7401.

In FIGS. 17E and 17F, the light-emitting apparatus of one embodiment of the present invention can be used in the display portion 7000. Thus, a highly reliable electronic appliance can be provided.

A larger area of the display portion 7000 can increase the amount of information that can be provided at a time. The display portion 7000 having a larger area attracts more attentions, so that the effectiveness of the advertisement can be increased, for example.

Specifically, in the case where the display device of one embodiment of the present invention is used for the digital signage 7300 and the digital signage 7400 shown in FIGS. 17E and 17F that display advertisements and the like, the display device being a light-transmitting panel can increase the flexibility of representation. The display device having a light-transmitting property can be manufactured, for example, by using a wiring and a support member that include a conductive film transmitting visible light and adjusting the distance between pixel electrodes.

The use of the light-emitting device of one embodiment of the present invention in addition to the wiring and the support member each of which is formed of the conductive film that transmits visible light can increase the luminance per pixel. That is, favorable display can be performed even when the display device has a low aperture ratio, so that the light-transmitting property of the display portion of the display device can be increased. Thus, such a structure is suitably used in the light-transmitting display device of one embodiment of the present invention.

As shown in FIGS. 17E and 17F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, a displayed image on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

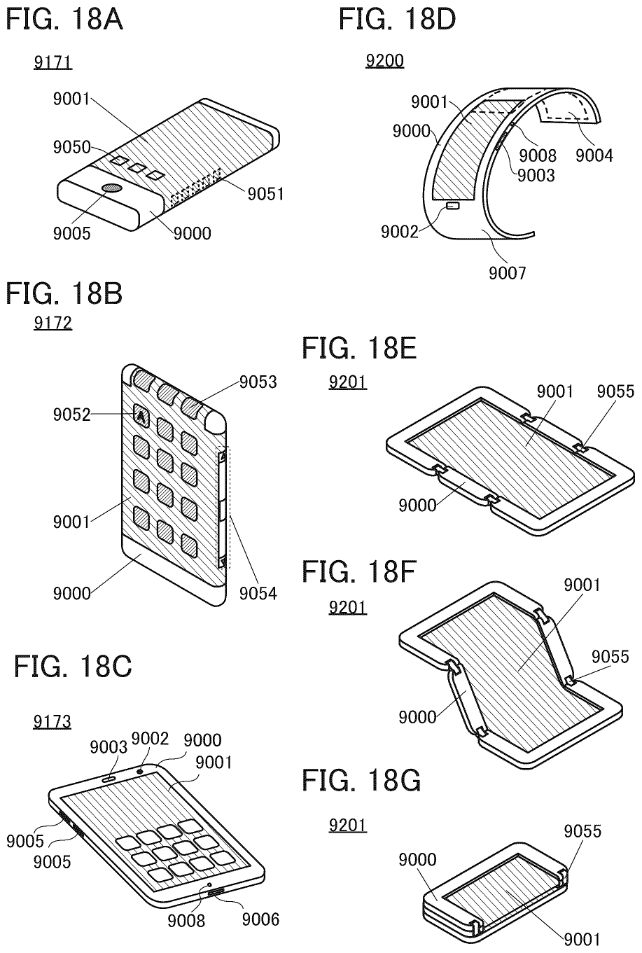

Electronic appliances shown in FIGS. 18A to 18G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays), a microphone 9008, and the like.

The electronic appliances shown in FIGS. 18A to 18G have a variety of functions. For example, the electronic appliances can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic appliances are not limited thereto, and the electronic appliances can have a variety of functions. The electronic appliances may include a plurality of display portions. The electronic appliances may be provided with a camera or the like and have a function of taking a still image or a moving image, a function of storing the taken image in a storage medium (an external storage medium or a storage medium incorporated in the camera), a function of displaying the taken image on the display portion, and the like.

The electronic appliances in FIGS. 18A to 18G are described in detail below.

FIG. 18A is a perspective view of a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 18A shows an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 18B is a perspective view of a portable information terminal 9172. The portable information terminal 9172 has a function of displaying information on three or more surfaces of the display portion 9001. Here, an example in which information 9052, information 9053, and information 9054 are displayed on different surfaces is described. For example, the user of the portable information terminal 9172 can check the information 9053 displayed so as to be seen from above the portable information terminal 9172, with the portable information terminal 9172 put in a breast pocket of his/her clothes. The user can see the display without taking out the portable information terminal 9172 from the pocket and decide whether to answer the call, for example.

FIG. 18C is a perspective view of a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 18D is a perspective view of a watch-type portable information terminal 9200. The portable information terminal 9200 can be used as a smartwatch (registered trademark), for example. The portable information terminal 9200 may include the operation key 9005 as a button for operation on the left side surface of the housing 9000 and include the sensor 9007 on the bottom surface of the housing 9000. Although the curved bangle-type housing 9000 is shown as an example, the housing 9000 may include a belt or the like in combination so that the portable information terminal 9200 can be worn. The display surface of the display portion 9001 is curved, and an image can be displayed on the curved display surface. A power storage device 9004 may be curved along the housing 9000. The power storage device 9004 has flexibility and can be bent in accordance with a change in shape at the time when the portable information terminal 9200 is worn or removed. Note that a charge control IC connected to the power storage device 9004 may be included. Furthermore, for example, mutual communication between the portable information terminal 9200 and a headset capable of wireless communication can be performed, and thus hands-free calling is possible. The portable information terminal 9200 can perform mutual data transmission with another information terminal without a wire and perform charging operation by wireless power feeding. Note that the connection terminal 9006 may be provided in the housing 9000 and data transmission and charging operation may be performed by wire.

FIGS. 18E to 18G are perspective views of a foldable portable information terminal 9201. FIG. 18E is a perspective view showing the portable information terminal 9201 that is opened. FIG. 18G is a perspective view showing the portable information terminal 9201 that is folded. FIG. 18F is a perspective view showing the portable information terminal 9201 that is shifted from one of the states in FIGS. 18E and 18G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined as appropriate with any of the other embodiments or examples. In this specification, in the case where a plurality of structure examples are shown in one embodiment, the structure examples can be combined as appropriate.

### Embodiment 7

In this embodiment, a light-emitting apparatus including the organic EL element described in Embodiments 1 and 2 will be described.

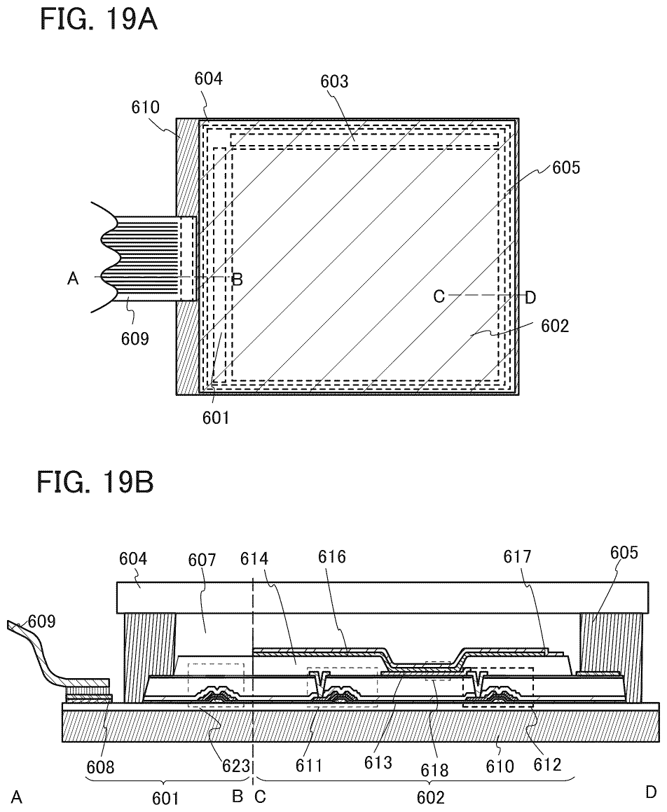

In this embodiment, the light-emitting apparatus manufactured using the organic EL element described in Embodiments 1 and 2 is described with reference to FIGS. 19A and 19B. Note that FIG. 19A is a top view of the light-emitting apparatus and FIG. 19B is a cross-sectional view taken along the lines A-B and C-D in FIG. 19A. This light-emitting apparatus includes a driver circuit portion (source line driver circuit) 601, a pixel portion 602, and a driver circuit portion (gate line driver circuit) 603, which are to control light emission of an organic EL element and illustrated with dotted lines. Reference numeral 604 denotes a sealing substrate; 605, a sealing material; and 607, a space surrounded by the sealing material 605.

Reference numeral 608 denotes a wiring for transmitting signals to be input to the source line driver circuit 601 and the gate line driver circuit 603 and receiving signals such as a video signal, a clock signal, a start signal, and a reset signal from a flexible printed circuit (FPC) 609 serving as an external input terminal. Although only the FPC is illustrated here, a printed wiring board (PWB) may be attached to the FPC. The light-emitting apparatus in this specification includes, in its category, not only the light-emitting apparatus itself but also the light-emitting apparatus provided with the FPC or the PWB.

Next, a cross-sectional structure is described with reference to FIG. 19B. The driver circuit portions and the pixel portion are formed over an element substrate 610; here, the source line driver circuit 601, which is a driver circuit portion, and one pixel in the pixel portion 602 are illustrated.

The element substrate 610 may be a substrate containing glass, quartz, an organic resin, a metal, an alloy, a semiconductor, or the like or a plastic substrate formed of fiber reinforced plastics (FRP), poly(vinyl fluoride) (PVF), polyester, an acrylic resin, or the like.

The structure of transistors used in pixels and driver circuits is not particularly limited. For example, inverted staggered transistors may be used, or staggered transistors may be used. Furthermore, top-gate transistors or bottom-gate transistors may be used. A semiconductor material used for the transistors is not particularly limited, and for example, silicon, germanium, silicon carbide, gallium nitride, or the like can be used. Alternatively, an oxide semiconductor containing at least one of indium, gallium, and zinc, such as an In—Ga—Zn-based metal oxide, may be used.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) can be used. A semiconductor having crystallinity is preferably used, in which case deterioration of transistor characteristics can be suppressed.

Here, an oxide semiconductor is preferably used for semiconductor devices such as the transistors provided in the pixels and driver circuits and transistors used for touch sensors described later, and the like. In particular, an oxide semiconductor having a wider band gap than silicon is preferably used. When an oxide semiconductor having a wider band gap than silicon is used, off-state current of the transistors can be reduced.

The oxide semiconductor preferably contains at least indium (In) or zinc (Zn). Further preferably, the oxide semiconductor contains an oxide represented by an In-M-Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and in which the adjacent crystal parts have no grain boundary.

The use of such materials for the semiconductor layer makes it possible to provide a highly reliable transistor in which a change in the electrical characteristics is suppressed.

Charge accumulated in a capacitor through a transistor including the above-described semiconductor layer can be held for a long time because of the low off-state current of the transistor. When such a transistor is used in a pixel, operation of a driver circuit can be stopped while a gray scale of an image in each display region is maintained. As a result, an electronic appliance with extremely low power consumption can be obtained.

For stable characteristics or the like of the transistor, a base film is preferably provided. The base film can be formed with a single-layer structure or a stacked-layer structure using an inorganic insulating film such as a silicon oxide film, a silicon nitride film, a silicon oxynitride film, or a silicon nitride oxide film. The base film can be formed by a sputtering method, a CVD method (e.g., a plasma CVD method, a thermal CVD method, or a metal organic CVD (MOCVD) method), an ALD method, a coating method, a printing method, or the like. Note that the base film is not necessarily provided.

Note that an FET 623 is illustrated as a transistor formed in the source line driver circuit 601. In addition, the driver circuit may be formed with any of a variety of circuits such as a CMOS circuit, a PMOS circuit, or an NMOS circuit. Although a driver integrated type in which the driver circuit is formed over the substrate is illustrated in this embodiment, the driver circuit is not necessarily formed over the substrate, and the driver circuit can be formed outside.

Although the pixel portion 602 includes a plurality of pixels each including a switching FET 611, a current controlling FET 612, and a first electrode 613 electrically connected to a drain of the current controlling FET 612, one embodiment of the present invention is not limited to the structure. The pixel portion 602 may include three or more FETs and a capacitor in combination.

Note that an insulator 614 is formed to cover an end portion of the first electrode 613. Here, the insulator 614 can be formed using a positive photosensitive acrylic resin film.

In order to improve coverage with an EL layer or the like which is formed later, the insulator 614 is formed to have a curved surface with curvature at its upper or lower end portion. For example, in the case where a positive photosensitive acrylic resin is used as a material of the insulator 614, only the upper end portion of the insulator 614 preferably has a curved surface with a curvature radius (0.2 μm to 3 μm). As the insulator 614, either a negative photosensitive resin or a positive photosensitive resin can be used.

An EL layer 616 and a second electrode 617 are formed over the first electrode 613. Here, as a material used for the first electrode 613 functioning as an anode, a material having a high work function is preferably used. For example, a single-layer film of an ITO film, an indium tin oxide film containing silicon, an indium oxide film containing zinc oxide at 2 wt % to 20 wt %, a titanium nitride film, a chromium film, a tungsten film, a Zn film, a Pt film, or the like, a stack of a titanium nitride film and a film containing aluminum as a main component, a stack of three layers of a titanium nitride film, a film containing aluminum as a main component, and a titanium nitride film, or the like can be used. The stacked-layer structure enables low wiring resistance, favorable ohmic contact, and a function of an anode.

The EL layer 616 is formed by any of a variety of methods such as an evaporation method using an evaporation mask, an ink-jet method, and a spin coating method. The EL layer 616 has the structure described in Embodiments 1 and 2. In the case where the EL layer 616 is formed from the first electrode 613 side and the first electrode 613 is an anode, the first hole-transport layer 112-1 and the second hole-transport layer 112-2 are formed in this order, and the anode, the first hole-transport layer, the second hole-transport layer, and the cathode are positioned in this order from the substrate side. As another material contained in the EL layer 616, a low molecular compound or a high molecular compound (including an oligomer or a dendrimer) may be used. As a material used for the second electrode 617, which is formed over the EL layer 616 and functions as a cathode, a material having a low work function (e.g., Al, Mg, Li, and Ca, or an alloy or a compound thereof, such as MgAg, MgIn, and AlLi) is preferably used. In the case where light generated in the EL layer 616 is transmitted through the second electrode 617, a stack of a thin metal film and a transparent conductive film (e.g., ITO, indium oxide containing zinc oxide at 2 wt % to 20 wt %, indium tin oxide containing silicon, or zinc oxide (ZnO)) is preferably used for the second electrode 617.

Note that the organic EL element is formed with the first electrode 613, the EL layer 616, and the second electrode 617. The organic EL element is the organic EL element described in Embodiments 1 and 2. In the light-emitting apparatus of this embodiment, the pixel portion, which includes a plurality of organic EL elements, may include both the organic EL element described in Embodiments 1 and 2 and an organic EL element having a different structure.

The sealing substrate 604 is attached to the element substrate 610 with the sealing material 605, so that an organic EL element 618 is provided in the space 607 surrounded by the element substrate 610, the sealing substrate 604, and the sealing material 605. The space 607 may be filled with a filler, or may be filled with an inert gas (such as nitrogen or argon), or the sealing material. It is preferable that the sealing substrate be provided with a depressed portion and a drying agent be provided in the depressed portion, in which case deterioration due to influence of moisture can be suppressed.

An epoxy resin or glass frit is preferably used for the sealing material 605. It is preferable that such a material not be permeable to moisture or oxygen as much as possible. As the sealing substrate 604, a glass substrate, a quartz substrate, or a plastic substrate formed of fiber reinforced plastics (FRP), poly(vinyl fluoride) (PVF), polyester, an acrylic resin, or the like can be used.

Although not illustrated in FIGS. 19A and 19B, a protective film may be provided over the second electrode. As the protective film, an organic resin film or an inorganic insulating film may be formed. The protective film may be formed so as to cover an exposed portion of the sealing material 605. The protective film may be provided so as to cover surfaces and side surfaces of the pair of substrates and exposed side surfaces of a sealing layer, an insulating layer, and the like.

The protective film can be formed using a material through which an impurity such as water does not permeate easily. Thus, diffusion of an impurity such as water from the outside into the inside can be effectively suppressed.

As a material of the protective film, an oxide, a nitride, a fluoride, a sulfide, a ternary compound, a metal, a polymer, or the like can be used. For example, the material may contain aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, aluminum nitride, hafnium nitride, silicon nitride, tantalum nitride, titanium nitride, niobium nitride, molybdenum nitride, zirconium nitride, gallium nitride, a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like.

The protective film is preferably formed using a deposition method with favorable step coverage. One such method is an ALD method. A material that can be formed by an ALD method is preferably used for the protective film. A dense protective film having reduced defects such as cracks or pinholes or a uniform thickness can be formed by an ALD method. Furthermore, damage caused to a process member in forming the protective film can be reduced.

By an ALD method, a uniform protective film with few defects can be formed even on, for example, a surface with a complex uneven shape or upper, side, and lower surfaces of a touch panel.

As described above, the light-emitting apparatus manufactured using the organic EL element described in Embodiments 1 and 2 can be obtained.

The light-emitting apparatus in this embodiment is manufactured using the organic EL element described in Embodiments 1 and 2 and thus can have favorable characteristics. Specifically, since the organic EL element described in Embodiments 1 and 2 has a low driving voltage, the light-emitting apparatus can achieve low power consumption.

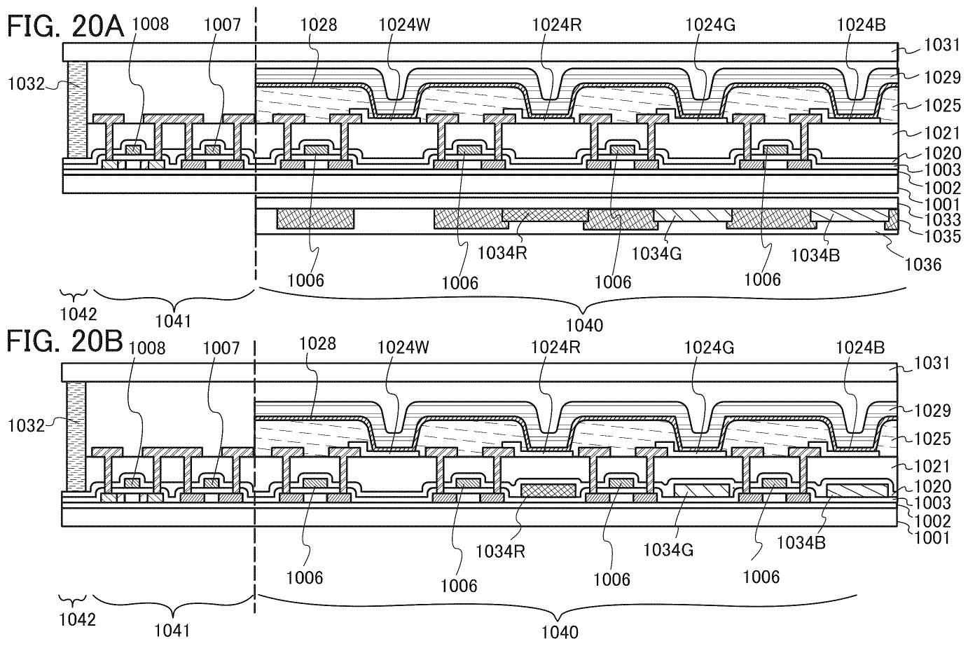

FIGS. 20A and 20B each illustrate an example of a light-emitting apparatus in which full color display is achieved by formation of an organic EL element exhibiting white light emission and with the use of coloring layers (color filters) and the like. In FIG. 20A, a substrate 1001, a base insulating film 1002, a gate insulating film 1003, gate electrodes 1006, 1007, and 1008, a first interlayer insulating film 1020, a second interlayer insulating film 1021, a peripheral portion 1042, a pixel portion 1040, a driver circuit portion 1041, first electrodes 1024W, 1024R, 1024G, and 1024B of organic EL elements, a partition 1025, an EL layer 1028, a second electrode 1029 of the organic EL elements, a sealing substrate 1031, a sealing material 1032, and the like are illustrated.

In FIG. 20A, coloring layers (a red coloring layer 1034R, a green coloring layer 1034G, and a blue coloring layer 1034B) are provided on a transparent base material 1033. A black matrix 1035 may be additionally provided. The transparent base material 1033 provided with the coloring layers and the black matrix is aligned and fixed to the substrate 1001. Note that the coloring layers and the black matrix 1035 are covered with an overcoat layer 1036. In FIG. 20A, light emitted from part of the light-emitting layer does not pass through the coloring layers, while light emitted from the other part of the light-emitting layer passes through the coloring layers. Since light which does not pass through the coloring layers is white and light which passes through any one of the coloring layers is red, green, or blue, an image can be displayed using pixels of the four colors.

FIG. 20B illustrates an example in which the coloring layers (the red coloring layer 1034R, the green coloring layer 1034G, and the blue coloring layer 1034B) are provided between the gate insulating film 1003 and the first interlayer insulating film 1020. As in the structure, the coloring layers may be provided between the substrate 1001 and the sealing substrate 1031.

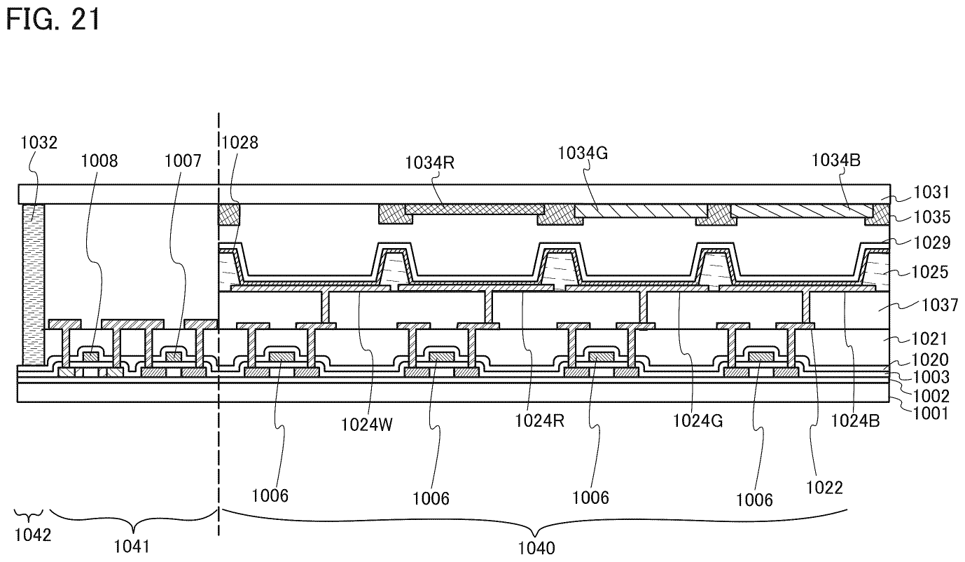

The above-described light-emitting apparatus has a structure in which light is extracted from the substrate 1001 side where FETs are formed (a bottom emission structure), but may have a structure in which light is extracted from the sealing substrate 1031 side (a top emission structure). FIG. 21 is a cross-sectional view of a light-emitting apparatus having a top emission structure. In this case, a substrate that does not transmit light can be used as the substrate 1001. The process up to the step of forming a connection electrode that connects the FET and the anode of the organic EL element is performed in a manner similar to that of the light-emitting apparatus having a bottom emission structure. Then, a third interlayer insulating film 1037 is formed to cover an electrode 1022. This insulating film may have a planarization function. The third interlayer insulating film 1037 can be formed using a material similar to that of the second interlayer insulating film 1021, and can alternatively be formed using any of other known materials.

The first electrodes 1024W, 1024R, 1024G, and 1024B of the organic EL elements each serve as an anode here, but may serve as a cathode. Furthermore, in the case of a light-emitting apparatus having a top emission structure as illustrated in FIG. 21, the first electrodes are preferably reflective electrodes. The EL layer 1028 is formed to have a structure similar to the structure of the organic compound layer 103, which is described in Embodiments 1 and 2, with which white light emission can be obtained.

In the case of a top emission structure as illustrated in FIG. 21, sealing can be performed with the sealing substrate 1031 on which the coloring layers (the red coloring layer 1034R, the green coloring layer 1034G, and the blue coloring layer 1034B) are provided. The scaling substrate 1031 may be provided with the black matrix 1035 which is positioned between pixels. The coloring layers (the red coloring layer 1034R, the green coloring layer 1034G, and the blue coloring layer 1034B) and the black matrix may be covered with the overcoat layer 1036. Note that a light-transmitting substrate is used as the sealing substrate 1031. Although an example in which full color display is performed using four colors of red, green, blue, and white is shown here, there is no particular limitation and full color display using four colors of red, yellow, green, and blue or three colors of red, green, and blue may be performed.

In the light-emitting apparatus having a top emission structure, a microcavity structure can be suitably employed. An organic EL element with a microcavity structure is formed with the use of a reflective electrode as the first electrode and a transflective electrode as the second electrode. The organic EL element with a microcavity structure includes at least an EL layer between the reflective electrode and the transflective electrode, which includes at least a light-emitting layer serving as a light-emitting region.

Note that the reflective electrode has a visible light reflectivity of 40% to 100%, preferably 70% to 100%, and a resistivity of 1×10⁻² Ω·cm or lower. In addition, the transflective electrode has a visible light reflectivity of 20% to 80%, preferably 40% to 70%, and a resistivity of 1×10⁻² Ω·cm or lower.

Light emitted from the light-emitting layer included in the EL layer is reflected and resonated by the reflective electrode and the transflective electrode.

In the organic EL element, by changing thicknesses of the transparent conductive film, the composite material, the carrier-transport material, and the like, the optical path length between the reflective electrode and the transflective electrode can be changed. Thus, light with a wavelength that is resonated between the reflective electrode and the transflective electrode can be intensified while light with a wavelength that is not resonated therebetween can be attenuated.

Note that light that is reflected back by the reflective electrode (first reflected light) considerably interferes with light that directly enters the transflective electrode from the light-emitting layer (first incident light). For this reason, the optical path length between the reflective electrode and the light-emitting layer is preferably adjusted to (2n−1) λ/4 (n is a natural number of 1 or larger and λ is a wavelength of light to be amplified). By adjusting the optical path length, the phases of the first reflected light and the first incident light can be aligned with each other and the light emitted from the light-emitting layer can be further amplified.

Note that in the above structure, the EL layer may include a plurality of light-emitting layers or may include a single light-emitting layer. The tandem organic EL element described above may be combined with a plurality of EL layers; for example, an organic EL element may have a structure in which a plurality of EL layers are provided, a charge-generation layer is provided between the EL layers, and each EL layer includes a plurality of light-emitting layers or a single light-emitting layer.

With the microcavity structure, emission intensity with a specific wavelength in the front direction can be increased, whereby power consumption can be reduced. Note that in the case of a light-emitting apparatus which displays images with subpixels of four colors, red, yellow, green, and blue, the light-emitting apparatus can have favorable characteristics because the luminance can be increased owing to yellow light emission and each subpixel can employ a microcavity structure suitable for wavelengths of the corresponding color.

The light-emitting apparatus in this embodiment is manufactured using the organic EL element described in Embodiments 1 and 2 and thus can have favorable characteristics. Specifically, since the organic EL element described in Embodiments 1 and 2 has a low driving voltage, the light-emitting apparatus can achieve low power consumption.

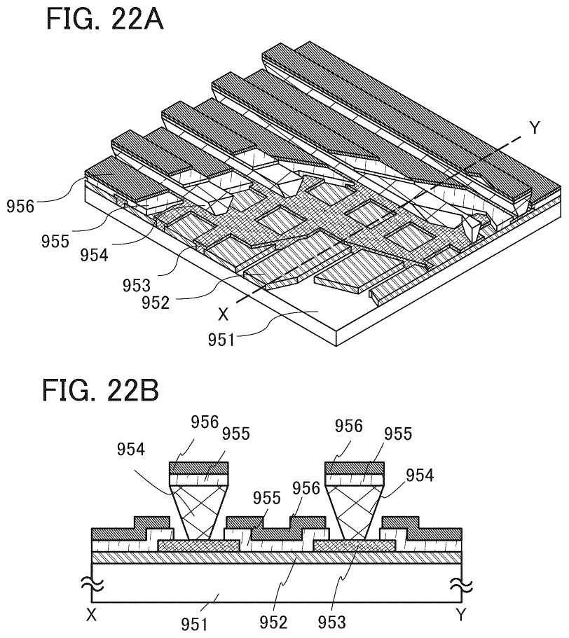

An active matrix light-emitting apparatus is described above, whereas a passive matrix light-emitting apparatus is described below. FIGS. 22A and 22B illustrate a passive matrix light-emitting apparatus manufactured using the present invention. Note that FIG. 22A is a perspective view of the light-emitting apparatus, and FIG. 22B is a cross-sectional view taken along the line X-Y in FIG. 22A. In FIGS. 22A and 22B, over a substrate 951, an EL layer 955 is provided between an electrode 952 and an electrode 956. An end portion of the electrode 952 is covered with an insulating layer 953. A partition layer 954 is provided over the insulating layer 953. The sidewalls of the partition layer 954 are aslope such that the distance between both sidewalls is gradually narrowed toward the surface of the substrate. In other words, a cross section taken along the direction of the short side of the partition layer 954 is trapezoidal, and the lower side (a side of the trapezoid which is parallel to the surface of the insulating layer 953 and is in contact with the insulating layer 953) is shorter than the upper side (a side of the trapezoid which is parallel to the surface of the insulating layer 953 and is not in contact with the insulating layer 953). The partition layer 954 provided in this manner can prevent defects in the organic EL element due to static electricity or others. The passive matrix light-emitting apparatus also includes the organic EL element described in Embodiments 1 and 2; thus, the light-emitting apparatus can have low power consumption.

Since many minute organic EL elements arranged in a matrix in the light-emitting apparatus described above can each be controlled, the light-emitting apparatus can be suitably used as a display device for displaying images.

This embodiment can be freely combined with any of the other embodiments.

### Embodiment 8

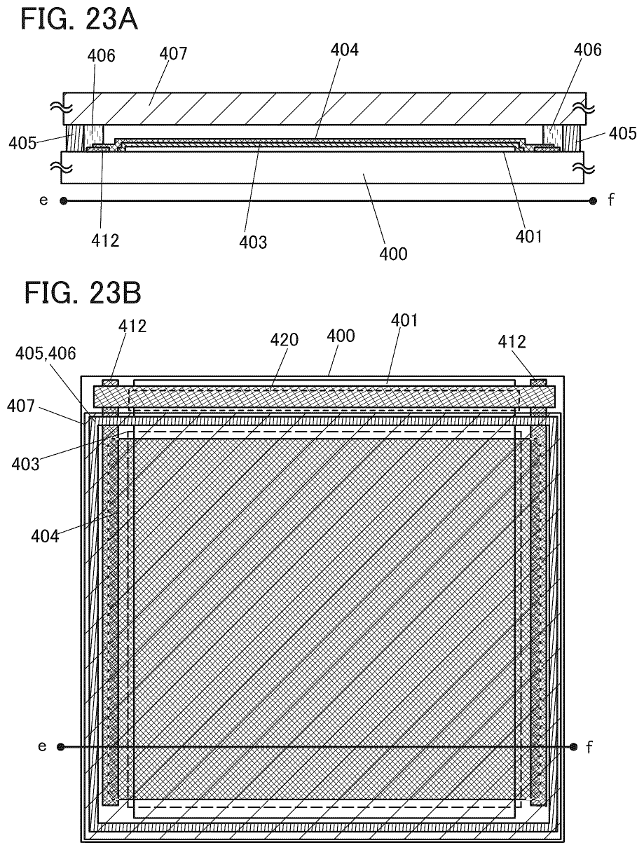

In this embodiment, a structure of a light-emitting apparatus in a lighting device of one embodiment of the present invention will be described with reference to FIGS. 23A and 23B.

FIG. 23A is a cross-sectional view taken along the line e-f in a top view of the lighting device in FIG. 23B.

In the light-emitting apparatus in this embodiment, a first electrode 401 is formed over a substrate 400 that is a support and has a light-transmitting property. The first electrode 401 corresponds to the first electrode 101 in Embodiment 2. When light is extracted from the first electrode 401 side, the first electrode 401 is formed using a material having a light-transmitting property.

A pad 412 for supplying voltage to a second electrode 404 is provided over the substrate 400.

An EL layer 403 is formed over the first electrode 401. The structure of the EL layer 403 corresponds to the structure of the organic compound layer 103 in Embodiments 1 and 2. Refer to the corresponding description for these structures.

The second electrode 404 is formed to cover the EL layer 403. The second electrode 404 corresponds to the second electrode 102 in Embodiment 2. The second electrode 404 is formed using a material having high reflectance when light is extracted from the first electrode 401 side. The second electrode 404 is connected to the pad 412 so that voltage is supplied to the second electrode 404.

As described above, the light-emitting apparatus described in this embodiment includes a light-emitting device including the first electrode 401, the EL layer 403, and the second electrode 404. Since the light-emitting device has high emission efficiency, the lighting device in this embodiment can have low power consumption.

The substrate 400 provided with the light-emitting device having the above structure and a sealing substrate 407 are fixed and sealed with sealing materials 405 and 406, whereby the lighting device is completed. It is possible to use only either the sealing material 405 or the sealing material 406. In addition, the inner sealing material 406 (not illustrated in FIG. 23B) can be mixed with a desiccant that enables moisture to be adsorbed, leading to an improvement in reliability.

When parts of the pad 412 and the first electrode 401 are extended to the outside of the sealing materials 405 and 406, the extended parts can serve as external input terminals. An IC chip 420 mounted with a converter or the like may be provided over the external input terminals.

### Embodiment 9

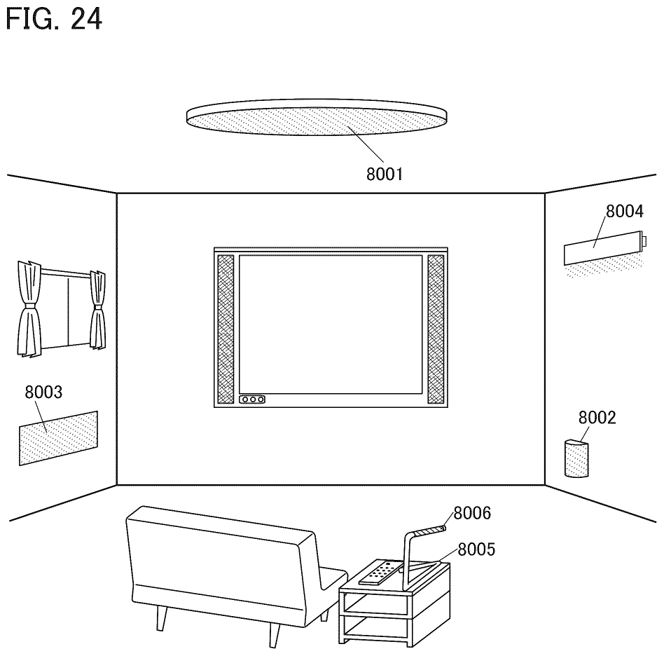

This embodiment will describe application examples of the light-emitting apparatus or the lighting device of one embodiment of the present invention with reference to FIG. 24.

A ceiling light 8001 can be used as an indoor lighting device. Examples of the ceiling light 8001 include a direct-mount light and an embedded light. Such lighting devices are fabricated using the light-emitting apparatus in combination with a shade, a housing, and a cover. Application to a cord pendant light (light that is suspended from a ceiling by a cord) is also possible.

A foot light 8002 lights a floor so that safety on the floor can be improved. For example, it can be effectively used in a bedroom, on a staircase, and on a passage. In such cases, the size and shape of the foot light can be changed in accordance with the dimensions and structure of a room. The foot light can be a stationary lighting device using the light-emitting apparatus and a support in combination.

A sheet-like lighting 8003 is a thin sheet-like lighting device. The sheet-like lighting, which is attached to a wall when used, is space-saving and thus can be used for a wide variety of uses. Furthermore, the area of the sheet-like lighting can be easily increased. The sheet-like lighting can also be used on a wall that has a curved surface.

A lighting device 8004 in which the direction of light from a light source is controlled to be only a desired direction can be used.

A desk lamp 8005 includes a light source 8006. As the light source 8006, the light-emitting apparatus of one embodiment of the present invention or the light-emitting device, which is part of the light-emitting apparatus, can be used.

Besides the above examples, when the light-emitting apparatus of one embodiment of the present invention or the light-emitting device, which is part of the light-emitting apparatus, is used as part of furniture in a room, a lighting device having a function of the furniture can be obtained.

As described above, a variety of lighting devices that include the light-emitting apparatus or the lighting device of one embodiment of the present invention can be obtained. Note that these lighting devices are also embodiments of the present invention.

The structures described in this embodiment can be used in appropriate combination with any of the structures described in the other embodiments.

### Example 1

In this example, a light-emitting device 1 and a light-emitting device 2 of embodiments of the present invention and a comparative light-emitting device 3 to a comparative light-emitting device 5 for comparison were fabricated. The results of measuring the device characteristics are described.

The structural formulae of organic compounds used in the light-emitting devices 1 and 2 and the comparative light-emitting devices 3 to 5 are shown below.

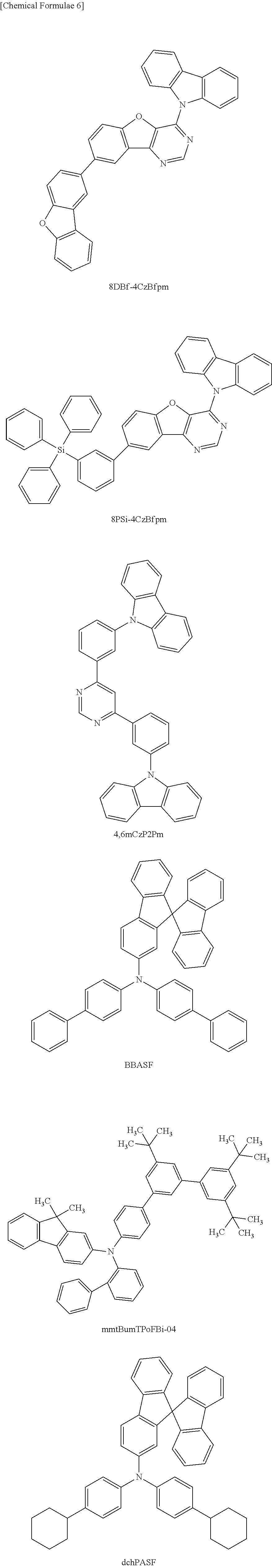

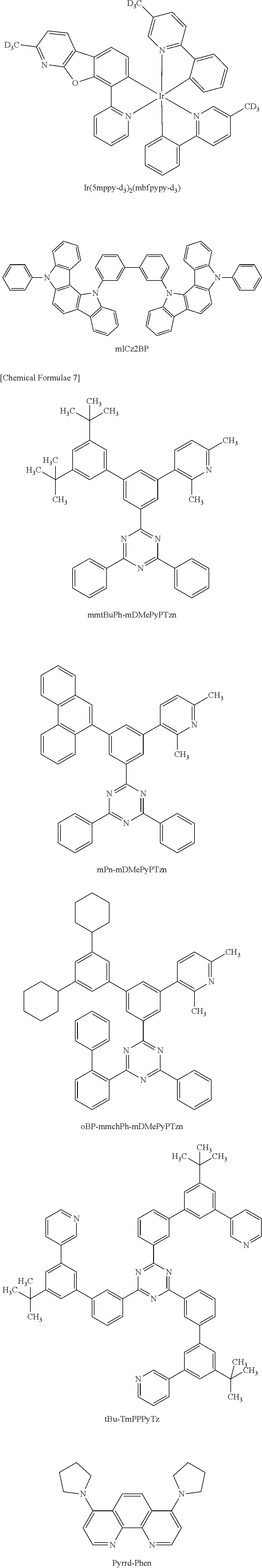

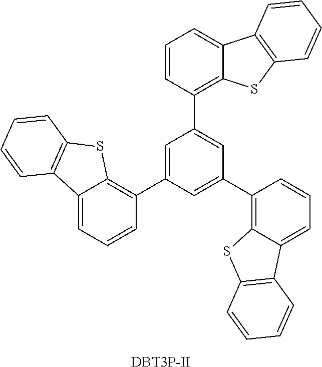 [SMILES: c1ccc2c(c1)sc1c(-c3cc(-c4cccc5c4sc4ccccc45)cc(-c4cccc5c4sc4ccccc45)c3)cccc12 ; "DBT3P-II"]

Note that as shown in the above structural formulae, N-(biphenyl-2-yl)-N-(3″,5′,5″-tri-tert-butyl-[1,1′: 3′,1″-terphenyl]-4-yl)-9,9-dimethyl-9H-fluoren-2-amine (abbreviation: mmtBumTPoFBi-04), N,N-bis(4-cyclohexylphenyl)-9,9′-spirobi[9H-fluoren]-2-amine (abbreviation: dchPASF), 2-{3-(2,6-dimethylpyridin-3-yl)-5-[(3,5-di-tert-butyl)phenyl]phenyl}-4,6-diphenyl-1,3,5-triazine (abbreviation: mmtBuPh-mDMePyPTzn), 2-(biphenyl-2-yl)-4-[3-(3,5-dicyclohexylphenyl)-5-(2,6-dimethylpyridin-3-yl)]phenyl-6-phenyl-1,3,5-triazine (abbreviation: oBP-mmchPh-mDMePyPTzn), and 2,4,6-tris[3′-(pyridin-3-yl)-5′-tert-butyl-biphenyl-3-yl]-1,3,5-triazine (abbreviation: tBu-TmPPPyTz) are organic compounds each having two or more groups selected from chain alkyl groups having 2 to 10 carbon atoms and cycloalkyl groups having 6 to 12 carbon atoms. In addition, N,N-bis(biphenyl-4-yl)-9,9′-spirobi[9H-fluoren]-2-amine (abbreviation: BBASF), mmtBumTPOFBi-04, and dchPASF are organic compounds each having an aromatic amine skeleton.

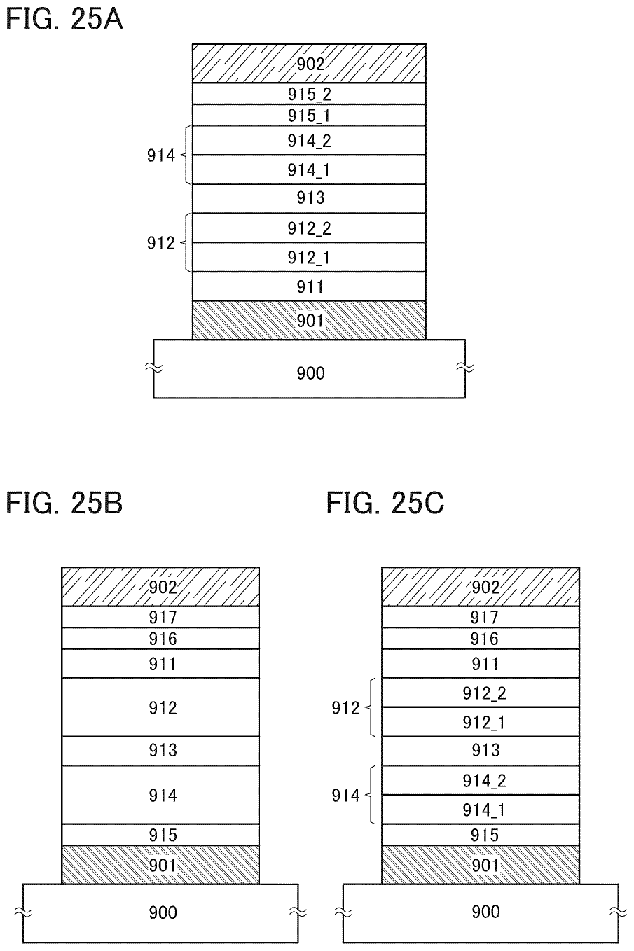

As illustrated in FIG. 25A, the light-emitting devices each have a structure of an ordered stacked light-emitting device in which a hole-injection layer 911, hole-transport layers 912 (a first hole-transport layer 912_1 and a second hole-transport layer 912_2), a light-emitting layer 913, electron-transport layers 914 (a first electron-transport layer 914_1 and a second electron-transport layer 914_2), and electron-injection layers 915 (a first electron-injection layer 915_1 and a second electron-injection layer 915_2) are stacked in this order over a first electrode 901 formed over a glass substrate 900, and a second electrode 902 is formed over the second electron-injection layer 915_2. Note that in the ordered stacked light-emitting device, the first electrode 901 and the second electrode 902 function as an anode and a cathode, respectively.

### <Fabrication Method of Light-Emitting Device 1>

Indium tin oxide containing silicon oxide (ITSO) was deposited by a sputtering method over the glass substrate 900 to a thickness of 70 nm, so that the first electrode 901 as a transparent electrode was formed. The electrode area was set to 4 mm² (2 mm×2 mm).

Next, in pretreatment for forming the light-emitting device over the substrate, the substrate surface was washed with water and baking was performed at 200° C. for 1 hour. Then, the substrate was transferred into a vacuum evaporation apparatus where the pressure was reduced to approximately 1×10⁻⁴ Pa, and vacuum baking was performed at 170° C. for 30 minutes in a heating chamber of the vacuum evaporation apparatus. After that, natural cooling was performed.

Then, the substrate provided with the first electrode 901 was fixed to a substrate holder provided in the vacuum evaporation apparatus so that the surface on which the first electrode 901 was formed faced downward. Over the first electrode 901, 4,4′,4″-(benzene-1,3,5-triyl)tri (dibenzothiophene) (abbreviation: DBT3P-II) and molybdenum (VI) oxide (MoO₃) were deposited by co-evaporation to a thickness of 10 nm such that the weight ratio of DBT3P-II to MoO₃ was 1:0.5, whereby the hole-injection layer 911 was formed.

Next, over the hole-injection layer 911, BBASF was deposited by evaporation to a thickness of 20 nm, so that the first hole-transport layer 912_1 was formed, and then dchPASF was deposited by evaporation to a thickness of 20 nm, so that the second hole-transport layer 912_2 was formed.

Subsequently, over the second hole-transport layer 912_2, 4-(9H-carbazol-9-yl)-8-(dibenzofuran-2-yl)-[1]benzofuro-[3,2-d]pyrimidine (abbreviation: 8DBf-4CzBfpm), 12,12′-(biphenyl-3,3′-diyl)bis(5,12-dihydro-5-phenylindolo[3,2-a]-5H, 12H-carbazole) (abbreviation: mICz2BP), and [2-d₃-methyl-8-(2-pyridinyl-κN)benzofuro[2,3-b]pyridine-κC]bis[2-(5-d₃-methyl-2-pyridinyl-κN²)phenyl-κC]iridium (III) (abbreviation: Ir(5mppy-d₃)₂ (mbfpypy-d₃)) were deposited by co-evaporation to a thickness of 40 nm using resistance heating such that the weight ratio between 8DBf-4CzBfpm, mICz2BP, and Ir(5mppy-d₃)₂ (mbfpypy-d₃) was 0.5:0.5:0.1, whereby the light-emitting layer 913 was formed.

Next, over the light-emitting layer 913, mmtBuPh-mDMePyPTzn was deposited by evaporation to a thickness of 20 nm, so that the first electron-transport layer 914_1 was formed, and then 2-[3-(2,6-dimethyl-3-pyridinyl)-5-(9-phenanthryl)phenyl]-4,6-diphenyl-1,3,5-triazine (abbreviation: mPn-mDMePyPTzn) was deposited by evaporation to a thickness of 20 nm, so that the second electron-transport layer 914_2 was formed.

Next, over the second electron-transport layer 914_2, 4,7-di-1-pyrrolidinyl-1,10-phenanthroline (abbreviation: Pyrrd-Phen) was deposited by evaporation to a thickness of 1 nm, so that the first electron-injection layer 915_1 was formed, and then lithium fluoride (LiF) was deposited by evaporation to a thickness of 1 nm, so that the second electron-injection layer 915_2 was formed.

Then, over the second electron-injection layer 915_2, aluminum (Al) was deposited by evaporation to a thickness of 200 nm to form the second electrode 902, whereby the light-emitting device 1 was fabricated.

### <Fabrication Method of Light-Emitting Device 2>

The light-emitting device 2 is different from the light-emitting device 1 in that BBASF used for the first hole-transport layer 912_1 of the light-emitting device I was replaced with mmtBumTPoFBi-04 and that mPn-mDMePyPTzn used for the second electron-transport layer 914_2 of the light-emitting device 1 was replaced with oBP-mmchPh-mDMePyPTzn. Other components of the light-emitting device 2 were fabricated in a manner similar to that for the light-emitting device 1.

### <Fabrication Method of Comparative Light-Emitting Device 3>

The comparative light-emitting device 3 is different from the light-emitting device 1 in that mPn-mDMePyPTzn used for the second electron-transport layer 914_2 of the light-emitting device 1 was replaced with tBu-TmPPPyTz. Other components of the comparative light-emitting device 3 were fabricated in a manner similar to that for the light-emitting device 1.

### <Fabrication Method of Comparative Light-Emitting Device 4>

The comparative light-emitting device 4 is different from the light-emitting device 1 in that 8DBf-4CzBfpm used for the light-emitting layer 913 of the light-emitting device 1 was replaced with 4-(9H-carbazol-9-yl)-8-[3-(triphenylsilyl)phenyl]-[1]benzofuro[3,2-d]pyrimidine (abbreviation: 8PSi-4CzBfpm). Other components of the comparative light-emitting device 4 were fabricated in a manner similar to that for the light-emitting device 1.

### <Fabrication Method of Comparative Light-Emitting Device 5>

The comparative light-emitting device 5 is different from the light-emitting device 1 in that 8DBf-4CzBfpm used for the light-emitting layer 913 of the light-emitting device 1 was replaced with 4,6-bis[3-(9H-carbazol-9-yl)phenyl]pyrimidine (abbreviation: 4,6mCzP2Pm). Other components of the comparative light-emitting device 5 were fabricated in a manner similar to that for the light-emitting device 1.

The structures of the light-emitting devices are listed in Table 3.

TABLE 3

| | | | | | Comparative | Comparative | Comparative |
|---|---|---|---|---|---|---|---|
| | | Thick- | Light- | Light- | light- | light- | light- |
| | | ness | emitting | emitting | emitting | emitting | emitting |
| | | (nm) | device 1 | device 2 | device 3 | device 4 | device 5 |
| Second | — | 200 | Al | | | | |
| electrode | | | | | | | |
| Electron- | 2 | 1 | LiF | | | | |
| injection | 1 | 1 | Pyrrd-Phen | | | | |
| layer | | | | | | | |
| Electron- | 2 | 20 | mPn- | oBP-mmchPh- | tBu- | mPn- | |
| transport | | | mDMePyPTzn | mDMePyPTzn | TmPPPyTz | mDMePyPTzn | |
| layer | 1 | 20 | mmtBuPh-mDMePyPTzn | | | | |
| Light- | — | 40 | 8DBf- | | | 8PSi- | 4,6mCzP2Pm:mICz2BP:Ir(5mppy- |
| emitting | | | 4CzBfpm:mICz2BP:Ir(5mppy- | | | 4CzBfpm:mICz2BP:Ir(5mppy- | d₃)₂(mbfpypy-d₃) (0.5:0.5:0.1) |
| layer | | | d₃)₂(mbfpypy-d₃) (0.5:0.5:0.1) | | | d₃)₂(mbfpypy-d₃) (0.5:0.5:0.1) | |
| Hole- | 2 | 20 | dchPASF | | | | |
| transport | 1 | 20 | BBASF | mmtBumTPoFBi- | BBASF | | |
| layer | | | | 04 | | | |

| | | | |
|---|---|---|---|
| Hole- | — | 10 | DBT3P-II:MoO₃ (1:0.5) |
| injection | | | |
| layer | | | |
| First | — | 70 | ITSO |
| electrode | | | |

### <Characteristics of Light-Emitting Device>

The light-emitting devices were sealed using a glass substrate in a glove box containing a nitrogen atmosphere so as not to be exposed to the air (a sealing material was applied to surround the devices and UV treatment and heat treatment at 80° C. for 1 hour were performed at the time of sealing). Then, the characteristics of the light-emitting devices were measured.

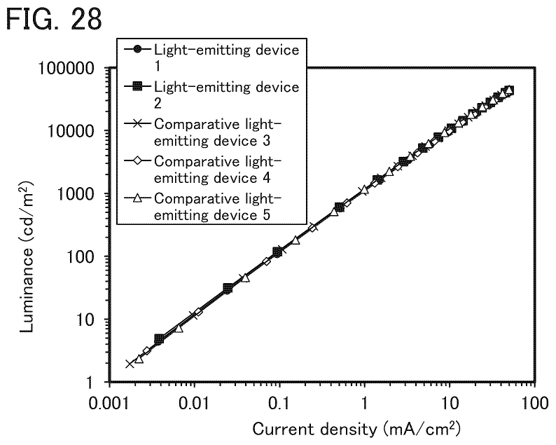

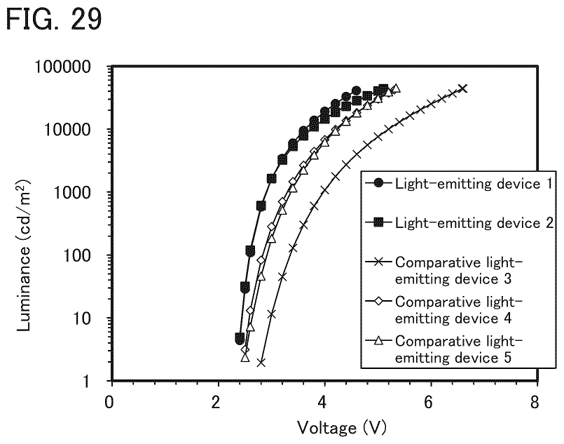

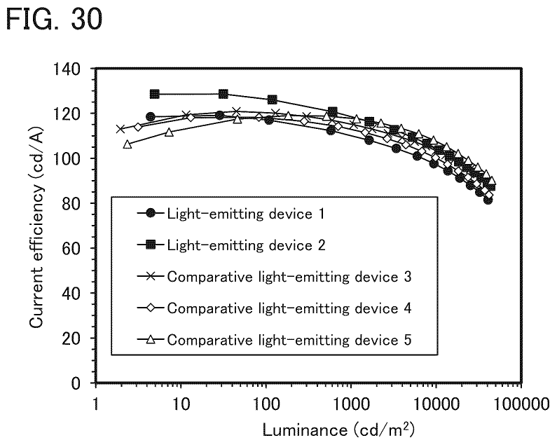

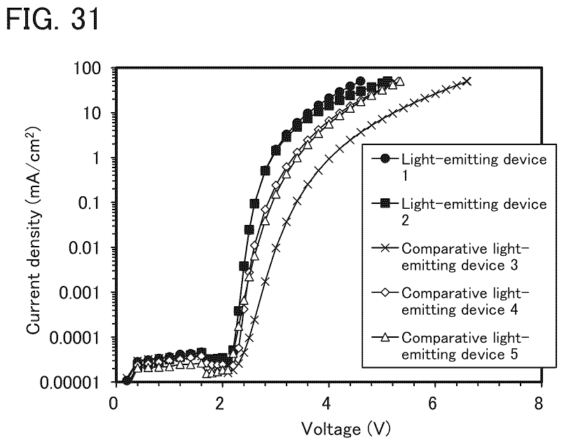

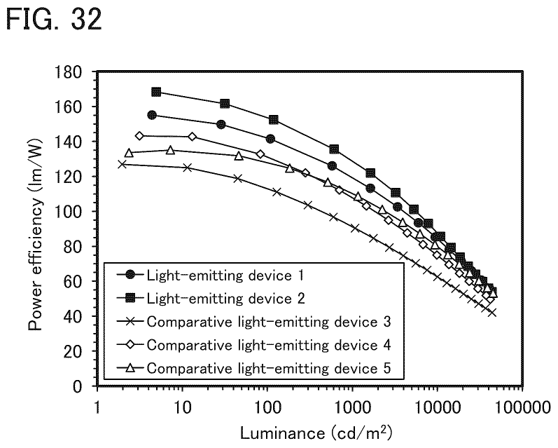

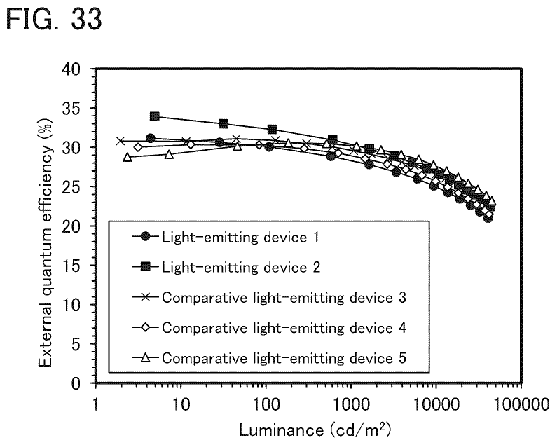

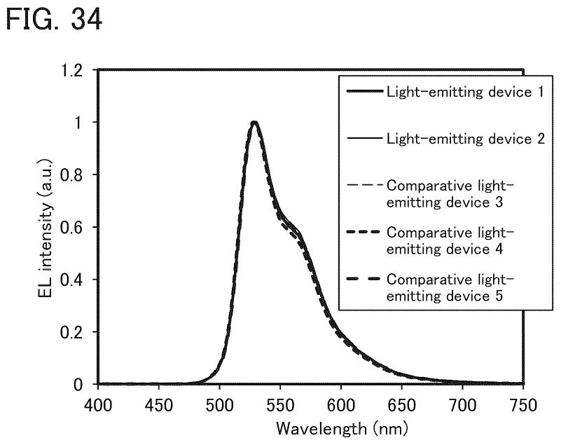

FIG. 28 shows the luminance-current density characteristics of the light-emitting devices. FIG. 29 shows the luminance-voltage characteristics thereof. FIG. 30 shows the current efficiency-luminance characteristics thereof. FIG. 31 shows the current density-voltage characteristics thereof. FIG. 32 shows the power efficiency-luminance characteristics thereof. FIG. 33 shows the external quantum efficiency-luminance characteristics thereof. FIG. 34 shows the electroluminescence spectra thereof.

Table 4 shows the main characteristics of the light-emitting devices at a luminance of approximately 1000 cd/m². The luminance, CIE chromaticity, and electroluminescence spectra were measured with a spectroradiometer (SR-ULIR, manufactured by TOPCON TECHNOHOUSE CORPORATION). The power efficiency and the external quantum efficiency were calculated from the luminance and the electroluminescence spectra measured with the spectroradiometer, on the assumption that the devices had Lambertian light-distribution characteristics.

TABLE 4

| | | | | | | | | | External |
|---|---|---|---|---|---|---|---|---|---|
| | | | Current | | | | Current | Power | quantum |
| | Voltage | Current | density | | | Luminance | efficiency | efficiency | efficiency |
| | (V) | (mA) | (mA/cm²) | Chromaticity x | Chromaticity y | (cd/m²) | (cd/A) | (lm/W) | (%) |
| Light-emitting device 1 | 2.80 | 0.0206 | 0.516 | 0.341 | 0.632 | 579 | 112 | 126 | 28.8 |
| Light-emitting device 2 | 2.80 | 0.0202 | 0.505 | 0.344 | 0.630 | 609 | 121 | 136 | 30.9 |
| Comparative | 4.00 | 0.0374 | 0.936 | 0.344 | 0.629 | 1076 | 115 | 90.3 | 29.6 |
| light-emitting device 3 | | | | | | | | | |
| Comparative | 3.20 | 0.0247 | 0.617 | 0.335 | 0.636 | 705 | 114 | 112 | 29.3 |
| light-emitting device 4 | | | | | | | | | |
| Comparative | 3.40 | 0.0396 | 0.990 | 0.343 | 0.630 | 1164 | 118 | 109 | 30.2 |
| light-emitting device 5 | | | | | | | | | |

From FIG. 28 to FIG. 34 and Table 4, the light-emitting devices 1 and 2 were found to be light-emitting devices with favorable characteristics that emit green light derived from Ir(5mppy-d₃)₂ (mbfpypy-d₃).

In addition, from FIG. 29, FIG. 31, and Table 4, the light-emitting devices 1 and 2 were found to have lower driving voltages than the comparative light-emitting devices 3 to 5.

Moreover, from FIG. 32 and Table 4, the light-emitting devices 1 and 2 were found to have higher power efficiency than the comparative light-emitting devices 3 to 5. Furthermore, the light-emitting device 2 was found to have high current efficiency, high external quantum efficiency, and particularly high power efficiency as compared with those of the light-emitting device 1 and the comparative light-emitting devices 3 to 5.

Here, Table 5 shows the GSP slopes and ordinary refractive indices (nₒ) of evaporated films of the organic compounds used for the first hole-transport layers, the second hole-transport layers, the first electron-transport layers, and the second electron-transport layers of the light-emitting devices 1 and 2 and the comparative light-emitting devices 3 to 5 and evaporated films of the host materials used for the light-emitting layers of these devices. Note that the GSP slopes in Table 5 were measured by the method described in Embodiment 1. Table 5 shows two kinds of ordinary refractive indices: the ordinary refractive index at 528 nm, which is the peak wavelength of the emission spectrum of a dichloromethane solution of Ir(5mppy-d₃)₂ (mbfpypy-d₃), and the ordinary refractive index at 530 nm, which is the peak wavelength of the electroluminescence spectrum of each light-emitting device. The measurement of the ordinary refractive index was performed with a spectroscopic ellipsometer (M-2000U, manufactured by J.A. Woollam Japan). To obtain films used as measurement samples, the material for each layer was deposited to a thickness of approximately 50 nm over a quartz substrate by a vacuum evaporation method.

TABLE 5

| | GSP slope | nₒ | nₒ |
|---|---|---|---|
| Abbreviation | (mV/nm) | (528 nm) | (530 nm) |
| 8DBf-4CzBfpm | 94.9 | 1.84 | 1.84 |
| 8PSi-4CzBfpm | 53.2 | 1.78 | 1.78 |
| 4,6mCzP2Pm | 4.2 | 1.80 | 1.80 |
| mICz2BP | 28.7 | 1.84 | 1.83 |
| BBASF | 7.5 | 1.81 | 1.81 |
| mmtBumTPoFBi-04 | 16.2 | 1.69 | 1.69 |
| dchPASF | 35.1 | 1.72 | 1.72 |
| mmtBuPh-mDMePyPTzn | 44.3 | 1.64 | 1.64 |
| mPn-mDMePyPTzn | 0.2 | 1.77 | 1.77 |
| oBP-mmchPh-mDMePyPTzn | 10.3 | 1.69 | 1.69 |
| tBu-TmPPPyTz | 72.5 | 1.74 | 1.74 |

Next, Table 6 lists the GSP slopes of the first hole-transport layers, the second hole-transport layers, the light-emitting layers, the first electron-transport layers, and the second electron-transport layers of the light-emitting devices 1 and 2 and the comparative light-emitting devices 3 to 5. Note that as the GSP slopes of the first hole-transport layer, the second hole-transport layer, the first electron-transport layer, and the second electron-transport layer, the GSP slopes of the evaporated films of the organic compounds used for the layers are shown, and as the GSP slope of the light-emitting layer, the average GSP slope of the evaporated films of the two host materials is shown.

TABLE 6

| | | | | |
|---|---|---|---|---|
| | | Comparative | Comparative | Comparative |
| Light-emitting | Light-emitting | light-emitting | light-emitting | light-emitting |
| device 1 | device 2 | device 3 | device 4 | device 5 |

| | | | | | |
|---|---|---|---|---|---|
| Electron-transport layer | 2 | 0.2 mV/nm | 10.3 mV/nm | 72.5 mV/nm | 0.2 mV/nm |

| | 1 | 44.3 mV/nm | | |
|---|---|---|---|---|
| Light-emitting layer | — | 61.8 mV/nm | 41.0 mV/nm | 16.5 mV/nm |

| Hole-transport layer | 2 | 35.1 mV/nm | | |
|---|---|---|---|---|
| | 1 | 7.5 mV/nm | 16.2 mV/nm | 7.5 mV/nm |

As shown in Table 6, in each of the light-emitting devices 1 and 2, the GSP slope of the light-emitting layer is larger than the GSP slopes of the first hole-transport layer, the second hole-transport layer, the first electron-transport layer, and the second electron-transport layer. In each of the light-emitting devices 1 and 2, the GSP slope of the second hole-transport layer is smaller than the GSP slope of the light-emitting layer and larger than the GSP slope of the first hole-transport layer. In each of the light-emitting devices 1 and 2, the GSP slope of the first electron-transport layer is smaller than the GSP slope of the light-emitting layer and larger than the GSP slope of the second electron-transport layer.

Meanwhile, as shown in Table 6, in the comparative light-emitting device 3, the GSP slope of the light-emitting layer is smaller than the GSP slope of the second electron-transport layer. In the comparative light-emitting device 4, the GSP slope of the light-emitting layer is smaller than the GSP slope of the first electron-transport layer. In the comparative light-emitting device 5, the GSP slope of the light-emitting layer is smaller than the GSP slopes of the second hole-transport layer and the first electron-transport layer.

As described above, the light-emitting devices 1 and 2 have lower driving voltages than the comparative light-emitting devices 3 to 5. Thus, it was revealed that the ordered stacked light-emitting device can have a low driving voltage when materials used for the layers are selected such that the GSP slope of the light-emitting layer is larger than the GSP slopes of the hole-transport layers (the first hole-transport layer and the second hole-transport layer) and the electron-transport layers (the first electron-transport layer and the second electron-transport layer). It was also revealed that the ordered stacked light-emitting device having the above structure can have a lower driving voltage when materials used for the layers are selected such that the GSP slope of the layer closer to the second electrode is larger than the GSP slope of the layer closer to the first electrode among a plurality of the hole-transport layers, and the GSP slope of the layer closer to the first electrode is larger than the GSP slope of the layer closer to the second electrode among a plurality of the electron-transport layers. In other words, it was revealed that the ordered stacked light-emitting device can have a low driving voltage when materials used for the layers are selected such that the average GSP slope of the evaporated films of the two host materials used for the light-emitting layer is larger than the GSP slopes of the evaporated films of the organic compounds used for the hole-transport layers (the first hole-transport layer and the second hole-transport layer) and the electron-transport layers (the first electron-transport layer and the second electron-transport layer). It was also revealed that the ordered stacked light-emitting device having the above structure can have a lower driving voltage when materials used for the layers are selected such that the GSP slope of the evaporated film of the organic compound used for the layer closer to the second electrode is larger than the GSP slope of the evaporated film of the organic compound used for the layer closer to the first electrode among the plurality of hole-transport layers, and the GSP slope of the evaporated film of the organic compound used for the layer closer to the first electrode is larger than the GSP slope of the evaporated film of the organic compound used for the layer closer to the second electrode among the plurality of electron-transport layers.

Table 7 lists the ordinary refractive indices (nₒ) of the first hole-transport layers, the second hole-transport layers, the light-emitting layers, the first electron-transport layers, and the second electron-transport layers of the light-emitting devices 1 and 2 and the comparative light-emitting devices 3 to 5. Note that as the ordinary refractive indices of the first hole-transport layer, the second hole-transport layer, the first electron-transport layer, and the second electron-transport layer, the ordinary refractive indices of the evaporated films of the organic compounds used for the layers are shown, and as the ordinary refractive index of the light-emitting layer, the average ordinary refractive index of the evaporated films of the two host materials is shown. The ordinary refractive index of each layer shown in Table 7 was obtained at 530 nm, which is the peak wavelength of the electroluminescence spectrum of each light-emitting device.

TABLE 7

| | | | | |
|---|---|---|---|---|
| | | Comparative | Comparative | Comparative |
| Light-emitting | Light-emitting | light-emitting | light-emitting | light-emitting |
| device 1 | device 2 | device 3 | device 4 | device 5 |

| | | | | | |
|---|---|---|---|---|---|
| Electron-transport layer | 2 | 1.77 | 1.69 | 1.74 | 1.77 |

| | 1 | 1.64 | | |
|---|---|---|---|---|
| Light-emitting layer | — | 1.84 | 1.81 | 1.82 |

| Hole-transport layer | 2 | 1.72 | | |
|---|---|---|---|---|
| | 1 | 1.81 | 1.69 | 1.81 |

As shown in Table 5, at a wavelength of 530 nm, the ordinary refractive indices of the first hole-transport layer, the second hole-transport layer, the first electron-transport layer, and the second electron-transport layer are lower than the ordinary refractive index of the light-emitting layer in each of the light-emitting devices 1 and 2.

As shown in Table 5, at a wavelength of 530 nm, the ordinary refractive index of the first hole-transport layer of the light-emitting device 2 is lower than the ordinary refractive indices of the first hole-transport layers of the light-emitting device 1 and the comparative light-emitting devices 3 to 5. At a wavelength of 530 nm, the ordinary refractive index of the second electron-transport layer of the light-emitting device 2 is lower than the ordinary refractive indices of the second electron-transport layers of the light-emitting device 1 and the comparative light-emitting devices 3 to 5.

As described above, the light-emitting device 2 has high external quantum efficiency, high current efficiency, and particularly high power efficiency as compared with those of the light-emitting device 1 and the comparative light-emitting devices 3 to 5. Thus, it was found that when the first hole-transport layer, the second hole-transport layer, the first electron-transport layer, and the second electron-transport layer have lower ordinary refractive indices at the peak wavelength of the electroluminescence spectrum of the light-emitting device, the light-emitting device can have higher power efficiency. In other words, it was found that when the first hole-transport layer, the second hole-transport layer, the first electron-transport layer, and the second electron-transport layer each contain an organic compound that has a lower ordinary refractive index in a film state at the peak wavelength of the electroluminescence spectrum of the light-emitting device, the light-emitting device can have higher power efficiency.

The above results reveal that the light-emitting device of one embodiment of the present invention has a low driving voltage and high emission efficiency (power efficiency, current efficiency, and external quantum efficiency).

### Example 2

In this example, a light-emitting device 6 to a light-emitting device 8 of embodiments of the present invention and a comparative light-emitting device 9 for comparison were fabricated. The results of measuring the device characteristics are described.

The structural formulae of organic compounds used in the light-emitting devices 6 to 8 and the comparative light-emitting device 9 are shown below.

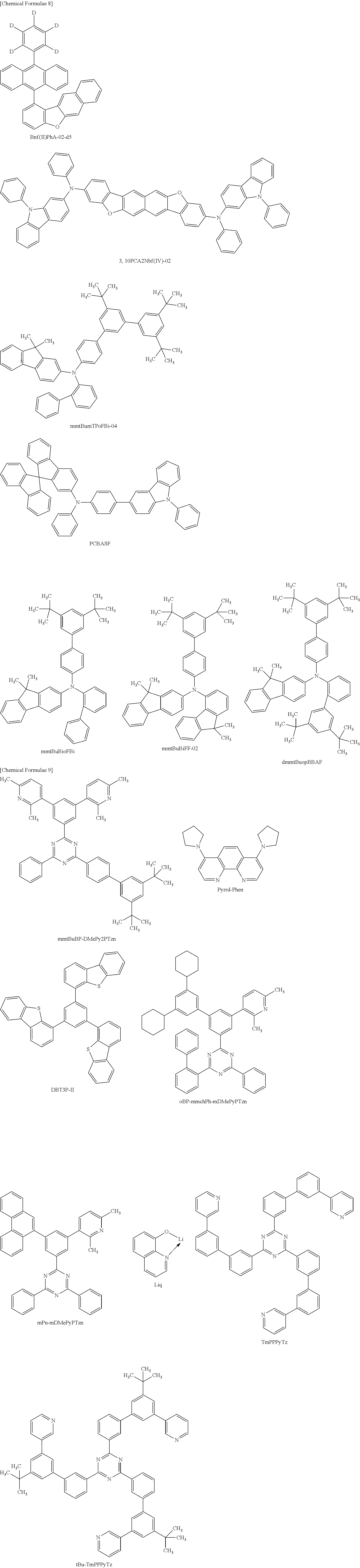

Note that as shown in the above structural formulae, mmtBumTPOFBi-04, N-(3′,5′-ditertiarybutylbiphenyl-4-yl)-N-(biphenyl-2-yl)-9,9-dimethyl-9H-fluoren-2-amine (abbreviation: 5 mmtBuBioFBi), N-(3′,5′-di-tert-butyl-biphenyl-4-yl)-N-(9,9-dimethyl-9H-fluoren-4-yl)-9,9-dimethyl-9H-fluoren-2-amine (abbreviation: mmtBuBiFF-02), N-(3′,5′-ditertiarybutylbiphenyl-4-yl)-N-(3′,5′-ditertiarybutylbiphenyl-2-yl)-9,9-dimethyl-9H-fluoren-2-amine (abbreviation: dmmtBuopBBAF), 2-[3,5-bis(2,6-dimethylpyridin-3-yl)phenyl]-4-(3′,5′-di-tert-butylbiphenyl-4-yl)-6-phenyl-1,3,5-triazine (abbreviation: mmtBuBP-DMePy2PTzn), and 2,4,6-tris[3′-(pyridin-3-10 yl)-5′-tert-butyl-biphenyl-3-yl]-1,3,5-triazine (abbreviation: tBu-TmPPPyTz) are organic compounds each having two or more groups selected from chain alkyl groups having 2 to 10 carbon atoms and cycloalkyl groups having 6 to 12 carbon atoms. In addition, mmtBumTPOFBi-04, N-phenyl-N-[4-(9-phenyl-9H-carbazol-3-yl)phenyl]-9,9′-spirobi[9H-fluoren]-2-amine (abbreviation: PCBASF), mmtBuBioFBi, mmtBuBiFF-02, and dmmtBuopBBAF are organic compounds each having an aromatic amine skeleton.

As illustrated in FIG. 25A, the light-emitting devices each have a structure of an ordered stacked light-emitting device in which the hole-injection layer 911, the hole-transport layers 912 (the first hole-transport layer 912_1 and the second hole-transport layer 912_2), the light-emitting layer 913, the electron-transport layers 914 (the first electron-transport layer 914_1 and the second electron-transport layer 914_2), and the electron-injection layers 915 (the first electron-injection layer 915_1 and the second electron-injection layer 915_2) are stacked in this order over the first electrode 901 formed over the glass substrate 900, and the second electrode 902 is formed over the second electron-injection layer 915_2. Note that in the ordered stacked light-emitting device, the first electrode 901 and the second electrode 902 function as an anode and a cathode, respectively.

### <Fabrication Method of Light-Emitting Device 6>

Indium tin oxide containing silicon oxide (ITSO) was deposited by a sputtering method over the glass substrate 900 to a thickness of 55 nm, so that the first electrode 901 as a transparent electrode was formed. The electrode area was set to 4 mm² (2 mm×2 mm).

Next, in pretreatment for forming the light-emitting device over the substrate, the substrate surface was washed with water and baking was performed at 200° C. for 1 hour. Then, the substrate was transferred into a vacuum evaporation apparatus where the pressure was reduced to approximately 1× 10-4 Pa, and vacuum baking was performed at 170° C. for 30 minutes in a heating chamber of the vacuum evaporation apparatus. After that, natural cooling was performed.

Then, the substrate provided with the first electrode 901 was fixed to a substrate holder provided in the vacuum evaporation apparatus so that the surface on which the first electrode 901 was formed faced downward. Over the first electrode 901, 4,4′,4″-(benzene-1,3,5-triyl)tri (dibenzothiophene) (abbreviation: DBT3P-II) and molybdenum (VI) oxide (MoO₃) were deposited by co-evaporation to a thickness of 10 nm such that the weight ratio of DBT3P-II to MoO₃ was 1:0.5, whereby the hole-injection layer 911 was formed.

Next, over the hole-injection layer 911, mmtBumTPoFBi-04 was deposited by evaporation to a thickness of 20 nm, so that the first hole-transport layer 912_1 was formed, and then mmtBuBioFBi was deposited by evaporation to a thickness of 15 nm, so that the second hole-transport layer 912_2 was formed.

Subsequently, over the second hole-transport layer 912_2, 1-[10-(phenyl-2,3,4,5,6-d₅)-9-anthryl]benzo[b]naphtho[2,3-d]furan (abbreviation: Bnf (II) PhA-02-d₅) and N,N′-diphenyl-N,N′-bis(9-phenyl-9H-carbazol-2-yl) naphtho[2,3-b;6,7-b′]bisbenzofuran-3,10-diamine (abbreviation: 3,10PCA2Nbf (IV)-02) were deposited by co-evaporation to a thickness of 25 nm using resistance heating such that the weight ratio of Bnf (II) PhA-02-d₅ to 3,10PCA2Nbf (IV)-02 was 1:0.015, whereby the light-emitting layer 913 was formed.

Next, over the light-emitting layer 913, mmtBuBP-DMePy2PTzn was deposited by evaporation to a thickness of 10 nm, so that the first electron-transport layer 914_1 was formed, and then oBP-mmchPh-mDMePyPTzn was deposited by evaporation to a thickness of 20 nm, so that the second electron-transport layer 914_2 was formed.

Next, over the second electron-transport layer 914_2, 4,7-di-1-pyrrolidinyl-1,10-phenanthroline (abbreviation: Pyrrd-Phen) was deposited by evaporation to a thickness of 1 nm, so that the first electron-injection layer 915_1 was formed, and then lithium fluoride (LiF) was deposited by evaporation to a thickness of 1 nm, so that the second electron-injection layer 915_2 was formed.

Then, over the second electron-injection layer 915_2, aluminum (Al) was deposited by evaporation to a thickness of 200 nm to form the second electrode 902, whereby the light-emitting device 6 was fabricated.

### <Fabrication Method of Light-Emitting Device 7>

The light-emitting device 7 is different from the light-emitting device 6 in that oBP-mmchPh-mDMePyPTzn used for the second electron-transport layer 914_2 of the light-emitting device 6 was replaced with 2,4,6-tris(3′-(pyridin-3-yl) biphenyl-3-yl)-1,3,5-triazine (abbreviation: TmPPPyTz). Other components of the light-emitting device 7 were fabricated in a manner similar to that for the light-emitting device 6.

### <Fabrication Method of Light-Emitting Device 8>

The light-emitting device 8 is different from the light-emitting device 6 in the structures of the hole-injection layer, the first hole-transport layer, the second hole-transport layer, and the second electron-transport layer. Specifically, the hole-injection layer of the light-emitting device 8 was formed by depositing PCBASF and an electron acceptor material containing fluorine with a molecular weight of 672 (OCHD-003) by co-evaporation to a thickness of 10 nm such that the weight ratio of PCBASF to OCHD-003 was 1:0.1. The first hole-transport layer of the light-emitting device 8 was formed by depositing PCBASF by evaporation to a thickness of 20 nm. The second hole-transport layer of the light-emitting device 8 was formed by depositing mmtBuBiFF-02 by evaporation to a thickness of 15 nm. The second electron-transport layer of the light-emitting device 8 was formed by depositing 2-[3-(2,6-dimethyl-3-pyridinyl)-5-(9-phenanthryl)phenyl]-4,6-diphenyl-1,3,5-triazine (abbreviation: mPn-mDMePyPTzn) and 8-quinolinolato-lithium (abbreviation: Liq) by co-evaporation to a thickness of 20 nm such that the weight ratio of mPn-mDMePyPTzn to Liq was 1:1. Other components of the light-emitting device 8 were fabricated in a manner similar to that for the light-emitting device 6.

### <Fabrication Method of Comparative Light-Emitting Device 9>

The comparative light-emitting device 9 is different from the light-emitting device 6 in that mmtBuBioFBi used for the second hole-transport layer 912_2 of the light-emitting device 6 was replaced with dmmtBuopBBAF and that oBP-mmchPh-mDMePyPTzn used for the second electron-transport layer 914_2 of the light-emitting device 6 was replaced with tBu-TmPPPyTz. Other components of the comparative light-emitting device 9 were fabricated in a manner similar to that for the light-emitting device 6.

The structures of the light-emitting devices are listed in Table 8.

TABLE 8

| | | | | | | Comparative |
|---|---|---|---|---|---|---|
| | | Thickness | Light-emitting | Light-emitting | Light-emitting | light-emitting |
| | | (nm) | device 6 | device 7 | device 8 | device 9 |
| Second electrode | — | 200 | Al | | | |
| Electron-injection layer | 2 | 1 | LiF | | | |
| | 1 | 1 | Pyrrd-Phen | | | |
| Electron-transport layer | 2 | 20 | oBP-mmchPh- | TmPPPyTz | mPn- | tBu-TmPPPyTz |
| | | | mDMePyPTzn | | mDMePyPTzn:Liq | |
| | | | | | (1:1) | |

| | 1 | 10 | mmtBuBP-DMePy2PTzn | | |
|---|---|---|---|---|---|
| Light-emitting layer | — | 25 | Bnf(II)PhA-02-d₅:3,10PCA2Nbf(IV)-02 (1:0.015) | | |
| Hole-transport layer | 2 | 15 | mmtBuBioFBi | mmtBuBiFF-02 | dmmtBuopBBAF |
| | 1 | 20 | mmtBumTPoFBi-04 | PCBASF | mmtBumTPoFBi-04 |
| Hole-injection layer | — | 10 | DBT3P-II:MoO₃ (1:0.5) | PCBASF:OCHD- | DBT3P-II:MoO₃ |

| | |
|---|---|
| 003 (1:0.1) | (1:0.5) |

| | | | |
|---|---|---|---|
| First electrode | — | 55 | ITSO |

### <Characteristics of Light-Emitting Device>

The light-emitting devices were sealed using a glass substrate in a glove box containing a nitrogen atmosphere so as not to be exposed to the air (a sealing material was applied to surround the devices and UV treatment and heat treatment at 80° C. for 1 hour were performed at the time of sealing). Then, the characteristics of the light-emitting devices were measured.

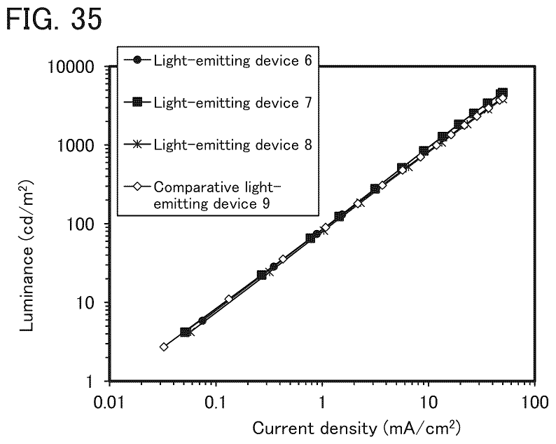

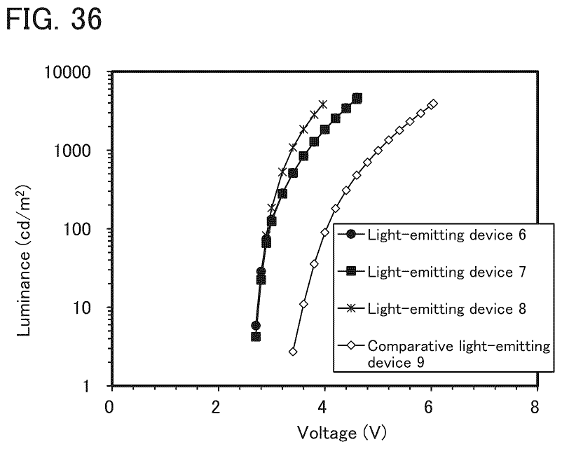

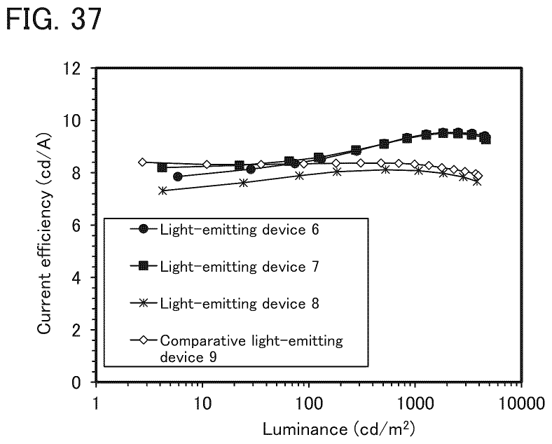

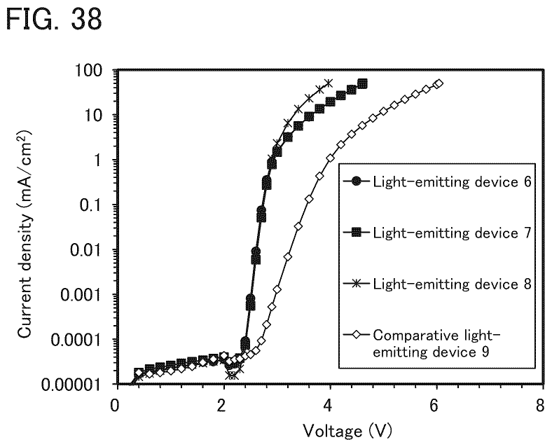

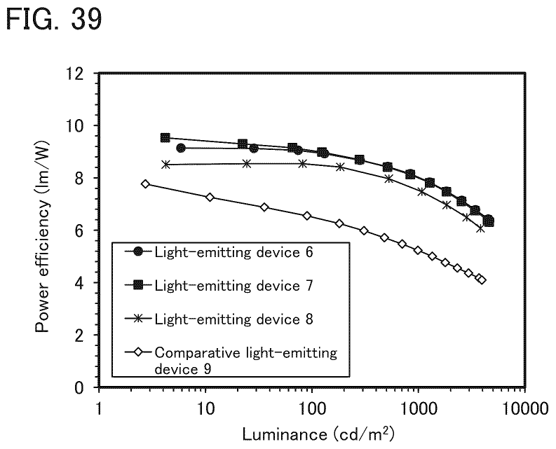

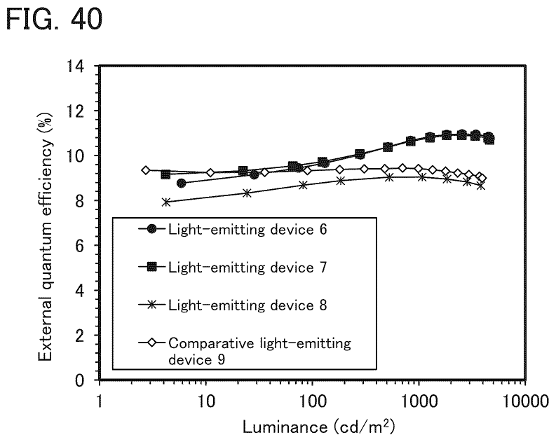

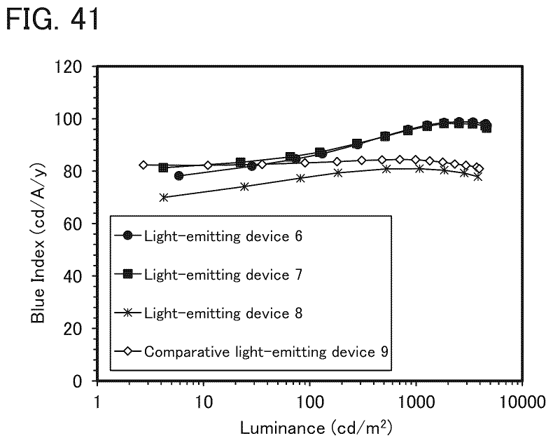

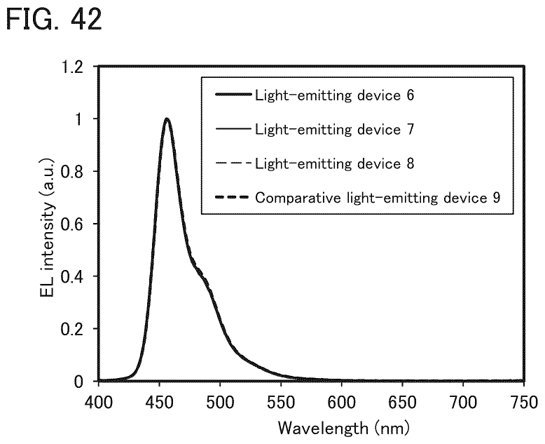

FIG. 35 shows the luminance-current density characteristics of the light-emitting devices. FIG. 36 shows the luminance-voltage characteristics thereof. FIG. 37 shows the current efficiency-luminance characteristics thereof. FIG. 38 shows the current density-voltage characteristics thereof. FIG. 39 shows the power efficiency-luminance characteristics thereof. FIG. 40 shows the external quantum efficiency-luminance characteristics thereof. FIG. 41 shows the blue index-luminance characteristics thereof. FIG. 42 shows the electroluminescence spectra thereof.

Note that the blue index (BI) is a value obtained by dividing current efficiency (cd/A) by the y value of CIE chromaticity (x, y), and is one of the indicators of characteristics of blue light emission. As the y chromaticity value of blue light emission becomes smaller, the color purity thereof tends to be higher. Blue light emission having a small y chromaticity value and high color purity enables expression of blue colors with a wide range of chromaticity in a display. Using blue light emission with high color purity reduces the luminance of blue light emission necessary for a display to express white, leading to lower power consumption of the display. Thus, the BI, which is current efficiency based on the y chromaticity value as one of the indicators of color purity of blue, is suitably used as a means for showing efficiency of blue light emission in some cases. The light-emitting device with a higher BI can be regarded as a blue-light-emitting device having higher efficiency for a display.

Table 9 shows the main characteristics of the light-emitting devices at a luminance of approximately 1000 cd/m². The luminance, CIE chromaticity, and electroluminescence spectra were measured with a spectroradiometer (SR-ULIR, manufactured by TOPCON TECHNOHOUSE CORPORATION). The power efficiency and the external quantum efficiency were calculated from the luminance and the electroluminescence spectra measured with the spectroradiometer, on the assumption that the devices had Lambertian light-distribution characteristics.

TABLE 9

| | | | | | | | | | External | |
|---|---|---|---|---|---|---|---|---|---|---|
| | | | Current | | | | Current | Power | quantum | BI |
| | Voltage | Current | density | Chromaticity | Chromaticity | Luminance | efficiency | efficiency | efficiency | (cd/A/ |
| | (V) | (mA) | (mA/cm²) | x | y | (cd/m²) | (cd/A) | (lm/W) | (%) | CIEy) |
| Light-emitting device 6 | 3.60 | 0.359 | 8.98 | 0.138 | 0.0974 | 839 | 9.34 | 8.15 | 10.7 | 95.9 |
| Light-emitting device 7 | 3.60 | 0.361 | 9.02 | 0.138 | 0.0974 | 840 | 9.31 | 8.12 | 10.6 | 95.6 |
| Light-emitting device 8 | 3.40 | 0.533 | 13.3 | 0.139 | 0.100 | 1077 | 8.08 | 7.47 | 9.04 | 80.9 |
| Comparative | 5.00 | 0.475 | 11.9 | 0.138 | 0.0987 | 989 | 8.32 | 5.23 | 9.42 | 84.3 |
| light-emitting device 9 | | | | | | | | | | |

From FIG. 35 to FIG. 42 and Table 9, the light-emitting devices 6 to 8 were found to be light-emitting devices with favorable characteristics that emit blue light derived from 3,10PCA2Nbf (IV)-02.

In addition, from FIG. 36, FIG. 38, and Table 9, the light-emitting devices 6 to 8 were found to have lower driving voltages than the comparative light-emitting device 9.

Moreover, from FIG. 39 and Table 9, the light-emitting devices 6 to 8 were found to have higher power efficiency than the comparative light-emitting device 9.

Here, Table 10 shows the GSP slopes and ordinary refractive indices (nₒ) of evaporated films of the organic compounds used for the first hole-transport layers, the second hole-transport layers, the first electron-transport layers, and the second electron-transport layers of the light-emitting devices 6 to 8 and the comparative light-emitting device 9 and evaporated films of the host materials used for the light-emitting layers of these devices. The GSP slopes in Table 10 were measured by the method described in Embodiment 1. Table 10 shows two kinds of ordinary refractive indices: the ordinary refractive index at 448 nm, which is the peak wavelength of the emission spectrum of a toluene solution of 3,10PCA2Nbf (IV)-02, and the ordinary refractive index at 456 nm, which is the peak wavelength of the electroluminescence spectrum of each light-emitting device. The measurement of the ordinary refractive index was performed with a spectroscopic ellipsometer (M-2000U, manufactured by J.A. Woollam Japan). To obtain films used as measurement samples, the material for each layer was deposited to a thickness of approximately 50 nm over a quartz substrate by a vacuum evaporation method. Table 10 also shows the GSP slope of a film formed by depositing mPn-mDMePyPTzn and Liq by co-evaporation such that the weight ratio of mPn-mDMePyPTzn to Liq was 1:1.

TABLE 10

| | GSP slope | nₒ | nₒ |
|---|---|---|---|
| Abbreviation | (mV/nm) | (448 nm) | (456 nm) |
| Bnf(II)PhA-02-d₅ | 35.2 | 1.86 | 1.84 |
| mmtBumTPoFBi-04 | 16.2 | 1.74 | 1.73 |
| PCBASF | 3.3 | 1.93 | 1.92 |
| mmtBuBioFBi | 24.3 | 1.75 | 1.74 |
| mmtBuBiFF-02 | 25.9 | 1.74 | 1.73 |
| dmmtBuopBBAF | 46.2 | 1.70 | 1.69 |
| mmtBuBP-DMePy2PTzn | 28.3 | 1.74 | 1.74 |
| oBP-mmchPh-mDMePyPTzn | 10.3 | 1.73 | 1.72 |
| TmPPPyTz | −2.1 | 1.87 | 1.86 |
| mPn-mDMePyPTzn | 0.2 | 1.82 | 1.81 |
| Liq | — | 1.73 | 1.72 |
| mPn-mDMePyPTzn:Liq (1:1) | 14.3 | — | — |
| tBu-TmPPPyTz | 72.5 | 1.78 | 1.78 |

Table 11 lists the GSP slopes of the first hole-transport layers, the second hole-transport layers, the light-emitting layers, the first electron-transport layers, and the second electron-transport layers of the light-emitting devices 6 to 8 and the comparative light-emitting device 9. Note that as the GSP slopes of the first hole-transport layer, the first electron-transport layer, and the second electron-transport layer, the GSP slopes of the evaporated films of the organic compounds used for the layers are shown, and as the GSP slope of the light-emitting layer, the GSP slope of the evaporated film of the host material is shown. Since the second hole-transport layer of the light-emitting device 8 contains two materials (mPn-mDMePyPTzn and Liq), the GSP slope of the film formed by depositing mPn-mDMePyPTzn and Liq by co-evaporation such that the weight ratio of mPn-mDMePyPTzn to Liq was 1:1 is shown.

TABLE 11

| | | | | | Comparative |
|---|---|---|---|---|---|
| | | Light- | Light- | Light- | light- |
| | | emitting | emitting | emitting | emitting |
| | | device 6 | device 7 | device 8 | device 9 |
| Electron-transport layer | 2 | 10.3 | −2.1 | 14.3 | 72.5 |

| | 1 | 28.3 | | |
|---|---|---|---|---|
| Light-emitting layer | — | 35.2 | | |
| Hole-transport layer | 2 | 24.3 | 25.9 | 46.2 |
| | 1 | 16.2 | 3.3 | 16.2 |

As shown in Table 11, in each of the light-emitting devices 6 to 8, the GSP slope of the light-emitting layer is larger than the GSP slopes of the first hole-transport layer, the second hole-transport layer, the first electron-transport layer, and the second electron-transport layer. In each of the light-emitting devices 6 to 8, the GSP slope of the second hole-transport layer is smaller than the GSP slope of the light-emitting layer and larger than the GSP slope of the first hole-transport layer. In each of the light-emitting devices 6 to 8, the GSP slope of the first electron-transport layer is smaller than the GSP slope of the light-emitting layer and larger than the GSP slope of the second electron-transport layer.

Meanwhile, as shown in Table 11, in the comparative light-emitting device 9, the GSP slope of the light-emitting layer is smaller than the GSP slopes of the second hole-transport layer and the second electron-transport layer.

As described above, the light-emitting devices 6 to 8 have lower driving voltages than the comparative light-emitting device 9. Thus, it was revealed that the ordered stacked light-emitting device can have a low driving voltage when materials used for the layers are selected such that the GSP slope of the light-emitting layer is larger than the GSP slopes of the hole-transport layers (the first hole-transport layer and the second hole-transport layer) and the electron-transport layers (the first electron-transport layer and the second electron-transport layer). It was also revealed that the ordered stacked light-emitting device having the above structure can have a lower driving voltage when materials used for the layers are selected such that the GSP slope of the layer closer to the second electrode is larger than the GSP slope of the layer closer to the first electrode among a plurality of the hole-transport layers, and the GSP slope of the layer closer to the first electrode is larger than the GSP slope of the layer closer to the second electrode among a plurality of the electron-transport layers. In other words, it was revealed that the ordered stacked light-emitting device can have a low driving voltage when materials used for the layers are selected such that the GSP slope of the evaporated film of the host material used for the light-emitting layer is larger than the GSP slopes of the evaporated films of the organic compounds used for the hole-transport layers (the first hole-transport layer and the second hole-transport layer) and the electron-transport layers (the first electron-transport layer and the second electron-transport layer). It was also revealed that the ordered stacked light-emitting device having the above structure can have a lower driving voltage when materials used for the layers are selected such that the GSP slope of the evaporated film of the organic compound used for the layer closer to the second electrode is larger than the GSP slope of the evaporated film of the organic compound used for the layer closer to the first electrode among the plurality of hole-transport layers, and the GSP slope of the evaporated film of the organic compound used for the layer closer to the first electrode is larger than the GSP slope of the evaporated film of the organic compound used for the layer closer to the second electrode among the plurality of electron-transport layers.

Table 12 lists the ordinary refractive indices (nₒ) of the first hole-transport layers, the second hole-transport layers, the light-emitting layers, the first electron-transport layers, and the second electron-transport layers of the light-emitting devices 6 to 8 and the comparative light-emitting device 9. Note that as the ordinary refractive indices of the first hole-transport layer, the second hole-transport layer, the first electron-transport layer, and the second electron-transport layer, the ordinary refractive indices of the evaporated films of the organic compounds used for the layers are shown, and as the ordinary refractive index of the light-emitting layer, the ordinary refractive index of the evaporated film of the host material is shown. Since the second hole-transport layer of the light-emitting device 8 contains two materials (mPn-mDMePyPTzn and Liq), Table 5 shows the average ordinary refractive index of the evaporated film of mPn-mDMePyPTzn and the evaporated film of Liq. The ordinary refractive index shown in Table 12 was obtained at 456 nm, which is the peak wavelength of the electroluminescence spectrum of each light-emitting device.

TABLE 12

| | | | | | Comparative |
|---|---|---|---|---|---|
| | | Light- | Light- | Light- | light- |
| | | emitting | emitting | emitting | emitting |
| | | device 6 | device 7 | device 8 | device 9 |
| Electron-transport layer | 2 | 1.72 | 1.86 | 1.77 | 1.78 |

| | 1 | 1.74 | | |
|---|---|---|---|---|
| Light-emitting layer | — | 1.84 | | |
| Hole-transport layer | 2 | 1.74 | 1.73 | 1.69 |
| | 1 | 1.73 | 1.92 | 1.73 |

As shown in Table 12, at a wavelength of 456 nm, the ordinary refractive indices of the first hole-transport layer, the second hole-transport layer, the first electron-transport layer, and the second electron-transport layer are lower than the ordinary refractive index of the light-emitting layer in each of the light-emitting device 6 and the comparative light-emitting device 9. This revealed that the magnitude relationship between the ordinary refractive indices of the layers was similar between the light-emitting device 6 and the comparative light-emitting device 9. However, as described above, the light-emitting device 6 had a lower driving voltage and higher power efficiency than the comparative light-emitting device 9, which indicates that the magnitude relationship between the GSP slopes of the layers more significantly affects the device characteristics of the light-emitting device of one embodiment of the present invention than the magnitude relationship between the ordinary refractive indices of the layers.

Next, Table 13 lists the HOMO levels of PCBASF used for the hole-injection layer and the first hole-transport layer of the light-emitting device 8, mmtBuBiFF-02 used for the second hole-transport layer of the light-emitting device 8, and Bnf (II) PhA-02-ds used for the light-emitting layer of the light-emitting device 8. Note that Table 13 shows both of the following two kinds of HOMO levels: the HOMO level obtained by CV measurement employing the method described in Embodiment 1 and the HOMO level obtained by IP measurement in which the value of an ionization potential in the air measured by a photoelectron spectroscopy method (AC-2, manufactured by Riken Keiki Co., Ltd.) is converted into a negative value.

TABLE 13

| | HOMO level | HOMO level |
|---|---|---|
| Abbreviation | (CV measurement) | (IP measurement) |
| PCBASF | −5.41 eV | −5.37 eV |
| mmtBuBiFF-02 | −5.46 eV | −5.52 eV |
| Bnf(II)PhA-02-d₅ | −5.9 eV | −5.94 eV |

The LUMO level of OCHD-003 used for the hole-injection layer of the light-emitting device 8 was calculated to be −5.27 eV by CV measurement. Thus, in order to use this material as a p-type dopant in the hole-injection layer, this material and a hole-transport material having a HOMO level close to the above LUMO level need to be deposited by co-evaporation, and PCBASF having the HOMO level shown in the above table is suitable as the hole-transport material.

As shown in Table 13, the HOMO levels of PCBASF used for the hole-injection layer and the first hole-transport layer of the light-emitting device 8 and mmtBuBiFF-02 used for the second hole-transport layer of the light-emitting device 8 are higher than the HOMO level of Bnf (II) PhA-02-d₅ used for the light-emitting layer of the light-emitting device 8. In addition, the HOMO level of PCBASF is higher than the HOMO level of mmtBuBiFF-02. In general, when a material having a high HOMO level is used for a layer closer to the hole-injection layer and a material having a low HOMO level is used for a layer closer to the light-emitting layer, a hole barrier due to a potential gap is generated at the interface between the layers and hinders hole injection, which tends to cause a problem of a high driving voltage of the light-emitting device. However, the light-emitting device 8 is a favorable light-emitting device having a low driving voltage and high power efficiency. This is because, as shown in Table 9, the GSP slope of the light-emitting layer is larger than the GSP slopes of the first hole-transport layer and the second hole-transport layer in the light-emitting device 8, which brings about the effect of attracting holes to the light-emitting layer due to spontaneous polarization of the light-emitting layer, so that the holes can get over the hole barrier due to the potential gap between the HOMO levels.

The above results reveal that the light-emitting device of one embodiment of the present invention has a low driving voltage and high power efficiency.

### Example 3

In this example, a light-emitting device 10 and a light-emitting device 11 of embodiments of the present invention and a comparative light-emitting device 12 to a comparative light-emitting device 14 for comparison were fabricated. The results of measuring the device characteristics are described.

The structural formulae of organic compounds used in the light-emitting devices 10 and 11 and the comparative light-emitting devices 12 to 14 are shown below.

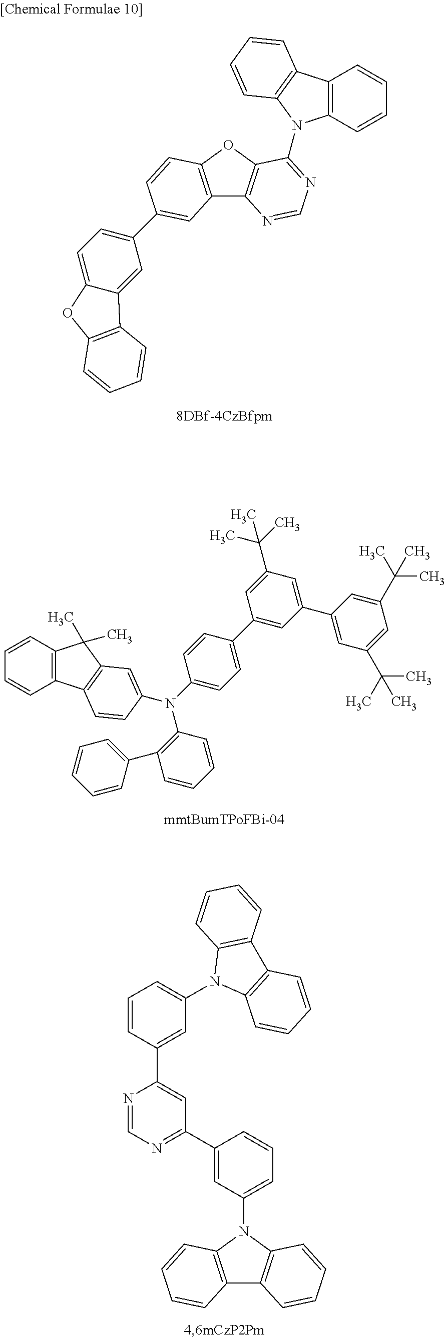 [SMILES: c1ccc2c(c1)oc1ccc(-c3ccc4oc5c(-n6c7ccccc7c7ccccc76)ncnc5c4c3)cc12 ; CC(C)(C)c1cc(-c2ccc(N(c3ccc4c(c3)C(C)(C)c3ccccc3-4)c3ccccc3-c3ccccc3)cc2)cc(-c2cc(C(C)(C)C)cc(C(C)(C)C)c2)c1 ; c1cc(-c2cc(-c3cccc(-n4c5ccccc5c5ccccc54)c3)ncn2)cc(-n2c3ccccc3c3ccccc32)c1]

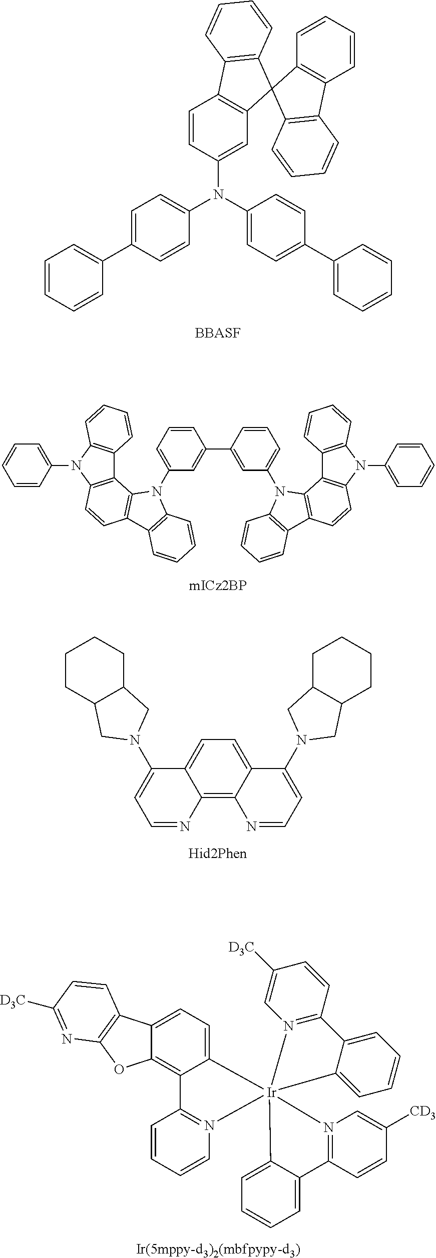

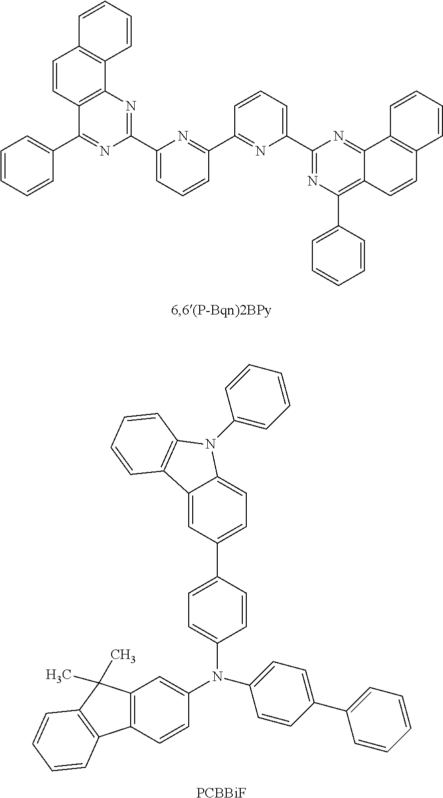

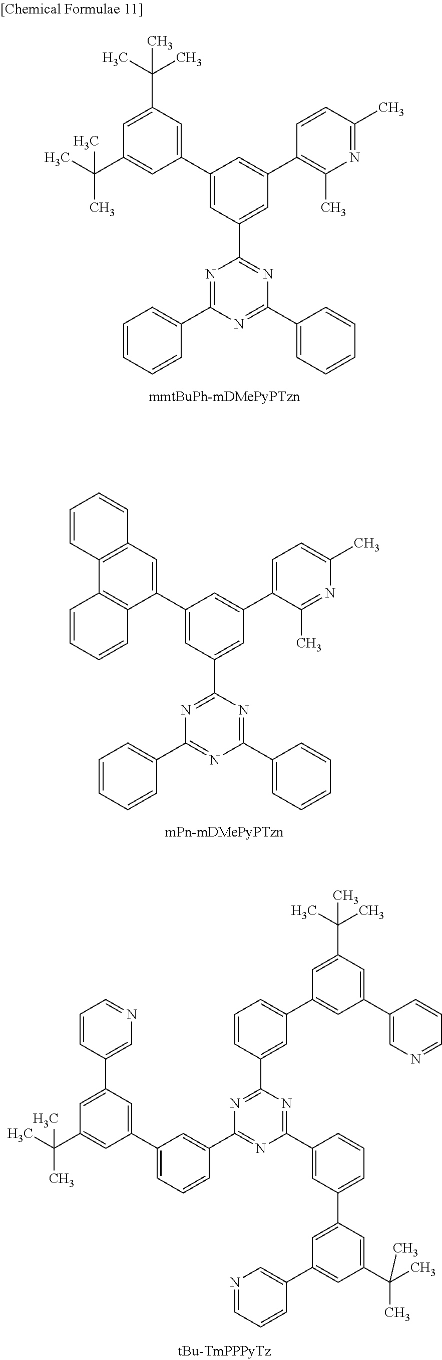

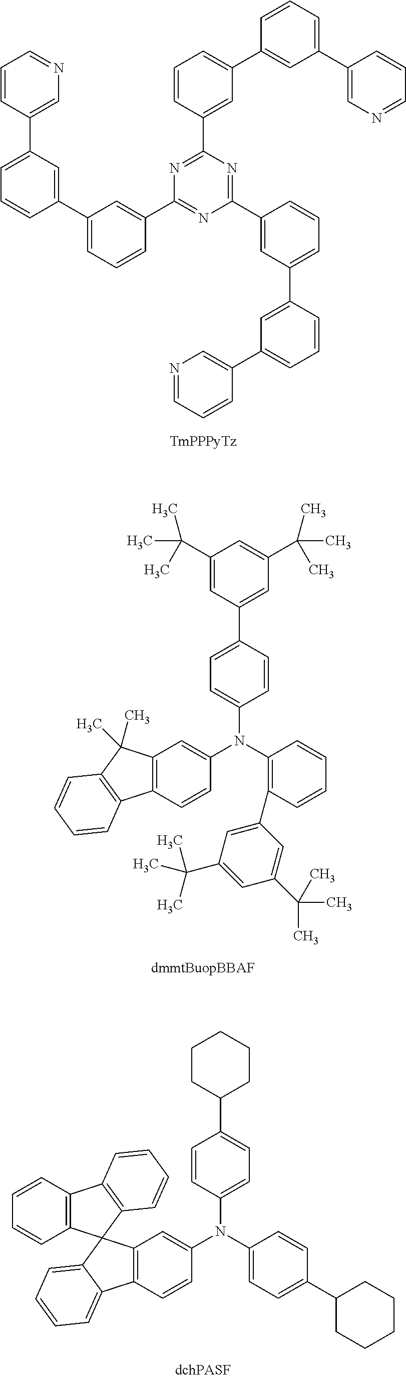 [SMILES: c1cncc(-c2cccc(-c3cccc(-c4nc(-c5cccc(-c6cccc(-c7cccnc7)c6)c5)nc(-c5cccc(-c6cccc(-c7cccnc7)c6)c5)n4)c3)c2)c1 ; CC(C)(C)c1cc(-c2ccc(N(c3ccc4c(c3)C(C)(C)c3ccccc3-4)c3ccccc3-c3cc(C(C)(C)C)cc(C(C)(C)C)c3)cc2)cc(C(C)(C)C)c1 ; c1ccc2c(c1)-c1ccccc1C21c2ccccc2-c2ccc(N(c3ccc(C4CCCCC4)cc3)c3ccc(C4CCCCC4)cc3)cc21]

Note that as shown in the above structural formulae, mmtBumTPOFBi-04, dchPASF, mmtBuPh-mDMePyPTzn, tBu-TmPPPyTz and dmmtBuopBBAF are organic compounds each having two or more groups selected from chain alkyl groups having 2 to 10 carbon atoms and cycloalkyl groups having 6 to 12 carbon atoms. In addition, N-(biphenyl-4-yl)-N-[4-(9-phenyl-9H-carbazol-3-yl)phenyl]-9,9-dimethyl-9H-fluoren-2-amine (abbreviation: PCBBiF), BBASF, mmtBumTPOFBi-04, dmmtBuopBBAF, and dchPASF are organic compounds each having an aromatic amine skeleton.

As illustrated in FIG. 25B, the light-emitting device 10 and the comparative light-emitting device 12 each have a structure of an inverted stacked light-emitting device in which the electron-injection layer 915, the electron-transport layer 914, the light-emitting layer 913, the hole-transport layer 912, the hole-injection layer 911, an electron-relay layer 916, and a charge generation buffer layer 917 are stacked in this order over the first electrode 901 formed over the glass substrate 900, and the second electrode 902 is formed over the charge generation buffer layer 917. As illustrated in FIG. 25C, the light-emitting device 11 and the comparative light-emitting devices 13 and 14 each have a structure of an inverted stacked light-emitting device in which the electron-injection layer 915, the electron-transport layers 914 (the first electron-transport layer 914_1 and the second electron-transport layer 914_2), the light-emitting layer 913, the hole-transport layers 912 (the first hole-transport layer 912_1 and the second hole-transport layer 912_2), the hole-injection layer 911, the electron-relay layer 916, and the charge generation buffer layer 917 are stacked in this order over the first electrode 901 formed over the glass substrate 900, and the second electrode 902 is formed over the charge generation buffer layer 917. Note that in the inverted stacked light-emitting device, the first electrode 901 and the second electrode 902 function as a cathode and an anode, respectively.

### <Fabrication Method of Light-Emitting Device 10>

Indium tin oxide containing silicon oxide (ITSO) was deposited by a sputtering method over the glass substrate 900 to a thickness of 70 nm, so that the first electrode 901 as a transparent electrode was formed. The electrode area was set to 4 mm² (2 mm×2 mm).

Next, in pretreatment for forming the light-emitting device over the substrate, the substrate surface was washed with water and baking was performed at 200° C. for 1 hour. Then, the substrate was transferred into a vacuum evaporation apparatus where the pressure was reduced to approximately 1× 10-4 Pa, and vacuum baking was performed at 170° C. for 30 minutes in a heating chamber of the vacuum evaporation apparatus. After that, natural cooling was performed.

Then, the substrate provided with the first electrode 901 was fixed to a substrate holder provided in the vacuum evaporation apparatus so that the surface on which the first electrode 901 was formed faced downward. Over the first electrode 901, 2,2′-([2,2′-bipyridine]-6,6′-diyl)bis(4-phenylbenzo[h]quinazoline) (abbreviation: 6,6′ (P-Bqn) 2BPy), 4,7-di(2,3,3a,4,5,6,7,7a-octahydro-1H-isoindol-2-yl)-1,10-phenanthroline (abbreviation: Hid2Phen), and lithium oxide (Li₂O) were deposited by co-evaporation to a thickness of 5 nm such that the volume ratio between 6,6′ (P-Bqn) 2BPy, Hid2Phen, and Li₂O was 0.5:0.5:0.02, whereby the electron-injection layer 915 was formed.

Next, over the electron-injection layer 915, mmtBuPh-mDMePyPTzn was deposited by evaporation to a thickness of 40 nm, so that the electron-transport layer 914 was formed.

Subsequently, over the electron-transport layer 914, 4,6mCzP2Pm, mICz2BP, and Ir(5mppy-d₃)₂ (mbfpypy-d₃) were deposited by co-evaporation to a thickness of 40 nm using resistance heating such that the weight ratio between 4,6mCzP2Pm, mICz2BP, and Ir(5mppy-d₃)₂ (mbfpypy-d₃) was 0.5:0.5:0.1, whereby the light-emitting layer 913 was formed.

Next, over the light-emitting layer 913, dchPASF was deposited by evaporation to a thickness of 40 nm, so that the hole-transport layer 912 was formed.

Then, over the hole-transport layer 912, PCBBIF and an electron acceptor material containing four or more fluorine atoms with a molecular weight of 672 (OCHD-003) were deposited by co-evaporation to a thickness of 5 nm such that the weight ratio of PCBBiF to OCHD-003 was 1:0.15, whereby the hole-injection layer 911 was formed.

Then, over the hole-injection layer 911, copper phthalocyanine (abbreviation: CuPc) was deposited to a thickness of 2 nm, whereby the electron-relay layer 916 was formed.

Subsequently, over the electron-relay layer 916, 6,6′ (P-Bqn) 2BPy, Hid2Phen, and Li₂O were deposited by co-evaporation to a thickness of 5 nm such that the volume ratio between 6,6′ (P-Bqn) 2BPy, Hid2Phen, and Li₂O was 0.5:0.5:0.02, whereby the charge generation buffer layer 917 was formed.

Then, over the charge generation buffer layer 917, aluminum (Al) was deposited by evaporation to a thickness of 100 nm to form the second electrode 902, whereby the light-emitting device 10 was fabricated.

### <Fabrication Method of Light-Emitting Device 11>

The light-emitting device 11 is different from the light-emitting device 10 in that the first electron-transport layer 914_1 was formed by depositing tBu-TmPPPyTz by evaporation to a thickness of 20 nm, the second electron-transport layer 914_2 was formed by depositing mmtBuPh-mDMePyPTzn by evaporation to a thickness of 20 nm, the first hole-transport layer 912_1 was formed by depositing dchPASF by evaporation to a thickness of 20 nm, and the second hole-transport layer 912_2 was formed by depositing dmmtBuopBBAF by evaporation to a thickness of 20 nm. Other components of the light-emitting device 11 were fabricated in a manner similar to that for the light-emitting device 10.

### <Fabrication Method of Comparative Light-Emitting Device 12>

The comparative light-emitting device 12 is different from the light-emitting device 10 in that 4,6mCzP2Pm used for the light-emitting layer 913 of the light-emitting device 10 was replaced with 8DBf-4CzBfpm. Other components of the comparative light-emitting device 12 were fabricated in a manner similar to that for the light-emitting device 10.

### <Fabrication Method of Comparative Light-Emitting Device 13>

The comparative light-emitting device 13 is different from the comparative light-emitting device 12 in that the first electron-transport layer 914_1 was formed by depositing mPn-mDMePyPTzn by evaporation to a thickness of 20 nm, the second electron-transport layer 914_2 was formed by depositing mmtBuPh-mDMePyPTzn by evaporation to a thickness of 20 nm, the first hole-transport layer 912_1 was formed by depositing dchPASF by evaporation to a thickness of 20 nm, and the second hole-transport layer 912_2 was formed by depositing BBASF by evaporation to a thickness of 20 nm. Other components of the comparative light-emitting device 13 were fabricated in a manner similar to that for the comparative light-emitting device 12.

### <Fabrication Method of Comparative Light-Emitting Device 14>

The comparative light-emitting device 14 is different from the comparative light-emitting device 12 in that the first electron-transport layer 914_1 was formed by depositing mmtBuPh-mDMePyPTzn by evaporation to a thickness of 20 nm, the second electron-transport layer 914_2 was formed by depositing tBu-TmPPPyTz by evaporation to a thickness of 20 nm, the first hole-transport layer 912_1 was formed by depositing dmmtBuopBBAF by evaporation to a thickness of 20 nm, and the second hole-transport layer 912_2 was formed by depositing dchPASF by evaporation to a thickness of 20 nm. Other components of the comparative light-emitting device 14 were fabricated in a manner similar to that for the comparative light-emitting device 12.

The structures of the light-emitting devices are listed in Table 14.

TABLE 14

| | | | | | Comparative | Comparative | Comparative |
|---|---|---|---|---|---|---|---|
| | | Thickness | Light-emitting | Light-emitting | light-emitting | light-emitting | light-emitting |
| | | (nm) | device 10 | device 11 | device 12 | device 13 | device 14 |
| Second electrode | — | 100 | Al | | | | |
| Charge generation buffer layer | — | 5 | 6,6′(P-Bqn)2BPy:Hid2Phen:Li₂O (0.5:0.5:0.02) | | | | |
| Electron-relay layer | — | 2 | CuPc | | | | |
| Hole-injection layer | — | 5 | PCBBiF:OCHD-003 (1:0.15) | | | | |
| Hole-transport layer | 2 | 20 | dchPASF | dmmtBuopBBAF | dchPASF | BBASF | dchPASF |
| | 1 | 20 | | dchPASF | | dchPASF | dmmtBuopBBAF |
| Light-emitting layer | — | 40 | 4,6mCzP2Pm:mICz2BP:Ir(5mppy- | | 8DBf-4CzBfpm:mICz2BP:Ir(5mppy- | | |
| | | | d₃)₂(mbfpypy-d₃) (0.5:0.5:0.1) | | d₃)₂(mbfpypy-d₃) (0.5:0.5:0.1) | | |
| Electron-transport layer | 2 | 20 | mmtBuPh- | mmtBuPh- | mmtBuPh- | mmtBuPh- | tBu-TmPPPyTz |
| | | | mDMePyPTzn | mDMePyPTzn | mDMePyPTzn | mDMePyPTzn | |
| | 1 | 20 | | tBu-TmPPPyTz | | mPn- | mmtBuPh- |
| | | | | | | mDMePyPTzn | mDMePyPTzn |

| | | | |
|---|---|---|---|
| Electron-injection layer | — | 5 | 6,6′(P-Bqn)2BPy:Hid2Phen:Li₂O (0.5:0.5:0.02) |
| First electrode | — | 70 | ITSO |

### <Characteristics of Light-Emitting Device>

The light-emitting devices were sealed using a glass substrate in a glove box containing a nitrogen atmosphere so as not to be exposed to the air (a sealing material was applied to surround the devices and UV treatment and heat treatment at 80° C. for 1 hour were performed at the time of sealing). Then, the characteristics of the light-emitting devices were measured.

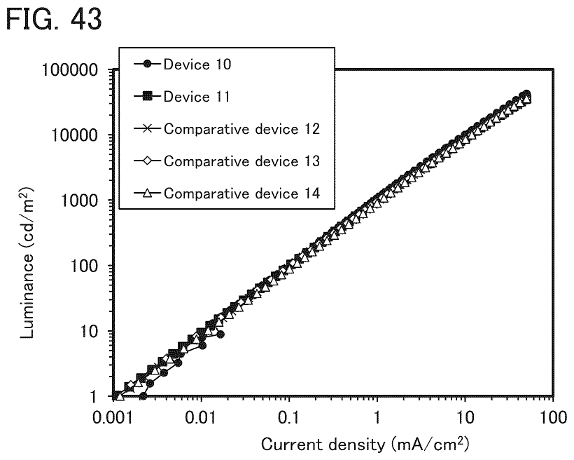

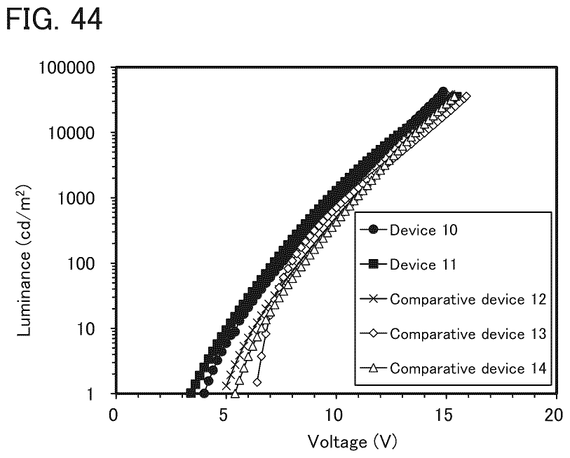

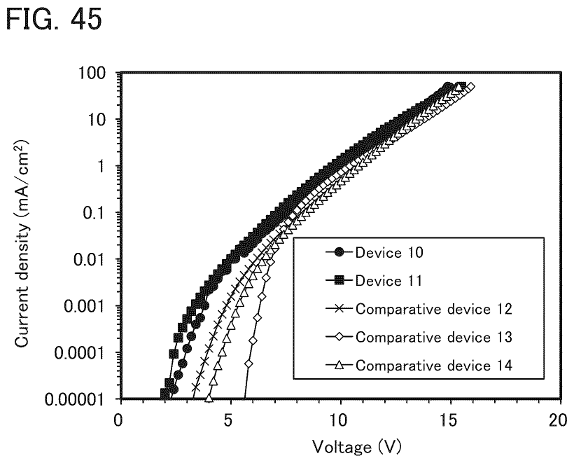

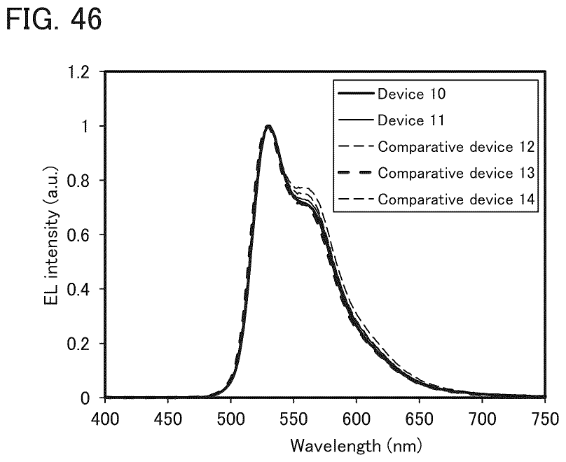

FIG. 43 shows the luminance-current density characteristics of the light-emitting devices. FIG. 44 shows the luminance-voltage characteristics thereof. FIG. 45 shows the current density-voltage characteristics thereof. FIG. 46 shows the electroluminescence spectra thereof. Note that in legends in FIG. 43 to FIG. 46, the light-emitting device 10 is denoted by Device 10, the light-emitting device 11 is denoted by Device 11, the comparative light-emitting device 12 is denoted by Comparative device 12, the comparative light-emitting device 13 is denoted by Comparative device 13, and the comparative light-emitting device 14 is denoted by Comparative device 14.

Table 15 shows the main characteristics of the light-emitting devices at a luminance of approximately 1000 cd/m². The luminance, CIE chromaticity, and electroluminescence spectra were measured with a spectroradiometer (SR-ULIR, manufactured by TOPCON TECHNOHOUSE CORPORATION). The power efficiency and the external quantum efficiency were calculated from the luminance and the electroluminescence spectra measured with the spectroradiometer, on the assumption that the devices had Lambertian light-distribution characteristics.

TABLE 15

| | | | | | | | | | External |
|---|---|---|---|---|---|---|---|---|---|
| | | | Current | | | | Current | Power | quantum |
| | Voltage | Current | density | | | Luminance | efficiency | efficiency | efficiency |
| | (V) | (mA) | (mA/cm²) | Chromaticity x | Chromaticity y | (cd/m²) | (cd/A) | (lm/W) | (%) |
| Light-emitting device 10 | 10.2 | 0.0393 | 0.983 | 0.365 | 0.613 | 1059 | 108 | 33.2 | 28.2 |
| Light-emitting device 11 | 9.40 | 0.0318 | 0.795 | 0.369 | 0.609 | 792 | 99.7 | 33.3 | 26.2 |
| Comparative | 10.6 | 0.0359 | 0.897 | 0.368 | 0.609 | 861 | 96.0 | 28.4 | 25.2 |
| light-emitting device 12 | | | | | | | | | |
| Comparative | 10.4 | 0.0392 | 0.980 | 0.360 | 0.616 | 940 | 95.9 | 29.0 | 25.0 |
| light-emitting device 13 | | | | | | | | | |
| Comparative | 11.0 | 0.0478 | 1.20 | 0.374 | 0.604 | 1080 | 90.4 | 25.8 | 23.9 |
| light-emitting device 14 | | | | | | | | | |

From FIG. 43 to FIG. 46 and Table 15, the light-emitting devices 10 and 11 were found to be light-emitting devices with favorable characteristics that emit green light derived from Ir(5mppy-d₃)₂ (mbfpypy-d₃).

In addition, from FIG. 44 and FIG. 45, the light-emitting devices 10 and 11 were found to have lower threshold voltages than the comparative light-emitting devices 12 to 14. That is, the light-emitting devices 10 and 11 were found to have lower driving voltages than the comparative light-emitting devices 12 to 14. Moreover, the light-emitting device 11 had a lower threshold voltage than the light-emitting device 10; that is, the light-emitting device 11 was found to have a lower driving voltage than the light-emitting device 10.

Moreover, from Table 15, the light-emitting devices 10 and 11 were found to have higher current efficiency, higher power efficiency, and higher external quantum efficiency than the comparative light-emitting devices 12 to 14.

Here, Table 16 lists the GSP slopes of the first hole-transport layers, the second hole-transport layers, the light-emitting layers, the first electron-transport layers, and the second electron-transport layers of the light-emitting devices 10 and 11 and the comparative light-emitting devices 12 to 14. Note that as the GSP slopes of the first hole-transport layer, the second hole-transport layer, the first electron-transport layer, and the second electron-transport layer, the GSP slopes of the evaporated films of the organic compounds used for the layers are shown, and as the GSP slope of the light-emitting layer, the average GSP slope of the evaporated films of the two host materials is shown.

TABLE 16

| | | | | Comparative | Comparative | Comparative |
|---|---|---|---|---|---|---|
| | | Light-emitting | Light-emitting | light-emitting | light-emitting | light-emitting |
| | | device 10 | device 11 | device 12 | device 13 | device 14 |
| Hole-transport layer | 2 | 35.1 | 46.2 | 35.1 | 7.5 | 35.1 |
| | 1 | | 35.1 | | 35.1 | 46.2 |
| Light-emitting layer | — | 16.5 | | 61.8 | | |
| Electron-transport layer | 2 | 44.3 | 44.3 | 44.3 | 44.3 | 72.5 |
| | 1 | | 72.5 | | 0.2 | 44.3 |

As shown in Table 16, in each of the light-emitting devices 10 and 11, the GSP slopes of the first hole-transport layer, the second hole-transport layer, the first electron-transport layer, and the second electron-transport layer are larger than the GSP slope of the light-emitting layer. In the light-emitting device 11, the GSP slope of the second hole-transport layer is larger than the GSP slope of the first hole-transport layer. In the light-emitting device 11, the GSP slope of the first electron-transport layer is larger than the GSP slope of the second electron-transport layer.

Meanwhile, as shown in Table 16, in each of the comparative light-emitting devices 12 and 14, the GSP slopes of the first hole-transport layer, the second hole-transport layer, the first electron-transport layer, and the second electron-transport layer are smaller than the GSP slope of the light-emitting layer. In the comparative light-emitting device 15, the GSP slopes of the first hole-transport layer, the second hole-transport layer, and the first electron-transport layer are smaller than the GSP slope of the light-emitting layer.

As described above, the light-emitting devices 10 and 11 have lower driving voltages than the comparative light-emitting devices 12 to 14. Thus, it was revealed that the inverted stacked light-emitting device can have a low driving voltage when materials used for the layers are selected such that the GSP slopes of the hole-transport layers (the first hole-transport layer and the second hole-transport layer) and the electron-transport layers (the first electron-transport layer and the second electron-transport layer) are larger than the GSP slope of the light-emitting layer. It was also revealed that the inverted stacked light-emitting device having the above structure can have a lower driving voltage when materials used for the layers are selected such that the GSP slope of the layer closer to the second electrode is larger than the GSP slope of the layer closer to the first electrode among a plurality of the hole-transport layers, and the GSP slope of the layer closer to the first electrode is larger than the GSP slope of the layer closer to the second electrode among a plurality of the electron-transport layers. In other words, it was revealed that the inverted stacked light-emitting device can have a low driving voltage when materials used for the layers are selected such that the GSP slopes of the evaporated films of the organic compounds used for the hole-transport layers (the first hole-transport layer and the second hole-transport layer) and the electron-transport layers (the first electron-transport layer and the second electron-transport layer) are larger than the average GSP slope of the evaporated films of the two host materials used for the light-emitting layer. It was also revealed that the inverted stacked light-emitting device having the above structure can have a lower driving voltage when materials used for the layers are selected such that the GSP slope of the evaporated film of the organic compound used for the layer closer to the second electrode is larger than the GSP slope of the evaporated film of the organic compound used for the layer closer to the first electrode among the plurality of hole-transport layers, and the GSP slope of the evaporated film of the organic compound used for the layer closer to the first electrode is larger than the GSP slope of the evaporated film of the organic compound used for the layer closer to the second electrode among the plurality of electron-transport layers.

The above results reveal that the light-emitting device of one embodiment of the present invention has a low driving voltage.

### Reference Synthesis Example 1

This synthesis example describes a method for synthesizing 2-(biphenyl-2-yl)-4-[3-(3,5-dicyclohexylphenyl)-5-(2,6-dimethylpyridin-3-yl)]phenyl-6-phenyl-1,3,5-triazine (abbreviation: oBP-mmchPh-mDMePyPTzn), which is the organic compound used for the light-emitting device of one embodiment of the present invention in Examples 1 and 2. The structural formula of oBP-mmchPh-mDMePyPTzn is shown below.

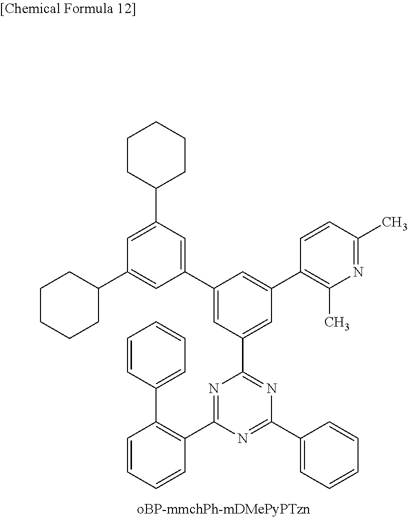 [SMILES: Cc1ccc(-c2cc(-c3cc(C4CCCCC4)cc(C4CCCCC4)c3)cc(-c3nc(-c4ccccc4)nc(-c4ccccc4-c4ccccc4)n3)c2)c(C)n1]

### Step 1: Synthesis of 2-(biphenyl-2-yl)-4-[3-chloro-5-(4,4,5,5-tetramethyl-1,3,2-dioxaborolan-2-yl)phenyl]-6-phenyl-1,3,5-triazine

Into a three-neck flask were put 9.2 g of 2-(biphenyl-2-yl)-4-(3-bromo-5-chlorophenyl)-6-phenyl-1,3,5-triazine, 5.2 g of bis(pinacolato)diboron, 5.5 g of potassium acetate, and 65 mL of N,N-dimethylformamide (abbreviation: DMF), and the mixture was degassed. To this mixture was added 0.57 g of [1,1′-bis(diphenylphosphino) ferrocene]palladium (II) dichloride dichloromethane adduct (abbreviation: Pd (dppf)₂Cl₂·CH₂Cl₂), and reaction was caused at 100° C. for 14.5 hours. After the reaction, extraction was performed with toluene, and magnesium sulfate was added to the obtained organic layer to adsorb moisture. This mixture was gravity-filtered, and the obtained filtrate was concentrated to give black oil. This oil was purified by silica gel column chromatography with a developing solvent of toluene and hexane in a ratio of 1:1, which was then changed to only toluene, to give 8.5 g of a target light-green solid in a yield of 84%. The synthesis scheme of Step 1 is shown in Formula (a-1) below.

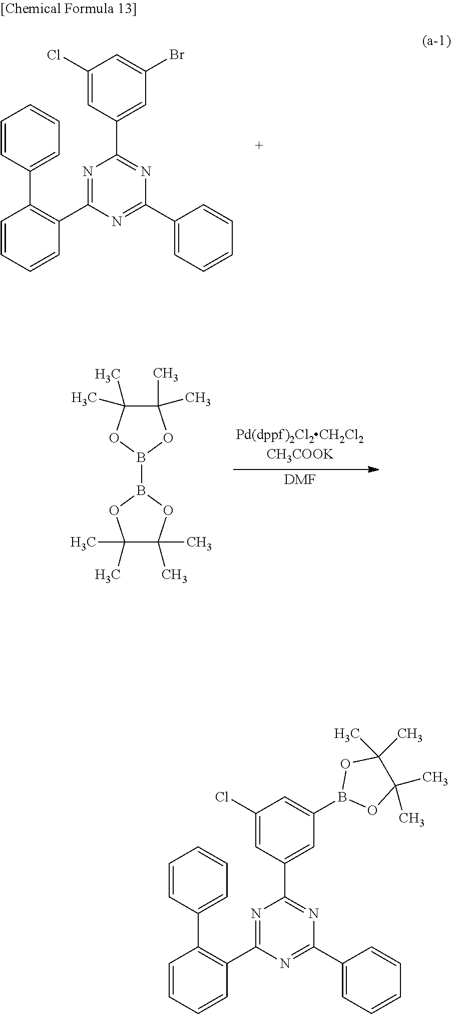

### Step 2: Synthesis of 2-(biphenyl-2-yl)-4-[3-chloro-5-(2,6-dimethylpyridin-3-yl)phenyl]-6-phenyl-1,3,5-triazine

Into a three-neck flask were put 5.2 g of 2-(biphenyl-2-yl)-4-[3-chloro-5-(4,4,5,5-tetramethyl-1,3,2-dioxaborolan-2-yl)phenyl]-6-phenyl-1,3,5-triazine obtained in Step 1, 1.5 g of 3-bromo-2,6-dimethylpyridine, 50 mL of tetrahydrofuran, and 14 mL of an aqueous solution of tripotassium phosphate (2 mol/L), and the mixture was degassed. To this mixture were added 19 mg of palladium (II) acetate and 79 mg of 2-dicyclohexylphosphino-2′,4′,6′-triisopropylbiphenyl (abbreviation: XPhos), and the mixture was stirred at 65° C. for 13 hours. After the reaction, extraction was performed with toluene, and magnesium sulfate was added to the obtained organic layer to adsorb moisture. This mixture was gravity-filtered, and the obtained filtrate was concentrated to give yellow oil. This oil was purified by silica gel column chromatography with a developing solvent of ethyl acetate and toluene in a ratio of 1:50, which was then changed to 1:20, to give light-yellow oil. This oil was subjected to purification by high performance liquid chromatography using chloroform as a mobile phase to give 3.4 g of a target white solid in a yield of 79%. The synthesis scheme of Step 2 is shown in Formula (a-2) below.

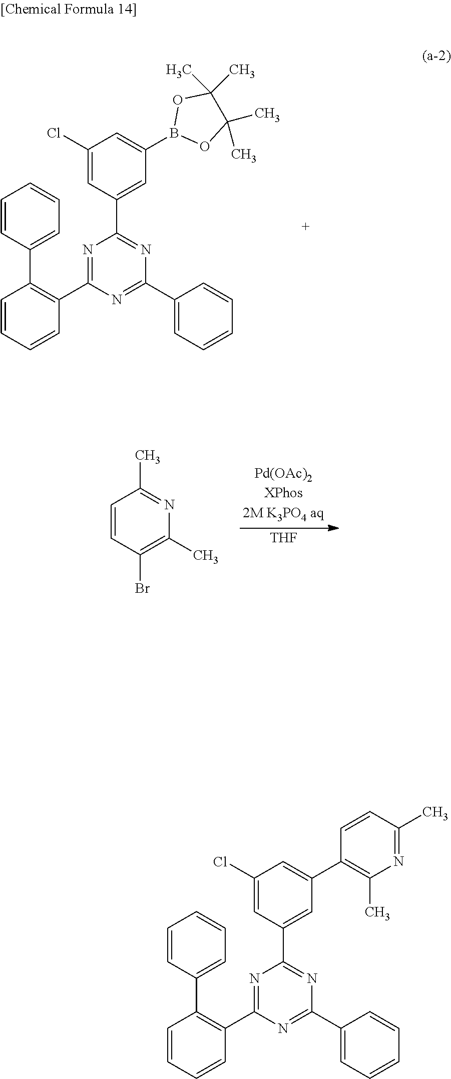

### Step 3: Synthesis of 2-(biphenyl-2-yl)-4-[3-(4,4,5,5-tetramethyl-1,3,2-dioxaborolan-2-yl)-5-(2,6-dimethylpyridin-3-yl)phenyl]-6-phenyl-1,3,5-triazine

Into a three-neck flask were put 3.4 g of 2-(biphenyl-2-yl)-4-[3-chloro-5-(2,6-dimethylpyridin-3-yl)phenyl]-6-phenyl-1,3,5-triazine obtained in Step 2, 2.5 g of bis(pinacolato)diboron, 1.9 g of potassium acetate, and 80 mL of 1,4-dioxane, and the mixture was degassed. To this mixture were added 15 mg of palladium (II) acetate and 62 mg of XPhos, and the mixture was stirred at 100° C. for 15.5 hours. After the reaction, extraction was performed with toluene, and magnesium sulfate was added to the obtained organic layer to adsorb moisture. This mixture was gravity-filtered, and the obtained filtrate was concentrated to give a gray solid. This solid was purified by silica gel column chromatography with a developing solvent of toluene and ethyl acetate in a ratio of 5:1, which was then changed to 2:1, to give 4.2 g of a light-yellow solid containing the target substance. The synthesis scheme of Step 3 is shown in Formula (a-3) below.

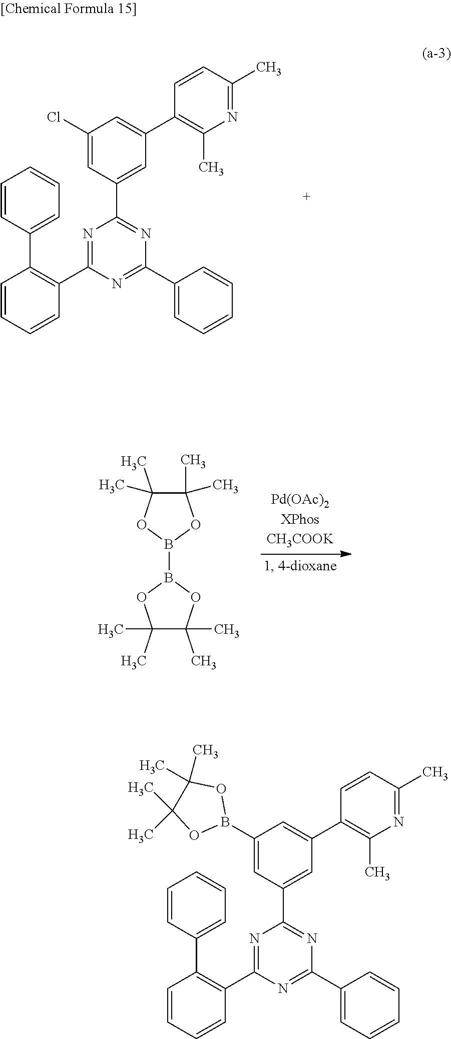

### Step 4: Synthesis of oBP-mmchPh-mDMePyPTzn

Into a three-neck flask were put 4.2 g of 2-(biphenyl-2-yl)-4-[3-(4,4,5,5-tetramethyl-1,3,2-dioxaborolan-2-yl)-5-(2,6-dimethylpyridin-3-yl)phenyl]-6-phenyl-1,3,5-triazine obtained in Step 3, 2.3 g of 3,5-dicyclohexyl-1-phenyltrifluoromethanesulfonate, 1.9 g of potassium carbonate, 65 mL of toluene, 13 mL of ethanol, and 7 mL of water, and the mixture was degassed. To this mixture were added 30 mg of palladium (II) acetate and 0.28 g of 2-dicyclohexylphosphino-2′,6′-dimethoxybiphenyl (abbreviation: SPhos), and reaction was caused at 80° C. for 13 hours. After the reaction, extraction was performed with toluene, and magnesium sulfate was added to the obtained organic layer to adsorb moisture. This mixture was gravity-filtered, and the obtained filtrate was concentrated to give brown oil. This oil was purified by silica gel column chromatography with a developing solvent of toluene and ethyl acetate in a ratio of 20:1, which was then changed to 10:1, to give 4.04 g of a white solid. This solid was recrystallized from toluene and ethanol to give 3.9 g of a target white solid in a yield of 91%. The synthesis scheme of Step 4 is shown in Formula (a-4) below.

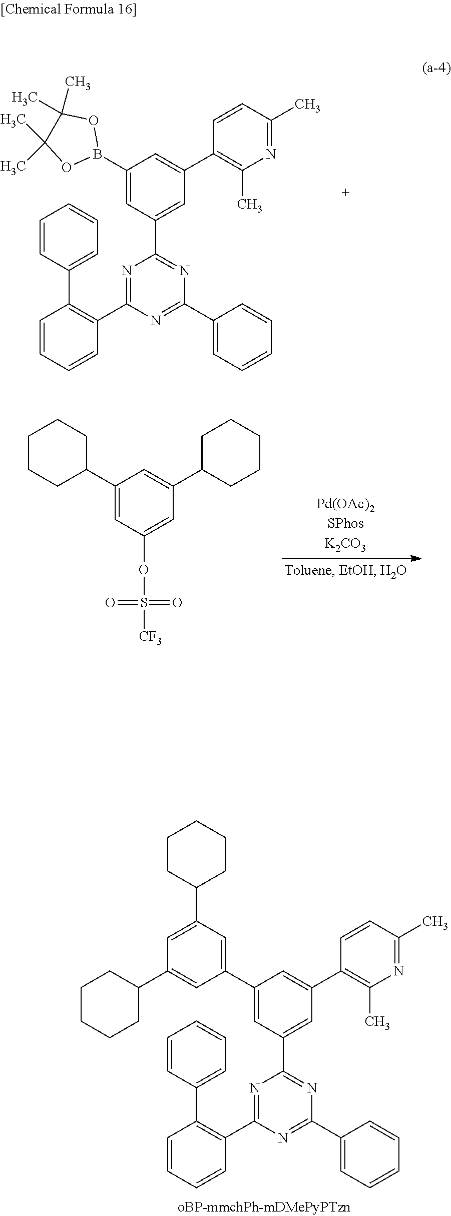

Then, 3.9 g of the obtained white solid was purified by a train sublimation method. In the purification by sublimation, the solid was heated under a pressure of 2.4 Pa at 290° C. for 22 hours while an argon gas was made to flow. After the purification by sublimation, 3.4 g of a target white solid was obtained at a collection rate of 87%.

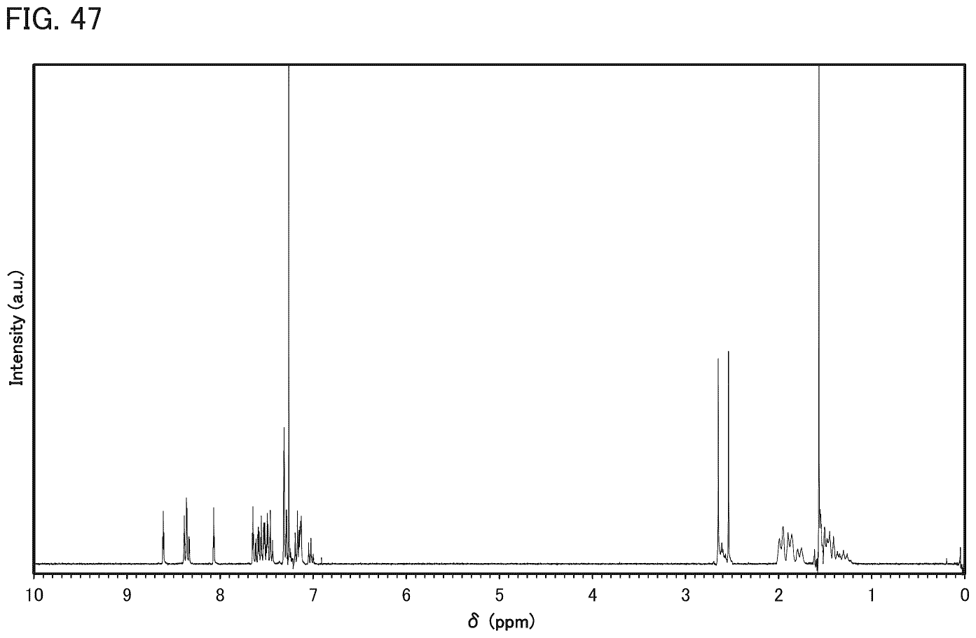

Analysis results by nuclear magnetic resonance (¹H NMR) spectroscopy of the obtained white solid are shown below. FIG. 47 is the ¹H NMR chart. The results confirm that oBP-mmchPh-mDMePyPTzn was obtained.

¹H NMR (CDCl₃, 300 MHz): δ=1.27-1.55 (m, 11H), 1.75-2.00 (m, 11H), 2.54 (s, 3H), 2.65 (s, 3H), 7.02 (tt, 1H, J=7.4 Hz, 1.7 Hz), 7.13-7.19 (m, 4H), 7.29-7.32 (m, 4H), 7.43-7.65 (m, 8H), 8.07 (t, 1H, J=1.7 Hz), 8.33-8.39 (m, 3H), 8.61 (t, 1H, J=1.7 Hz).

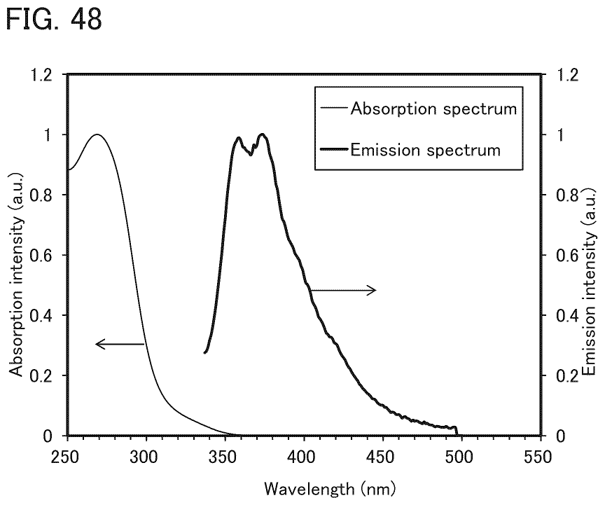

Next, an ultraviolet-visible absorption spectrum (hereinafter, simply referred to as an “absorption spectrum”) of a dichloromethane solution of oBP-mmchPh-mDMePyPTzn and an emission spectrum thereof were measured. The absorption spectrum was measured with an ultraviolet-visible spectrophotometer (V-770DS, manufactured by JASCO Corporation). The emission spectrum was measured with a fluorescence spectrophotometer (FP-8600, manufactured by JASCO Corporation). FIG. 48 shows the obtained absorption and emission spectra of the dichloromethane solution of oBP-mmchPh-mDMePyPTzn. The horizontal axis represents the wavelength and the vertical axes represent the absorption intensity and the emission intensity.

As shown by the results in FIG. 48, the dichloromethane solution of oBP-mmchPh-mDMePyPTzn exhibited an absorption peak at around 269 nm and emission peaks at around 373 nm and 358 nm (an excitation wavelength: 300 nm).

### Reference Synthesis Example 2

This synthesis example describes a method for synthesizing 2-[3,5-bis(2,6-dimethylpyridin-3-yl)phenyl]-4-(3′,5′-di-tert-butylbiphenyl-4-yl)-6-phenyl-1,3,5-triazine (abbreviation: mmtBuBP-DMePy2PTzn), which is the organic compound used for the light-emitting device of one embodiment of the present invention in Example 2. The structural formula of mmtBuBP-DMePy2PTzn is shown below.

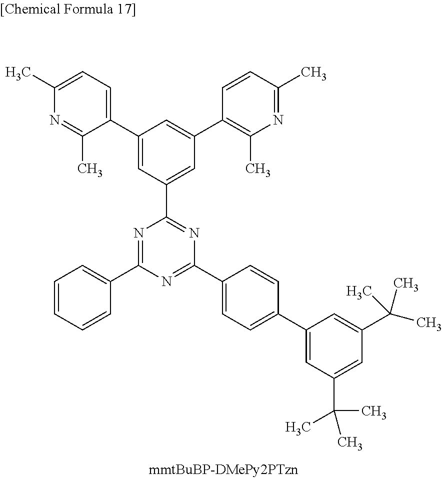 [SMILES: Cc1ccc(-c2cc(-c3nc(-c4ccccc4)nc(-c4ccc(-c5cc(C(C)(C)C)cc(C(C)(C)C)c5)cc4)n3)cc(-c3ccc(C)nc3C)c2)c(C)n1]

### Step 1: Synthesis of 2-(3′,5′-di-tert-butylbiphenyl-4-yl)-4-chloro-6-phenyl-1,3,5-triazine

Into a three-neck flask were put 8.0 g of 2,4-dichloro-6-phenyl-1,3,5-triazine, 13.9 g of 2-(3′,5′-di-tert-butylbiphenyl-4-yl)-4,4,5,5-tetramethyl-1,3,2-dioxaborolane, 140 mL of toluene, 35 mL of ethanol, and 35 mL of an aqueous solution of potassium carbonate (2 mol/L), and the mixture was degassed. To this mixture were added 79 mg of palladium (II) acetate (abbreviation: Pd(OAc)₂) and 0.22 g of tris(2-methylphenyl)phosphine (abbreviation: P(o-tolyl)₃), and the mixture was stirred at room temperature for 72 hours. After the reaction, the reacted solution was filtered. The filtrate was collected, extraction was performed with toluene, and magnesium sulfate was added to the obtained organic layer to adsorb moisture. This mixture was gravity-filtered, and the obtained filtrate was concentrated to give yellow oil. This oil was purified by silica gel column chromatography with a developing solvent of toluene and hexane in a ratio of 1:8, which was then changed to 1:2, to give 7.1 g of a target white solid in a yield of 44%. The synthesis scheme of Step 1 is shown in Formula (b-1) below.

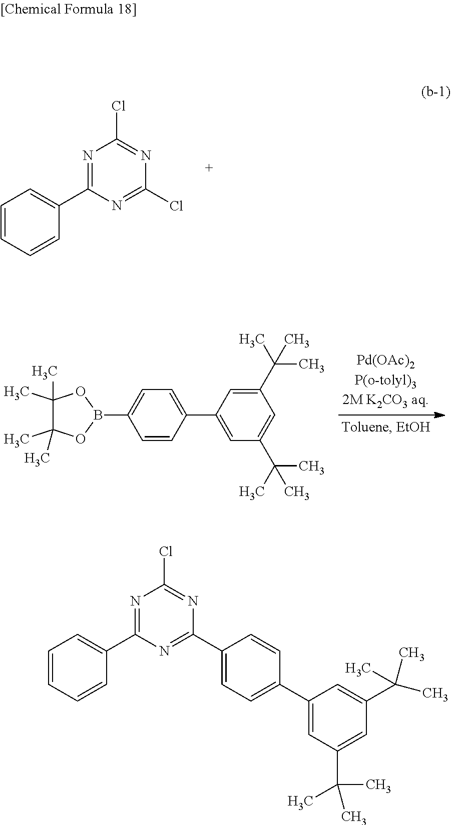 [SMILES: Clc1nc(Cl)nc(-c2ccccc2)n1 ; CC(C)(C)c1cc(-c2ccc(B3OC(C)(C)C(C)(C)O3)cc2)cc(C(C)(C)C)c1 ; CC(C)(C)c1cc(-c2ccc(-c3nc(Cl)nc(-c4ccccc4)n3)cc2)cc(C(C)(C)C)c1]

### Step 2: Synthesis of 2-(3,5-dibromophenyl)-4-(3′,5′-di-tert-butylbiphenyl-4-yl)-6-phenyl-1,3,5-triazine

Into a three-neck flask were put 7.2 g of 2-(3′,5′-di-tert-butylbiphenyl-4-yl)-4-chloro-6-phenyl-1,3,5-triazine obtained in Step 1, 3.9 g of 3,5-dibromophenylboronic acid, 3.3 g of sodium carbonate, 60 mL of toluene, 12 mL of ethanol, and 15 mL of water, and the mixture was degassed. To this mixture was added 0.36 g of tetrakis(triphenylphosphine) palladium (0) (abbreviation: Pd(PPh₃)₄), and the mixture was stirred while being heated at 70° C. for 15 hours. The reaction solution was filtered, and a residue and a filtrate were collected. The filtrate was subjected to extraction with toluene, and magnesium sulfate was added to the obtained organic layer to adsorb moisture. This mixture was gravity-filtered, and the obtained filtrate was concentrated to give yellow oil. This yellow oil was purified by silica gel column chromatography with a developing solvent of toluene and hexane in a ratio of 1:5, which was then changed to 2:5, to give a white solid. This white solid and the residue obtained by the filtration of the reaction solution were combined and then subjected to purification by high performance liquid chromatography using chloroform as a mobile phase to give 5.7 g of a target white solid in a yield of 63%. The synthesis scheme of Step 2 is shown in Formula (b-2) below.

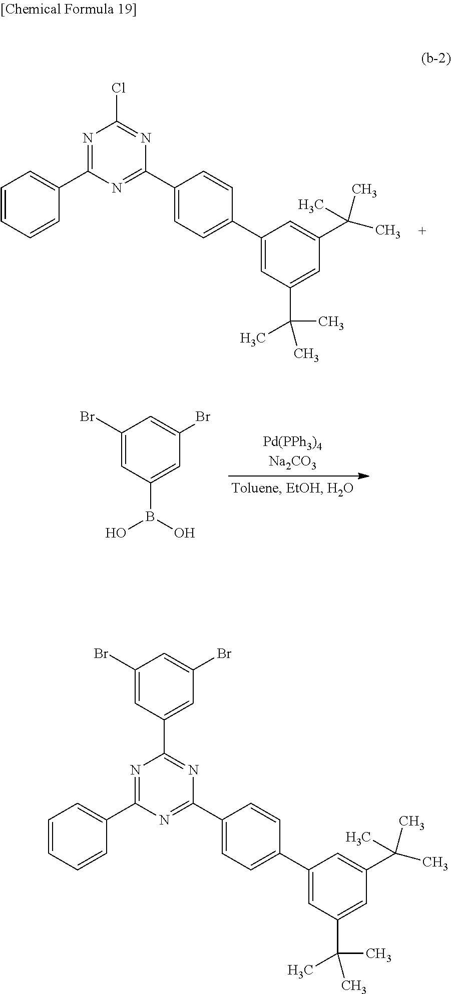 [SMILES: CC(C)(C)c1cc(-c2ccc(-c3nc(Cl)nc(-c4ccccc4)n3)cc2)cc(C(C)(C)C)c1 ; OB(O)c1cc(Br)cc(Br)c1 ; CC(C)(C)c1cc(-c2ccc(-c3nc(-c4ccccc4)nc(-c4cc(Br)cc(Br)c4)n3)cc2)cc(C(C)(C)C)c1]

### Step 3: Synthesis of 2-(3′,5′-di-tert-butylbiphenyl-4-yl)-4-[3,5-bis(4,4,5,5-tetramethyl-1,3,2-dioxaborolan-2-yl)phenyl]-6-phenyl-1,3,5-triazine

Into a three-neck flask were put 5.7 g of 2-(3,5-dibromophenyl)-4-(3′,5′-di-tert-butylbiphenyl-4-yl)-6-phenyl-1,3,5-triazine obtained in Step 2, 5.1 g of bis(pinacolato)diboron, 5.1 g of potassium acetate, and 50 mL of N,N-dimethylformamide (abbreviation: DMF), and the mixture was degassed. To this mixture was added 0.71 g of [1,1′-bis(diphenylphosphino) ferrocene]palladium (II) dichloride dichloromethane adduct (abbreviation: Pd(dppf)₂Cl₂·CH₂Cl₂), and the mixture was stirred while being heated at 100° C. for 6.5 hours. After the reaction, extraction was performed with toluene, and magnesium sulfate was added to the obtained organic layer to adsorb moisture. This mixture was gravity-filtered, and the obtained filtrate was concentrated to give black oil. This black oil was purified by silica gel column chromatography with a developing solvent of only toluene, which was then changed to toluene and ethyl acetate in a ratio of 10:1, to give 7.0 g of a light-brown solid containing the target substance. The synthesis scheme of Step 3 is shown in Formula (b-3) below.

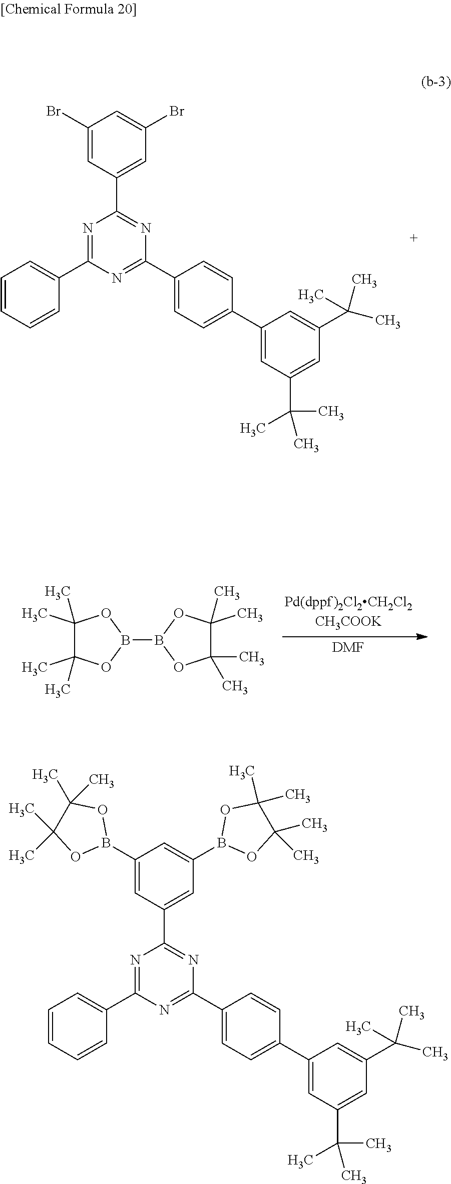

### Step 4: Synthesis of mmtBuBP-DMePy2PTzn

Into a three-neck flask were put 3.5 g of 2-(3′,5′-di-tert-butylbiphenyl-4-yl)-4-[3,5-bis(4,4,5,5-tetramethyl-1,3,2-dioxaborolan-2-yl)phenyl]-6-phenyl-1,3,5-triazine obtained in Step 3, 1.6 g of 3-bromo-2,6-dimethylpyridine, 46 mL of tetrahydrofuran (abbreviation: THF), and 14 mL of an aqueous solution of tripotassium phosphate (2 mol/L), and the mixture was degassed. To this mixture were added 21 mg of Pd(OAc)₂ and 89 mg of 2-dicyclohexylphosphino-2′,4′,6′-triisopropylbiphenyl (abbreviation: XPhos), and the mixture was stirred while being heated at 65° C. for 11 hours. After the reaction, extraction was performed with toluene, and magnesium sulfate was added to the obtained organic layer to adsorb moisture. This mixture was gravity-filtered, and the obtained filtrate was concentrated to give a light-yellow solid. This light-yellow solid was purified by silica gel column chromatography with a developing solvent of toluene and ethyl acetate in a ratio of 2:1, which was then changed to 1:1. The obtained solid was recrystallized from toluene and ethanol to give 2.0 g of a target white solid in a yield of 62%. Then, 2.0 g of the obtained white solid was purified by a train sublimation method. In the purification by sublimation, the solid was heated at 280° C. for 19 hours and then at 285° C. for 25 hours under a pressure of 2.3 Pa while an argon gas was made to flow. After the purification by sublimation, 1.7 g of a target white solid was obtained at a collection rate of 84%. The synthesis scheme of Step 4 is shown in Formula (b-4) below.

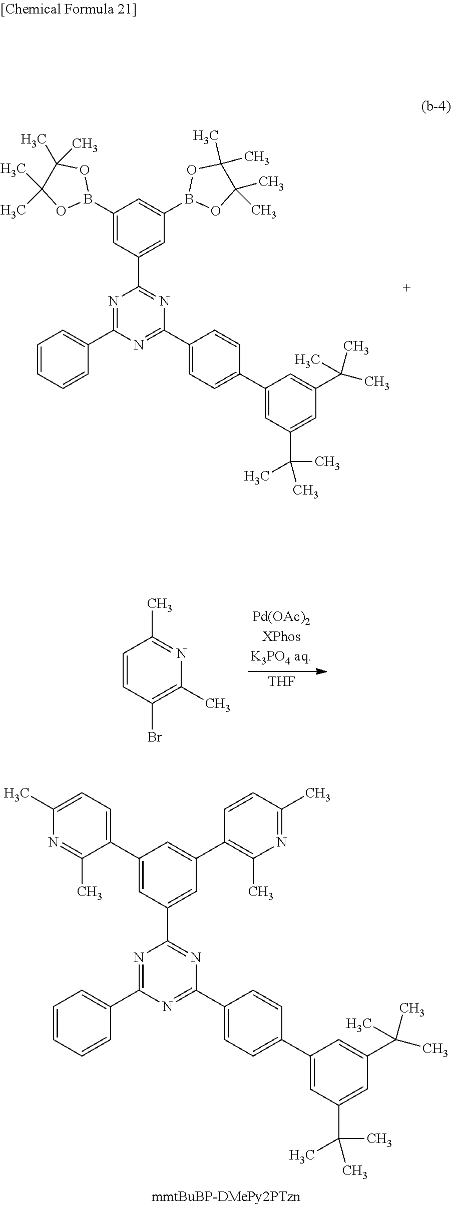

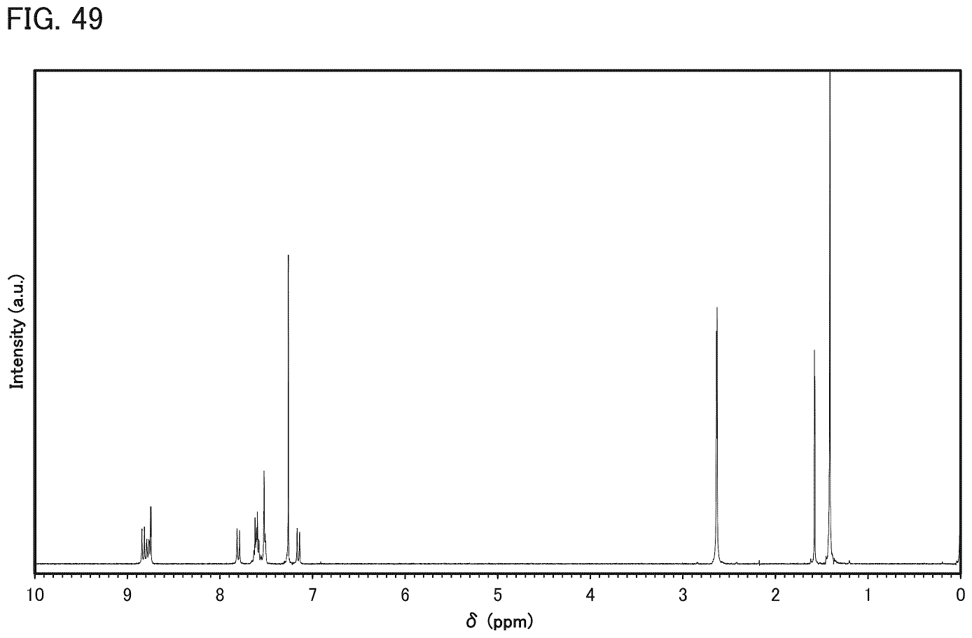

Analysis results by nuclear magnetic resonance (¹H NMR) spectroscopy of the white solid obtained in Step 4 are shown below. FIG. 49 is the ¹H NMR chart. The results confirm that mmtBuBP-DMePy2PTzn was obtained in this synthesis example.

¹H NMR (CDCl₃, 300 MHz): δ=1.41 (s, 18H), 2.63 (s, 6H), 2.64 (s, 6H), 7.15 (d, 2H, J=7.8 Hz), 7.50-7.63 (m, 9H), 7.80 (d, 2H, J=8.1 Hz), 8.74-8.85 (m, 6H).

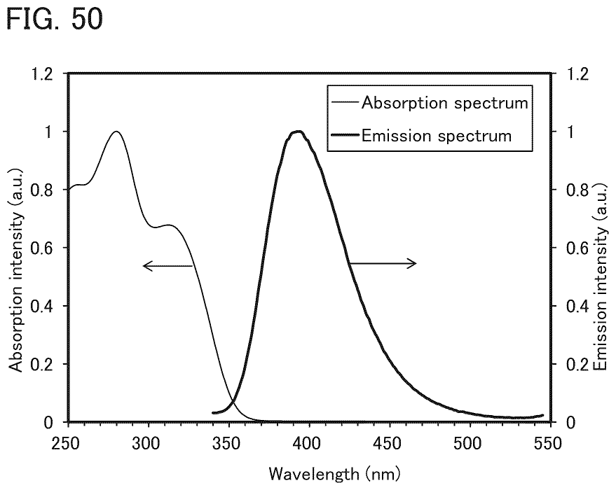

Next, an ultraviolet-visible absorption spectrum (hereinafter, simply referred to as an “absorption spectrum”) of a dichloromethane solution of mmtBuBP-DMePy2PTzn and an emission spectrum thereof were measured. The absorption spectrum was measured with an ultraviolet-visible spectrophotometer (V-770DS, manufactured by JASCO Corporation). The emission spectrum was measured with a fluorescence spectrophotometer (FP-8600, manufactured by JASCO Corporation). FIG. 50 shows the obtained absorption and emission spectra of the dichloromethane solution of mmtBuBP-DMePy2PTzn. The horizontal axis represents the wavelength and the vertical axes represent the absorption intensity and the emission intensity.

As shown in FIG. 50, the dichloromethane solution of mmtBuBP-DMePy2PTzn exhibited absorption peaks at around 280 nm and 312 nm and an emission peak at around 394 nm (an excitation wavelength: 280 nm).

### Reference Synthesis Example 3

This synthesis example describes a method for synthesizing N-(3′,5′-ditertiarybutylbiphenyl-4-yl)-N-(3′,5′-ditertiarybutylbiphenyl-2-yl)-9,9-dimethyl-9H-fluoren-2-amine (abbreviation: dmmtBuopBBAF), which is the organic compound used for the light-emitting device of one embodiment of the present invention in Example 2. The structural formula of dmmtBuopBBAF is shown below.

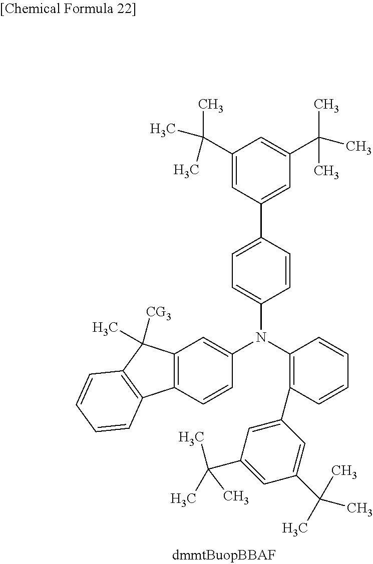

### Step 1: Synthesis of 3′,5′-di-tert-butyl-4-chlorobiphenyl

Into a 2000-mL three-neck flask were put 30 g (0.11 mol) of 3,5-di-tert-butyl-1-bromobenzene, 19 g (0.12 mmol) of 4-chlorophenylboronic acid, 46 g (0.33 mol) of potassium carbonate, 550 mL of toluene, 140 mL of ethanol, and 160 mL of water, the mixture was degassed by being stirred under reduced pressure, and the air in the flask was replaced with nitrogen. After that, to this mixture were added 0.25 g (1.1 mmol) of palladium acetate and 0.70 g (2.3 mmol) of tris(2-methylphenyl)phosphine, and the mixture was stirred while being heated at 90° C. for approximately 5 hours. Then, the temperature of the flask was lowered to room temperature, separation was performed, and the organic layer was washed with a saturated aqueous solution of sodium carbonate and saturated brine. The obtained organic layer was dried with magnesium sulfate, and then filtration was performed. The filtrate was concentrated, and the obtained solution was purified by silica gel column chromatography. The resulting solution was concentrated to give a concentrated toluene solution. The toluene solution was dropped into ethanol for reprecipitation. The suspension was cooled, the precipitate was collected by filtration at approximately 10° C., and the obtained solid was dried at approximately 60° C. under reduced pressure to give 30 g of a target white solid in a yield of 89%. The synthesis scheme of Step 1 is shown in Formula (c-1) below.

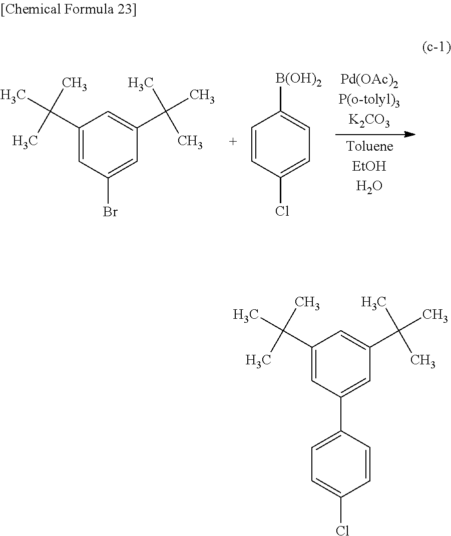 [SMILES: CC(C)(C)c1cc(Br)cc(C(C)(C)C)c1 ; OB(O)c1ccc(Cl)cc1 ; CC(C)(C)c1cc(-c2ccc(Cl)cc2)cc(C(C)(C)C)c1]

### Step 2: Synthesis of N-(3′,5′-di-tert-butylbiphenyl-2-yl)-9,9-dimethyl-9H-fluoren-2-amine

Into a 50-mL three-neck flask were put 3.6 g (10 mmol) of 2-bromo-3′,5′-di-tert-butylbiphenyl, 1.1 g (5.3 mmol) of 9,9-dimethyl-9H-fluoren-2-amine, 1.7 g (18 mmol) of sodium tert-butoxide, and 26 mL of mesitylene, the mixture was degassed by being stirred under reduced pressure, and the air in the flask was replaced with nitrogen. After that, to this mixture were added 40 mg (0.11 mmol) of allylpalladium (II) chloride dimer (abbreviation: (AllylPdCl)₂) and 0.10 mL of a 10% hexane solution of tri-tert-butylphosphine, and the mixture was stirred while being heated at approximately 140° C. for approximately 2 hours. Then, the temperature of the flask was lowered to room temperature, approximately 2 mL of water was added to the mixture, and a precipitated solid was separated by filtration. The filtrate was concentrated, and the obtained concentrated solution was purified by silica gel column chromatography. The resulting solution was concentrated and then dried at room temperature under reduced pressure to give 4.4 g of a target brown oily substance in a yield of 89%. The synthesis scheme of Step 2 is shown in Formula (c-2) below.

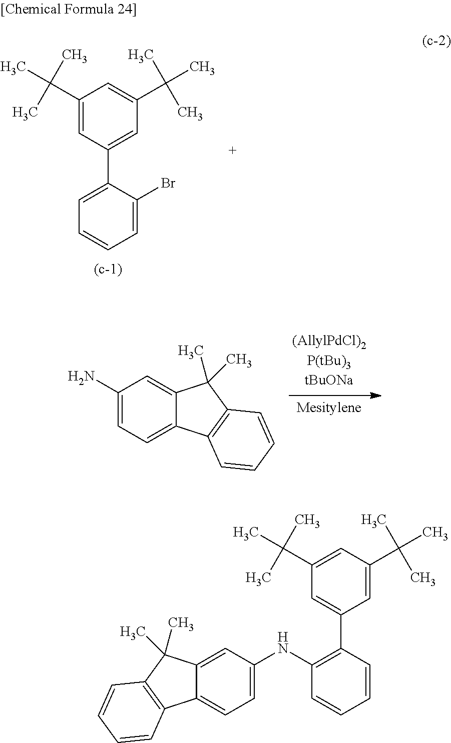 [SMILES: CC(C)(C)c1cc(-c2ccccc2Br)cc(C(C)(C)C)c1 ; CC1(C)c2ccccc2-c2ccc(N)cc21 ; CC(C)(C)c1cc(-c2ccccc2Nc2ccc3c(c2)C(C)(C)c2ccccc2-3)cc(C(C)(C)C)c1]

### Step 3: Synthesis of dmmtBuopBBAF

Into a 200-mL three-neck flask were put 3.2 g (6.8 mmol) of N-(3′,5′-di-tert-butylbiphenyl-2-yl)-9,9-dimethyl-9H-fluoren-2-amine, 2.2 g (7.3 mmol) of 3′,5′-di-tert-butyl-4-chlorobiphenyl, 2.0 g (21 mmol) of sodium tert-butoxide, and 38 mL of xylene, the mixture was degassed by being stirred under reduced pressure, and the air in the flask was replaced with nitrogen. After that, to this mixture were added 29 mg (79 μmol) of allylpalladium (II) chloride dimer (abbreviation: (AllylPdCl)₂) and 0.10 g (0.28 mmol) of di-tert-butyl (1-methyl-2,2-diphenylcyclopropyl)phosphine (abbreviation: cBRIDP (registered trademark)), and the mixture was stirred while being heated at 160° C. for approximately 12 hours. Then, the temperature of the flask was lowered to 70° C., approximately 2 mL of water was added to the mixture, and a precipitated solid was separated by filtration. The filtrate was concentrated, and the obtained concentrated solution was purified by silica gel column chromatography. The resulting solution was concentrated to give a concentrated toluene solution. The toluene solution was dropped into ethanol for reprecipitation. The precipitate was collected by filtration at approximately 10° C., and the obtained solid was dried at approximately 130° C. under reduced pressure to give 2.5 g of a target white solid in a yield of 50%. The synthesis scheme of Step 3 is shown in Formula (c-3) below.

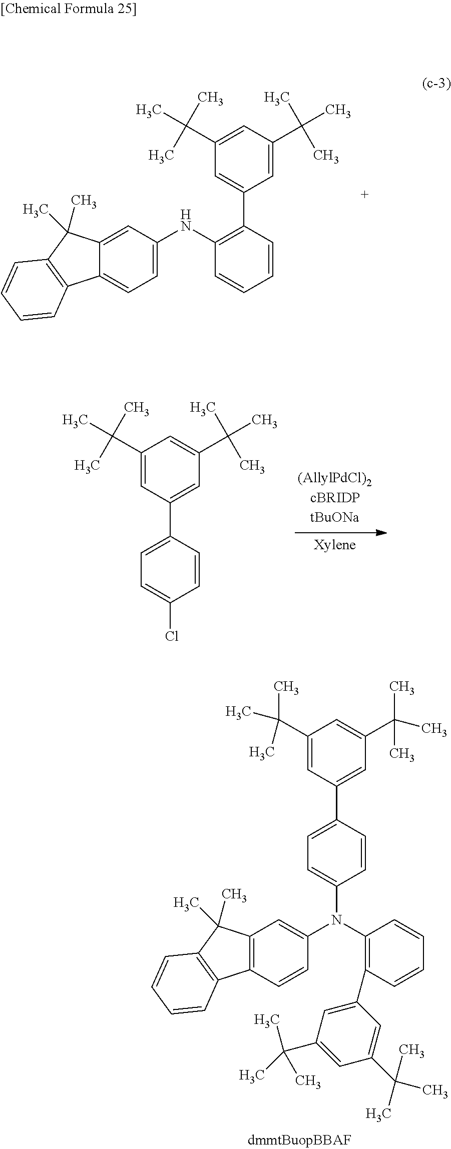

Then, 2.5 g of the obtained white solid was purified by a train sublimation method. In the purification by sublimation, a boat in which the white solid was put was heated under conditions where the argon flow rate was 10 mL/min and the pressure was 2.5 Pa. The boat was sandwiched between two heating bands, and the heating temperature of one of the heating bands was set to 222° C. and the heating temperature of the other heating band was set to 217° C. The heating temperature in a portion where a material was collected was set to 185° C., and the heating was performed for approximately 29 hours. After the purification by sublimation, 2.2 g of a light-yellow glassy solid was obtained at a collection rate of 88%.

Analysis results by 1H NMR spectroscopy of the obtained light-yellow glassy solid are shown below. The results confirm that dmmtBuopBBAF was obtained in this synthesis example.

¹H NMR (CDCl₃, 300 MHz): δ=7.57 (d, 1H, J=7.0 Hz), 7.47-7.28 (m, 10H), 7.25-7.20 (m, 3H), 7.10 (t, 1H, J=1.8 Hz), 7.05-7.00 (m, 3H), 6.89-6.85 (m, 3H), 1.36 (s, 18H), 1.35 (s, 6H), 1.11 (s, 18H).

### Reference Synthesis Example 4

This synthesis example describes a method for synthesizing 4-(9H-carbazol-9-yl)-8-[3-(triphenylsilyl)phenyl]-[1]benzofuro[3,2-d]pyrimidine (abbreviation: 8PSi-4CzBfpm), which is the organic compound used for the light-emitting device of one embodiment of the present invention in Example 1. The structural formula of 8PSi-4CzBfpm is shown below.

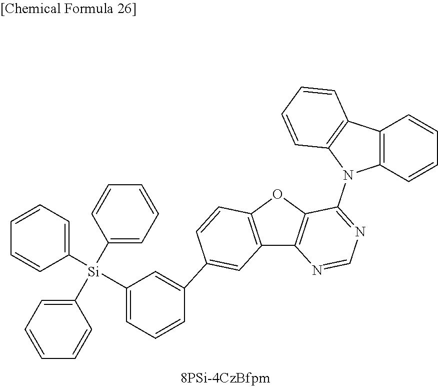 [SMILES: c1ccc([Si](c2ccccc2)(c2ccccc2)c2cccc(-c3ccc4oc5c(-n6c7ccccc7c7ccccc76)ncnc5c4c3)c2)cc1]

### Step 1: Synthesis of 4-(9H-carbazol-9-yl)-8-chloro-[1]benzofuro[3,2-d]pyrimidine

First, in Step 1, 4-(9H-carbazol-9-yl)-8-chloro-[1]benzofuro[3,2-d]pyrimidine was synthesized. Step 1 was performed in the following procedure.

Into a 300-mL three-neck flask were put 6.4 g (27 mmol) of 4,8-dichloro-[1]benzofuro[3,2-d]pyrimidine, 4.5 g (27 mmol) of 9H-carbazole, and 5.7 g (27 mmol) of tripotassium phosphate. To this mixture was added 135 mL of dimethylsulfoxide, and the mixture was stirred while being heated under a nitrogen stream at 90° C. for 6 hours. After the stirring, water was added to the mixture, and the solid was collected by suction filtration. Toluene was added to the obtained solid, heating and stirring were performed, and a solid was collected, whereby 7.5 g of a light-brown solid was obtained in a yield of 75%. The synthesis scheme of Step 1 is shown in (d-1) below.

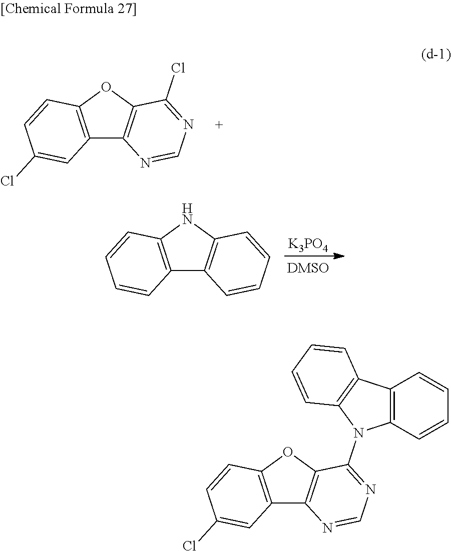

Analysis results by nuclear magnetic resonance spectroscopy (1H NMR) of a deuterated chloroform (abbreviation: CDCl₃) solution of the light-brown solid obtained in Step 1 are shown below. The results confirm that 4-(9H-carbazol-9-yl)-8-chloro-[1]benzofuro[3,2-d]pyrimidine was obtained.

¹H NMR (CDCl₃, 300 MHz): δ=7.39-7.52 (m, 4H), 7.59 (d, J1=8.7 Hz, 1H), 7.68 (dd, J1=8.7 Hz, J2=1.8 Hz, 1H), 7.81 (d, J1=8.1 Hz, 2H), 8.15 (d, J1=7.5 Hz, 2H), 8.31 (d, J1=2.1 Hz, 1H), 9.28 (s, 1H).

### Step 2: Synthesis of 8PSi-4CzBfpm

Next, 8PSi-4CzBfpm was synthesized using 4-(9H-carbazol-9-yl)-8-chloro-[1]benzofuro[3,2-d]pyrimidine obtained in Step 1. Step 2 was performed in the following procedure.

Into a 200-mL three-neck flask were put 1.7 g (4.5 mmol) of 4-(9H-carbazol-9-yl)-8-chloro-[1]benzofuro[3,2-d]pyrimidine obtained in Step 1, 2.3 g (4.9 mmol) of 2-[3-(triphenylsilyl)phenyl]-4,4,5,5-tetramethyl-1,3,2-dioxaborolane, 96 mg (0.27 mmol) of di(1-adamantyl)-n-butylphosphine, 2.9 g (13 mmol) of tripotassium phosphate, and 1.0 g (13 mmol) of tert-butanol. To this mixture was added 40 mL of diethylene glycol dimethyl ether. The mixture was degassed by being stirred while the pressure was reduced. To this mixture was added 30 mg (0.13 mmol) of palladium (II) acetate, and the mixture was stirred under a nitrogen stream at 120° C. for 6 hours. After the stirring, water was added to the mixture, and the solid was collected by suction filtration. This solid was purified by silica gel column chromatography (developing solvent:toluene and then toluene and ethyl acetate in a 50:1 ratio). The obtained solid was recrystallized from ethyl acetate to give 2.3 g of a white solid in a yield of 77%. Then, 2.3 g of the obtained solid was purified by a train sublimation method. The purification by sublimation was performed by heating at 290° C. under a pressure of 3.6 Pa with an argon flow rate of 15 mL/min. After the sublimation purification, 2.2 g of a white solid was obtained at a collection rate of 94%. The synthesis scheme of Step 2 is shown in (d-2) below.

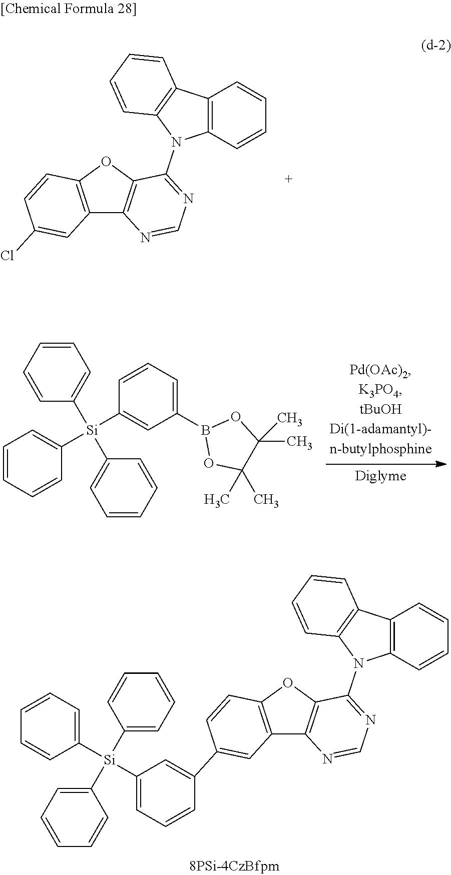 [SMILES: Clc1ccc2oc3c(-n4c5ccccc5c5ccccc54)ncnc3c2c1 ; CC1(C)OB(c2cccc([Si](c3ccccc3)(c3ccccc3)c3ccccc3)c2)OC1(C)C ; c1ccc([Si](c2ccccc2)(c2ccccc2)c2cccc(-c3ccc4oc5c(-n6c7ccccc7c7ccccc76)ncnc5c4c3)c2)cc1]

### <Characteristics of Organic Compound>

Analysis results by nuclear magnetic resonance spectroscopy (1H NMR) of a CDCl₃ solution of the white solid obtained in Step 2 are shown below. The results confirm that 8PSi-4CzBfpm was obtained in this synthesis example.

¹H NMR (CDCl₃, 300 MHz): δ=7.39-7.68 (m, 22H), 7.76-7.90 (m, 5H), 8.15 (d, J1=7.5 Hz, 2H), 8.47 (d, J1=1.5 Hz, 1H), 9.27 (s, 1H).

### Reference Synthesis Example 5

This synthesis example describes a method for synthesizing 4-(9H-carbazol-9-yl)-8-(dibenzofuran-2-yl)-[1]benzofuro-[3,2-d]pyrimidine (abbreviation: 8DBf-4CzBfpm), which is the organic compound used for the light-emitting device of one embodiment of the present invention in Examples 1 and 2. The structural formula of 8DBf-4CzBfpm is shown below.

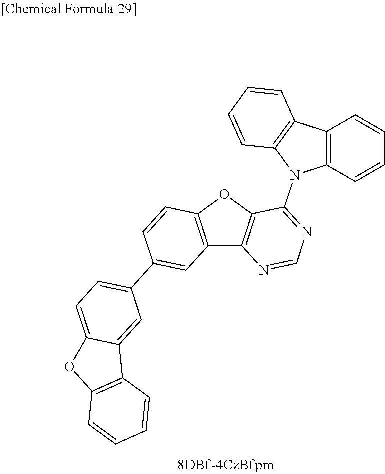 [SMILES: c1ccc2c(c1)oc1ccc(-c3ccc4oc5c(-n6c7ccccc7c7ccccc76)ncnc5c4c3)cc12]

### Synthesis of 8DBf-4CzBfpm

Using 4-(9H-carbazol-9-yl)-8-chloro-[1]benzofuro[3,2-d]pyrimidine obtained in Step 1 of Reference synthesis example 4, 8DBf-4CzBfpm was synthesized. The synthesis was performed in the following procedure.

Into a 200-mL three-neck flask were put 1.7 g (4.5 mmol) of 4-(9H-carbazol-9-yl)-8-chloro-[1]benzofuro[3,2-d]pyrimidine obtained in Step 1 of Reference synthesis example 4, 2.3 g (4.9 mmol) of 2-[3-(triphenylsilyl)phenyl]-4,4,5,5-tetramethyl-1,3,2-dioxaborolane, 96 mg (0.27 mmol) of di(1-adamantyl)-n-butylphosphine, 2.9 g (13 mmol) of tripotassium phosphate, and 1.0 g (13 mmol) of tert-butanol. To this mixture was added 40 mL of diethylene glycol dimethyl ether. The mixture was degassed by being stirred while the pressure was reduced. To this mixture was added 30 mg (0.13 mmol) of palladium (II) acetate, and the mixture was stirred under a nitrogen stream at 120° C. for 6 hours. After the stirring, water was added to the mixture, and the solid was collected by suction filtration. This solid was purified by silica gel column chromatography (developing solvent:toluene and then toluene and ethyl acetate in a 50:1 ratio). The obtained solid was recrystallized from ethyl acetate to give 2.3 g of a white solid in a yield of 77%. Then, 2.3 g of the obtained solid was purified by a train sublimation method. The purification by sublimation was performed by heating at 290° C. under a pressure of 3.6 Pa with an argon flow rate of 15 mL/min. After the sublimation purification, 2.2 g of a white solid was obtained at a collection rate of 94%. The synthesis scheme is shown in (e-1) below.

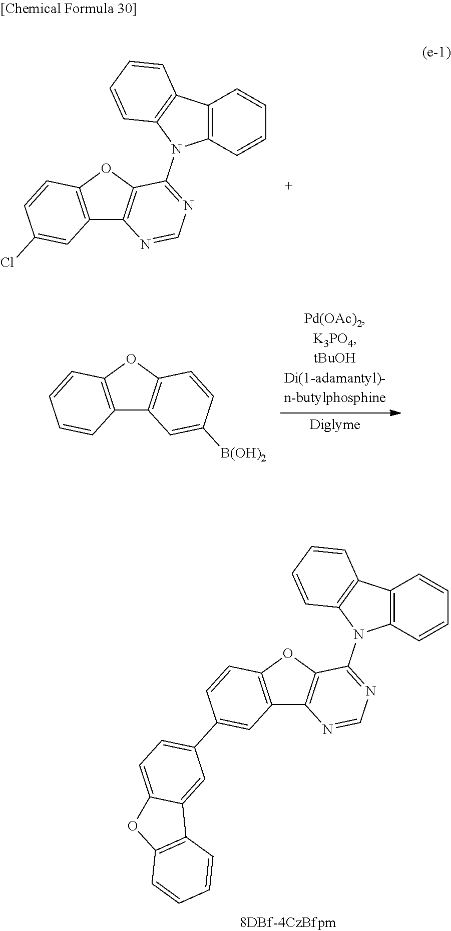 [SMILES: Clc1ccc2oc3c(-n4c5ccccc5c5ccccc54)ncnc3c2c1 ; OB(O)c1ccc2oc3ccccc3c2c1 ; c1ccc2c(c1)oc1ccc(-c3ccc4oc5c(-n6c7ccccc7c7ccccc76)ncnc5c4c3)cc12]

### <Characteristics of Organic Compound>

Analysis results by nuclear magnetic resonance spectroscopy (¹H NMR) of a CDCl₃solution of the obtained white solid are shown below. The results confirm that 8DBf-4CzBfpm was obtained in this synthesis example.

¹H NMR (CDCl₃, 300 MHz): δ=7.38-7.54 (m, 6H), 7.62-7.82 (m, 4H), 7.86 (d, J1=7.8 Hz, 2H), 8.03-8.07 (m, 2H), 8.17 (d, J1=7.2 Hz, 2H), 8.28 (d, J1=1.5 Hz, 1H), 8.63 (d, J1=1.5 Hz, 1H), 9.31 (s, 1H).

This application is based on Japanese Patent Application Serial No. 2024-115982 filed with Japan Patent Office on Jul. 19, 2024, the entire contents of which are hereby incorporated by reference.

What is claimed is:

1. A light-emitting device comprising:
a first electrode;
a second electrode;
a light-emitting layer;
a first layer; and
a second layer,
wherein the first electrode is over a substrate and is between the second electrode and the substrate,
wherein the light-emitting layer is between the first electrode and the second electrode,
wherein the first layer is between the first electrode and the light-emitting layer,
wherein the second layer is between the second electrode and the light-emitting layer,
wherein one of the first electrode and the second electrode is an anode and the other is a cathode,
wherein a GSP slope (mV/nm) of one of the light-emitting layer and the first layer closer to the cathode is larger than a GSP slope (mV/nm) of the other closer to the anode,
wherein a GSP slope (mV/nm) of one of the light-emitting layer and the second layer closer to the anode is larger than a GSP slope (mV/nm) of the other closer to the cathode, and
wherein the GSP slope (mV/nm) is a parameter represented by ΔV/Δd, where ΔV (mV) is an amount of change in a surface potential with respect to an amount of change in a thickness Δd (nm).

2. The light-emitting device according to claim 1,
wherein the first electrode is an anode,
wherein the second electrode is a cathode,
wherein the GSP slope (mV/nm) of the light-emitting layer is larger than the GSP slope (mV/nm) of the first layer, and
wherein the GSP slope (mV/nm) of the light-emitting layer is larger than the GSP slope (mV/nm) of the second layer.

3. The light-emitting device according to claim 1,
wherein the first electrode is a cathode,
wherein the second electrode is an anode,
wherein the GSP slope (mV/nm) of the first layer is larger than the GSP slope (mV/nm) of the light-emitting layer, and
wherein the GSP slope (mV/nm) of the second layer is larger than the GSP slope (mV/nm) of the light-emitting layer.

4. The light-emitting device according to claim 1,
wherein at a peak wavelength of an electroluminescence spectrum of the light-emitting device, a refractive index of at least one of the first layer and the second layer is less than or equal to 1.75.

5. The light-emitting device according to claim 1, further comprising:
a third layer; and
a fourth layer,
wherein the third layer is between the first layer and the first electrode,
wherein the fourth layer is between the second layer and the second electrode,
wherein a GSP slope (mV/nm) of one of the first layer and the third layer closer to the cathode is larger than a GSP slope (mV/nm) of the other closer to the anode, and
wherein a GSP slope (mV/nm) of one of the second layer and the fourth layer closer to the anode is larger than a GSP slope (mV/nm) of the other closer to the cathode.

6. The light-emitting device according to claim 2, further comprising:
a third layer; and
a fourth layer,
wherein the third layer is between the first layer and the first electrode,
wherein the fourth layer is between the second layer and the second electrode,
wherein the GSP slope (mV/nm) of the first layer is larger than a GSP slope (mV/nm) of the third layer, and
wherein the GSP slope (mV/nm) of the second layer is larger than a GSP slope (mV/nm) of the fourth layer.

7. The light-emitting device according to claim 3, further comprising:
a third layer; and
a fourth layer,
wherein the third layer is between the first layer and the first electrode,
wherein the fourth layer is between the second layer and the second electrode,
wherein a GSP slope (mV/nm) of the third layer is larger than the GSP slope (mV/nm) of the first layer, and
wherein a GSP slope (mV/nm) of the fourth layer is larger than the GSP slope (mV/nm) of the second layer.

8. The light-emitting device according to claim 5,
wherein at a peak wavelength of an electroluminescence spectrum of the light-emitting device, a refractive index of at least one of the first layer, the second layer, the third layer, and the fourth layer is less than or equal to 1.75.

9. A light-emitting device comprising:
a first electrode;
a second electrode;
a light-emitting layer;
a first layer; and
a second layer,
wherein the first electrode is over a substrate and is between the second electrode and the substrate,
wherein the light-emitting layer is between the first electrode and the second electrode,
wherein the first layer is between the first electrode and the light-emitting layer,
wherein the second layer is between the second electrode and the light-emitting layer,
wherein the first electrode is an anode,
wherein the second electrode is a cathode,
wherein the light-emitting layer comprises a first host material and a light-emitting substance,
wherein the first layer comprises a first organic compound,
wherein the second layer comprises a second organic compound,
wherein a GSP slope (mV/nm) of an evaporated film of the first host material is larger than a GSP slope (mV/nm) of an evaporated film of the first organic compound,
wherein the GSP slope (mV/nm) of the evaporated film of the first host material is larger than a GSP slope (mV/nm) of an evaporated film of the second organic compound, and
wherein the GSP slope (mV/nm) is a parameter represented by ΔV/Δd, where ΔV (mV) is an amount of change in a surface potential with respect to an amount of change in a thickness Δd (nm).

10. A light-emitting device comprising:
a first electrode;
a second electrode;
a light-emitting layer;
a first layer; and
a second layer,
wherein the first electrode is over a substrate and is between the second electrode and the substrate,
wherein the light-emitting layer is between the first electrode and the second electrode,
wherein the first layer is between the first electrode and the light-emitting layer,
wherein the second layer is between the second electrode and the light-emitting layer,
wherein the first electrode is a cathode,
wherein the second electrode is an anode,
wherein the light-emitting layer comprises a first host material and a light-emitting substance,
wherein the first layer comprises a first organic compound,
wherein the second layer comprises a second organic compound,
wherein a GSP slope (mV/nm) of an evaporated film of the first organic compound is larger than a GSP slope (mV/nm) of an evaporated film of the first host material,
wherein a GSP slope (mV/nm) of an evaporated film of the second organic compound is larger than the GSP slope (mV/nm) of the evaporated film of the first host material, and
wherein the GSP slope (mV/nm) is a parameter represented by ΔV/Δd, where ΔV (mV) is an amount of change in a surface potential with respect to an amount of change in a thickness Δd (nm).

11. The light-emitting device according to claim 9,
wherein the light-emitting layer further comprises a second host material,
wherein an average GSP slope (mV/nm) of the evaporated film of the first host material and an evaporated film of the second host material is larger than the GSP slope (mV/nm) of the evaporated film of the first organic compound, and
wherein the average GSP slope (mV/nm) of the evaporated film of the first host material and the evaporated film of the second host material is larger than the GSP slope (mV/nm) of the evaporated film of the second organic compound.

12. The light-emitting device according to claim 10,
wherein the light-emitting layer further comprises a second host material,
wherein the GSP slope (mV/nm) of the evaporated film of the first organic compound is larger than an average GSP slope (mV/nm) of the evaporated film of the first host material and an evaporated film of the second host material, and
wherein the GSP slope (mV/nm) of the evaporated film of the second organic compound is larger than the average GSP slope (mV/nm) of the evaporated film of the first host material and the evaporated film of the second host material.

13. The light-emitting device according to claim 9,
wherein at a peak wavelength of an electroluminescence spectrum of the light-emitting device, a refractive index of at least one of a film of the first organic compound and a film of the second organic compound is less than or equal to 1.75.

14. The light-emitting device according to claim 9,
wherein at least one of the first organic compound and the second organic compound comprises at least one group selected from chain alkyl groups having 2 to 10 carbon atoms and cycloalkyl groups having 6 to 12 carbon atoms.

15. The light-emitting device according to claim 9, further comprising:
a third layer; and
a fourth layer,
wherein the third layer is between the first layer and the first electrode,
wherein the fourth layer is between the second layer and the second electrode,
wherein the third layer comprises a third organic compound,
wherein the fourth layer comprises a fourth organic compound,
wherein the GSP slope (mV/nm) of the evaporated film of the first organic compound is larger than a GSP slope (mV/nm) of an evaporated film of the third organic compound, and
wherein the GSP slope (mV/nm) of the evaporated film of the second organic compound is larger than a GSP slope (mV/nm) of an evaporated film of the fourth organic compound.

16. The light-emitting device according to claim 10, further comprising:
a third layer; and
a fourth layer,
wherein the third layer is between the first layer and the first electrode,
wherein the fourth layer is between the second layer and the second electrode,
wherein the third layer comprises a third organic compound,
wherein the fourth layer comprises a fourth organic compound,
wherein a GSP slope (mV/nm) of an evaporated film of the third organic compound is larger than the GSP slope (mV/nm) of the evaporated film of the first organic compound, and
wherein a GSP slope (mV/nm) of an evaporated film of the fourth organic compound is larger than the GSP slope (mV/nm) of the evaporated film of the second organic compound.

17. The light-emitting device according to claim 15,
wherein at a peak wavelength of an electroluminescence spectrum of the light-emitting device, a refractive index of at least one of a film of the first organic compound, a film of the second organic compound, a film of the third organic compound, and a film of the fourth organic compound is less than or equal to 1.75.

18. The light-emitting device according to claim 15,
wherein at least one of the first organic compound, the second organic compound, the third organic compound, and the fourth organic compound comprises at least one group selected from chain alkyl groups having 2 to 10 carbon atoms and cycloalkyl groups having 6 to 12 carbon atoms.

19. The light-emitting device according to claim 15,
wherein the first organic compound and the third organic compound each independently comprise a π-electron rich heteroaromatic ring or an aromatic amine skeleton, and
wherein a HOMO level of the third organic compound is higher than a HOMO level of the first organic compound.
